(19) United States
(12) Patent Application Publication
(10) Pub. No.: US 2023/0120766 A1
(43) Pub. Date: Apr. 20, 2023

(54) FUSED POLYCYCLIC COMPOUND AND LIGHT EMITTING DEVICE INCLUDING THE SAME

(71) Applicant: Samsung Display Co., Ltd., Yongin-si (KR)

(72) Inventors: Yuji SUZAKI, Yokohama (JP); Hirokazu KUWABARA, Yokohama (JP); Ryuhei FURUE, Yokohama (JP); Tetuji HAYANO, Yokohama (JP)

(73) Assignee: Samsung Display Co., Ltd., Yongin-si (KR)

(21) Appl. No.: 17/834,464

(22) Filed: Jun. 7, 2022

(30) Foreign Application Priority Data
Aug. 30, 2021 (KR) 10-2021-0114985

(51) Int. Cl. H01L 51/00; C07F 5/02; C09K 11/06

(52) U.S. Cl. CPC H01L 51/008; C07F 5/027; C09K 11/06; H01L 51/0072; C09K 2211/1022; H01L 51/5016

(57) ABSTRACT

A light emitting device includes an emission layer disposed between electrodes. The emission layer includes a host and a delayed fluorescence dopant. The delayed fluorescence dopant includes a fused polycyclic compound represented by Formula 1:

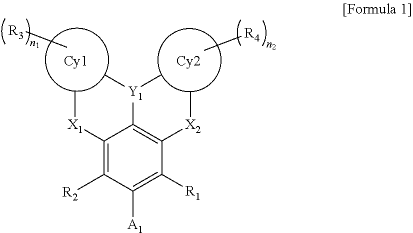

### CROSS-REFERENCE TO RELATED APPLICATION(S)

This U.S. non-provisional patent application claims priority to and benefits of Korean Patent Application No. 10-2021-0114985 under 35 U.S.C. § 119, filed on Aug. 30, 2021 in the Korean Intellectual Property Office, the entire contents of which are hereby incorporated by reference.

### BACKGROUND

The disclosure herein relates to a fused polycyclic compound and a light emitting device including the same, and more particularly, to a light emitting device including a novel fused polycyclic compound used as a luminescent material.

Recently, there have been the development of an organic electroluminescence display apparatus as an image display apparatus. Compared with liquid crystal display apparatuses and the like, the organic electroluminescence display apparatus is called self-luminescent display apparatus in which holes and electrons injected from a first electrode and a second electrode recombine in an emission layer, and thus a luminescent material including an organic compound in the emission layer emits light to display an image.

In the application of an organic electroluminescence device to a display, decrease of the driving voltage, increase of the emission efficiency, and longer life of the organic electroluminescence device are desired. Thus, there has been development of materials for stably attaining an organic electroluminescence device with the desired properties.

In order to accomplish an organic electroluminescence device with high efficiency, there have been developments on techniques such as phosphorescence emission which uses energy in a triplet state, and delayed fluorescence emission which uses the generating phenomenon of singlet excitons by the collision of triplet excitons (triplet-triplet annihilation, TTA). Also, development has been made on a material for thermally activated delayed fluorescence (TADF) using delayed fluorescence phenomenon.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting device in which luminous efficiency and a device service life are improved.

The disclosure also provides a fused polycyclic compound capable of improving luminous efficiency and a device service life of a light emitting device.

In an embodiment, provided is a fused polycyclic compound represented by Formula 1.

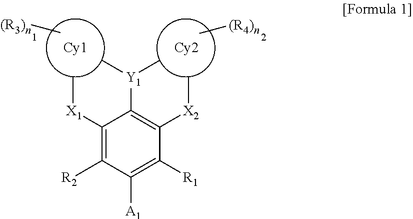

In Formula 1, Y₁ is P, B, or N, X₁ and X₂ are each independently O, S, CR₅R₆, PR₇, SiR₈R₉, NR₁₀, or BR₁₁, or are represented by Formula 2, Cy1 and Cy2 are each independently a monocyclic aromatic hydrocarbon ring having 6 to 30 ring-forming carbon atoms, or a monocyclic aromatic heterocycle having 2 to 30 ring-forming carbon atoms, A₁ is a hydrogen atom, a deuterium atom, a substituted or unsubstituted amine group, a substituted or unsubstituted oxy group, a substituted or unsubstituted silyl group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are represented by Formula 3, R₁, R₂, and R₅ to R₁₁ are each independently a hydrogen atom, a deuterium atom, a halogen atom, a cyano group, a nitro group, a substituted or unsubstituted amine group, a substituted or unsubstituted silyl group, a substituted or unsubstituted boron group, a substituted or unsubstituted oxy group, a substituted or unsubstituted thio group, a substituted or unsubstituted phosphine group, a substituted or unsubstituted alkyl group having 1 to 30 carbon atoms, a substituted or unsubstituted alkenyl group having 2 to 30 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring, R₃ and R₄ are each independently a hydrogen atom, a deuterium atom, a halogen atom, a cyano group, a nitro group, a substituted or unsubstituted amine group, a substituted or unsubstituted silyl group, a substituted or unsubstituted boron group, a substituted or unsubstituted oxy group, a substituted or unsubstituted thio group, a substituted or unsubstituted phosphine group, a substituted or unsubstituted alkyl group having 1 to 30 carbon atoms, a substituted or unsubstituted alkenyl group having 2 to 30 carbon atoms, a substituted or unsubstituted aryl group having 6 to 60 ring-forming carbon atoms, a substituted or unsubstituted heteroaryl group having 2 to 60 ring-forming carbon atoms, or are represented by Formula 3, or are bonded to an adjacent group to form a ring, and at least one of X₁ or X₂ is represented by Formula 2, or at least one of A₁, R₃, or R₄ is represented by Formula 3, or at least one of X₁ or X₂ is represented by Formula 2 and at least one of A₁, R₃, or R₄ is represented by Formula 3, and when each of R₃ and R₄ is bonded to an adjacent group to form a ring, the formed ring does not include Si as a ring-forming atom, and when neither R₃ nor R₄ is bonded to an adjacent group to form a ring, at least one of X₁ or X₂ is S, and n₁ and n₂ are each independently an integer of 0 to 4.

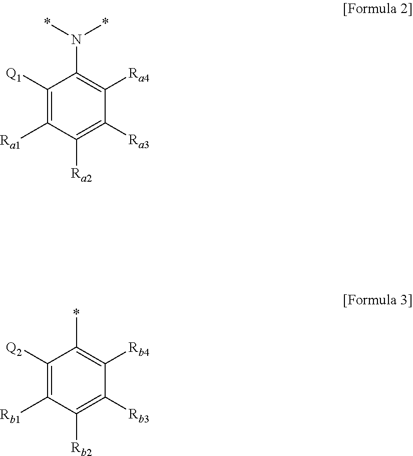

In Formula 2 and Formula 3, Q₁ and Q₂ are each independently a substituted or unsubstituted arylamine group, a substituted or unsubstituted arylsilyl group, a substituted or unsubstituted arylthio group, a substituted or unsubstituted aryloxy group, a substituted or unsubstituted alkyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, Rₐ₁ to Rₐ₄ and R_{b1} to R_{b4} are each independently a hydrogen atom, a deuterium atom, a halogen atom, a cyano group, a nitro group, a substituted or unsubstituted amine group, a substituted or unsubstituted silyl group, a substituted or unsubstituted boron group, a substituted or unsubstituted oxy group, a substituted or unsubstituted thio group, a substituted or unsubstituted phosphine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In an embodiment, when at least one of X₁ or X₂ is represented by Formula 2, the at least one of X₁ or X₂ represented by Formula 2 may be represented by Formula 2-1 or Formula 2-2:

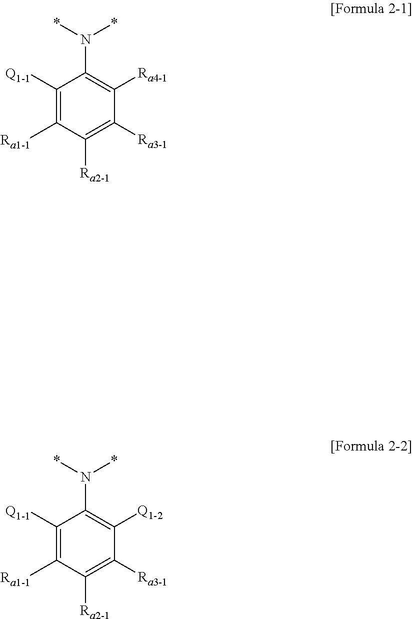

In Formula 2-1 and Formula 2-2, Q₁₋₁ and Q₁₋₂ are each independently a substituted or unsubstituted arylamine group, a substituted or unsubstituted arylsilyl group, a substituted or unsubstituted arylthio group, a substituted or unsubstituted aryloxy group, a substituted or unsubstituted alkyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and Rₐ₁₋₁ to Rₐ₄₋₁ are each independently a hydrogen atom, a deuterium atom, a substituted or unsubstituted alkyl group having 1 to 20 carbon atoms, a substituted or unsubstituted aryl group having 6 to 30 ring-forming carbon atoms.

In an embodiment, when A₁ is represented by Formula 3, A₁ may be represented by one of Formula 3-1 to 3-5:

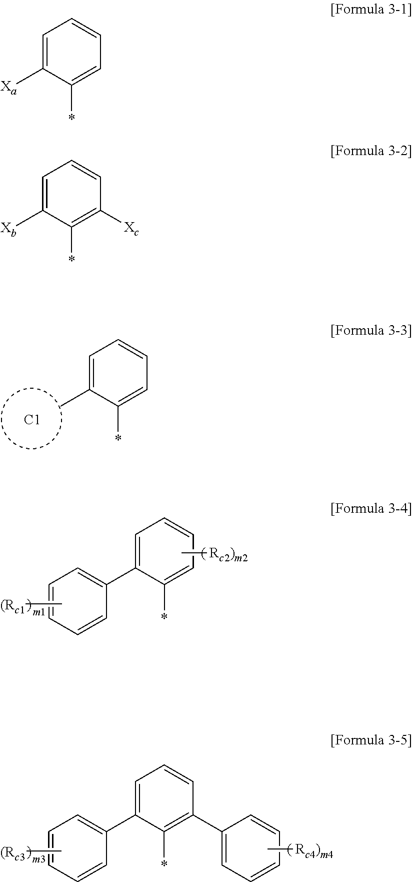

In Formula 3-1 to Formula 3-5, Xₐ to X_{c} are each independently NR_{c5}R_{c6}, SR_{c7}, OR_{c8}, SiR_{c9}R_{c10}R_{c11}, or a substituted or unsubstituted alkyl group having 2 to 10 carbon atoms, C1 is a substituted or unsubstituted cycloalkyl group having 3 to 10 carbon atoms, R_{c1} to R_{c4} are each independently a hydrogen atom, a deuterium atom, a halogen atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring, R_{c5} to R_{c11} are each independently a substituted or unsubstituted phenyl group, m1, m3, and m4 are each independently an integer of 0 to 5, and m2 is an integer of 0 to 4.

In an embodiment, the fused polycyclic compound represented by Formula 1 may be represented by Formula 1-1:

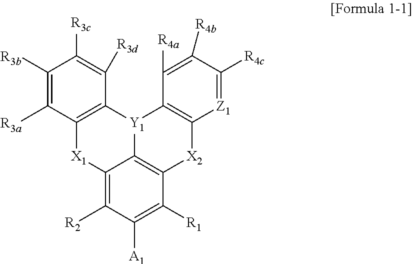

In Formula 1-1, Z₁ is CR_{4d} or N, R₃ₐ to R_{3d} and R₄ₐ to R_{4d} are each independently a hydrogen atom, a deuterium atom, a halogen atom, a cyano group, a nitro group, a substituted or unsubstituted amine group, a substituted or unsubstituted silyl group, a substituted or unsubstituted boron group, a substituted or unsubstituted oxy group, a substituted or unsubstituted thio group, a substituted or unsubstituted phosphine group, a substituted or unsubstituted alkyl group having 1 to 30 carbon atoms, a substituted or unsubstituted alkenyl group having 2 to 30 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring, at least one of X₁ or X₂ is represented by Formula 2, at least one among A₁, R₃ₐ to R_{3d}, and R₄ₐ to R_{4c} is represented by Formula 3, or at least one of X₁ or X₂ is represented by Formula 2, at least one among A₁, R₃ₐ to R_{3d}, and R₄ₐ to R_{4c} is represented by Formula 3, and when each of R₃ₐ to R_{3d} and R₄ₐ to R_{4d} is bonded to an adjacent group to form a ring, the formed ring does not include Si as a ring-forming atom, and when none of R₃ₐ to R_{3d} and R₄ₐ to R_{4d} is bonded to an adjacent group to form a ring, at least one of X₁ or X₂ is S.

In Formula 1-1, the same as defined in Formula 1 above may be applied to X₁, X₂, Y₁, A₁, R₁, and R₂.

In an embodiment, the fused polycyclic compound represented by Formula 1-1 may be represented by Formula 1-2:

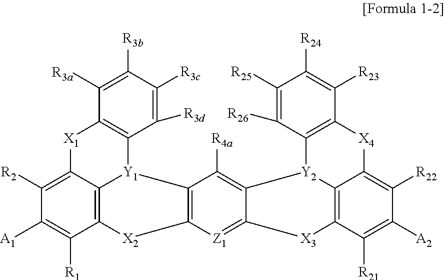

In Formula 1-2, Y₂ is P, B, or N, X₃ and X₄ are each independently O, S, CR₂₇R₂₈, PR₂₉, NR₃₀, or BR₃₁ or are represented by Formula 2, A₂ is a hydrogen atom, a deuterium atom, a substituted or unsubstituted amine group, a substituted or unsubstituted oxy group, a substituted or unsubstituted silyl group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or is represented by Formula 3, and R₂₁ to R₃₁ are each independently a hydrogen atom, a deuterium atom, a halogen atom, a cyano group, a nitro group, a substituted or unsubstituted amine group, a substituted or unsubstituted silyl group, a substituted or unsubstituted boron group, a substituted or unsubstituted oxy group, a substituted or unsubstituted thio group, a substituted or unsubstituted phosphine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring.

In Formula 1-2, the same as defined in Formula 1 and Formula 1-1 may be applied to X₁, X₂, Y₁, Z₁, A₁, R₁, R₂, R₃ₐ to R_{3d}, and R₄ₐ.

In an embodiment, A₁ and A₂ may be each independently a substituted or unsubstituted alkyl group having 1 to 10 carbon atoms, or may be represented by Formula 3 or one of Formula 4-1 to Formula 4-5:

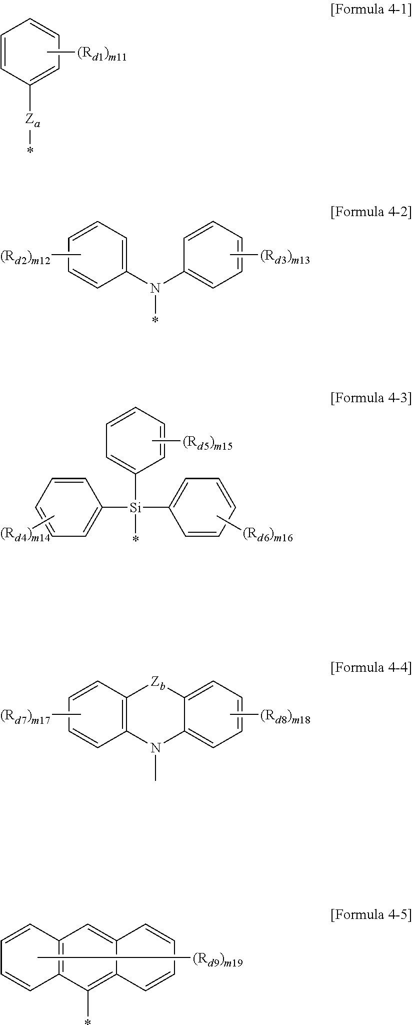

In Formula 4-1 to Formula 4-5, Zₐ is a direct linkage or O, Z_{b} is a direct linkage, CR_{d10}R_{d11}, or SiR_{d12}R_{d13}, R_{d1} is a hydrogen atom, a deuterium atom, a halogen atom, a nitro group, a substituted or unsubstituted alkyl group having 1 to 10 carbon atoms, a substituted or unsubstituted silyl group, or a substituted or unsubstituted phenyl group, R_{d2} to R_{d13} are each independently a hydrogen atom, a deuterium atom, a halogen atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring, m11 to m16 are each independently an integer of 0 to 5, m17 and m18 are each independently an integer of 0 to 4, and m19 is an integer of 0 to 9.

In an embodiment, the fused polycyclic compound represented by Formula 1-2 may be represented by one of Formula 5-1 to Formula 5-10:

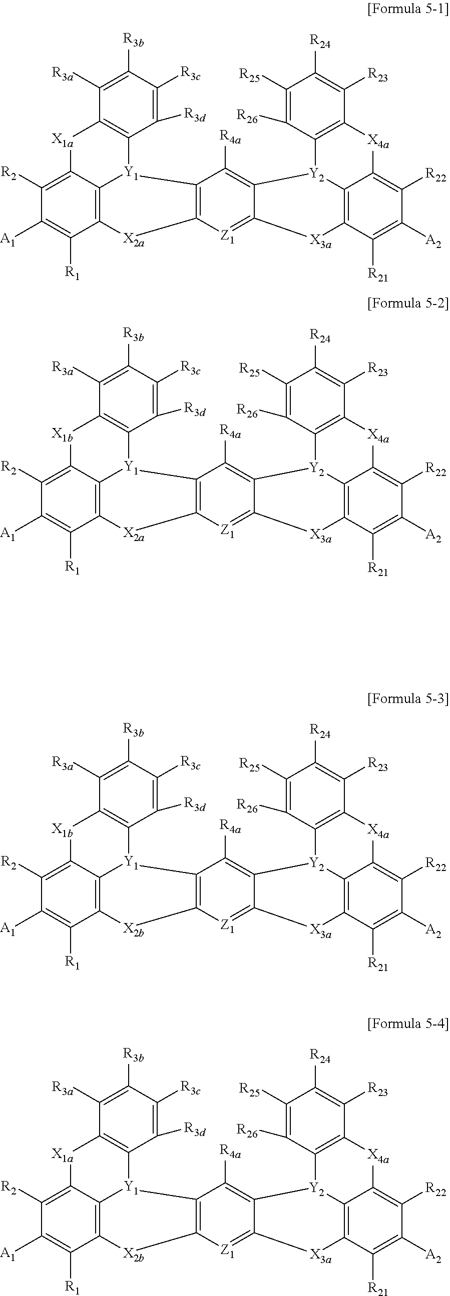

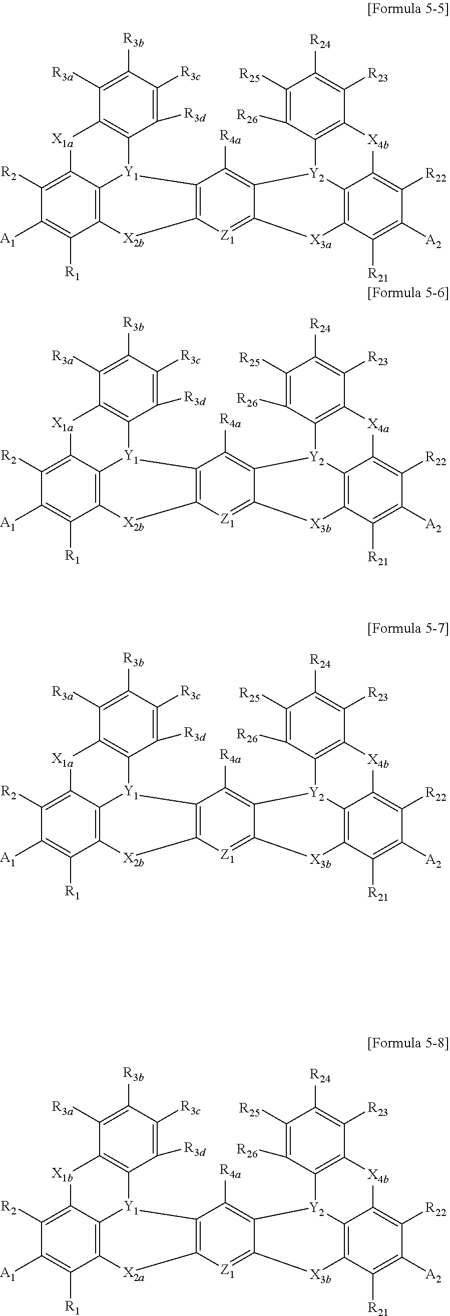

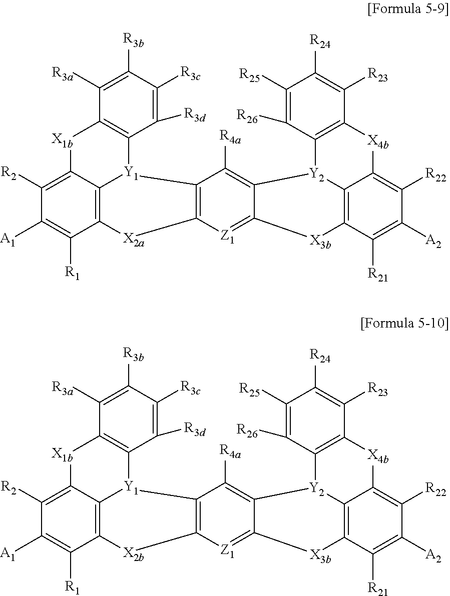

In Formula 5-1 to Formula 5-10, X₁ₐ to X₄ₐ are each independently represented by Formula 2, X_{1b} to X_{4b} are each independently O, S, CR₄₁R₄₂, PR₄₃, NR₄₄, or BR₄₅, and R₄₁ to R₄₅ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula 5-1 to Formula 5-10, the same as defined in Formula 1, Formula 1-1, and Formula 1-2 may be applied to Z₁, A₁, A₂, Y₁, Y₂, R₁, R₂, R₃ₐ to R_{3d}, R₄ₐ, and R₂₁ to R₂₆.

In an embodiment, the fused polycyclic compound represented by Formula 1-2 may be represented by one of Formula 6-1 to Formula 6-4:

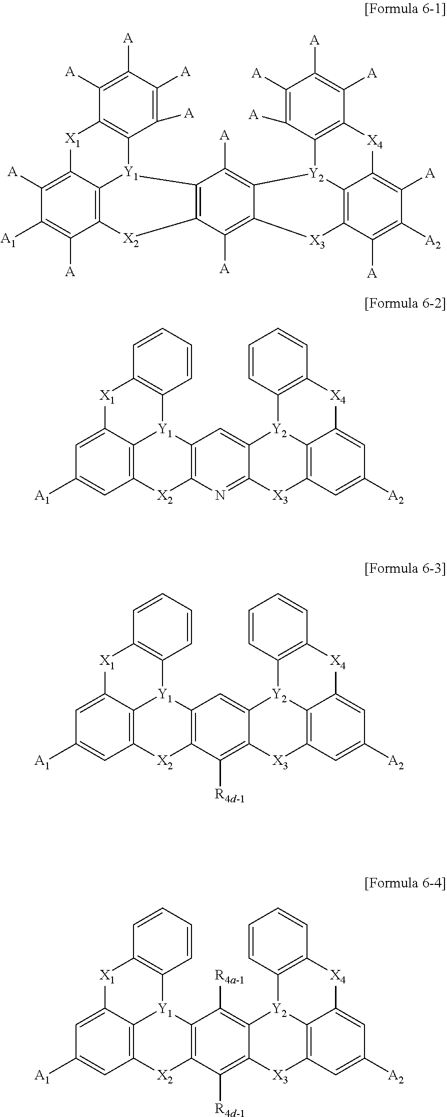

In Formula 6-1 to Formula 6-4, A is a hydrogen atom or a dideuterium atom, and R₄ₐ₋₁ and R_{4d-1} are each independently a substituted or unsubstituted silyl group, a substituted or unsubstituted alkyl group having 1 to 20 carbon atoms, or a substituted or unsubstituted aryl group having 6 to 30 ring-forming carbon atoms.

In Formula 6-1 to Formula 6-4, the same as defined in Formula 1 and Formula 1-2 may be applied to X₁ to X₄, Y₁, Y₂, A₁, and A₂.

In an embodiment, the fused polycyclic compound represented by Formula 1-2 may be represented by one of Formula 7-1 to Formula 7-5:

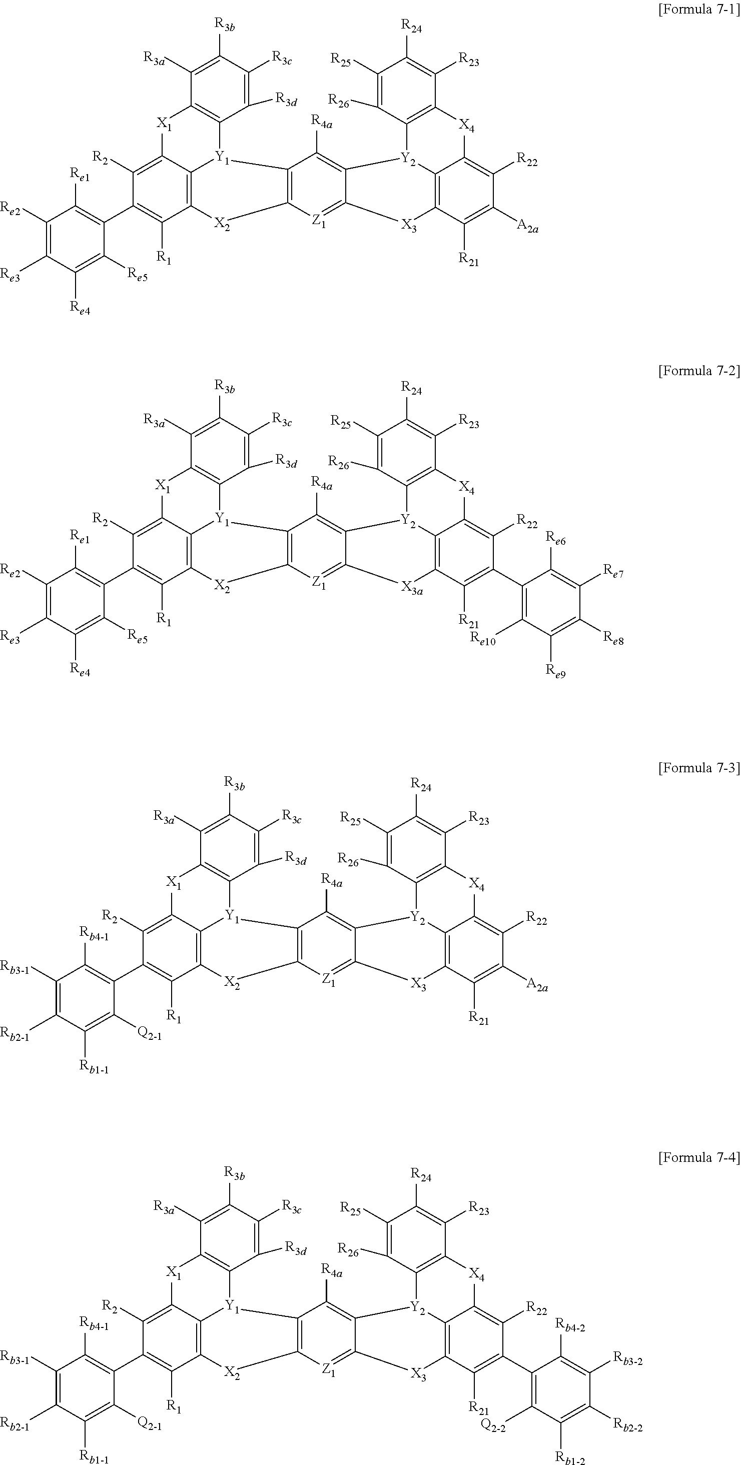

In Formula 7-1 to Formula 7-4, A₂ₐ is a hydrogen atom, a deuterium atom, a substituted or unsubstituted amine group, a substituted or unsubstituted oxy group, a substituted or unsubstituted silyl group, a substituted or unsubstituted alkyl group having 1 to 20 carbon atoms, or a substituted or unsubstituted heteroaryl group containing N as a ring-forming atom, Rₑ₁ to Rₑ₁₀ are each independently a hydrogen atom, a deuterium atom, a halogen atom, a nitro group, a substituted or unsubstituted silyl group, a substituted or unsubstituted methyl group, a substituted or unsubstituted alkenyl group having 2 to 20 carbon atoms, or a substituted or unsubstituted phenyl group, or are bonded to an adjacent group to form a ring, Q₂₋₁ and Q₂₋₂ are each independently a substituted or unsubstituted arylamine group, a substituted or unsubstituted arylsilyl group, a substituted or unsubstituted arylthio group, a substituted or unsubstituted aryloxy group, a substituted or unsubstituted alkyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and R_{b1-1} to R_{b4-1}, and R_{b1-2} to R_{b4-2} are each independently a hydrogen atom, a deuterium atom, a substituted or unsubstituted alkyl group having 1 to 20 carbon atoms, or a substituted or unsubstituted aryl group having 6 to 30 ring-forming carbon atoms.

In Formula 7-1 to Formula 7-4, the same as defined in Formula 1, Formula 1-1, and Formula 1-2 may be applied to X₁ to X₄, Y₁, Y₂, Z₁, R₁, R₂, R₃ₐ to R_{3d}, R₄ₐ, and R₂₁ to R₂₆.

In an embodiment, a light emitting device may include a first electrode, a second electrode facing the first electrode, and an emission layer disposed between the first electrode and the second electrode. The emission layer may include a host and a delayed fluorescence dopant. The host may include a compound represented by Formula E-2a or Formula E-2b. The delayed fluorescence dopant may include a fused polycyclic compound represented by Formula 1.

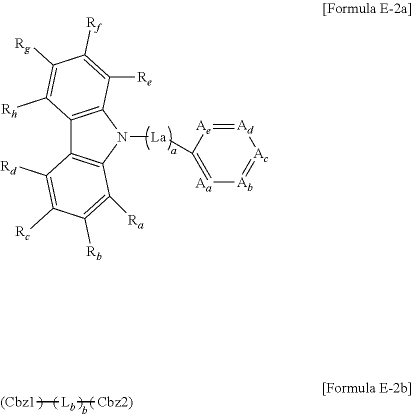

In Formula E-2a, a is an integer of 0 to 10, Lₐ is a direct linkage, a substituted or unsubstituted arylene group having 6 to 30 ring-forming carbon atoms, or a substituted or unsubstituted heteroarylene group having 2 to 30 ring-forming carbon atoms, Aₐ to Aₑ are each independently N or CRᵢ, Rₐ to Rᵢ are each independently a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring, and two or three selected from among Aₐ to Aₑ are N, and the others are CRᵢ.

In Formula E-2b, Cbz1 and Cbz2 are each independently an unsubstituted carbazole group, or a carbazole group substituted with an aryl group having 6 to 30 ring-forming carbon atoms, L_{b} is a direct linkage, a substituted or unsubstituted arylene group having 6 to 30 ring-forming carbon atoms, or a substituted or unsubstituted heteroarylene group having 2 to 30 ring-forming carbon atoms, and b is an integer of 0 to 10.

### BRIEF DESCRIPTION OF THE DRAWINGS

The accompanying drawings are incorporated in and constitute a part of this specification. The drawings illustrate the embodiments together with the description. In the drawings:

FIG. 1 is a plan view of a display apparatus according to an embodiment;

FIG. 2 is a cross-sectional view of a display apparatus according to an embodiment;

FIG. 3 is a cross-sectional view schematically illustrating a light emitting device according to an embodiment;

FIG. 4 is a cross-sectional view schematically illustrating a light emitting device according to an embodiment;

FIG. 5 is a cross-sectional view schematically illustrating a light emitting device according to an embodiment;

FIG. 6 is a cross-sectional view schematically illustrating a light emitting device according to an embodiment;

FIGS. 7 and 8 are cross-sectional views of a display apparatus according to an embodiment.

FIG. 9 is a cross-sectional view illustrating a display apparatus according to an embodiment; and

FIG. 10 is a cross-sectional view illustrating a display apparatus according to an embodiment.

### DETAILED DESCRIPTION OF THE EMBODIMENTS

The embodiments may be modified in various alternate forms. It should be understood that it is not intended to limit the invention to the embodiments disclosed herein. Instead it is intended to cover all modifications, equivalents, and alternatives falling within the spirit and scope of the invention.

When explaining each of drawings, like reference numbers are used for referring to like elements. In the accompanying drawings, the dimensions of each structure are exaggeratingly illustrated for clarity of the present disclosure. It will be understood that, although the terms “first,” “second,” etc. may be used herein to describe various components, these components should not be limited by these terms. These terms are only used to distinguish one component from another. For example, a first component may be referred to as a second component, and, similarly, the second component may be referred to as the first component, without departing from the scope of the inventive concept. As used herein, the singular forms, “a”, “an” and “the” are intended to include the plural forms as well, unless the context clearly indicates otherwise.

In the present application, it will be understood that the terms “include,” “have” etc., specify the presence of a feature, a fixed number, a step, an operation, an element, a component, or a combination thereof disclosed in the disclosure, but do not exclude the possibility of presence or addition of one or more other features, fixed numbers, steps, operations, elements, components, or combination thereof.

In the present application, when a part such as a layer, a film, a region, or a plate is referred to as being “on” or “above” another part, it can be directly on the other part, or an intervening part may also be present. On the contrary, when a part such as a layer, a film, a region, or a plate is referred to as being “under” or “below” another part, it can be directly under the other part, or an intervening part may also be present. In addition, it will be understood that when a part is referred to as being “on” another part, it can be disposed on the other part, or disposed under the other part as well.

In the disclosure, the term “substituted or unsubstituted” may mean substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, an alkoxy group, a hydrocarbon ring group, an aryl group, and a heterocyclic group. In addition, each of the above-mentioned substituents may be substituted or unsubstituted. For example, a biphenyl group may be interpreted as an aryl group or a phenyl group substituted with a phenyl group.

In the disclosure, the phrase “bonded to an adjacent group to form a ring” may indicate that one is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocyclic or polycyclic. In addition, the rings formed by being bonded to each other may be connected to another ring to form a spiro structure.

In the disclosure, the term “adjacent group” may mean a substituent substituted for an atom that is directly linked to an atom substituted with a corresponding substituent, another substituent substituted for an atom that is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In addition, two methyl groups in 4,5-dimethylphenanthrene may be interpreted as “adjacent groups” to each other.

In the disclosure, examples of the halogen atom may include a fluorine atom, a chlorine atom, a bromine atom, or an iodine atom.

In the disclosure, the alkyl group may be a linear, branched or cyclic type. The number of carbons in the alkyl group is 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but the embodiment is not limited thereto.

In the disclosure, a cycloalkyl group may mean a cyclic alkyl group. The number of carbons in the cycloalkyl group is 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but the embodiment is not limited thereto.

In the disclosure, an alkenyl group means a hydrocarbon group including at least one carbon double bond in the middle or terminal of an alkyl group having 2 or more carbon atoms. The alkenyl group may be a linear chain or a branched chain. The carbon number is not specifically limited, but is 2 to 30, 2 to 20 or 2 to 10. Examples of the alkenyl group include a vinyl group, a 1-butenyl group, a 1-pentenyl group, a 1,3-butadienyl aryl group, a styrenyl group, a styrylvinyl group, etc., without limitation.

The hydrocarbon ring group herein means any functional group or substituent derived from an aliphatic hydrocarbon ring. The hydrocarbon ring group may be a saturated hydrocarbon ring group having 5 to 20 ring-forming carbon atoms.

In the disclosure, an aryl group means any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but the embodiment is not limited thereto.

The heterocyclic group herein means any functional group or substituent derived from a ring including at least one of B, O, N, P, Si, or Se as a heteroatom. The heterocyclic group includes an aliphatic heterocyclic group and an aromatic heterocyclic group. The aromatic heterocyclic group may be a heteroaryl group. The aliphatic heterocycle and the aromatic heterocycle may be monocyclic or polycyclic.

In the disclosure, the heterocyclic group may include at least one of B, O, N, P, Si or S as a heteroatom. If the heterocyclic group includes two or more heteroatoms, the two or more heteroatoms may be the same as or different from each other. The heterocyclic group may be a monocyclic heterocyclic group or a polycyclic heterocyclic group and has the concept including a heteroaryl group. The number of ring-forming carbon atoms in the heterocyclic group may be 2 to 30, 2 to 20, or 2 to 10.

In the disclosure, the heteroaryl group may include at least one of B, O, N, P, Si, or S as a heteroatom. When the heteroaryl group contains two or more heteroatoms, the two or more heteroatoms may be the same as or different from each other. The heteroaryl group may be a monocyclic heteroaryl group or polycyclic heteroaryl group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but the embodiment is not limited thereto.

In the disclosure, a silyl group includes an alkylsilyl group and an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but the embodiment is not limited thereto.

In the disclosure, a thio group may include an alkylthio group and an arylthio group. The thio group may mean that a sulfur atom is bonded to the alkyl group or the aryl group as defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but the embodiment is not limited thereto.

In the disclosure, an oxy group may mean that an oxygen atom is bonded to the alkyl group or the aryl group as defined above. The oxy group may include an alkoxy group and an aryl oxy group. The alkoxy group may be a linear chain, a branched chain or a ring chain. The number of carbon atoms in the alkoxy group may be, for example, 1 to 20 or 1 to 10, but is not limited thereto. Examples of the oxy group include methoxy, ethoxy, n-propoxy, isopropoxy, butoxy, pentyloxy, hexyloxy, octyloxy, nonyloxy, decyloxy, benzyloxy, etc., but the embodiment is not limited thereto.

The boron group herein may mean that a boron atom is bonded to the alkyl group or the aryl group as defined above. The boron group includes an alkyl boron group and an aryl boron group. Examples of the boron group may include a trimethylboron group, a triethylboron group, a t-butyldimethylboron group, a triphenylboron group, a diphenylboron group, a phenylboron group, etc., but the embodiment is not limited thereto.

In the disclosure, the number of carbon atoms in an amine group is may be 1 to 30 but not limited thereto. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, a triphenylamine group, etc., but the embodiment is not limited thereto.

In the disclosure, the aryl group among an aryloxy group, an arylthio group, an arylsulfoxy group, an arylamino group, an arylboron group, an arylsilyl group, an arylamine group is the same as the examples of the aryl group described above.

A direct linkage herein may mean a single bond.

In the disclosure, “ [symbol] *” represents a position to be connected.

Hereinafter, the embodiments will be described with reference to the accompanying drawings.

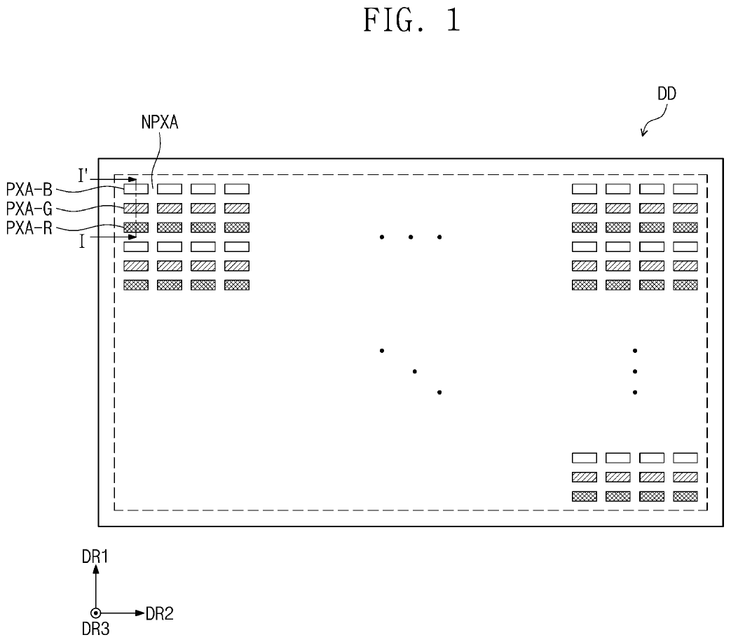

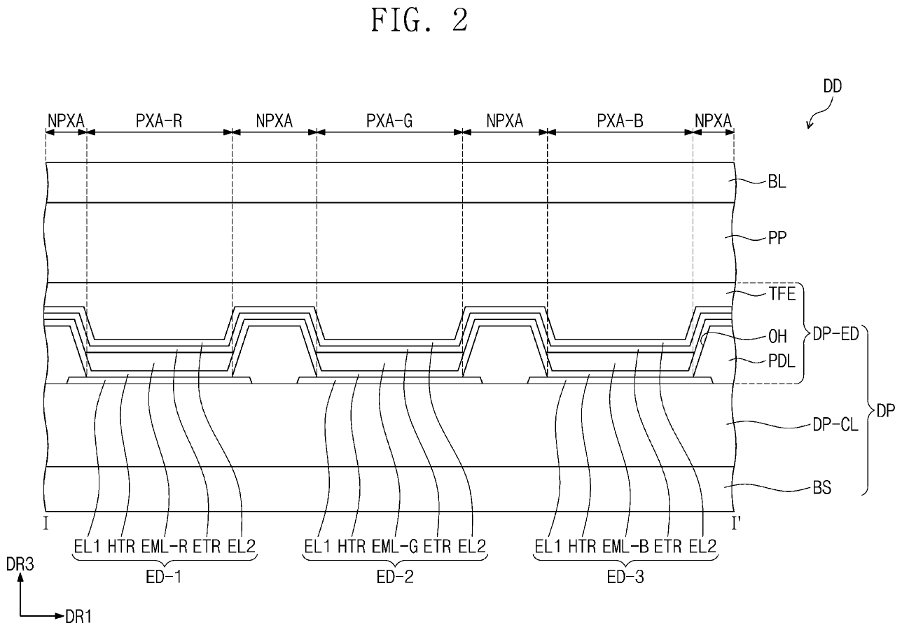

FIG. 1 is a plan view illustrating an embodiment of a display apparatus DD. FIG. 2 is a cross-sectional view of the display apparatus DD of the embodiment. FIG. 2 is a cross-sectional view illustrating a portion corresponding to line I-I′ of FIG. 1.

The display apparatus DD may include a display panel DP and an optical layer PP disposed on the display panel DP. The display panel DP includes light emitting devices ED-1, ED-2, and ED-3. The display apparatus DD may include a plurality of light emitting devices ED-1, ED-2, and ED-3. The optical layer PP may be disposed on the display panel DP and control reflected light in the display panel DP due to external light. The optical layer PP may include, for example, a polarization layer or a color filter layer. In other embodiments, the optical layer PP may be omitted from the display apparatus DD.

A base substrate BL may be disposed on the optical layer PP. The base substrate BL may be a member which provides a base surface on which the optical layer PP disposed. The base substrate BL may be a glass substrate, a metal substrate, a plastic substrate, etc. However, the embodiment is not limited thereto. For example, the base substrate BL may be an inorganic layer, an organic layer, or a composite material layer. In another embodiment, the base substrate BL may be omitted.

The display apparatus DD according to an embodiment may further include a filling layer (not shown). The filling layer (not shown) may be disposed between a display device layer DP-ED and the base substrate BL. The filling layer (not shown) may be an organic material layer. The filling layer (not shown) may include at least one of an acrylic-based resin, a silicone-based resin, or an epoxy-based resin.

The display panel DP may include a base layer BS, a circuit layer DP-CL provided on the base layer BS, and the display device layer DP-ED. The display device layer DP-ED may include a pixel defining film PDL, the light emitting devices ED-1, ED-2, and ED-3 disposed between portions of the pixel defining film PDL, and an encapsulation layer TFE disposed on the light emitting devices ED-1, ED-2, and ED-3.

The base layer BS may be a member which provides a base surface on which the display device layer DP-ED is disposed. The base layer BS may be a glass substrate, a metal substrate, a plastic substrate, etc. However, the embodiment is not limited thereto. For example, the base layer BS may be an inorganic layer, an organic layer, or a composite material layer.

In an embodiment, the circuit layer DP-CL is disposed on the base layer BS, and the circuit layer DP-CL may include a plurality of transistors (not shown). Each of the transistors (not shown) may include a control electrode, an input electrode, and an output electrode. For example, the circuit layer DP-CL may include a switching transistor and a driving transistor in order to drive the light emitting devices ED-1, ED-2, and ED-3 of the display device layer DP-ED.

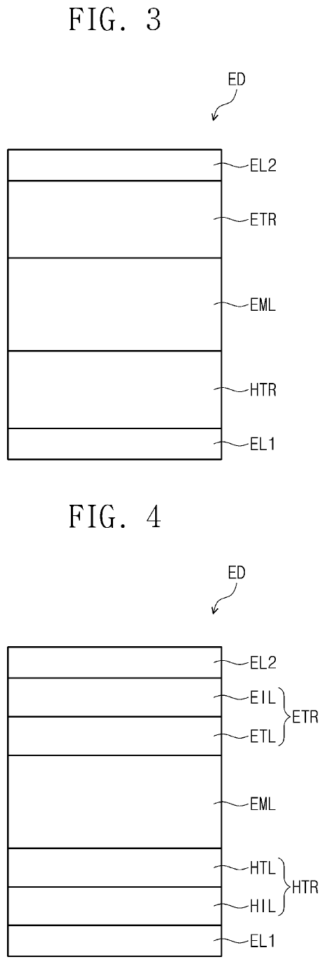

Each of the light emitting devices ED-1, ED-2, and ED-3 may have a structure of a light emitting device ED of an embodiment according to FIGS. 3 to 6, which will be described later. Each of the light emitting devices ED-1, ED-2 and ED-3 may include a first electrode EL1, a hole transport region HTR, emission layers EML-R, EML-G and EML-B, an electron transport region ETR, and a second electrode EL2.

FIG. 2 illustrates an embodiment in which the emission layers EML-R, EML-G, and EML-B of the light emitting devices ED-1, ED-2, and ED-3 are disposed in the openings OH defined in the pixel defining film PDL, and the hole transport region HTR, the electron transport region ETR, and the second electrode EL2 are provided as a common layer in the entire light emitting devices ED-1, ED-2, and ED-3. However, the embodiment is not limited thereto. For example, the hole transport region HTR and the electron transport region ETR in an embodiment may be provided by being patterned inside the openings OH defined in the pixel defining film PDL. For example, the hole transport region HTR, the emission layers EML-R, EML-G, and EML-B, and the electron transport region ETR of the light emitting devices ED-1, ED-2, and ED-3 in an embodiment may be provided by being patterned in an inkjet printing method.

The encapsulation layer TFE may cover the light emitting devices ED-1, ED-2 and ED-3. The encapsulation layer TFE may seal the display device layer DP-ED. The encapsulation layer TFE may be a thin film encapsulation layer. The encapsulation layer TFE may be formed by laminating one layer or a plurality of layers. The encapsulation layer TFE includes at least one insulation layer. The encapsulation layer TFE according to an embodiment may include at least one inorganic film (hereinafter, an encapsulation-inorganic film). The encapsulation layer TFE according to an embodiment may also include at least one organic film (hereinafter, an encapsulation-organic film) and at least one encapsulation-inorganic film.

The encapsulation-inorganic film protects the display device layer DP-ED from moisture/oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, or the like, but the embodiment is not limited thereto. The encapsulation-organic film may include an acrylic-based compound, an epoxy-based compound, or the like. The encapsulation-organic film may include a photopolymerizable organic material, but the embodiment is not limited thereto.

The encapsulation layer TFE may be disposed on the second electrode EL2 and may be disposed filling the openings OH.

Referring to FIGS. 1 and 2, the display apparatus DD may include a non-light emitting region NPXA and light emitting regions PXA-R, PXA-G and PXA-B. The light emitting regions PXA-R, PXA-G and PXA-B each may be a region which emits light generated from the light emitting devices ED-1, ED-2 and ED-3, respectively. The light emitting regions PXA-R, PXA-G, and PXA-B may be spaced apart from each other in a plan view.

Each of the light emitting regions PXA-R, PXA-G, and PXA-B may be a region divided by the pixel defining film PDL. The non-light emitting regions NPXA may be regions between the adjacent light emitting regions PXA-R, PXA-G, and PXA-B, which correspond to portions of the pixel defining film PDL. In the disclosure, each of the light emitting regions PXA-R, PXA-G, and PXA-B may correspond to a pixel. The pixel defining film PDL may separate the light emitting elements ED-1, ED-2, and ED-3. The emission layers EML-R, EML-G and EML-B of the light emitting devices ED-1, ED-2 and ED-3 may be disposed in openings OH defined by the pixel defining film PDL and separated from each other.

The light emitting regions PXA-R, PXA-G and PXA-B may be divided into a plurality of groups according to the color of light generated from the light emitting devices ED-1, ED-2 and ED-3. In the display apparatus DD of an embodiment shown in FIGS. 1 and 2, three light emitting regions PXA-R, PXA-G, and PXA-B may emit, for example, red light, green light, and blue light, respectively. For example, the display apparatus DD of an embodiment may include the red light emitting region PXA-R, the green light emitting region PXA-G, and the blue light emitting region PXA-B which are separated from one another.

In the display apparatus DD according to an embodiment, the plurality of light emitting devices ED-1, ED-2 and ED-3 may emit light beams having wavelengths different from one another. For example, in an embodiment, the display apparatus DD may include a first light emitting device ED-1 that emits red light, a second light emitting device ED-2 that emits green light, and a third light emitting device ED-3 that emits blue light. That is, the red light emitting region PXA-R, the green light emitting region PXA-G, and the blue light emitting region PXA-B of the display apparatus DD may correspond to the first light emitting device ED-1, the second light emitting device ED-2, and the third light emitting device ED-3, respectively.

However, the embodiment is not limited thereto, For example, the first to third light emitting devices ED-1, ED-2, and ED-3 may emit light beams in the same wavelength range or at least one light emitting device may emit a light beam in a wavelength range different from the others. For example, the first to third light emitting devices ED-1, ED-2, and ED-3 may all emit blue light.

The light emitting regions PXA-R, PXA-G, and PXA-B in the display apparatus DD according to an embodiment may be arranged in a stripe form. Referring to FIG. 1, the plurality of red light emitting regions PXA-R, the plurality of green light emitting regions PXA-G, and the plurality of blue light emitting regions PXA-B each may be arranged along a second directional axis DR2. In addition, the red light emitting region PXA-R, the green light emitting region PXA-G, and the blue light emitting region PXA-B may be alternately arranged in this order along a first directional axis DR1.

FIGS. 1 and 2 illustrate that all the light emitting regions PXA-R, PXA-G, and PXA-B have similar area, but the embodiment is not limited thereto. For example, the light emitting regions PXA-R, PXA-G, and PXA-B may have different areas from each other according to a wavelength range of the emitted light. In this case, the areas of the light emitting regions PXA-R, PXA-G, and PXA-B may mean areas in a plan view or when viewed in a plane defined by the first directional axis DR1 and the second directional axis DR2.

The arrangement form of the light emitting regions PXA-R, PXA-G, and PXA-B is not limited to the feature illustrated in FIG. 1. The order in which the red light emitting region PXA-R, the green light emitting region PXA-G, and the blue light emitting region PXA-B are arranged may be variously combined and provided according to characteristics of a display quality required in the display apparatus DD. For example, the arrangement form of the light emitting regions PXA-R, PXA-G, and PXA-B may be a pentile (PENTILE®) arrangement form or a diamond arrangement form.

In addition, the areas of the light emitting regions PXA-R, PXA-G, and PXA-B may be different from each other. For example, in an embodiment, the area of the green light emitting region PXA-G may be smaller than that of the blue light emitting region PXA-B, but the embodiment is not limited thereto.

Hereinafter, FIGS. 3 to 6 are cross-sectional views schematically illustrating light emitting devices according to embodiments. Each of the light emitting devices ED according to embodiments may include a first electrode EL1, a hole transport region HTR, an emission layer EML, an electron transport region ETR, and a second electrode EL2 that are sequentially stacked.

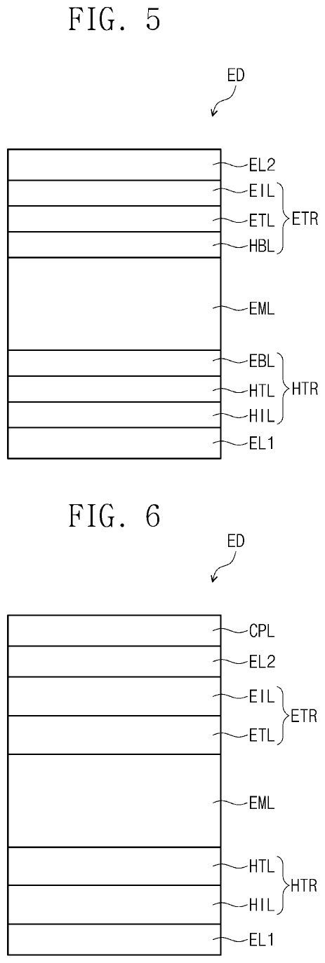

Compared to FIG. 3, FIG. 4 illustrates a cross-sectional view of a light emitting device ED of an embodiment, in which a hole transport region HTR includes a hole injection layer HIL and a hole transport layer HTL, and an electron transport region ETR includes an electron injection layer EIL and an electron transport layer ETL. In addition, compared to FIG. 3, FIG. 5 illustrates a cross-sectional view of a light emitting device ED of an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. Compared to FIG. 4, FIG. 6 illustrates a cross-sectional view of a light emitting device ED of an embodiment including a capping layer CPL disposed on a second electrode EL2.

The first electrode EL1 has conductivity. The first electrode EL1 may be formed of a metal material, a metal alloy, or a conductive compound. The first electrode EL1 may be an anode or a cathode. However, the embodiment is not limited thereto. For example, the first electrode EL1 may be a pixel electrode. The first electrode EL1 may be a transmissive electrode, a transflective electrode, or a reflective electrode. If the first electrode EL1 is the transmissive electrode, the first electrode EL1 may be formed using a transparent metal oxide such as indium tin oxide (ITO), indium zinc oxide (IZO), zinc oxide (ZnO), and indium tin zinc oxide (ITZO). If the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca, LiF/Al, Mo, Ti, W, a compound thereof, or a mixture thereof (e.g., a mixture of Ag and Mg). Alternatively, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but the embodiment is not limited thereto. In other embodiments, the first electrode EL1 may include the above-described metal materials, combinations of at least two metal materials of the above-described metal materials, oxides of the above-described metal materials, or the like. The thickness of the first electrode EL1 may be from about 700 Å to about 10,000 Å. For example, the thickness of the first electrode EL1 may be from about 1,000 Å to about 3,000 Å.

The hole transport region HTR is provided on the first electrode EL1. The hole transport region HTR may include at least one of a hole injection layer HIL, a hole transport layer HTL, a buffer layer or an emission-auxiliary layer (not shown), or an electron blocking layer EBL. The thickness of the hole transport region HTR may be, for example, from about 50 Å to about 15,000 Å.

The hole transport region HTR may have a single layer formed of a single material, a single layer formed of a plurality of different materials, or a multilayer structure including a plurality of layers formed of a plurality of different materials.

For example, the hole transport region HTR may have a single layer structure of the hole injection layer HIL or the hole transport layer HTL, or may have a single layer structure formed of a hole injection material and a hole transport material. In addition, the hole transport region HTR may have a single layer structure formed of a plurality of different materials, or a structure in which a hole injection layer HIL/hole transport layer HTL, a hole injection layer HIL/hole transport layer HTL/buffer layer (not shown), a hole injection layer HIL/buffer layer (not shown), a hole transport layer HTL/buffer layer (not shown), or a hole injection layer HIL/hole transport layer HTL/electron blocking layer EBL are stacked in order from the first electrode EL1, but the embodiment is not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

The hole transport region HTR may include a compound represented by Formula H-1 below:

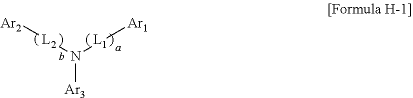

In Formula H-1 above, L₁ and L₂ may be each independently a direct linkage, a substituted or unsubstituted arylene group having 6 to 30 ring-forming carbon atoms, or a substituted or unsubstituted heteroarylene group having 2 to 30 ring-forming carbon atoms. a and b may be each independently an integer of 0 to 10. For example, when a or b is an integer of 2 or greater, a plurality of L₁'s and L₂'s may be each independently a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may be each independently a substituted or unsubstituted aryl group having 6 to 30 ring-forming carbon atoms, or a substituted or unsubstituted heteroaryl group having 2 to 30 ring-forming carbon atoms. In addition, in Formula H-1, Ar₃ may be a substituted or unsubstituted aryl group having 6 to 30 ring-forming carbon atoms, or a substituted or unsubstituted heteroaryl group having 2 to 30 ring-forming carbon atoms.

The compound represented by Formula H-1 above may be a monoamine compound. Alternatively, the compound represented by Formula H-1 above may be a diamine compound in which at least one among Ar₁ to Ar₃ includes the amine group as a substituent. In addition, the compound represented by Formula H-1 above may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be represented by any one among the compounds of Compound Group H below. However, the compounds listed in Compound Group H below are examples, and the compounds represented by Formula H-1 are not limited to those represented by Compound Group H below:

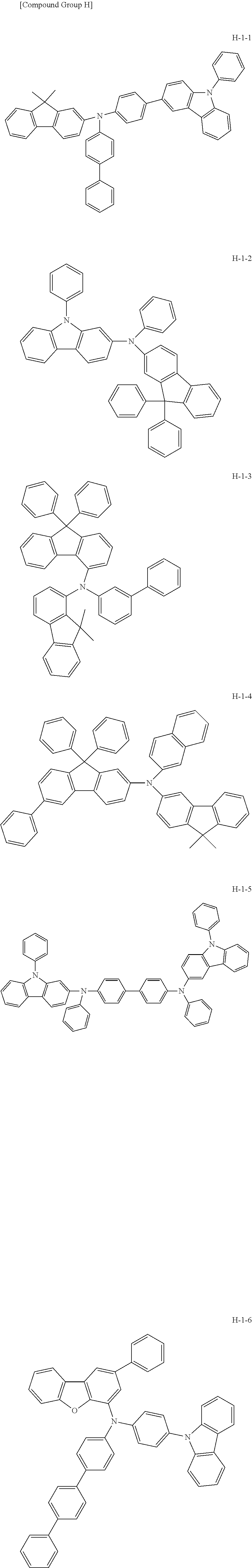

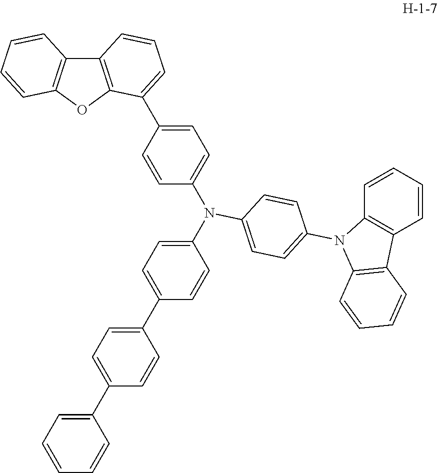 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

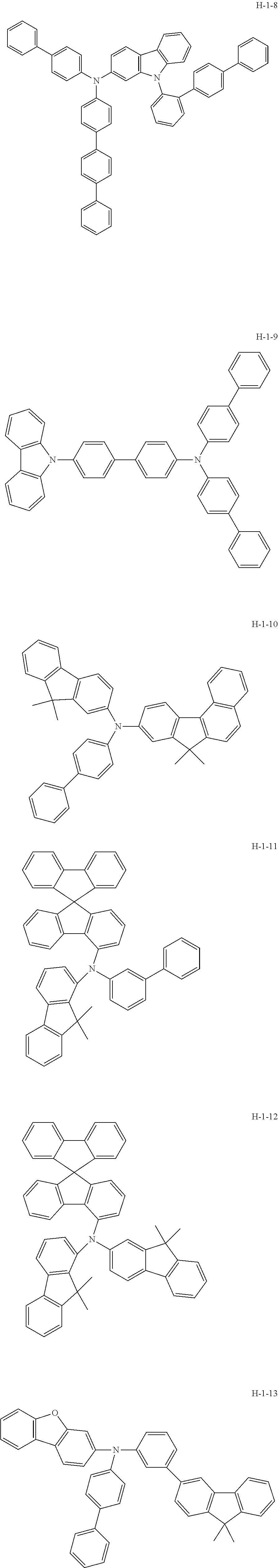

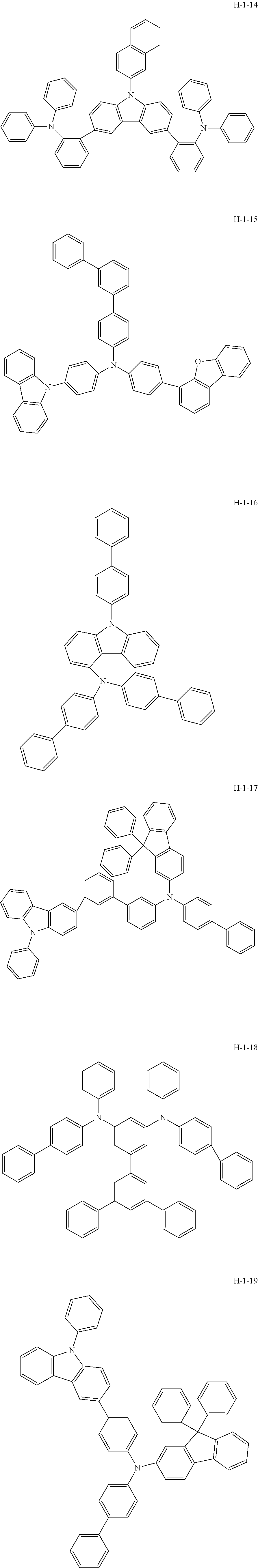

The hole transport region HTR may include a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino] triphenylamine (m-MTDATA), 4,4′4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole and polyvinyl carbazole, a fluorene-based derivative, N,N′-bis(3-methylphenyl)-N,N′-diphenyl-[1,1-biphenyl]-4,4′-diamine (TPD), a triphenylamine-based derivative such as 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

In addition, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compound of the hole transport region in at least one of a hole injection layer HIL, a hole transport layer HTL, or an electron blocking layer EBL.

The thickness of the hole transport region HTR may be from about 100 Å to about 10,000 Å, for example, from about 100 Å to about 5,000 Å. When the hole transport region HTR includes the hole injection layer HIL, the hole injection layer HIL may have, for example, a thickness of about 30 Å to about 1,000 Å. When the hole transport region HTR includes the hole transport layer HTL, the hole transport layer HTL may have a thickness of about 30 Å to about 1,000 Å. For example, when the hole transport region HTR includes the electron blocking layer EBL, the electron blocking layer EBL may have a thickness of about 10 Å to about 1,000 Å. If the thicknesses of the hole transport region HTR, the hole injection layer HIL, the hole transport layer HTL and the electron blocking layer EBL satisfy the above-described ranges, satisfactory hole transport properties may be achieved without a substantial increase in a driving voltage.

The hole transport region HTR may further include a charge generating material to increase conductivity in addition to the above-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but the embodiment is not limited thereto. For example, the p-dopant may include a metal halide compound such as CuI and RbI, a quinone derivative such as tetracyanoquinodimethane (TCNQ) and 2,3,5,6-tetrafluoro-7,7′8,8-tetracyanoquinodimethane (F4-TCNQ), a metal oxide such as tungsten oxide and molybdenum oxide, a cyano group-containing compound such as dipyrazino[2,3-f: 2′,3′-h] quinoxaline-2,3,6,7,10,11-hexacarbonitrile (HATCN), 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but the embodiment is not limited thereto.

As described above, the hole transport region HTR may further include at least one of the buffer layer (not shown) or the electron blocking layer EBL in addition to the hole injection layer HIL and the hole transport layer HTL. The buffer layer (not shown) may compensate for a resonance distance according to the wavelength of light emitted from the emission layer EML and may thus increase light emission efficiency. A material that may be included in the hole transport region HTR may be used as a material to be included in the buffer layer (not shown). The electron blocking layer EBL is a layer that serves to prevent the electron injection from the electron transport region ETR to the hole transport region HTR.

The emission layer EML is provided on the hole transport region HTR. The emission layer EML may have a thickness of, for example, about 100 Å to about 1,000 Å or about 100 Å to about 300 Å. The emission layer EML may have a single layer formed of a single material, a single layer formed of a plurality of different materials, or a multilayer structure having a plurality of layers formed of a plurality of different materials.

The emission layer EML in the light emitting device ED according to an embodiment may include a fused polycyclic compound of an embodiment.

The fused polycyclic compound of an embodiment may include a structure in which a plurality of aromatic rings are fused through at least one boron atom and at least two heteroatoms. The fused polycyclic compound of an embodiment may include a structure in which a plurality of aromatic rings are fused through at least one boron atom and at least two heteroatoms selected from the group consisting of a nitrogen atom, an oxygen atom, a sulfur atom, a phosphorus atom, a carbon atom, and a silicon atom. In addition, the fused polycyclic compound of an embodiment may include at least one steric hindrance substituent connected to a fused cyclic core. The steric hindrance substituent may have a structure in which a bulky substituent is connected at the position of carbon adjacent to the carbon connected to the fused cyclic core.

The fused polycyclic compound of an embodiment is represented by Formula 1 below:

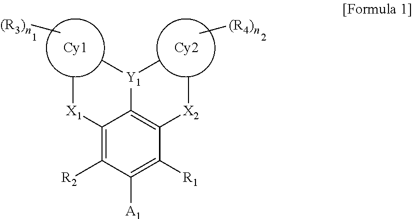

In Formula 1, Y₁ is P, B, or N.

In Formula 1, X₁ and X₂ are each independently O, S, CR₅R₆, PR₇, SiR₈R₉, NR₁₀, or BR₁₁, or are represented by Formula 2 below.

The atom located at each of X₁ and X₂ may be different from the atom located at Y₁. For example, if Y₁ is B, neither X₁ nor X₂ may be BR₁₁. If Y₁ is N, neither X₁ nor X₂ may be NR₁₀, or be represented by Formula 2 below. If Y₁ is P, neither X₁ nor X₂ may be PR₇.

In Formula 1, Cy1 and Cy2 are each independently a substituted or unsubstituted monocyclic aromatic hydrocarbon ring having 6 to 30 ring-forming carbon atoms, or a substituted or unsubstituted monocyclic aromatic heterocycle having 2 to 30 ring-forming carbon atoms. Cy1 and Cy2 may be each independently a 5-membered or 6-membered aromatic hydrocarbon ring, or a 5-membered or 6-membered aromatic heterocycle. In an embodiment, Cy1 and Cy2 may be each independently a 6-membered aromatic hydrocarbon ring, or a 6-membered aromatic heterocycle. For example, Cy1 and Cy2 may be each independently a benzene ring or a pyridine ring.

In Formula 1, A₁ is a hydrogen atom, a deuterium atom, a substituted or unsubstituted amine group, a substituted or unsubstituted oxy group, a substituted or unsubstituted silyl group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or is represented by Formula 3 below. For example, A₁ may be a hydrogen atom, a deuterium atom, a substituted or unsubstituted diphenylamine group, a substituted or unsubstituted phenyloxy group, a substituted or unsubstituted triphenylsilyl group, a substituted or unsubstituted t-butyl group, a substituted or unsubstituted isopropyl group, a substituted or unsubstituted cyclohexyl group, a substituted or unsubstituted adamantyl group, a substituted or unsubstituted phenyl group, a substituted or unsubstituted biphenyl group, a substituted or unsubstituted anthracenyl group, a substituted or unsubstituted carbazole group, a substituted or unsubstituted dibenzo azasiline group, or a substituted or unsubstituted spirobiacridine group (10H,10′H-9,9′-Spirobi[acridine]), or may be a substituent represented by Formula 3 below.

In Formula 1, R₁, R₂, and R₅ to R₁₁ are each independently a hydrogen atom, a deuterium atom, a halogen atom, a cyano group, a nitro group, a substituted or unsubstituted amine group, a substituted or unsubstituted silyl group, a substituted or unsubstituted boron group, a substituted or unsubstituted oxy group, a substituted or unsubstituted thio group, a substituted or unsubstituted phosphine group, a substituted or unsubstituted alkyl group having 1 to 30 carbon atoms, a substituted or unsubstituted alkenyl group having 2 to 30 carbon atoms, a substituted or unsubstituted aryl group having 6 to 60 ring-forming carbon atoms, or a substituted or unsubstituted heteroaryl group having 2 to 60 ring-forming carbon atoms. Alternatively, each of R₁, R₂, and R₅ to R₁₁ may be bonded to an adjacent group to form a ring. For example, R₁ and R₂ may be each independently a hydrogen atom or a deuterium atom. R₅ to R₁₁ may be each independently a substituted or unsubstituted methyl group, a substituted or unsubstituted phenyl group, a substituted or unsubstituted biphenyl group, or a substituted or unsubstituted anthracenyl group.

In Formula 1, R₃ and R₄ are each independently a hydrogen atom, a deuterium atom, a halogen atom, a cyano group, a nitro group, a substituted or unsubstituted amine group, a substituted or unsubstituted silyl group, a substituted or unsubstituted boron group, a substituted or unsubstituted oxy group, a substituted or unsubstituted thio group, a substituted or unsubstituted phosphine group, a substituted or unsubstituted alkyl group having 1 to 30 carbon atoms, a substituted or unsubstituted alkenyl group having 2 to 30 carbon atoms, a substituted or unsubstituted aryl group having 6 to 60 ring-forming carbon atoms, or a substituted or unsubstituted heteroaryl group having 2 to 60 ring-forming carbon atoms, or are represented by Formula 3 below. Alternatively, each of R₃ and R₄ may be bonded to an adjacent group to form a ring. For example, R₃ and R₄ may be each independently a hydrogen atom, a deuterium atom, a substituted or unsubstituted alkyl group having 1 to 20 carbon atoms, a substituted or unsubstituted arylamine group, a substituted or unsubstituted arylboron group, a substituted or unsubstituted aryloxy group, a substituted or unsubstituted arylthio group, a substituted or unsubstituted dialkylarylsilyl group, a substituted or unsubstituted arylphosphine group, a substituted or unsubstituted phenyl group, a substituted or unsubstituted biphenyl group, or a substituted or unsubstituted terphenyl group, or may be a substituent represented by Formula 3 below. Alternatively, each of R₃ and R₄ may be provided in plurality, and each of R₃'s and R₄'s may be bonded to an adjacent group to form a ring.

In Formula 1, at least one of X₁ or X₂ is represented by Formula 2 above, or at least one of A₁, R₃, or R₄ is represented by Formula 3 above, or at least one of X₁ or X₂ is represented by Formula 2 above, and at least one of A₁, R₃, or R₄ is represented by Formula 3 above. That is, the fused polycyclic compound represented by Formula 1 of an embodiment may include at least one substituent represented by Formula 2 or Formula 3 in the fused cyclic core. For example, at least one of X₁ or X₂ may be represented by Formula 2. In this case, at least one of A₁, R₃, or R₄ may be represented by Formula 3, or none of A₁, R₃, and R₄ may be represented by Formula 3. In addition, at least one of A₁, R₃ or R₄ may be represented by Formula 3. In this case, at least one of X₁ or X₂ may be represented by Formula 2, or neither X₁ nor X₂ may be represented by Formula 2. When A₁ is not represented by Formula 3, A₁ may be a hydrogen atom, a deuterium atom, a substituted or unsubstituted amine group, a substituted or unsubstituted oxy group, a substituted or unsubstituted silyl group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. When neither R₃ nor R₄ is represented by Formula 3, R₃ and R₄ may be each independently a hydrogen atom, a deuterium atom, a halogen atom, a cyano group, a nitro group, a substituted or unsubstituted amine group, a substituted or unsubstituted silyl group, a substituted or unsubstituted boron group, a substituted or unsubstituted oxy group, a substituted or unsubstituted thio group, a substituted or unsubstituted phosphine group, a substituted or unsubstituted alkyl group having 1 to 30 carbon atoms, a substituted or unsubstituted alkenyl group having 2 to 30 carbon atoms, a substituted or unsubstituted aryl group having 6 to 60 ring-forming carbon atoms, or a substituted or unsubstituted heteroaryl group having 2 to 60 ring-forming carbon atoms. When neither X₁ nor X₂ is represented by Formula 2, X₁ and X₂ may be each independently O, S, CR₅R₆, PR₇, SiR₈R₉, NR₁₀, or BR₁₁.

In Formula 1, when each of R₃ and R₄ is bonded to an adjacent group to form a ring, the formed ring does not include Si as a ring-forming atom. For example, when each of R₃ and R₄ is bonded to an adjacent group to form a ring, the formed ring may not include a substituted or unsubstituted silafluorene moiety.

In Formula 1, when neither R₃ nor R₄ is bonded to an adjacent group to form a ring, at least one of X₁ or X₂ is S.

In Formula 1, n₁ and n₂ are each independently an integer of 0 to 4. If each of n₁ and n₂ is 0, the fused polycyclic compound according to an embodiment may not be substituted with each of R₃ and R₄. In Formula 1, the case where each of n₁ and n₂ is 4 and R₃'s and R₄'s are each hydrogen atoms may be the same as the case where each of n₁ and n₂ in Formula 1 is 0. When each of n₁ and n₂ is an integer of 2 or more, a plurality of R₃'s and R₄'s may each be the same or at least one among the plurality of R₃'s and R₄'s may be different from the others.

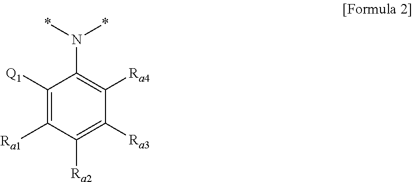

In Formula 2, Q₁ is a substituted or unsubstituted arylamine group, a substituted or unsubstituted arylsilyl group, a substituted or unsubstituted arylthio group, a substituted or unsubstituted aryloxy group, a substituted or unsubstituted alkyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Q₁ may be a substituted or unsubstituted isopropyl group, a substituted or unsubstituted cyclohexyl group, a substituted or unsubstituted adamantyl group, a substituted or unsubstituted phenyl group, a substituted or unsubstituted biphenyl group, a substituted or unsubstituted terphenyl group, a substituted or unsubstituted naphthyl group, a substituted or unsubstituted diphenylamine group, a substituted or unsubstituted phenylthio group, a substituted or unsubstituted phenyloxy group, or a substituted or unsubstituted triphenylsilyl group.

In Formula 2, Rₐ₁ and Rₐ₄ are each independently a hydrogen atom, a deuterium atom, a halogen atom, a cyano group, a nitro group, a substituted or unsubstituted amine group, a substituted or unsubstituted silyl group, a substituted or unsubstituted boron group, a substituted or unsubstituted oxy group, a substituted or unsubstituted thio group, a substituted or unsubstituted phosphine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Rₐ₁ to Rₐ₄ may be each independently a hydrogen atom, a deuterium atom, a substituted or unsubstituted methyl group, a substituted or unsubstituted isopropyl group, or a substituted or unsubstituted phenyl group.

In Formula 2, each “ [symbol] *” may be a part bonded to a fused cyclic ring in Formula 1.

In an embodiment, X₁ may be a structure represented by Formula 2, one of two [symbol] * in Formula 2 may be linked to Cy1 in Formula 1, and the other may be linked at the ortho position with respect to Y₁ and R₂ in Formula 1.

In an embodiment, X₂ may be a structure represented by Formula 2, one of two [symbol] * in Formula 2 may be linked to Cy2 in Formula 1, and the other may be linked at the ortho position with respect to Y₁ and R₁ in Formula 1.

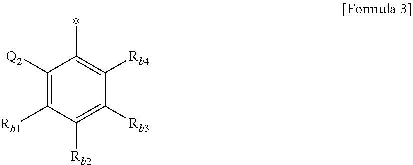

In Formula 3, Q₂ is a substituted or unsubstituted arylamine group, a substituted or unsubstituted arylsilyl group, a substituted or unsubstituted arylthio group, a substituted or unsubstituted aryloxy group, a substituted or unsubstituted alkyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Q₂ may be a substituted or unsubstituted ethyl group, a substituted or unsubstituted cyclopentyl group, a substituted or unsubstituted anthracenyl group, a substituted or unsubstituted adamantyl group, a substituted or unsubstituted phenyl group, a substituted or unsubstituted naphthyl group, a substituted or unsubstituted diphenylamine group, or a substituted or unsubstituted triphenylsilyl group.

In Formula 3, R_{b1} to R_{b4} are each independently a hydrogen atom, a deuterium atom, a halogen atom, a cyano group, a nitro group, a substituted or unsubstituted amine group, a substituted or unsubstituted silyl group, a substituted or unsubstituted boron group, a substituted or unsubstituted oxy group, a substituted or unsubstituted thio group, a substituted or unsubstituted phosphine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R_{b1} to R_{b4} may be a hydrogen atom, a deuterium atom, a substituted or unsubstituted methyl group, a substituted or unsubstituted ethyl group, or a substituted or unsubstituted phenyl group.

In Formula 3, “ [symbol] *” may be a part bonded to the fused cyclic ring in Formula 1. In an embodiment, the substituent represented by Formula 3 may be substituted at the para position with respect to Y₁ in a fused cyclic skeleton in Formula 1.

In an embodiment, when at least one of X₁ or X₂ is represented by Formula 2 above, at least one, represented by Formula 2, of X₁ or X₂ may be represented by Formula 2-1 or Formula 2-2 below:

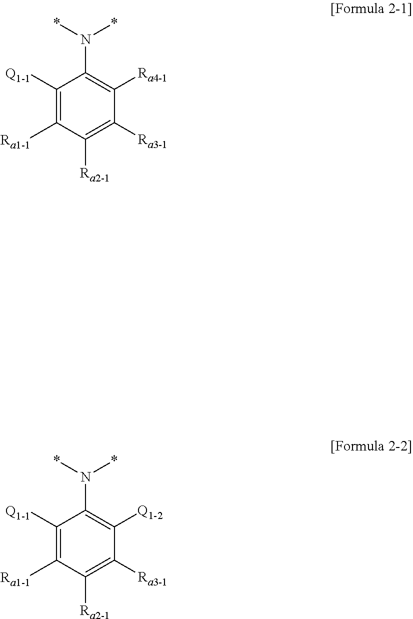

In Formula 2-1 and Formula 2-2, Q₁₋₁ and Q₁₋₂ are each independently a substituted or unsubstituted arylamine group, a substituted or unsubstituted arylsilyl group, a substituted or unsubstituted arylthio group, a substituted or unsubstituted aryloxy group, a substituted or unsubstituted alkyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Q₁₋₁ and Q₁₋₂ may be each independently a substituted or unsubstituted isopropyl group, a substituted or unsubstituted cyclohexyl group, a substituted or unsubstituted adamantyl group, a substituted or unsubstituted phenyl group, a substituted or unsubstituted biphenyl group, a substituted or unsubstituted terphenyl group, a substituted or unsubstituted naphthyl group, a substituted or unsubstituted diphenylamine group, a substituted or unsubstituted phenylthio group, a substituted or unsubstituted phenyloxy group, or a substituted or unsubstituted triphenylsilyl group.

Rₐ₁₋₁ to Rₐ₄₋₁ may be each independently a hydrogen atom, a deuterium atom, a substituted or unsubstituted alkyl group having 1 to 20 carbon atoms, or a substituted or unsubstituted aryl group having 6 to 30 ring-forming carbon atoms. For example, Rₐ₁₋₁ to Rₐ₄₋₁ may be each independently a hydrogen atom, a deuterium atom, a substituted or unsubstituted methyl group, a substituted or unsubstituted isopropyl group, or a substituted or unsubstituted phenyl group.

In an embodiment, when A₁ is represented by Formula 3, A₁ may be represented by any one among Formula 3-1 to 3-5 below:

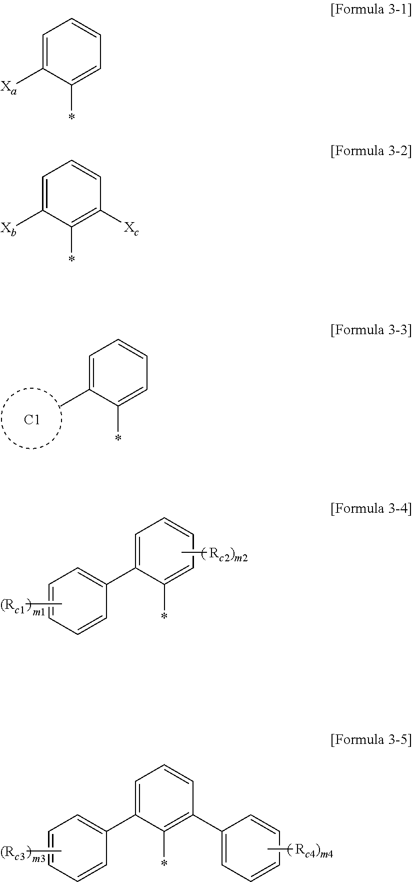

In Formula 3-1 and Formula 3-2, Xₐ to X_{c} may be each independently NR_{c5}R_{c6}, SR_{c7}, OR_{c8}, SiR_{c9}R_{c10}R_{c11}, or a substituted or unsubstituted alkyl group having 2 to 10 carbon atoms.

In Formula 3-3, C1 may be a substituted or unsubstituted cycloalkyl group having 3 to 10 carbon atoms. For example, C1 may be a substituted or unsubstituted cyclopentyl group or a substituted or unsubstituted adamantyl group.

In Formula 3-4 and Formula 3-5, R_{c1} to R_{c4} may be each independently a hydrogen atom, a deuterium atom, a halogen atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. Alternatively, each of R_{c1} to R_{c4} may be bonded to an adjacent group to form a ring.

In Formula 3-1 and Formula 3-2, R_{c5} to R_{c11} may be each independently a substituted or unsubstituted phenyl group.

In Formula 3-4 and Formula 3-5, m1, m3, and m4 are each independently an integer of 0 to 5. If each of m1, m3, and m4 is 0, the fused polycyclic compound of an embodiment may not be substituted with each of R_{c1}, R_{c3}, and R_{c4}. The case where each of m1, m3, and m4 is 5 and each of R_{c1}, R_{c3}, and R_{c4} is a hydrogen atom in Formula 3-4 and Formula 3-5 may be the same as the case where each of m1, m3, and m4 is 0 in Formula 3-4 and Formula 3-5. If each of m1, m3, and m4 is an integer of 2 or more, a plurality of R_{c1}'s, R_{c3}'s, and R_{c4}'s each may be the same or at least one among the plurality of R_{c1}'s, R_{c3}'s, and R_{c4}'s may be different from the others.

In Formula 3-4, m2 is an integer of 0 to 4. If m2 is 0, the fused polycyclic compound of an embodiment may not be substituted with R_{c2}. The case where m2 is 4 and R_{c2}'s are all hydrogen atoms in Formula 3-4 may be the same as the case where m2 is 0 in Formula 3-4. If m2 is an integer of 2 or more, a plurality of R_{c2}'s may be all the same or at least one of the plurality of R_{c2}'s may be different from the others.

In an embodiment, the fused polycyclic compound represented by Formula 1 may be represented by Formula 1-1 below:

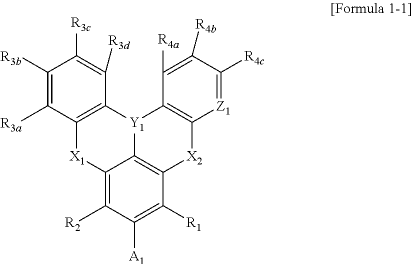

Formula 1-1 represents the case where Cy1 and Cy2 in Formula 1 are each independently a benzene ring or a pyridine ring.

In Formula 1-1, Z₁ may be CR_{4d} or N.

In Formula 1-1, R₃ₐ to R_{3d}, and R₄ₐ to R_{4d} may be each independently a hydrogen atom, a deuterium atom, a halogen atom, a cyano group, a nitro group, a substituted or unsubstituted amine group, a substituted or unsubstituted silyl group, a substituted or unsubstituted boron group, a substituted or unsubstituted oxy group, a substituted or unsubstituted thio group, a substituted or unsubstituted phosphine group, a substituted or unsubstituted alkyl group having 1 to 30 carbon atoms, a substituted or unsubstituted alkenyl group having 2 to 30 carbon atoms, a substituted or unsubstituted aryl group having 6 to 60 ring-forming carbon atoms, or a substituted or unsubstituted heteroaryl group having 2 to 60 ring-forming carbon atoms. Alternatively, each of R₃ₐ to R_{3d}, and R₄ₐ to R_{4d} may be bonded to an adjacent group to form a ring. For example, R_{3b} and R_{3c}, and R_{4b} and R_{4c}, which are adjacent groups, may be respectively bonded via an amine group, a boron group, an oxy group, a thio group, a phosphine group, a silyl group, an alkyl group, or the like to form a ring. The description of R₃ and R₄ in Formula 1 above may be equally applied to R₃ₐ to R_{3d}, and R₄ₐ to R_{4d}.

In Formula 1-1, at least one of X₁ or X₂ may be represented by Formula 2 above, or at least one among A₁, R₃ₐ to R_{3d} and R₄ₐ to R_{4c} may be represented by Formula 3 above, or at least one of X₁ or X₂ may be represented by Formula 2 above, and at least one among A₁, R₃ₐ to R_{3d} and R₄ₐ to R_{4c} may be represented by Formula 3 above. That is, the fused polycyclic compound represented by Formula 1-1 of an embodiment may include at least one substituent represented by Formula 2 or Formula 3 in the fused cyclic core. For example, at least one of X₁ or X₂ may be represented by Formula 2. In this case, at least one among A₁, R₃ₐ to R_{3d} and R₄ₐ to R_{4c} may be represented by Formula 3, or none of A₁, R₃ₐ to R_{3d} and R₄ₐ to R_{4c} may be represented by Formula 3. In addition, at least one among A₁, R₃ₐ to R_{3d} and R₄ₐ to R_{4c} may be represented by Formula 3. In this case, at least one of X₁ or X₂ may be represented by Formula 2, or neither X₁ nor X₂ may be represented by Formula 2.

In Formula 1-1, when each of R₃ₐ to R_{3d} and R₄ₐ to R_{4c} is bonded to an adjacent group to form a ring, the formed ring may not include Si as a ring-forming atom. For example, when each of R₃ₐ to R_{3d} and R₄ₐ to R_{4c} is bonded to an adjacent group to form a ring, the formed ring may not include a substituted or unsubstituted silafluorene moiety.

In Formula 1-1, when none of R₃ₐ to R_{3d} and R₄ₐ to R_{4c} is bonded to an adjacent group to form a ring, at least one of X₁ or X₂ may be S.

In Formula 1-1, the same as described in Formula 1 above may be applied to X₁, X₂, Y₁, A₁, R₁, and R₂.

In an embodiment, the fused polycyclic compound represented by Formula 1-1 may be represented by Formula 1-2 below:

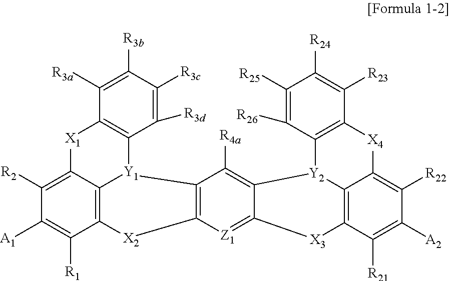

Formula 1-2 represents the case where R_{4b} and R_{4c} in Formula 1-1 are bonded to each other to form a further ring. Formula 1-2 represents a structure in which two rings are further fused via X₃, X₄, and Y₂ in the fused cyclic core in Formula 1-1.

In Formula 1-2, Y₂ may be P, B or N.

In Formula 1-2, X₃ and X₄ may be each independently O, S, CR₂₇R₂₈, PR₂₉, NR₃₀, or BR₃₁, or may be represented by Formula 2 above.

A₂ may be a hydrogen atom, a deuterium atom, a substituted or unsubstituted amine group, a substituted or unsubstituted oxy group, a substituted or unsubstituted silyl group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be represented by Formula 3 above. For example, A₂ may be a hydrogen atom, a deuterium atom, a substituted or unsubstituted diphenylamine group, a substituted or unsubstituted phenyloxy group, a substituted or unsubstituted triphenylsilyl group, a substituted or unsubstituted t-butyl group, a substituted or unsubstituted isopropyl group, a substituted or unsubstituted cyclohexyl group, a substituted or unsubstituted adamantyl group, a substituted or unsubstituted phenyl group, a substituted or unsubstituted biphenyl group, a substituted or unsubstituted anthracenyl group, a substituted or unsubstituted carbazole group, a substituted or unsubstituted dibenzo azasiline group, or a substituted or unsubstituted spirobiacridine group (10H,10′H-9,9′-Spirobi[acridine]), or may be a substituent represented by Formula 3 above.

In Formula 1-2, R₂₁ to R₃₁ may be each independently a hydrogen atom, a deuterium atom, a halogen atom, a cyano group, a nitro group, a substituted or unsubstituted amine group, a substituted or unsubstituted silyl group, a substituted or unsubstituted boron group, a substituted or unsubstituted oxy group, a substituted or unsubstituted thio group, a substituted or unsubstituted phosphine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. Alternatively, each of R₂₁ to R₃₁ may be bonded to an adjacent group to form a ring.

As described above in Formula 1, in Formula 1-2, at least one of X₁ or X₂ is represented by Formula 2 or A₁ is represented by Formula 3 above, or at least of X₁ or X₂ is represented by Formula 2 above and A₁ is represented by Formula 3 above. That is, the fused polycyclic compound represented by Formula 1-2 of an embodiment may also include at least one substituent represented by Formula 2 or Formula 3 in the fused cyclic core.

In Formula 1-2 above, the same as described in Formula 1 and Formula 1-1 above may be applied to X₁, X₂, Y₁, Z₁, A₁, R₁, R₂, R₃ₐ to R_{3d}, and R₄ₐ.

In an embodiment, A₁ and A₂ may be each independently a substituted or unsubstituted alkyl group having 1 to 10 carbon atoms, or may be represented by Formula 3 or any one among Formula 4-1 to Formula 4-5 below:

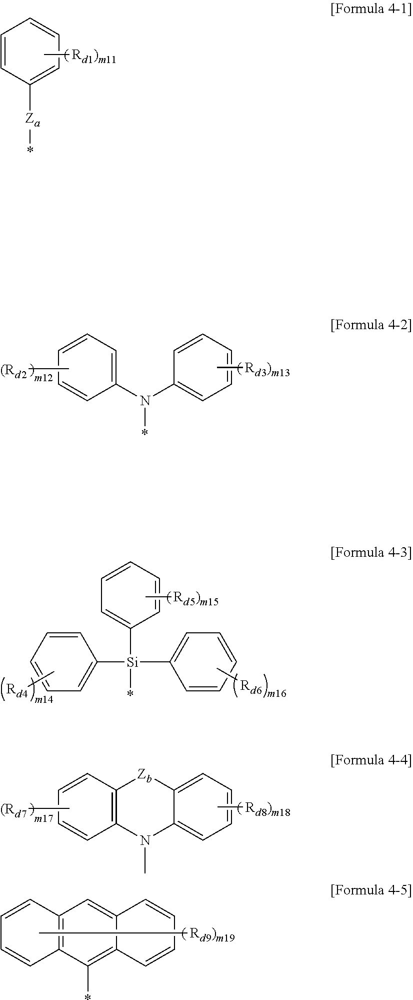

In Formula 4-1, Zₐ may be a direct linkage or O.

In Formula 4-1, R_{d1} may be a hydrogen atom, a deuterium atom, a halogen atom, a nitro group, a substituted or unsubstituted alkyl group having 1 to 10 carbon atoms, a substituted or unsubstituted silyl group, or a substituted or unsubstituted phenyl group.

In Formula 4-4, Z_{b} may be a direct linkage, CR_{d10}R_{d11}, or SiR_{d12}R_{d13}.

In Formula 4-2 to Formula 4-5, R_{d2} to R_{d13} may be each independently a hydrogen atom, a deuterium atom, a halogen atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. Alternatively, each of R_{d2} to R_{d13} may be bonded to an adjacent group to form a ring. For example, R_{d2} to R_{d13} may be each independently a hydrogen atom, a deuterium atom, a substituted or unsubstituted phenyl group, or a substituted or unsubstituted carbazole group.

In Formula 4-1 to Formula 4-5, m11 to m16 are each independently an integer of 0 to 5, m17 and m18 are each independently an integer of 0 to 4, and m19 is an integer of 0 to 9.

If each of m11 to m16 is 0, the fused polycyclic compound according to an embodiment may not be substituted with each of R_{d1} to R_{d6}. The case where each of m11 to m16 is 5 and R_{d1}'s to R_{d6}'s each are hydrogen atoms may be the same as the case where each of m11 to m16 is 0. When each of m11 to m16 is an integer of 2 or more, a plurality of R_{d1}'s and R_{d6}'s each may be the same or at least one among the plurality of R_{d1}'s and R_{d6}'s may be different from the others.

If each of m17 and m18 is 0, the fused polycyclic compound according to an embodiment may not be substituted with each of R_{d7} and R_{d8}. The case where each of m17 and m18 is 4 and R_{d7}'s and R_{d8}'s each are hydrogen atoms may be the same as the case where each of m17 and m18 is 0. When each of m17 and m18 is an integer of 2 or more, a plurality of R_{d7}'s and R_{d8}'s each may be the same or at least one among the plurality of R_{d7}'s and R_{d8}'s may be different from the others.

If m19 is 0, the fused polycyclic compound according to an embodiment may not be substituted with R_{d9}. The case where m19 is 9 and R_{d9}'s are all hydrogen atoms may be the same as the case where m19 is 0. When m19 is an integer of 2 or more, a plurality of R_{d9}'s may be all the same or at least one of the plurality of R_{d9}'s may be different from the others.

In an embodiment, the fused polycyclic compound represented by Formula 1-2 may be represented by any one among Formula 5-1 to Formula 5-10 below:

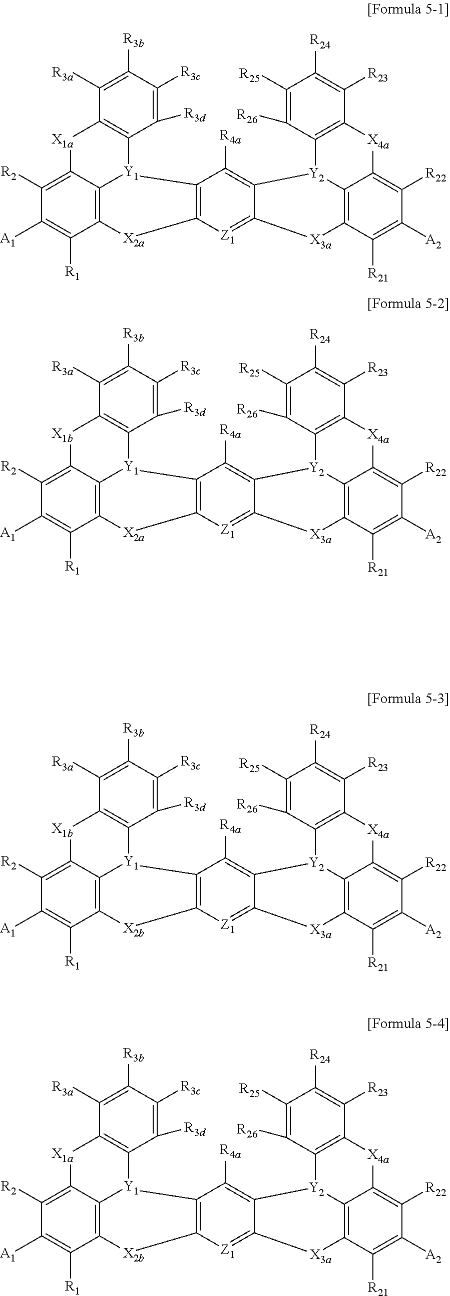

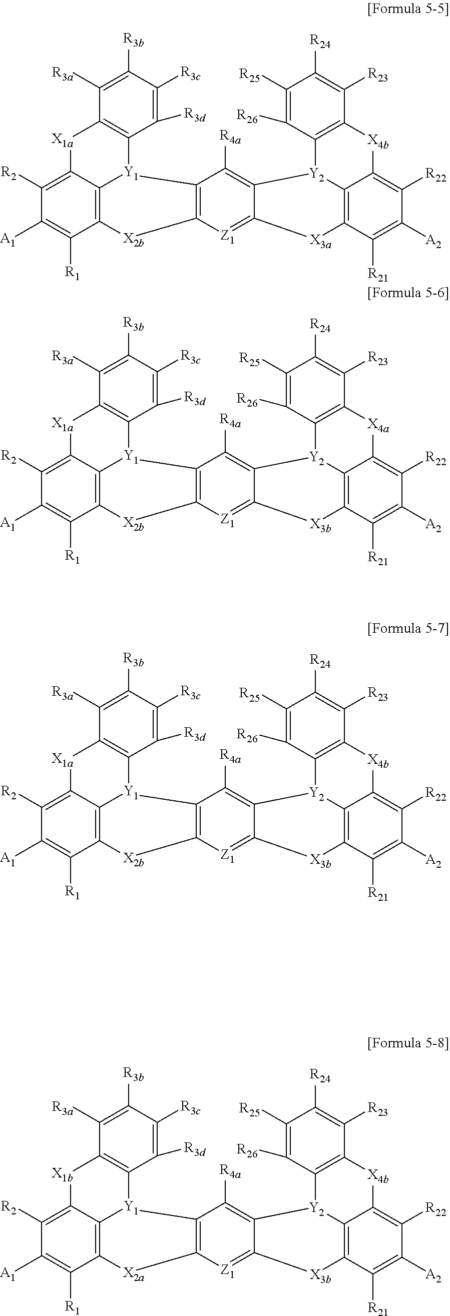

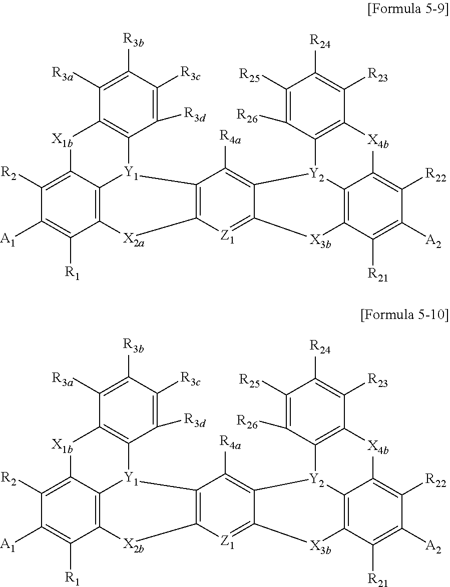

Formula 5-1 to Formula 5-10 represent the cases where the types of substituents, X₁ to X₄, are specified.

In Formula 5-1 to Formula 5-9, X₁ₐ to X₄ₐ may each independently be represented by Formula 2 above.

In Formula 5-2 to Formula 5-10, X_{1b} to X_{4b} may be each independently O, S, CR₄₁R₄₂, PR₄₃, NR₄₄, or BR₄₅.

In Formula 5-2 to Formula 5-10, R₄₁ to R₄₅ may be each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₄₁ to R₄₅ may be each independently a substituted or unsubstituted methyl group, a substituted or unsubstituted phenyl group, a substituted or unsubstituted biphenyl group, or a substituted or unsubstituted anthracenyl group.

In Formula 5-1 to Formula 5-10, the same as defined in Formula 1, Formula 1-1, and Formula 1-2 above may be applied to Z₁, A₁, A₂, Y₁, Y₂, R₁, R₂, R₃ₐ to R_{3d}, R₄ₐ, and R₂₁ to R₂₆.

In an embodiment, the fused polycyclic compound represented by Formula 1-2 may be represented by any one among Formula 6-1 to Formula 6-4 below:

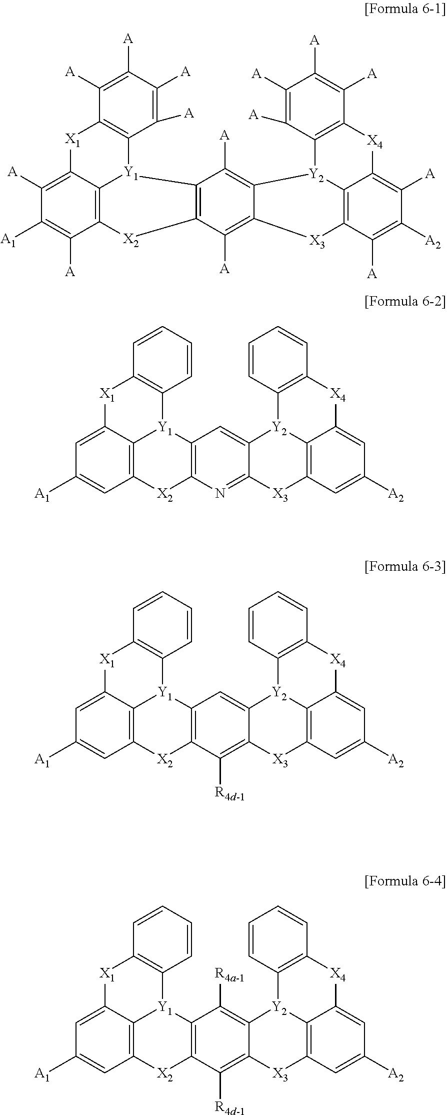

Formula 6-1 to Formula 6-4 represent the cases where the types of substituents, R₁, R₂, R₃ₐ to R_{3d}, R₄ₐ, Z₁, and R₂₁ to R₂₆, are specified in Formula 1-2. Formula 6-1 to Formula 6-4 represent the cases where the substituents represented by R₁, R₂, R₃ₐ to R₃ₐ, R₄ₐ, Z₁, and R₂₁ to R₂₆ in Formula 1-2 are specified as a hydrogen atom, a deuterium atom, or a nitrogen atom, or as linked to other substituents.

In Formula 6-1, A may be a hydrogen atom or a deuterium atom. Each position of a plurality of substituents represented by A in Formula 6-1 may be a hydrogen atom or a deuterium atom, or some positions may be hydrogen atoms and the other positions may be deuterium atoms.

In Formula 6-3 and Formula 6-4, R₄ₐ₋₁ and R_{4d-1} may be each independently a substituted or unsubstituted silyl group, a substituted or unsubstituted alkyl group having 1 to 20 carbon atoms, or a substituted or unsubstituted aryl group having 6 to 30 ring-forming carbon atoms. For example, R₄ₐ₋₁ and R_{4d-1} may be each independently a substituted or unsubstituted methyl group, a substituted or unsubstituted phenyl group, or a substituted or unsubstituted alkylsilyl group. That is, R₄ₐ₋₁ and R_{4d-1} may be substituents other than a hydrogen atom or a deuterium atom. For example, R₄ₐ₋₁ and R_{4d-1} may be each independently a substituted or unsubstituted methyl group, a substituted or unsubstituted phenyl group, or a substituted or unsubstituted alkylsilyl group.

In Formula 6-1 to Formula 6-4, the same as described in Formula 1 and Formula 1-2 above may be applied to X₁ to X₄, Y₁, Y₂, A₁, and A₂.

In an embodiment, the fused polycyclic compound represented by Formula 1-2 may be represented by any one among Formula 7-1 to Formula 7-5 below:

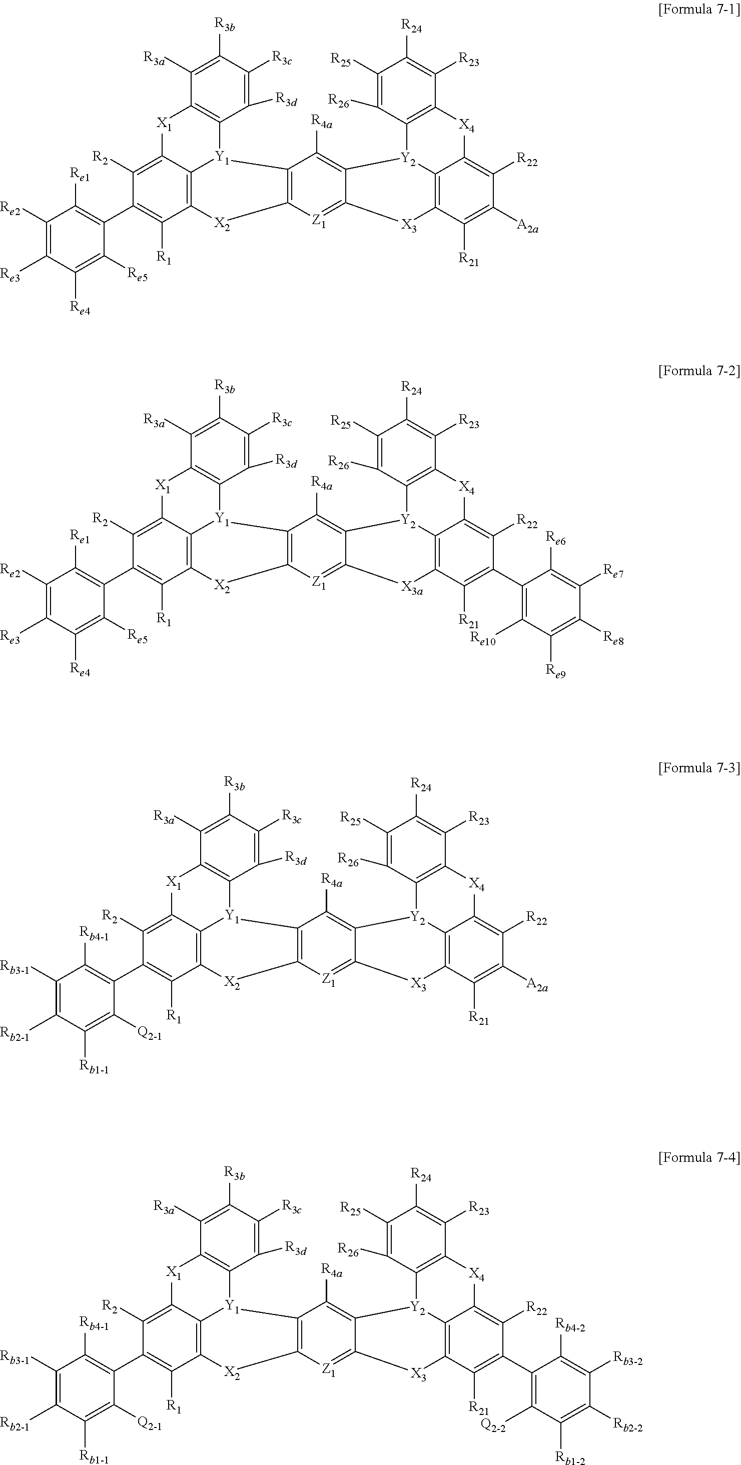

Formula 7-1 to Formula 7-4 represent the cases where the types of substituents, A₁ and A₂, are specified. Formula 7-1 represents the case where Ar₁ is a substituted or unsubstituted phenyl group in Formula 1-2. Formula 7-2 represents the case where each of Ar₁ and Ar₂ is a substituted or unsubstituted phenyl group in Formula 1-2. Formula 7-3 represents the case where Ar₁ is represented by Formula 3 in Formula 1-2. Formula 7-4 represents the case where each of Ar₁ and Ar₂ is represented by Formula 3 in Formula 1-2.

In Formula 7-1 and Formula 7-3, A₂ₐ may be a hydrogen atom, a deuterium atom, a substituted or unsubstituted amine group, a substituted or unsubstituted oxy group, a substituted or unsubstituted silyl group, a substituted or unsubstituted alkyl group having 1 to 20 carbon atoms, or a substituted or unsubstituted heteroaryl group containing N as a ring-forming atom. For example, A₂ₐ may be a hydrogen atom, a deuterium atom, a substituted or unsubstituted t-butyl group, a substituted or unsubstituted isopropyl group, a substituted or unsubstituted cyclohexyl group, a substituted or unsubstituted adamantyl group, a substituted or unsubstituted diphenylamine group, a substituted or unsubstituted phenyloxy group, a substituted or unsubstituted triphenylsilyl group, a substituted or unsubstituted carbazole group, a substituted or unsubstituted dibenzoazasiline group, or a substituted or unsubstituted spirobiacridine group (10H,10′H-9,9′-Spirobi[acridine]).

In Formula 7-1 and Formula 7-2, Rₑ₁ to Rₑ₁₀ may be each independently a hydrogen atom, a deuterium atom, a halogen atom, a nitro group, a substituted or unsubstituted silyl group, a substituted or unsubstituted methyl group, a substituted or unsubstituted alkenyl group having 2 to 20 carbon atoms, or a substituted or unsubstituted phenyl group. Alternatively, each of Rₑ₁ to Rₑ₁₀ may be bonded to an adjacent group to form a ring.

In Formula 7-3 and Formula 7-4, Q₂₋₁ and Q₂₋₂ may be each independently a substituted or unsubstituted arylamine group, a substituted or unsubstituted arylsilyl group, a substituted or unsubstituted arylthio group, a substituted or unsubstituted aryloxy group, a substituted or unsubstituted alkyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. The description of Q₂ in Formula 3 may be equally applied to Q₂₋₁ and Q₂₋₂.

In Formula 7-3 and Formula 7-4, R_{b1-1} to R_{b4-1} and R_{b1-2} to R_{b4-2} may be each independently a hydrogen atom, a deuterium atom, a substituted or unsubstituted alkyl group having 1 to 20 carbon atoms, or a substituted or unsubstituted aryl group having 6 to 30 ring-forming carbon atoms. R_{b1-1} to R_{b4-1} and R_{b1-2} to R_{b4-2} may be each independently a hydrogen atom, a deuterium atom, a substituted or unsubstituted methyl group, a substituted or unsubstituted ethyl group, a substituted or unsubstituted isopropyl group, or a substituted or unsubstituted phenyl group.

In Formula 7-1 to Formula 7-4, the same as described in Formula 1, Formula 1-1, and Formula 1-2 above may be applied to X₁ to X₄, Y₁, Y₂, Z₁, R₁, R₂, R₃ₐ to R_{3d}, R₄ₐ, and R₂₁ to R₂₆.

The fused polycyclic compound of an embodiment may be any one among the compounds represented by Compound Group 1 below. The light emitting device ED of an embodiment may include at least one fused polycyclic compound among the compounds represented by Compound Group 1 in the emission layer EML.

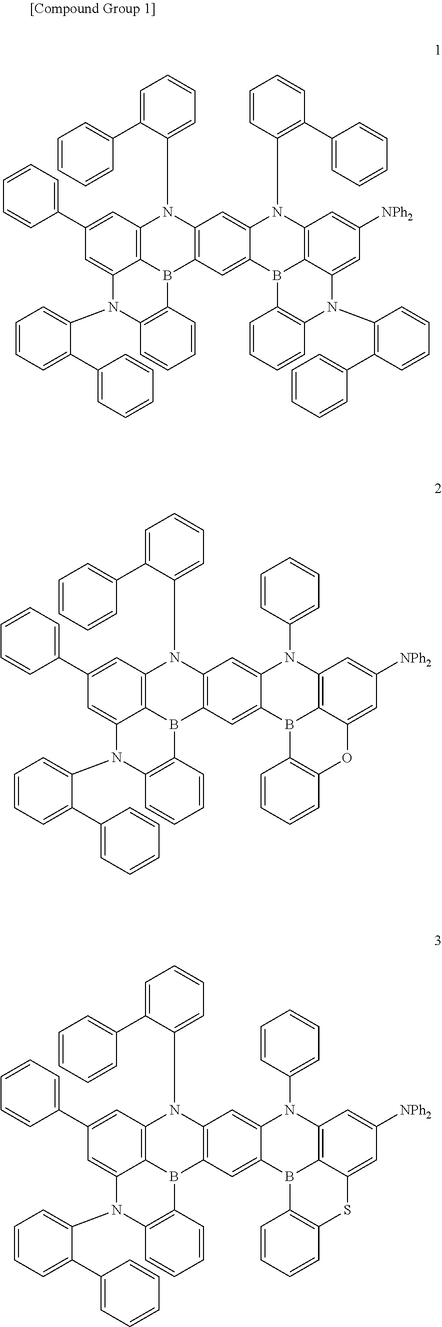

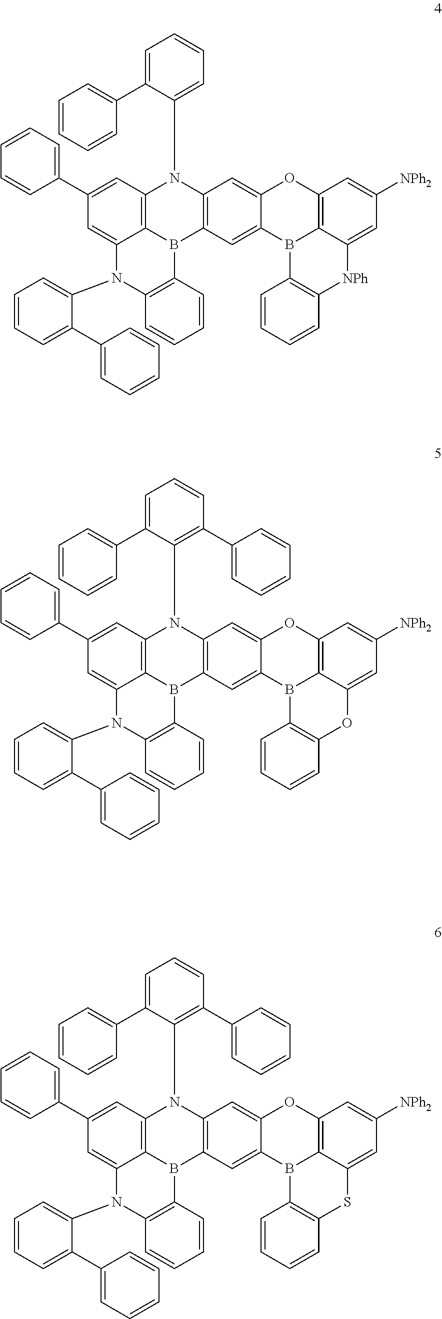

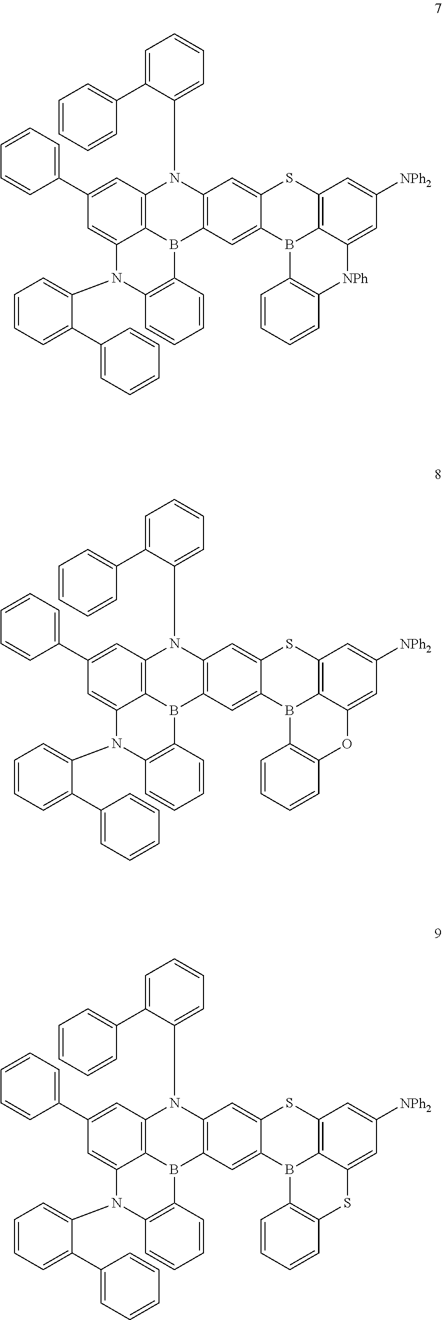

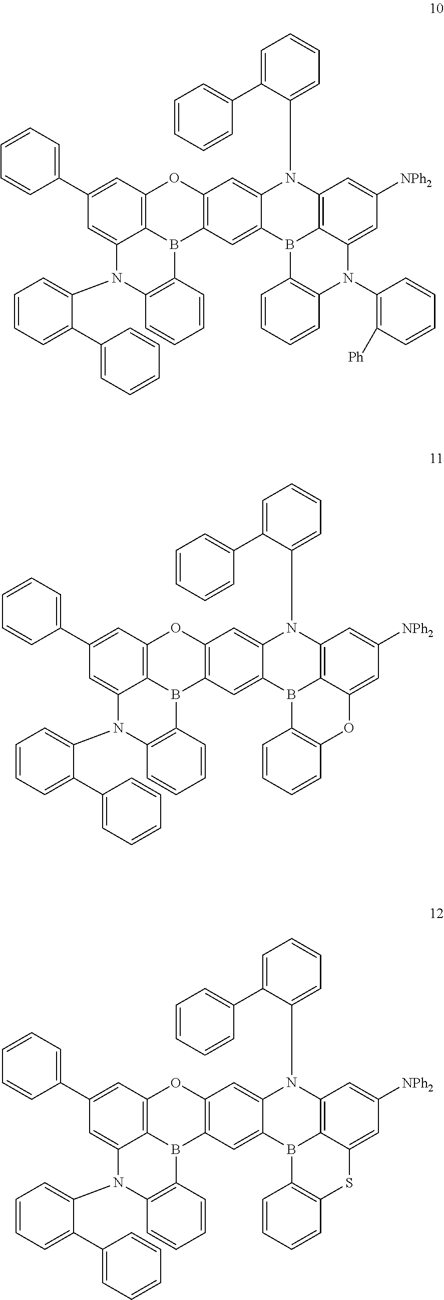

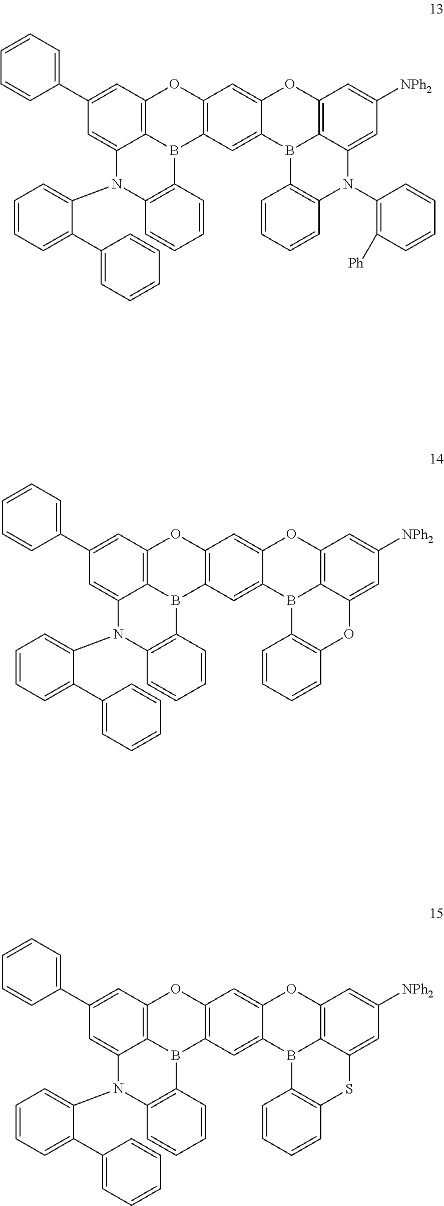

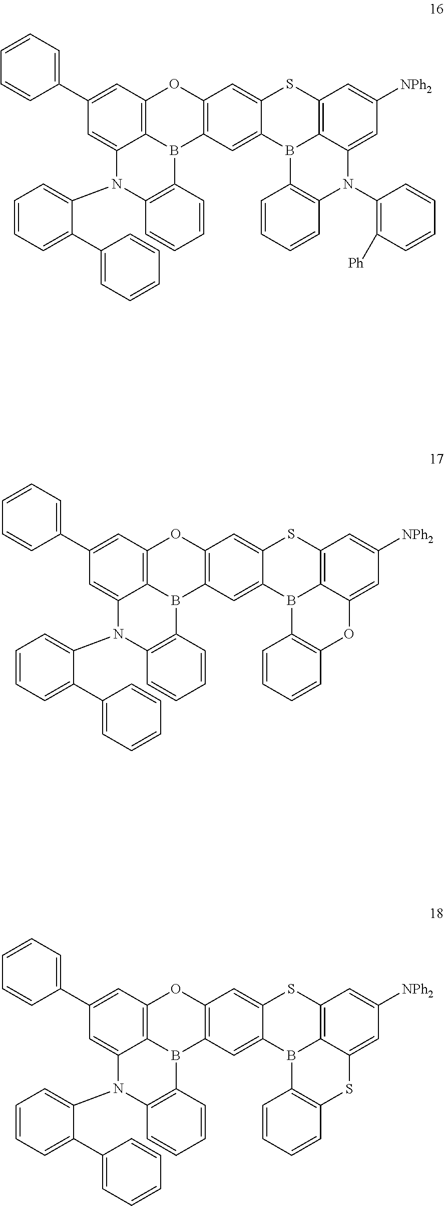

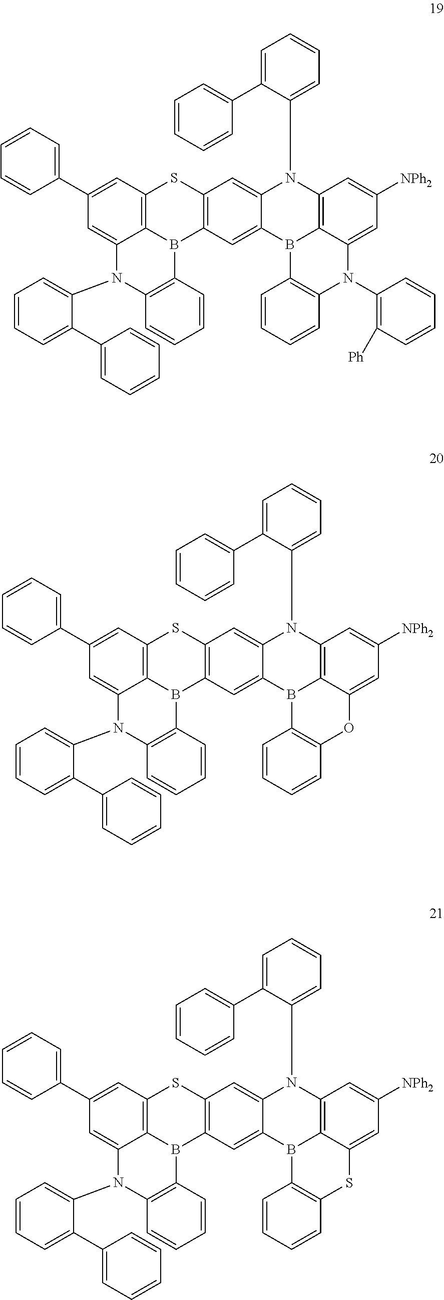

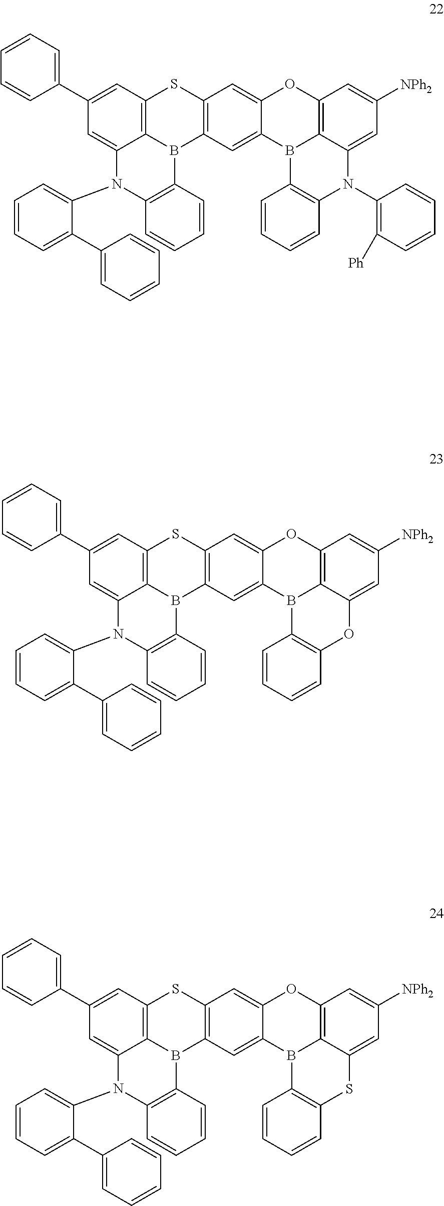

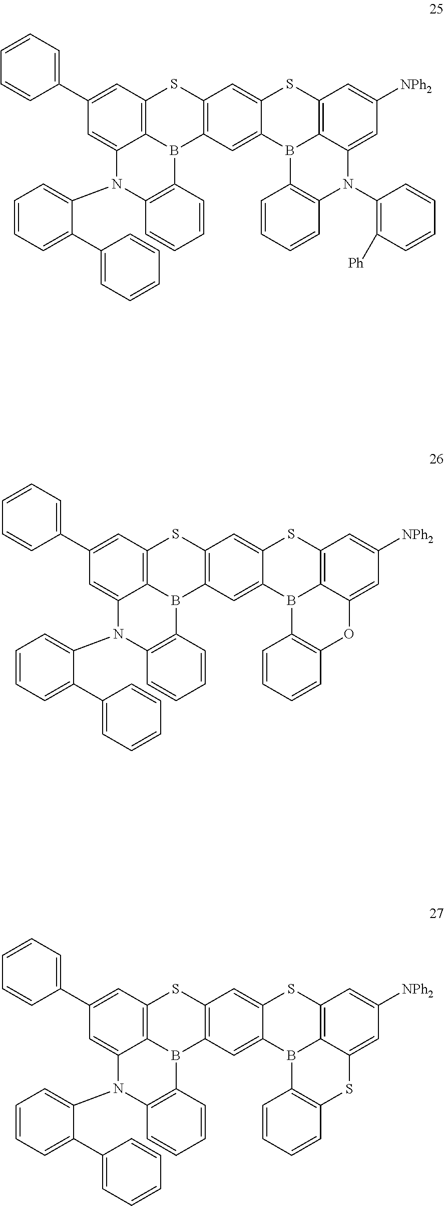

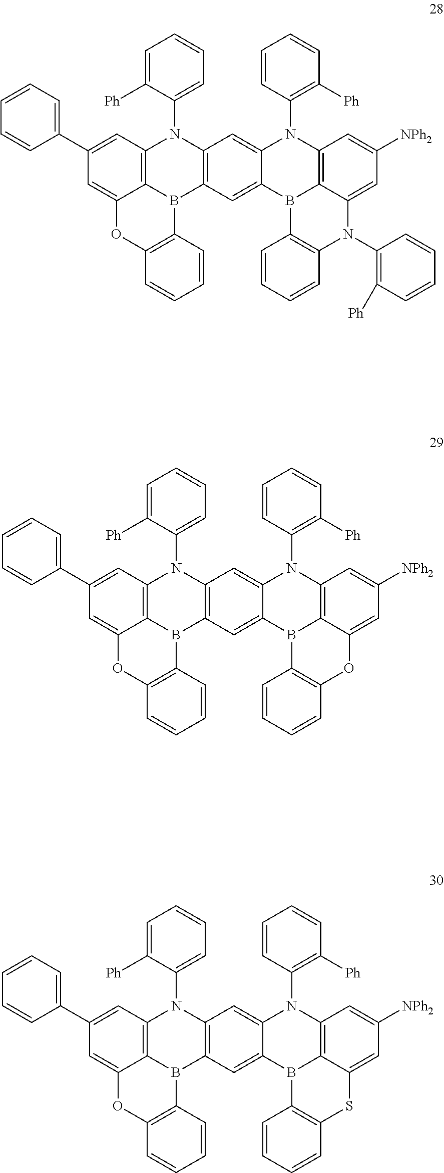

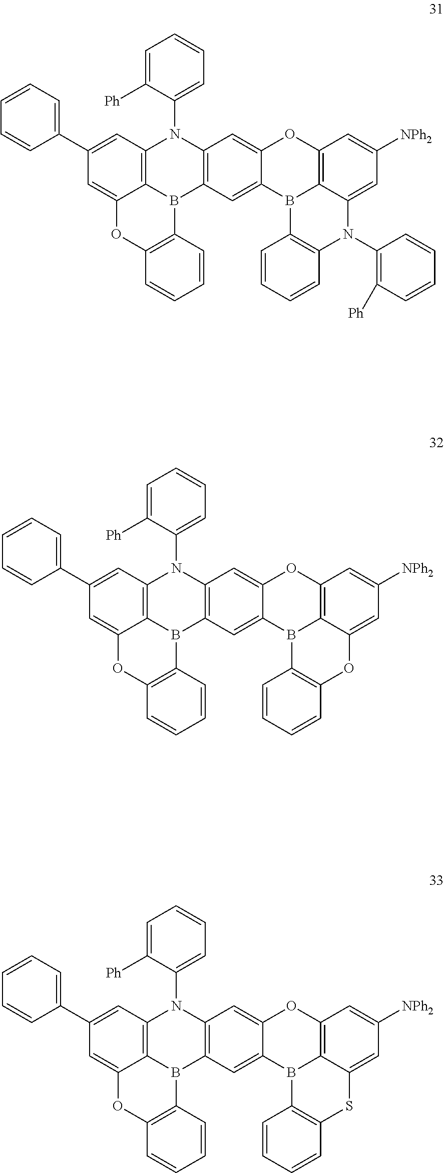

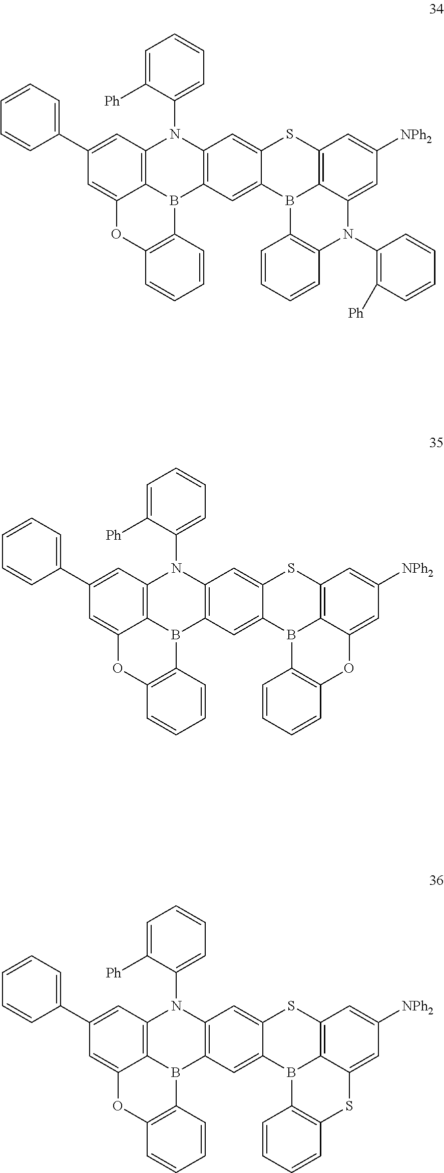

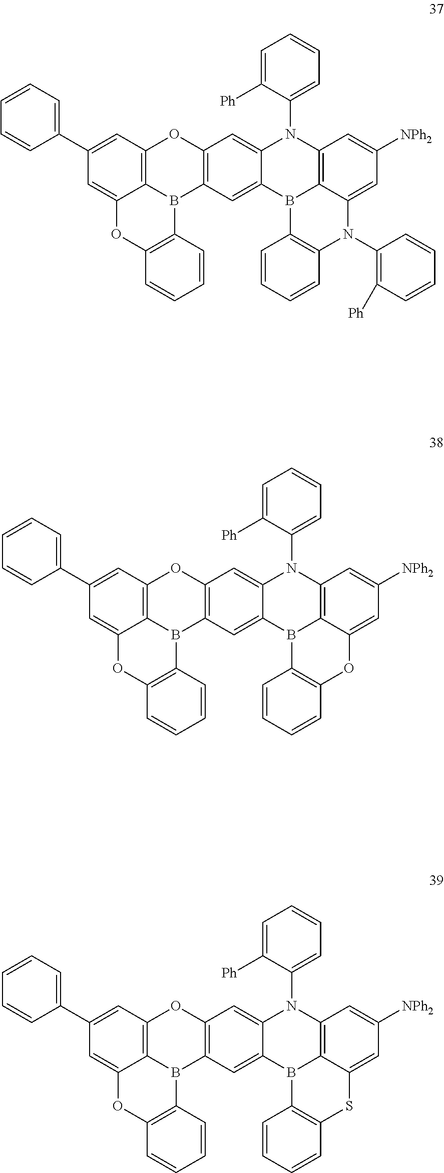

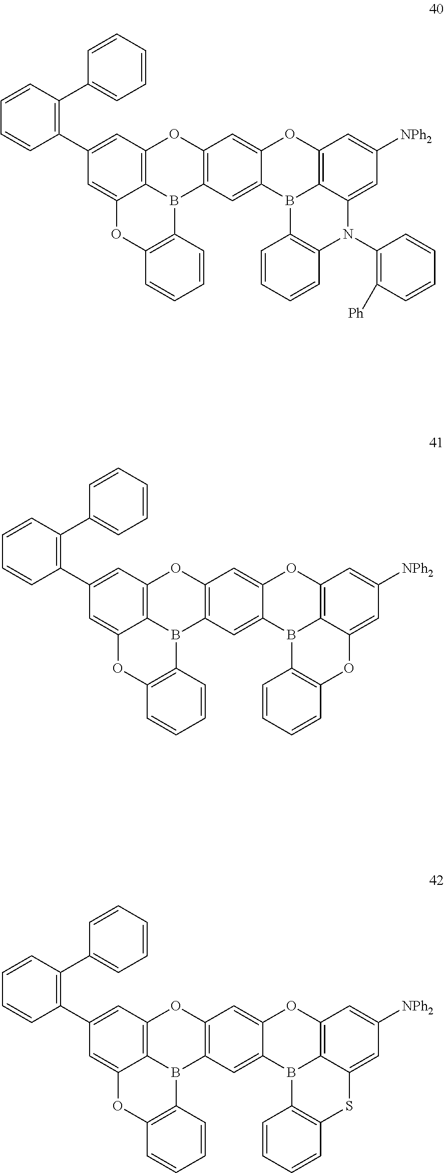

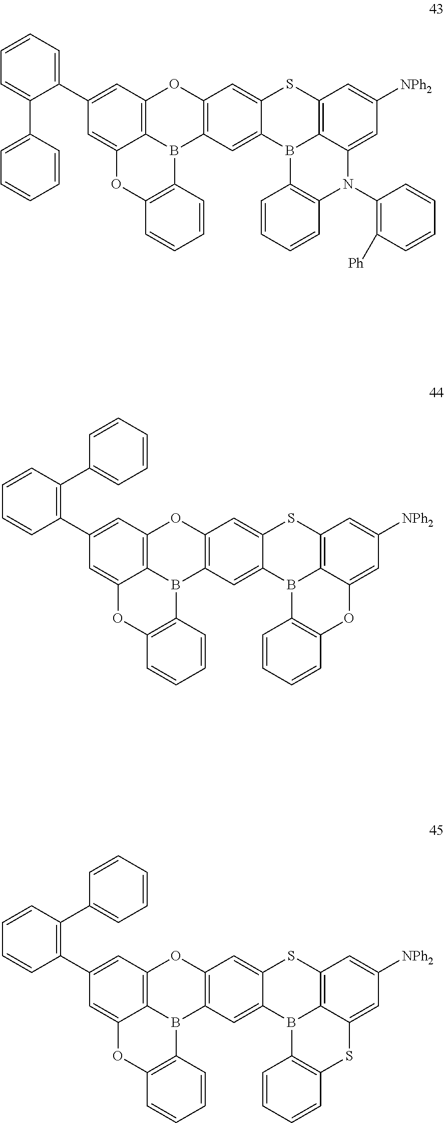

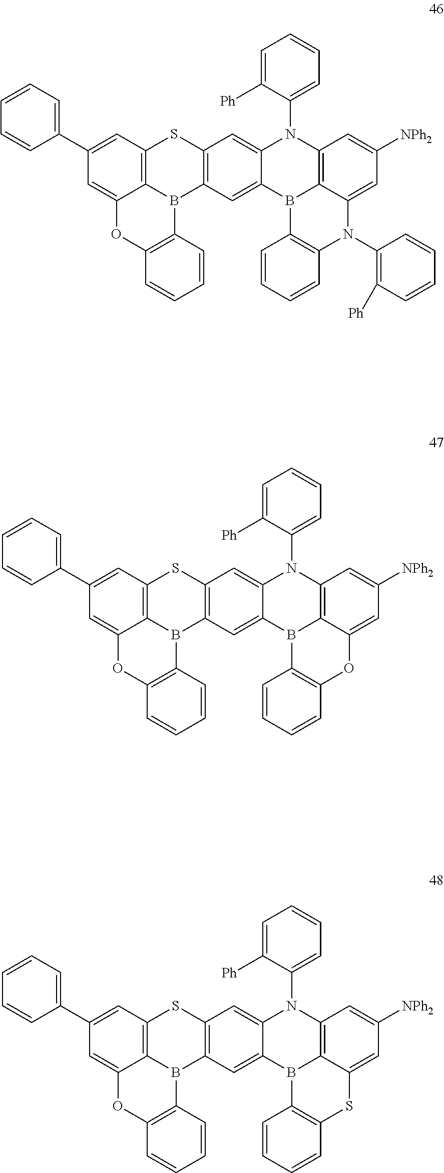

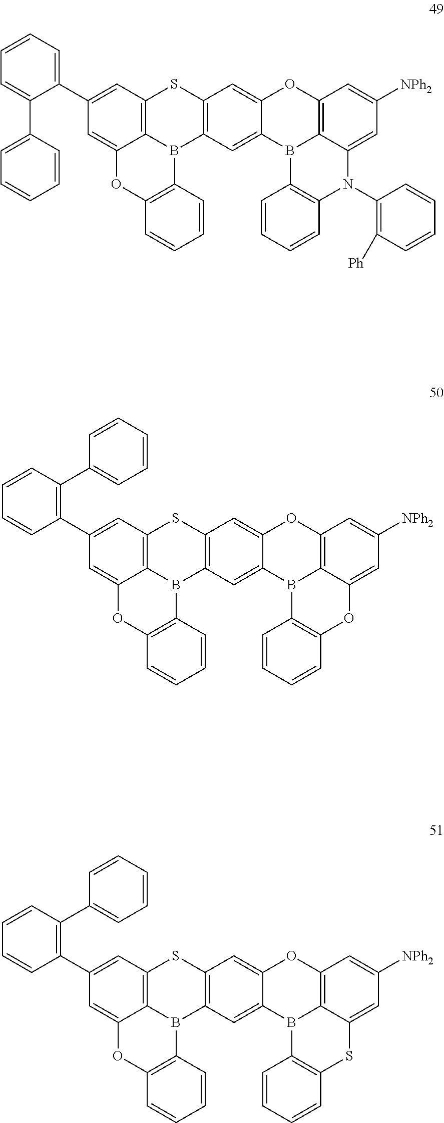

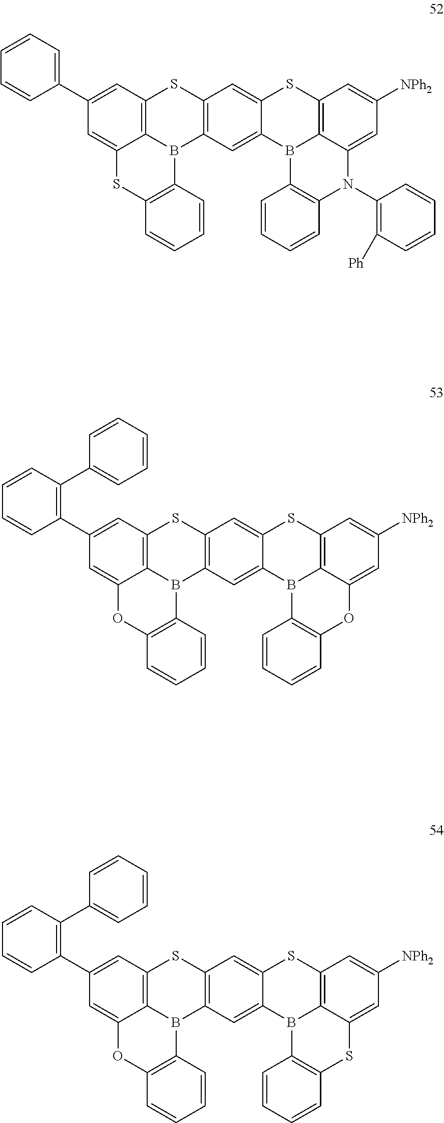

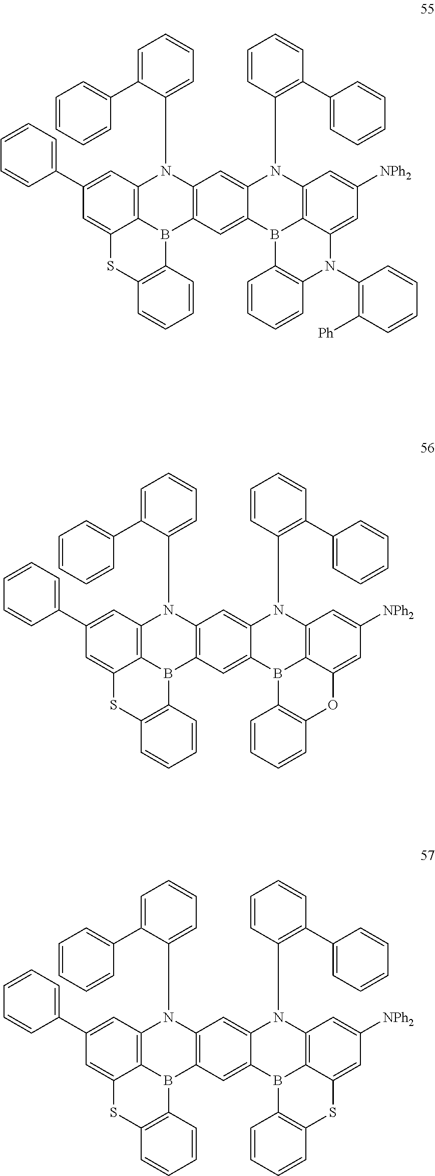

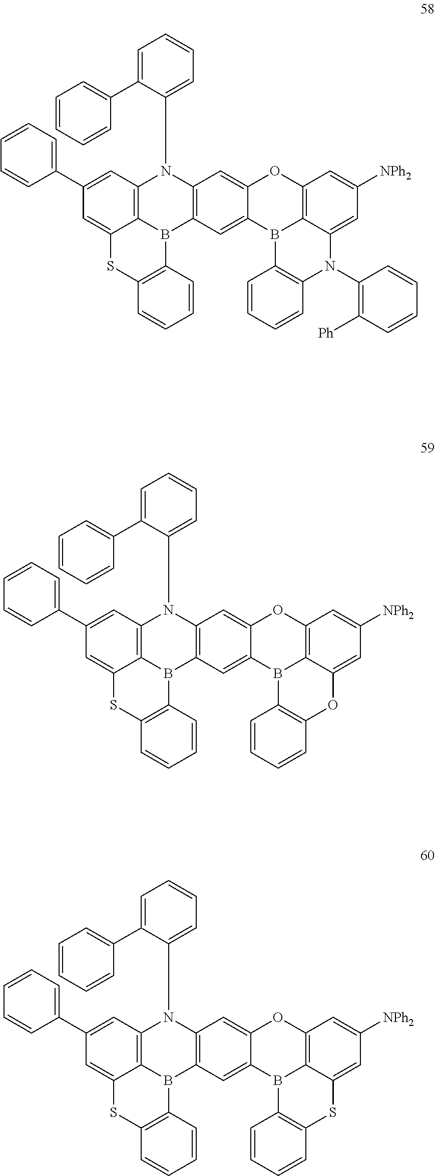

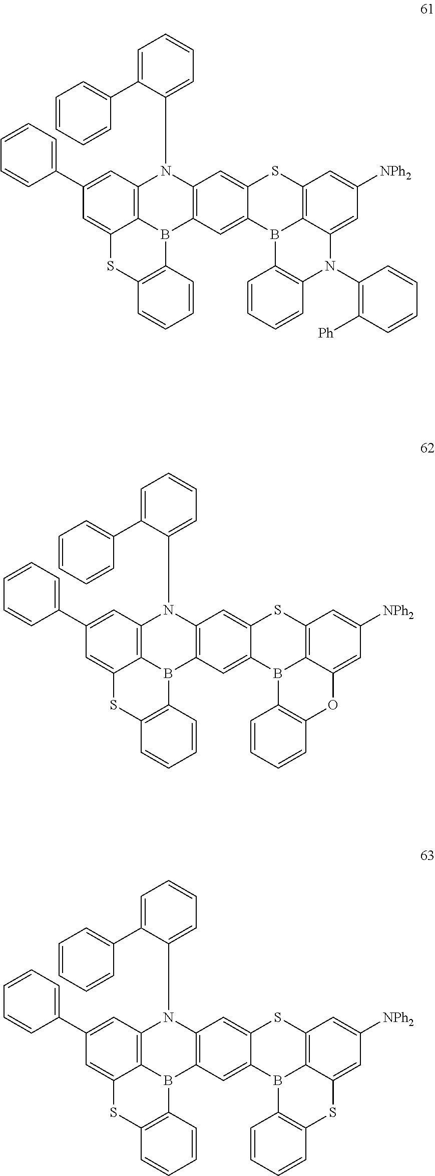

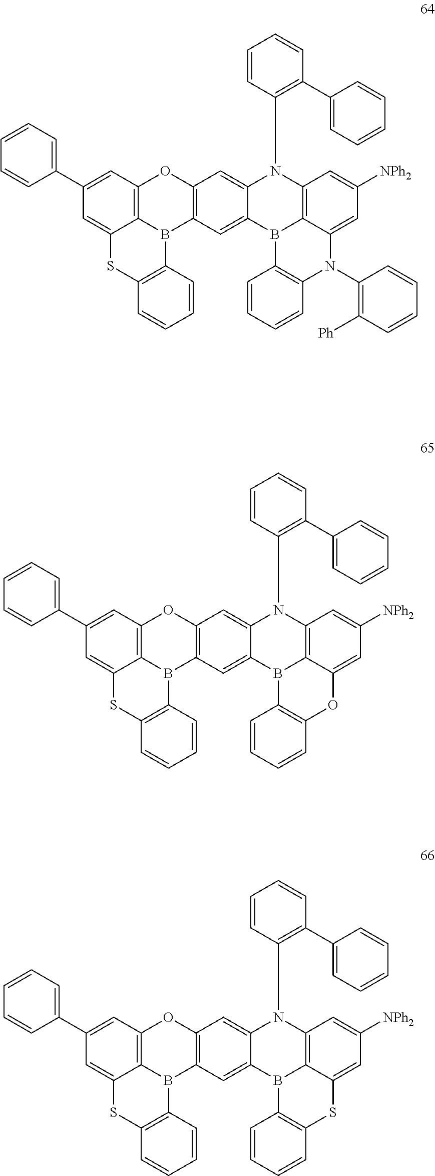

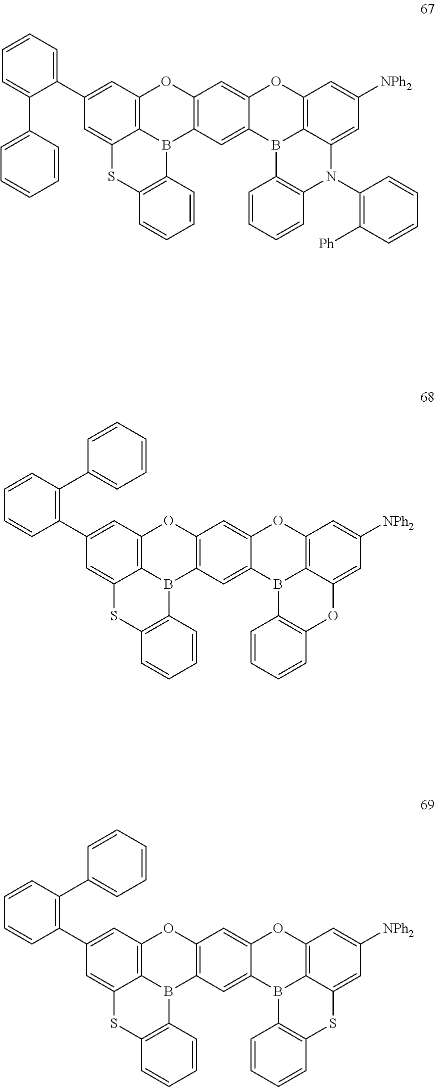

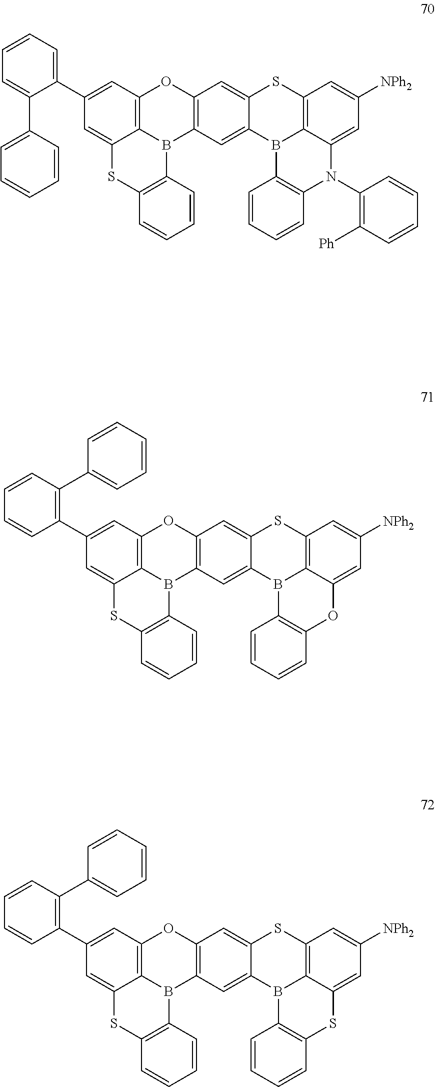

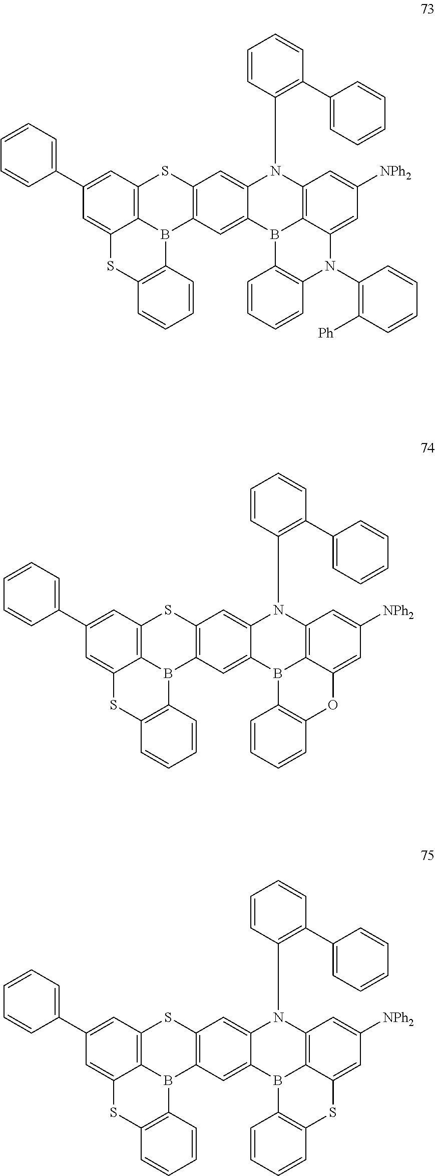

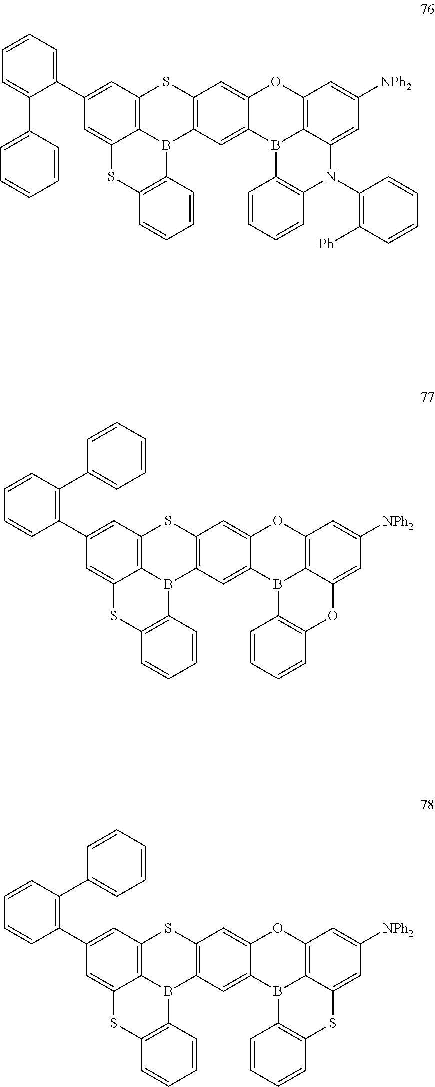

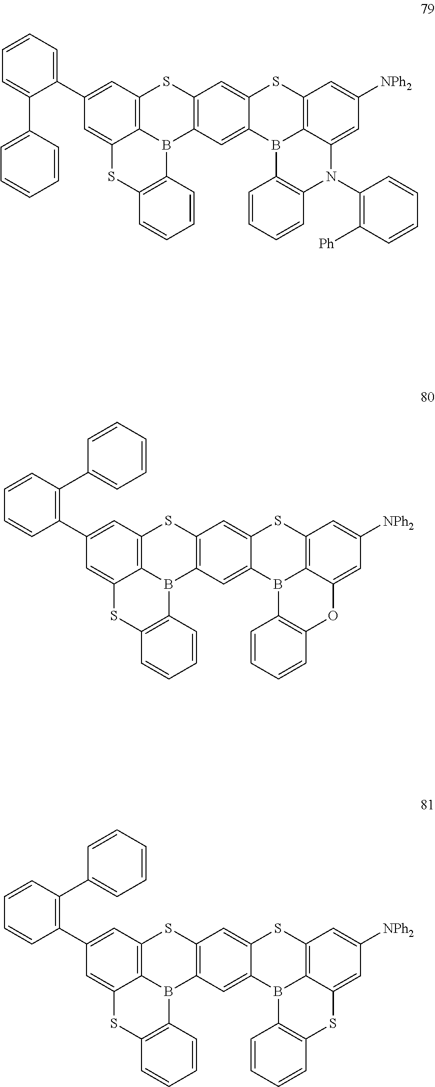

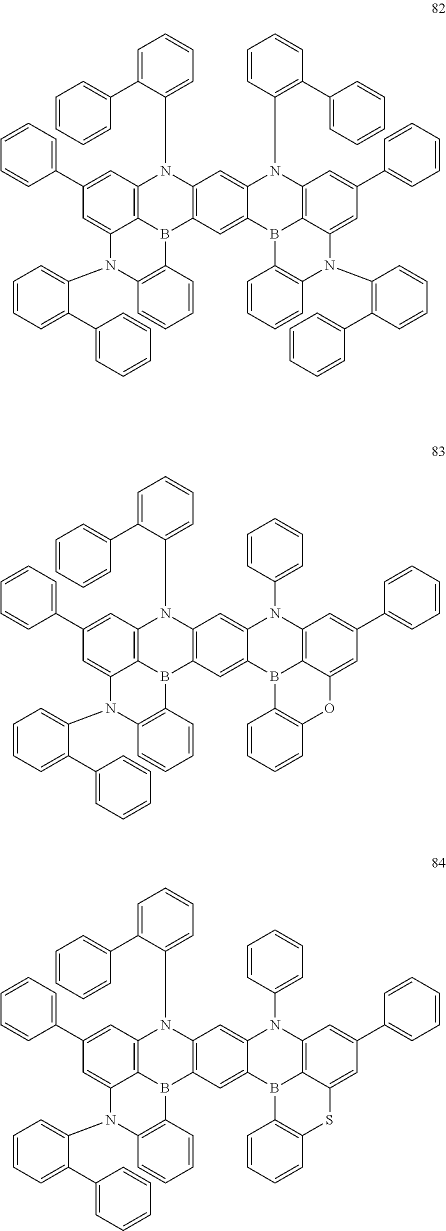 [SMILES: c1ccc(-c2cc3c4c(c2)N(c2ccccc2-c2ccccc2)c2cc5c(cc2B4c2ccccc2N3c2ccccc2-c2ccccc2)B2c3ccccc3N(c3ccccc3-c3ccccc3)c3cc(-c4ccccc4)cc(c32)N5c2ccccc2-c2ccccc2)cc1 ; c1ccc(-c2cc3c4c(c2)N(c2ccccc2)c2cc5c(cc2B4c2ccccc2O3)B2c3ccccc3N(c3ccccc3-c3ccccc3)c3cc(-c4ccccc4)cc(c32)N5c2ccccc2-c2ccccc2)cc1 ; c1ccc(-c2cc3c4c(c2)N(c2ccccc2)c2cc5c(cc2B4c2ccccc2S3)B2c3ccccc3N(c3ccccc3-c3ccccc3)c3cc(-c4ccccc4)cc(c32)N5c2ccccc2-c2ccccc2)cc1]

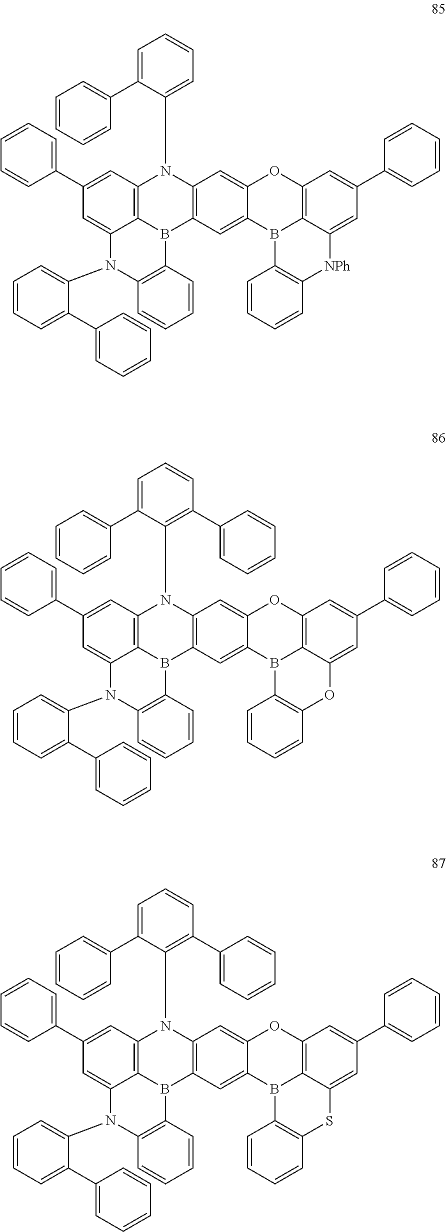

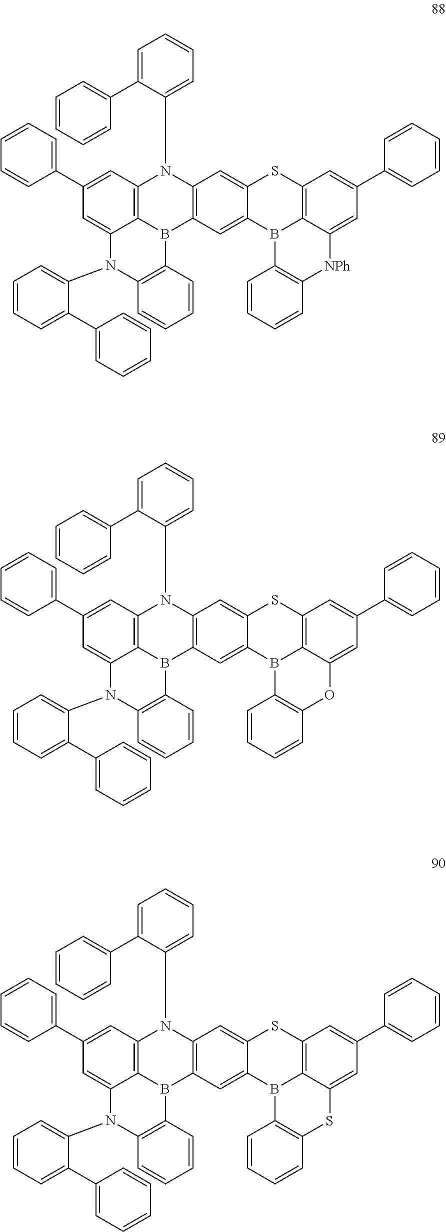

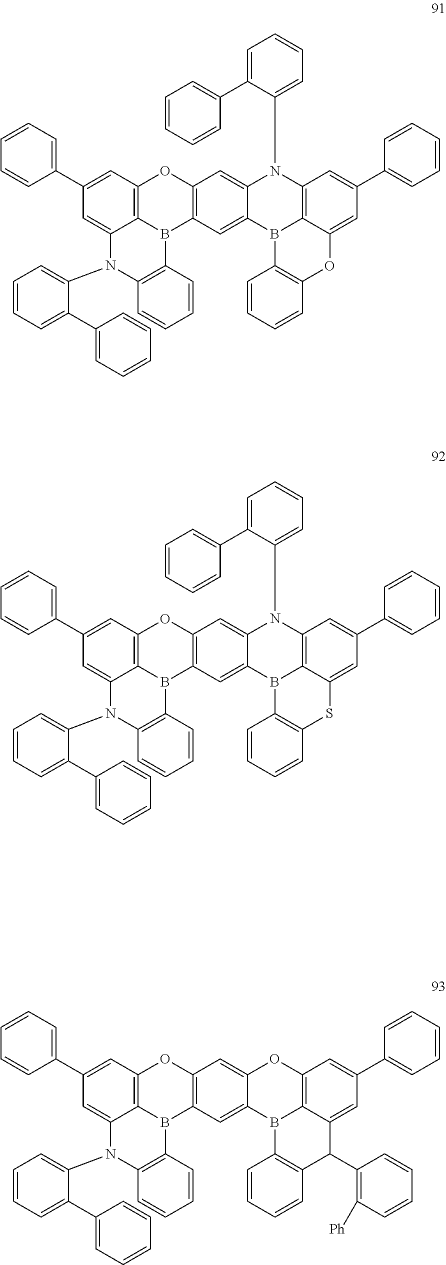 [SMILES: c1ccc(-c2cc3c4c(c2)N(c2ccccc2-c2ccccc2)c2ccccc2B4c2cc4c(cc2O3)N(c2ccccc2-c2ccccc2)c2cc(-c3ccccc3)cc3c2B4c2ccccc2O3)cc1 ; c1ccc(-c2cc3c4c(c2)N(c2ccccc2-c2ccccc2)c2ccccc2B4c2cc4c(cc2O3)N(c2ccccc2-c2ccccc2)c2cc(-c3ccccc3)cc3c2B4c2ccccc2S3)cc1 ; c1ccc(-c2cc3c4c(c2)C(c2ccccc2-c2ccccc2)c2ccccc2B4c2cc4c(cc2O3)Oc2cc(-c3ccccc3)cc3c2B4c2ccccc2N3c2ccccc2-c2ccccc2)cc1]

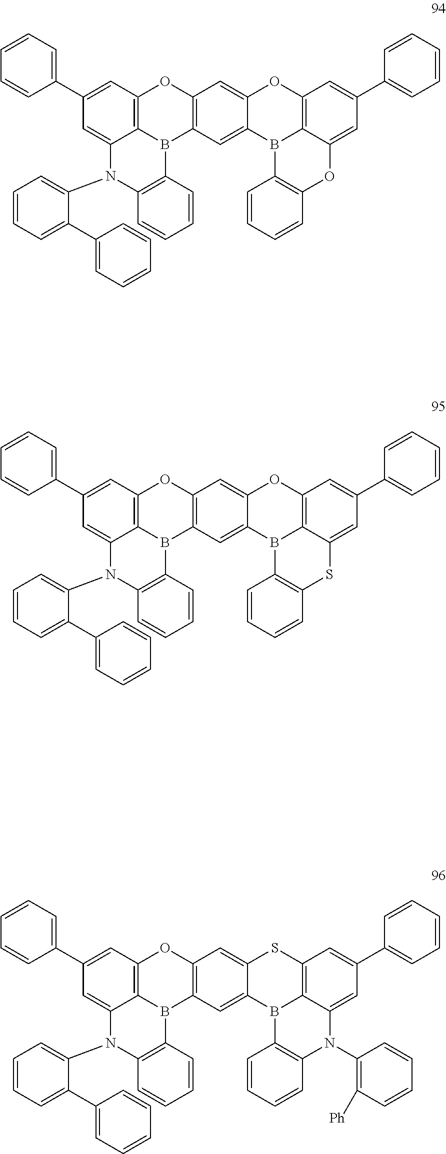 [SMILES: c1ccc(-c2cc3c4c(c2)Oc2cc5c(cc2B4c2ccccc2O3)B2c3ccccc3N(c3ccccc3-c3ccccc3)c3cc(-c4ccccc4)cc(c32)O5)cc1 ; c1ccc(-c2cc3c4c(c2)Sc2ccccc2B4c2cc4c(cc2O3)Oc2cc(-c3ccccc3)cc3c2B4c2ccccc2N3c2ccccc2-c2ccccc2)cc1 ; c1ccc(-c2cc3c4c(c2)N(c2ccccc2-c2ccccc2)c2ccccc2B4c2cc4c(cc2O3)Sc2cc(-c3ccccc3)cc3c2B4c2ccccc2N3c2ccccc2-c2ccccc2)cc1]

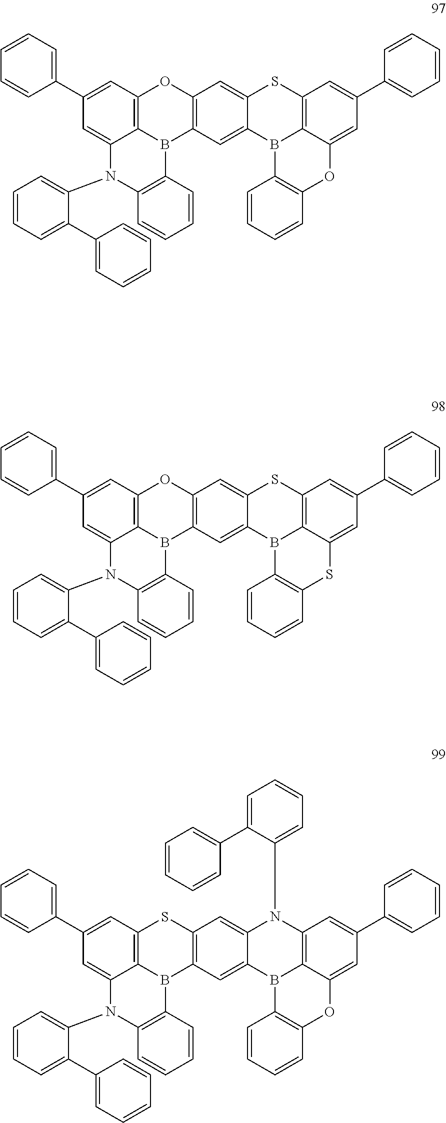 [SMILES: c1ccc(-c2cc3c4c(c2)Sc2cc5c(cc2B4c2ccccc2O3)B2c3ccccc3N(c3ccccc3-c3ccccc3)c3cc(-c4ccccc4)cc(c32)O5)cc1 ; c1ccc(-c2cc3c4c(c2)Sc2cc5c(cc2B4c2ccccc2S3)B2c3ccccc3N(c3ccccc3-c3ccccc3)c3cc(-c4ccccc4)cc(c32)O5)cc1 ; c1ccc(-c2cc3c4c(c2)N(c2ccccc2-c2ccccc2)c2cc5c(cc2B4c2ccccc2O3)B2c3ccccc3N(c3ccccc3-c3ccccc3)c3cc(-c4ccccc4)cc(c32)S5)cc1]

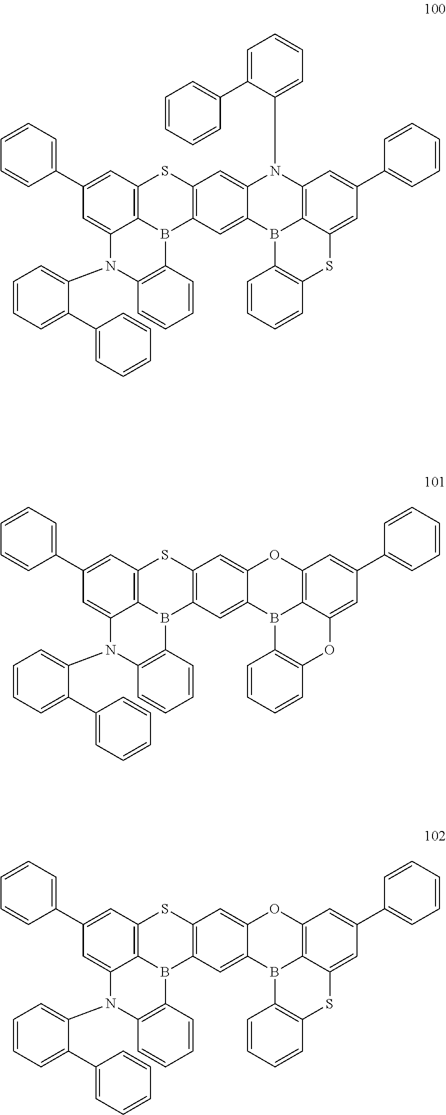 [SMILES: c1ccc(-c2cc3c4c(c2)N(c2ccccc2-c2ccccc2)c2ccccc2B4c2cc4c(cc2S3)N(c2ccccc2-c2ccccc2)c2cc(-c3ccccc3)cc3c2B4c2ccccc2S3)cc1 ; c1ccc(-c2cc3c4c(c2)Oc2cc5c(cc2B4c2ccccc2O3)B2c3ccccc3N(c3ccccc3-c3ccccc3)c3cc(-c4ccccc4)cc(c32)S5)cc1 ; c1ccc(-c2cc3c4c(c2)Sc2ccccc2B4c2cc4c(cc2O3)Sc2cc(-c3ccccc3)cc3c2B4c2ccccc2N3c2ccccc2-c2ccccc2)cc1]

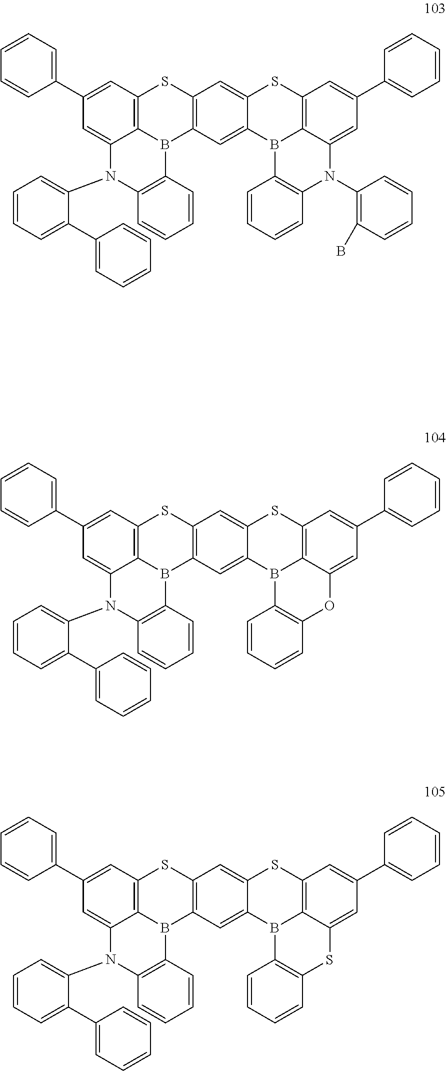

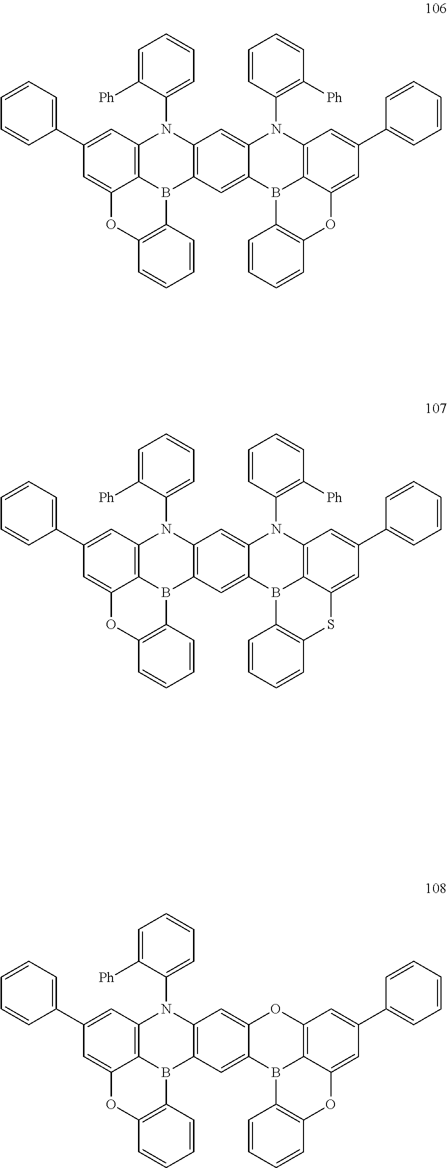 [SMILES: c1ccc(-c2cc3c4c(c2)N(c2ccccc2-c2ccccc2)c2cc5c(cc2B4c2ccccc2O3)B2c3ccccc3Oc3cc(-c4ccccc4)cc(c32)N5c2ccccc2-c2ccccc2)cc1 ; c1ccc(-c2cc3c4c(c2)N(c2ccccc2-c2ccccc2)c2cc5c(cc2B4c2ccccc2O3)B2c3ccccc3Sc3cc(-c4ccccc4)cc(c32)N5c2ccccc2-c2ccccc2)cc1 ; c1ccc(-c2cc3c4c(c2)Oc2cc5c(cc2B4c2ccccc2O3)B2c3ccccc3Oc3cc(-c4ccccc4)cc(c32)N5c2ccccc2-c2ccccc2)cc1]

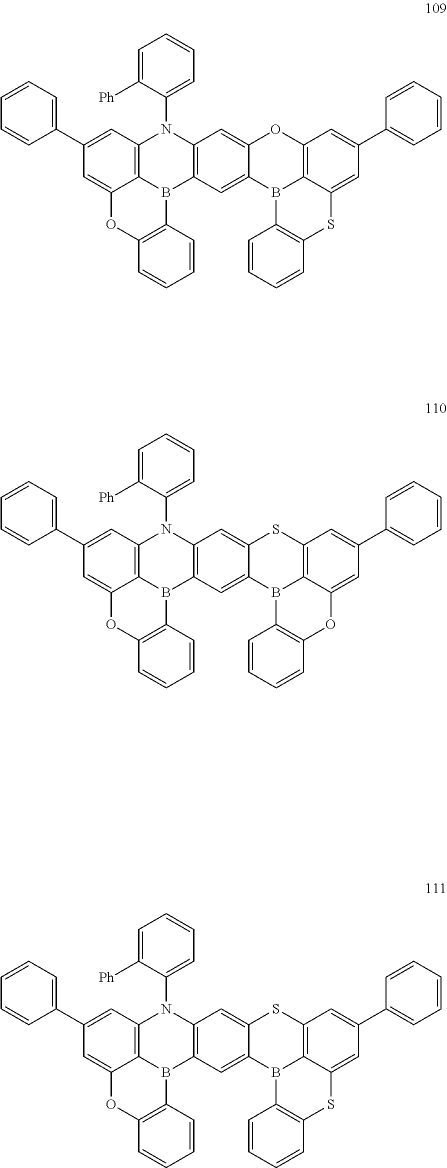 [SMILES: c1ccc(-c2cc3c4c(c2)Sc2ccccc2B4c2cc4c(cc2O3)N(c2ccccc2-c2ccccc2)c2cc(-c3ccccc3)cc3c2B4c2ccccc2O3)cc1 ; c1ccc(-c2cc3c4c(c2)Sc2cc5c(cc2B4c2ccccc2O3)B2c3ccccc3Oc3cc(-c4ccccc4)cc(c32)N5c2ccccc2-c2ccccc2)cc1 ; c1ccc(-c2cc3c4c(c2)Sc2cc5c(cc2B4c2ccccc2S3)B2c3ccccc3Oc3cc(-c4ccccc4)cc(c32)N5c2ccccc2-c2ccccc2)cc1]

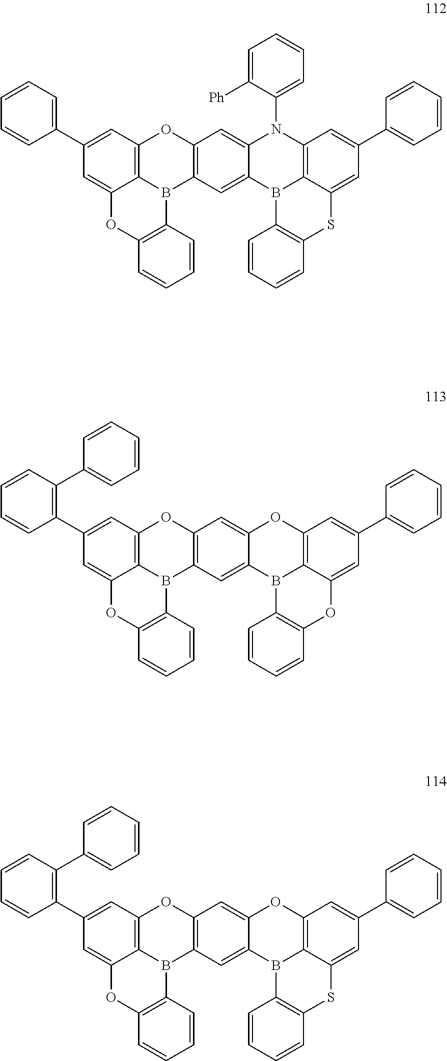 [SMILES: c1ccc(-c2cc3c4c(c2)Oc2cc5c(cc2B4c2ccccc2O3)B2c3ccccc3Sc3cc(-c4ccccc4)cc(c32)N5c2ccccc2-c2ccccc2)cc1 ; c1ccc(-c2cc3c4c(c2)Oc2cc5c(cc2B4c2ccccc2O3)B2c3ccccc3Oc3cc(-c4ccccc4-c4ccccc4)cc(c32)O5)cc1 ; c1ccc(-c2cc3c4c(c2)Sc2ccccc2B4c2cc4c(cc2O3)Oc2cc(-c3ccccc3-c3ccccc3)cc3c2B4c2ccccc2O3)cc1]

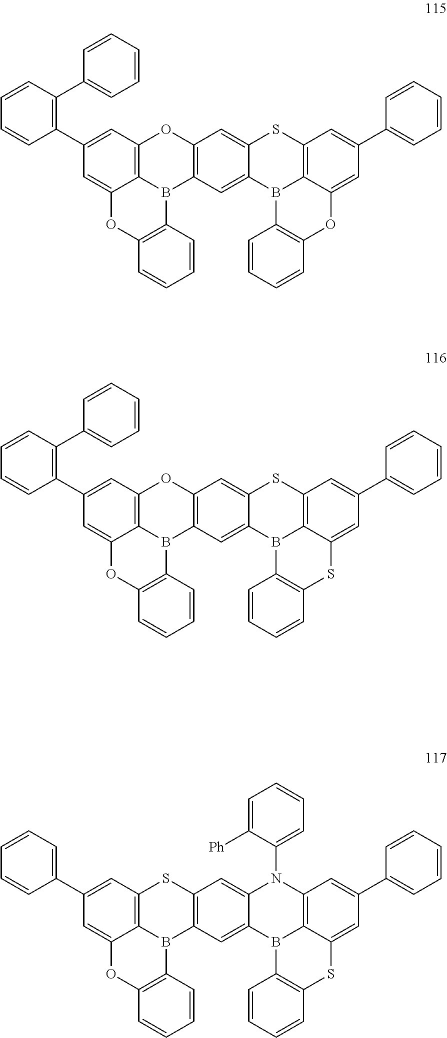 [SMILES: c1ccc(-c2cc3c4c(c2)Sc2cc5c(cc2B4c2ccccc2O3)B2c3ccccc3Oc3cc(-c4ccccc4-c4ccccc4)cc(c32)O5)cc1 ; c1ccc(-c2cc3c4c(c2)Sc2cc5c(cc2B4c2ccccc2S3)B2c3ccccc3Oc3cc(-c4ccccc4-c4ccccc4)cc(c32)O5)cc1 ; c1ccc(-c2cc3c4c(c2)Sc2cc5c(cc2B4c2ccccc2O3)B2c3ccccc3Sc3cc(-c4ccccc4)cc(c32)N5c2ccccc2-c2ccccc2)cc1]

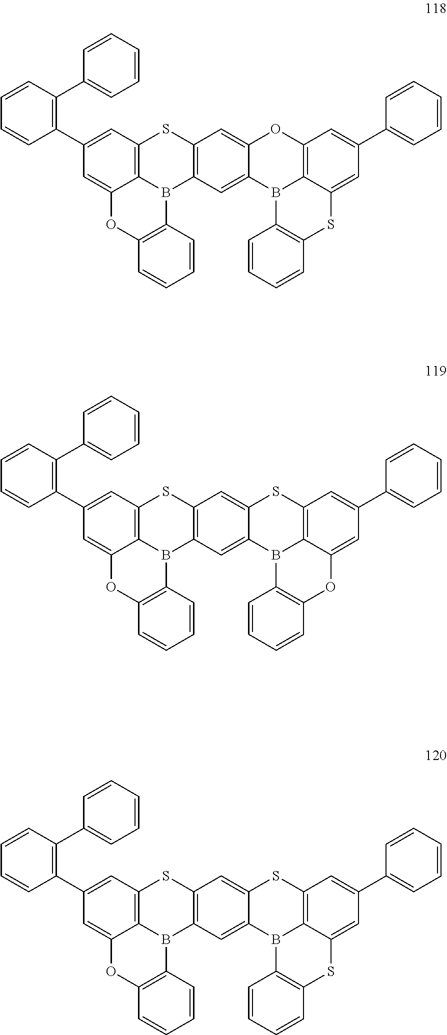 [SMILES: c1ccc(-c2cc3c4c(c2)Sc2ccccc2B4c2cc4c(cc2O3)Sc2cc(-c3ccccc3-c3ccccc3)cc3c2B4c2ccccc2O3)cc1 ; c1ccc(-c2cc3c4c(c2)Sc2cc5c(cc2B4c2ccccc2O3)B2c3ccccc3Oc3cc(-c4ccccc4-c4ccccc4)cc(c32)S5)cc1 ; c1ccc(-c2cc3c4c(c2)Sc2cc5c(cc2B4c2ccccc2S3)B2c3ccccc3Oc3cc(-c4ccccc4-c4ccccc4)cc(c32)S5)cc1]

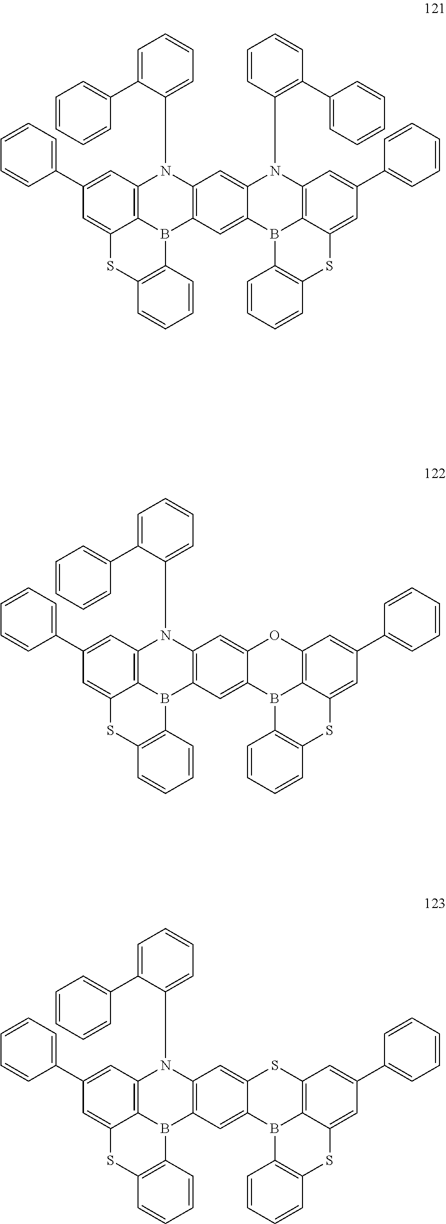 [SMILES: c1ccc(-c2cc3c4c(c2)N(c2ccccc2-c2ccccc2)c2cc5c(cc2B4c2ccccc2S3)B2c3ccccc3Sc3cc(-c4ccccc4)cc(c32)N5c2ccccc2-c2ccccc2)cc1 ; c1ccc(-c2cc3c4c(c2)Sc2ccccc2B4c2cc4c(cc2O3)N(c2ccccc2-c2ccccc2)c2cc(-c3ccccc3)cc3c2B4c2ccccc2S3)cc1 ; c1ccc(-c2cc3c4c(c2)Sc2cc5c(cc2B4c2ccccc2S3)B2c3ccccc3Sc3cc(-c4ccccc4)cc(c32)N5c2ccccc2-c2ccccc2)cc1]

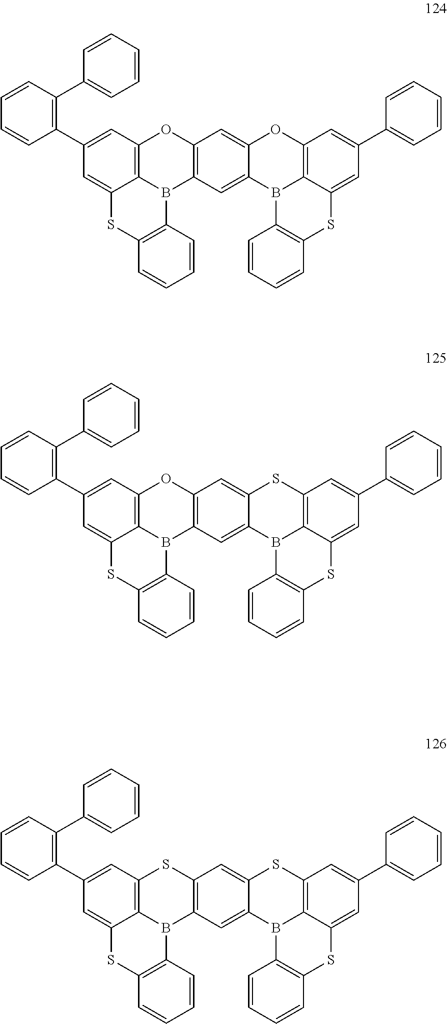 [SMILES: c1ccc(-c2cc3c4c(c2)Sc2ccccc2B4c2cc4c(cc2O3)Oc2cc(-c3ccccc3-c3ccccc3)cc3c2B4c2ccccc2S3)cc1 ; c1ccc(-c2cc3c4c(c2)Sc2cc5c(cc2B4c2ccccc2S3)B2c3ccccc3Sc3cc(-c4ccccc4-c4ccccc4)cc(c32)O5)cc1 ; c1ccc(-c2cc3c4c(c2)Sc2cc5c(cc2B4c2ccccc2S3)B2c3ccccc3Sc3cc(-c4ccccc4-c4ccccc4)cc(c32)S5)cc1]

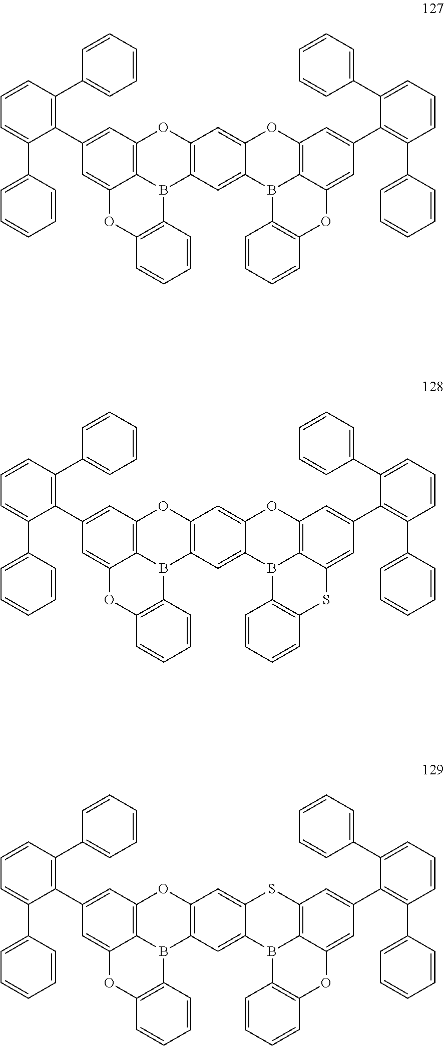 [SMILES: c1ccc(-c2cccc(-c3ccccc3)c2-c2cc3c4c(c2)Oc2cc5c(cc2B4c2ccccc2O3)B2c3ccccc3Oc3cc(-c4c(-c6ccccc6)cccc4-c4ccccc4)cc(c32)O5)cc1 ; c1ccc(-c2cccc(-c3ccccc3)c2-c2cc3c4c(c2)Oc2cc5c(cc2B4c2ccccc2O3)B2c3ccccc3Sc3cc(-c4c(-c6ccccc6)cccc4-c4ccccc4)cc(c32)O5)cc1 ; c1ccc(-c2cccc(-c3ccccc3)c2-c2cc3c4c(c2)Oc2cc5c(cc2B4c2ccccc2O3)B2c3ccccc3Oc3cc(-c4c(-c6ccccc6)cccc4-c4ccccc4)cc(c32)S5)cc1]

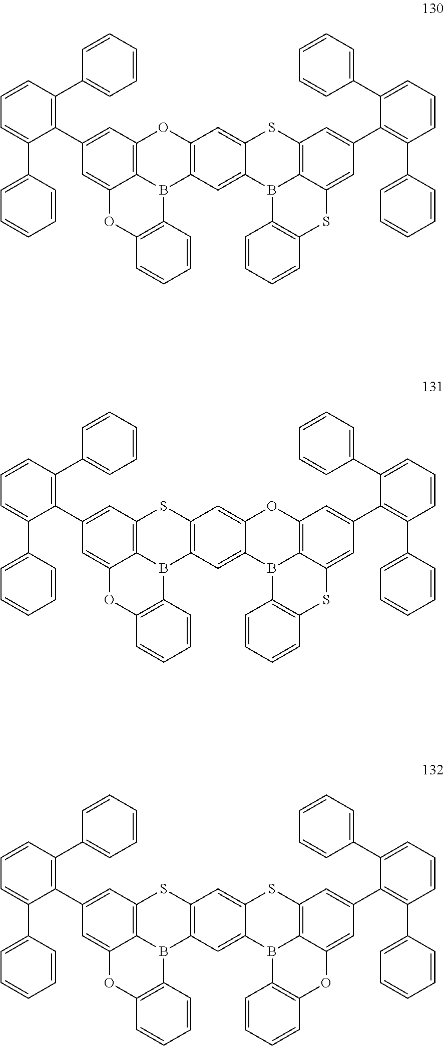 [SMILES: c1ccc(-c2cccc(-c3ccccc3)c2-c2cc3c4c(c2)Oc2cc5c(cc2B4c2ccccc2O3)B2c3ccccc3Sc3cc(-c4c(-c6ccccc6)cccc4-c4ccccc4)cc(c32)S5)cc1 ; c1ccc(-c2cccc(-c3ccccc3)c2-c2cc3c4c(c2)Sc2ccccc2B4c2cc4c(cc2O3)Sc2cc(-c3c(-c5ccccc5)cccc3-c3ccccc3)cc3c2B4c2ccccc2O3)cc1 ; c1ccc(-c2cccc(-c3ccccc3)c2-c2cc3c4c(c2)Sc2cc5c(cc2B4c2ccccc2O3)B2c3ccccc3Oc3cc(-c4c(-c6ccccc6)cccc4-c4ccccc4)cc(c32)S5)cc1]

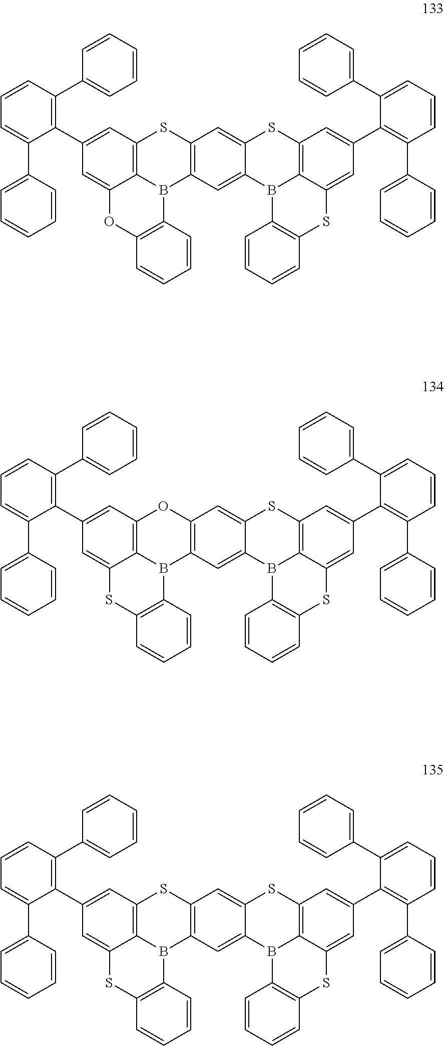 [SMILES: c1ccc(-c2cccc(-c3ccccc3)c2-c2cc3c4c(c2)Sc2cc5c(cc2B4c2ccccc2O3)B2c3ccccc3Sc3cc(-c4c(-c6ccccc6)cccc4-c4ccccc4)cc(c32)S5)cc1 ; c1ccc(-c2cccc(-c3ccccc3)c2-c2cc3c4c(c2)Sc2ccccc2B4c2cc4c(cc2O3)Sc2cc(-c3c(-c5ccccc5)cccc3-c3ccccc3)cc3c2B4c2ccccc2S3)cc1 ; c1ccc(-c2cccc(-c3ccccc3)c2-c2cc3c4c(c2)Sc2cc5c(cc2B4c2ccccc2S3)B2c3ccccc3Sc3cc(-c4c(-c6ccccc6)cccc4-c4ccccc4)cc(c32)S5)cc1]

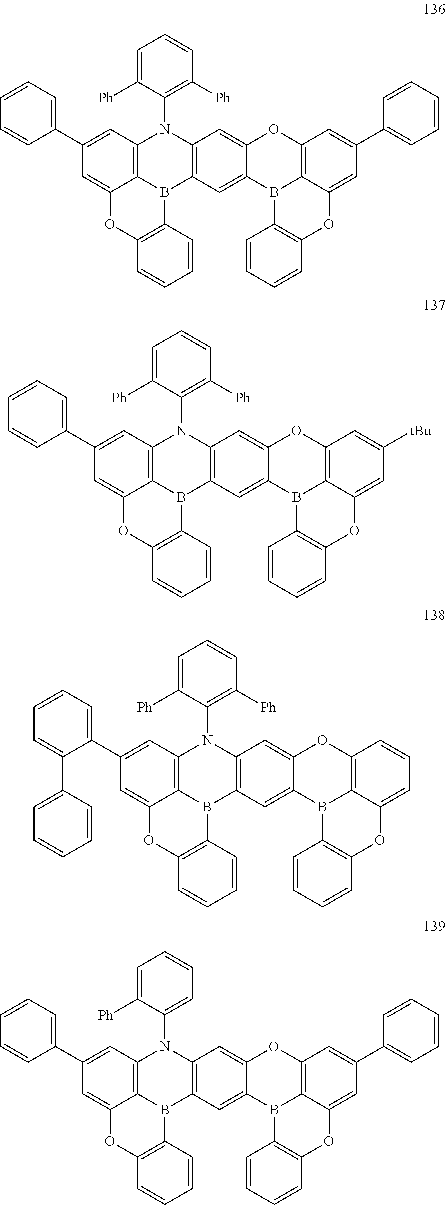 [SMILES: c1ccc(-c2cc3c4c(c2)Oc2cc5c(cc2B4c2ccccc2O3)B2c3ccccc3Oc3cc(-c4ccccc4)cc(c32)N5c2c(-c3ccccc3)cccc2-c2ccccc2)cc1 ; CC(C)(C)c1cc2c3c(c1)Oc1cc4c(cc1B3c1ccccc1O2)B1c2ccccc2Oc2cc(-c3ccccc3)cc(c21)N4c1c(-c2ccccc2)cccc1-c1ccccc1 ; c1ccc(-c2ccccc2-c2cc3c4c(c2)N(c2c(-c5ccccc5)cccc2-c2ccccc2)c2cc5c(cc2B4c2ccccc2O3)B2c3ccccc3Oc3cccc(c32)O5)cc1 ; c1ccc(-c2cc3c4c(c2)Oc2cc5c(cc2B4c2ccccc2O3)B2c3ccccc3Oc3cc(-c4ccccc4)cc(c32)N5c2ccccc2-c2ccccc2)cc1]

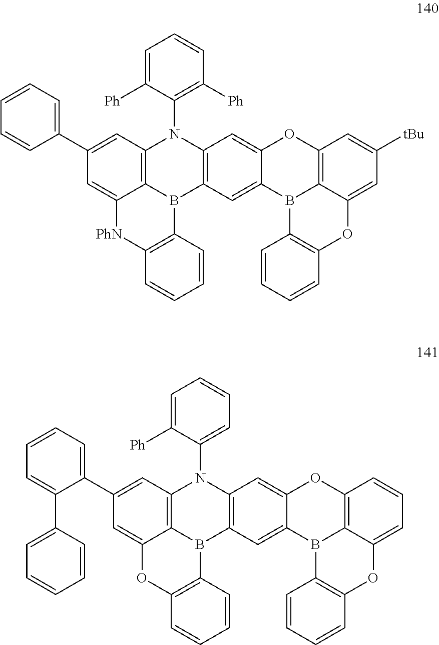

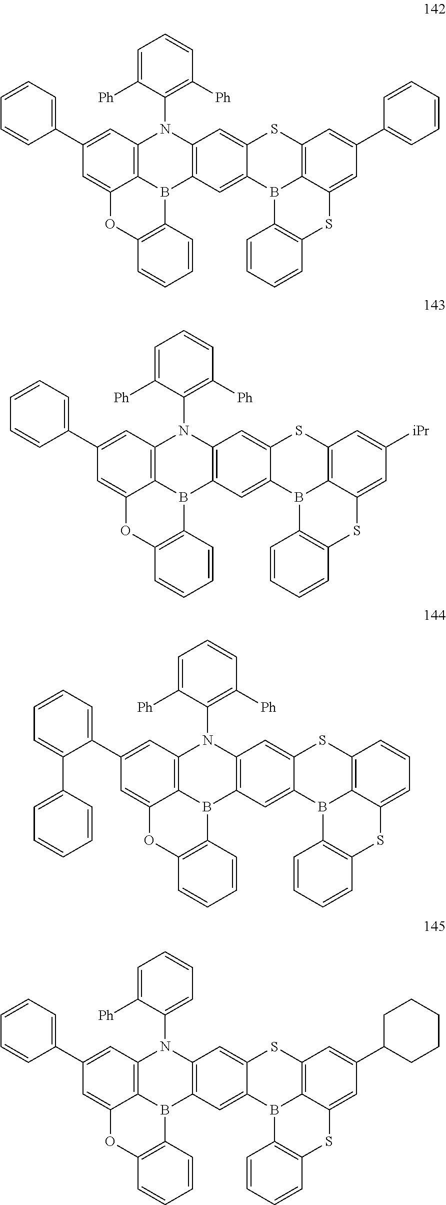 [SMILES: c1ccc(-c2cc3c4c(c2)Sc2cc5c(cc2B4c2ccccc2S3)B2c3ccccc3Oc3cc(-c4ccccc4)cc(c32)N5c2c(-c3ccccc3)cccc2-c2ccccc2)cc1 ; CC(C)c1cc2c3c(c1)Sc1cc4c(cc1B3c1ccccc1S2)B1c2ccccc2Oc2cc(-c3ccccc3)cc(c21)N4c1c(-c2ccccc2)cccc1-c1ccccc1 ; c1ccc(-c2ccccc2-c2cc3c4c(c2)N(c2c(-c5ccccc5)cccc2-c2ccccc2)c2cc5c(cc2B4c2ccccc2O3)B2c3ccccc3Sc3cccc(c32)S5)cc1 ; c1ccc(-c2cc3c4c(c2)N(c2ccccc2-c2ccccc2)c2cc5c(cc2B4c2ccccc2O3)B2c3ccccc3Sc3cc(C4CCCCC4)cc(c32)S5)cc1]

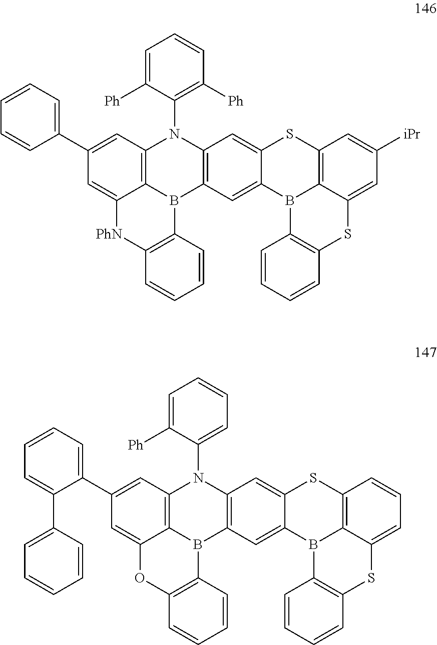

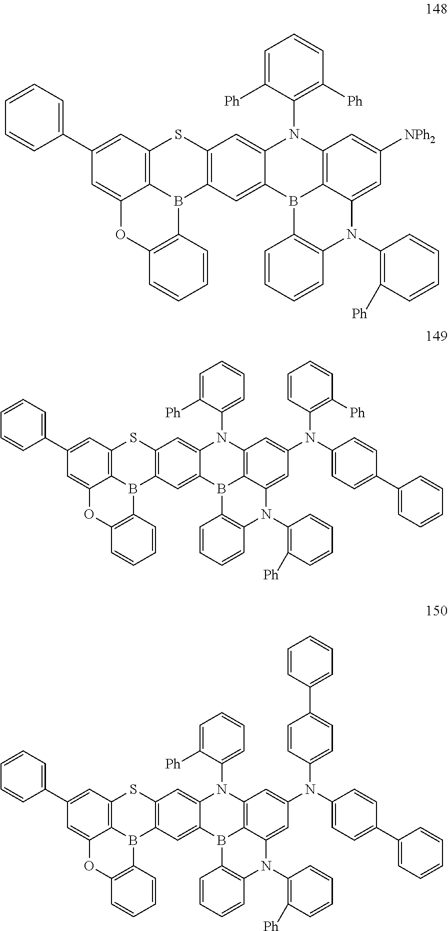

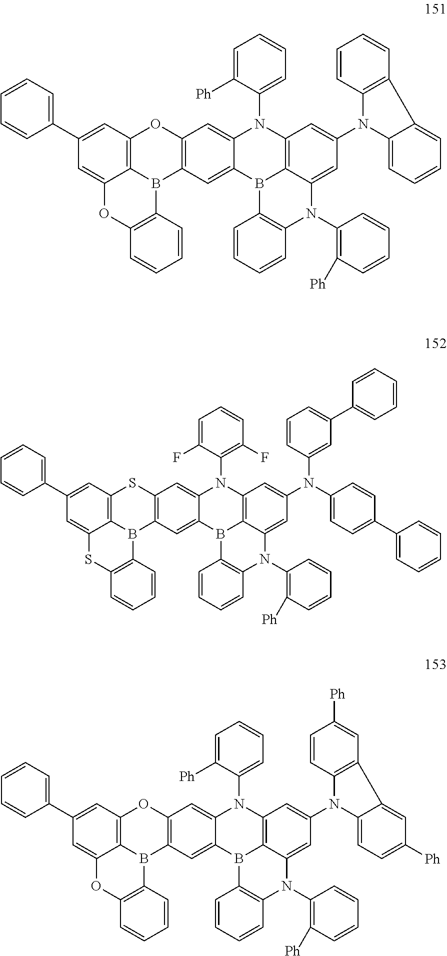 [SMILES: c1ccc(-c2cc3c4c(c2)Oc2cc5c(cc2B4c2ccccc2O3)B2c3ccccc3N(c3ccccc3-c3ccccc3)c3cc(-n4c6ccccc6c6ccccc64)cc(c32)N5c2ccccc2-c2ccccc2)cc1 ; Fc1cccc(F)c1N1c2cc3c(cc2B2c4ccccc4N(c4ccccc4-c4ccccc4)c4cc(N(c5ccc(-c6ccccc6)cc5)c5cccc(-c6ccccc6)c5)cc1c42)B1c2ccccc2Sc2cc(-c4ccccc4)cc(c21)S3 ; c1ccc(-c2cc3c4c(c2)Oc2cc5c(cc2B4c2ccccc2O3)B2c3ccccc3N(c3ccccc3-c3ccccc3)c3cc(-n4c6ccc(-c7ccccc7)cc6c6cc(-c7ccccc7)ccc64)cc(c32)N5c2ccccc2-c2ccccc2)cc1]

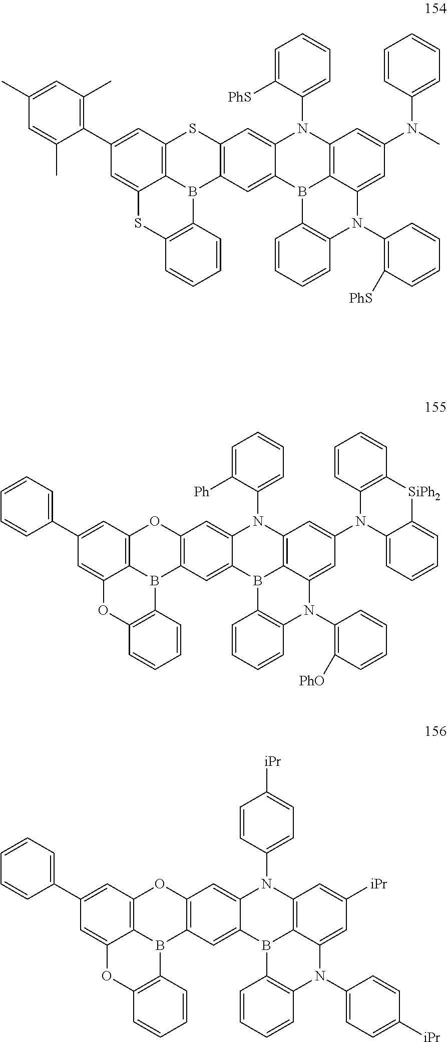

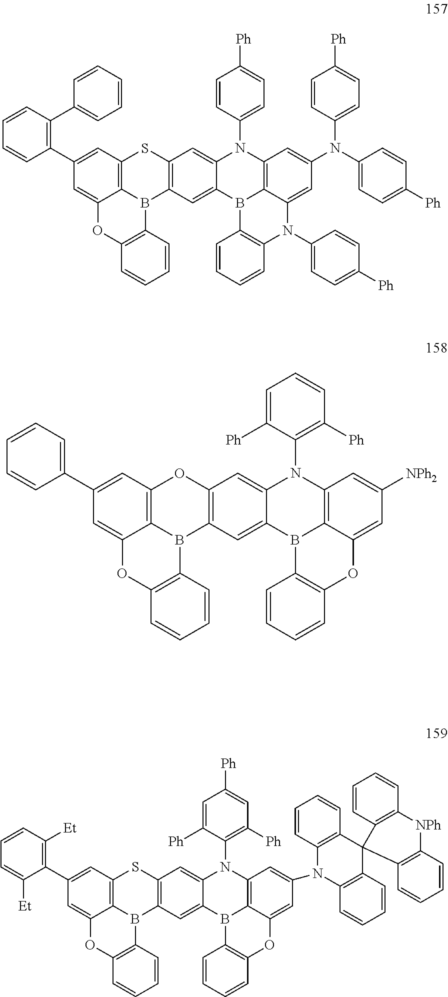

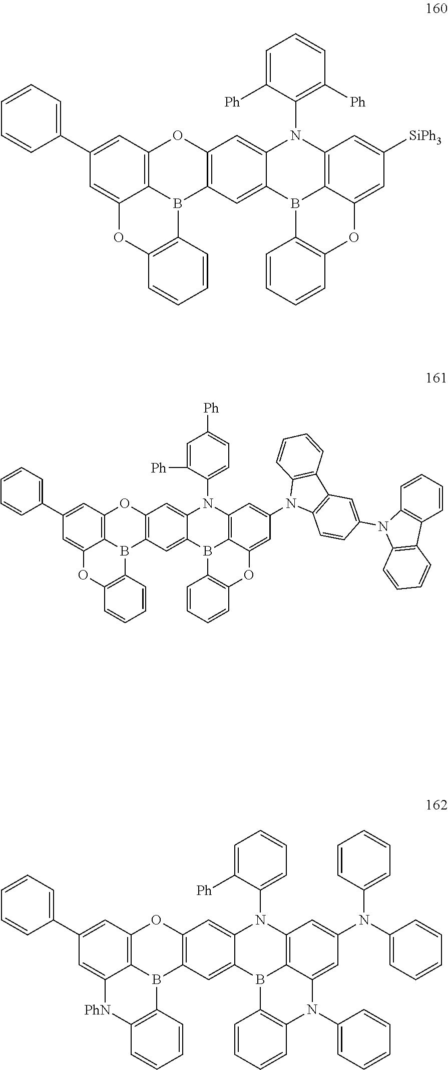

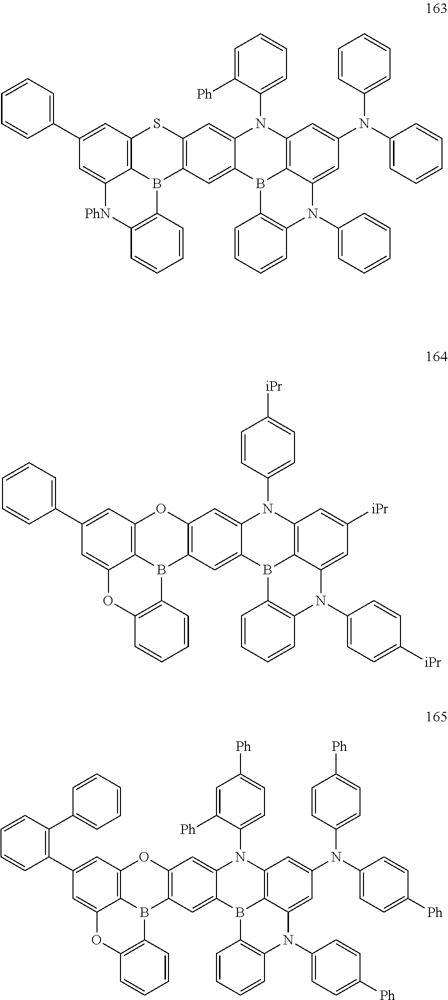

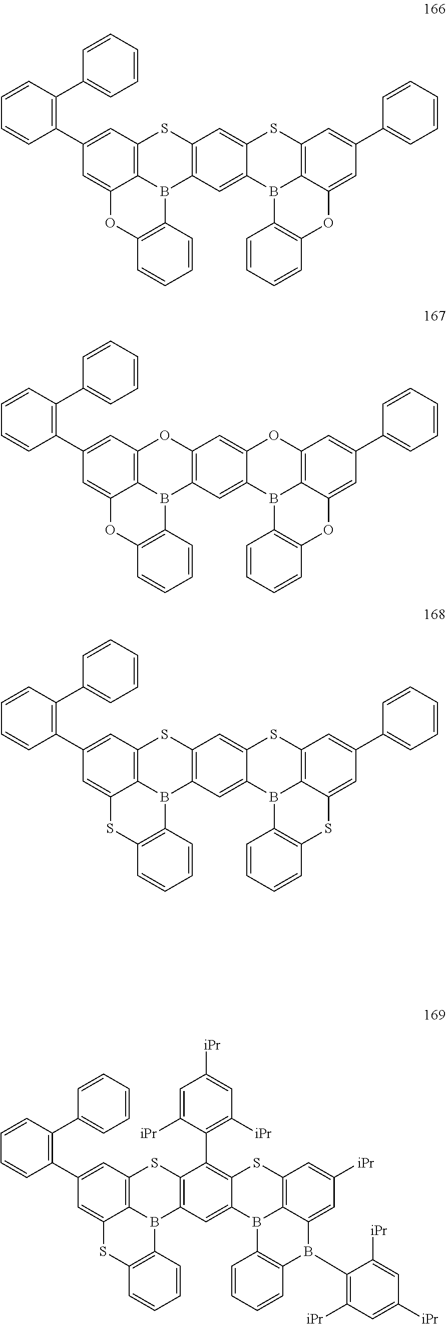 [SMILES: c1ccc(-c2cc3c4c(c2)Sc2cc5c(cc2B4c2ccccc2O3)B2c3ccccc3Oc3cc(-c4ccccc4-c4ccccc4)cc(c32)S5)cc1 ; c1ccc(-c2cc3c4c(c2)Oc2cc5c(cc2B4c2ccccc2O3)B2c3ccccc3Oc3cc(-c4ccccc4-c4ccccc4)cc(c32)O5)cc1 ; c1ccc(-c2cc3c4c(c2)Sc2cc5c(cc2B4c2ccccc2S3)B2c3ccccc3Sc3cc(-c4ccccc4-c4ccccc4)cc(c32)S5)cc1 ; CC(C)c1cc2c3c(c1)B(c1c(C(C)C)cc(C(C)C)cc1C(C)C)c1ccccc1B3c1cc3c(c(-c4c(C(C)C)cc(C(C)C)cc4C(C)C)c1S2)Sc1cc(-c2ccccc2-c2ccccc2)cc2c1B3c1ccccc1S2]

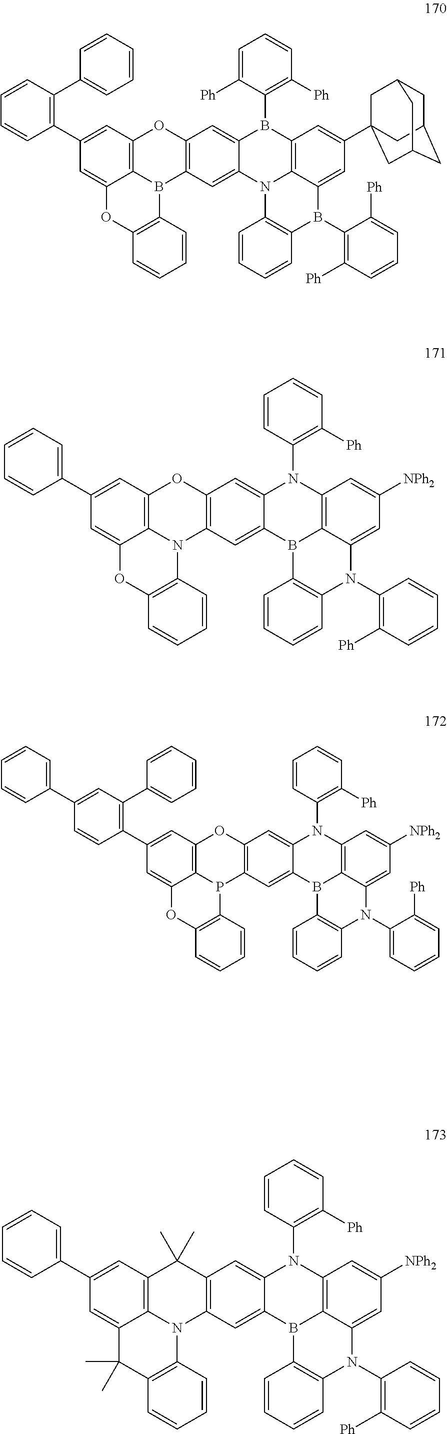

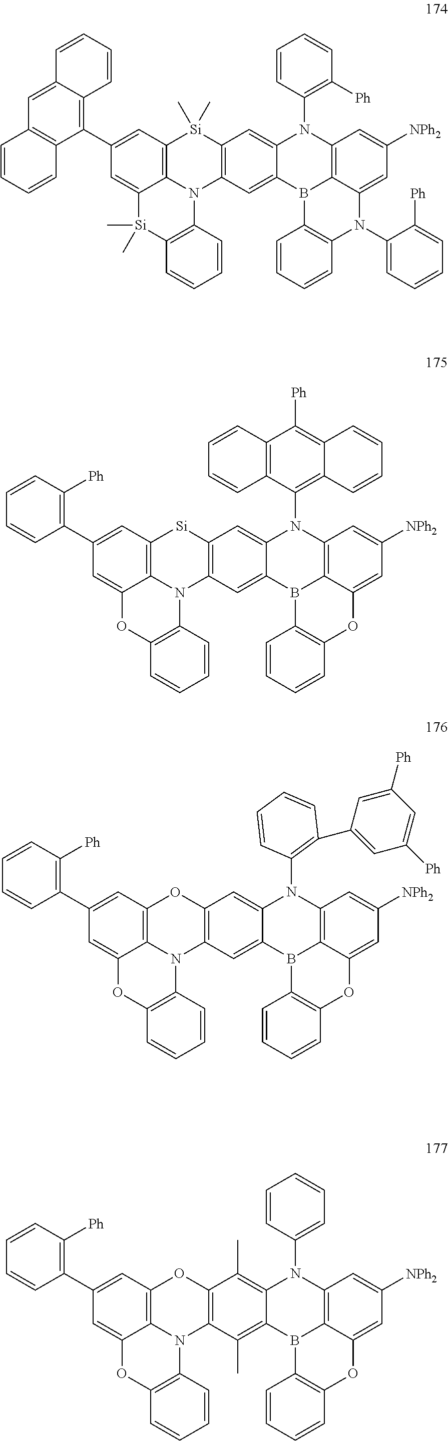

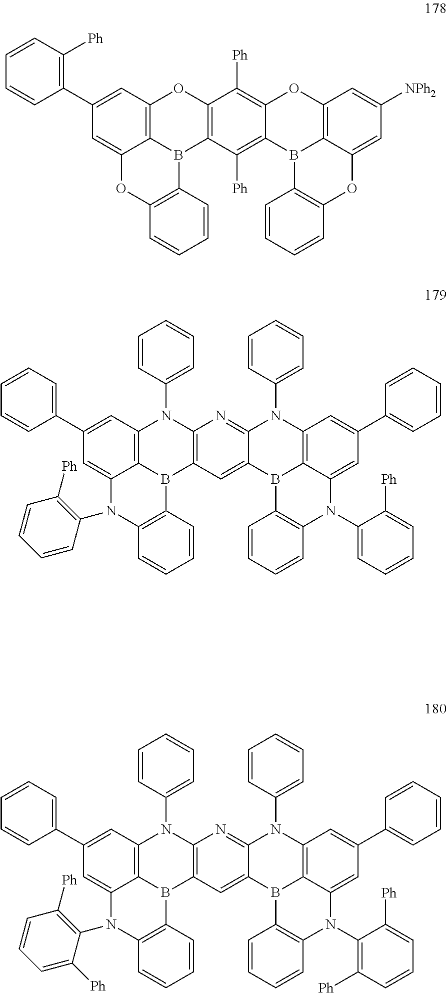

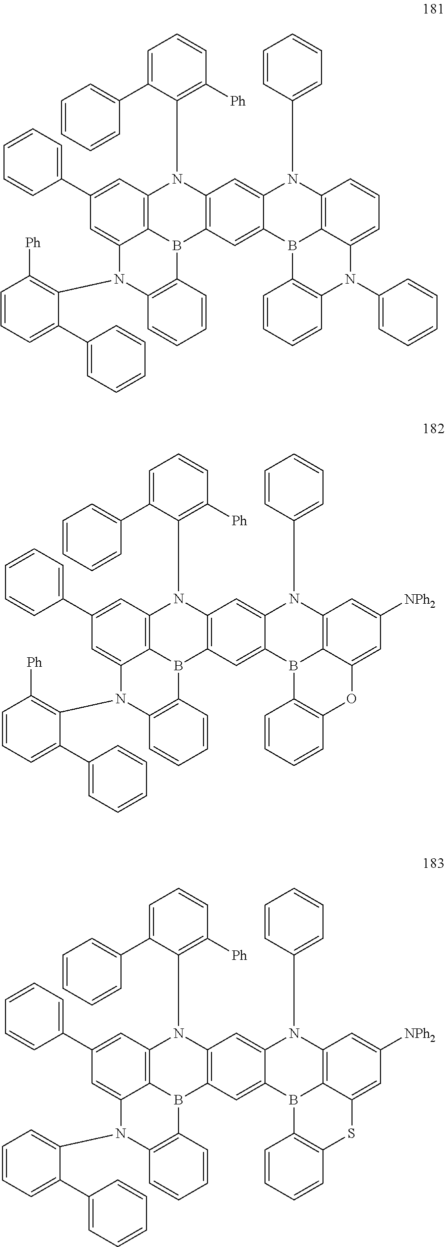

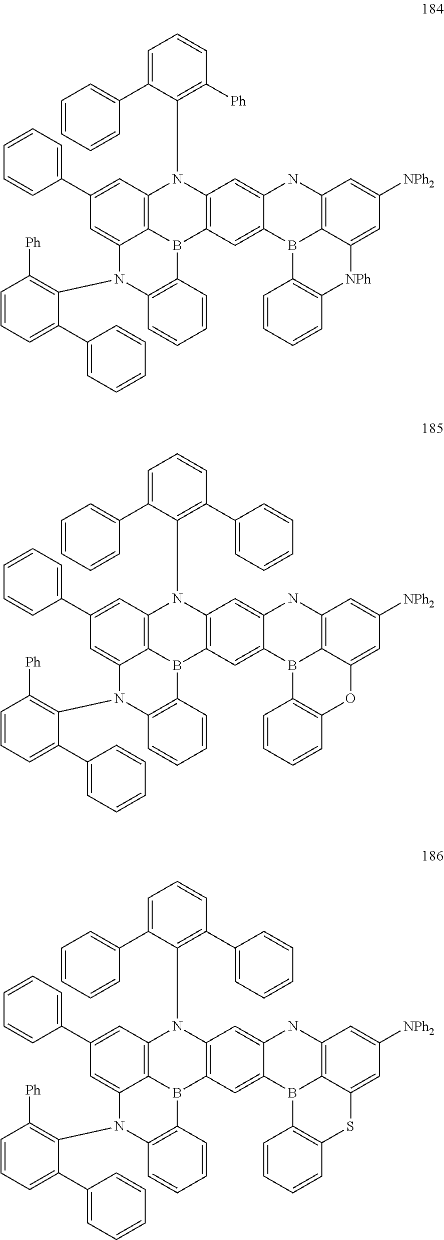

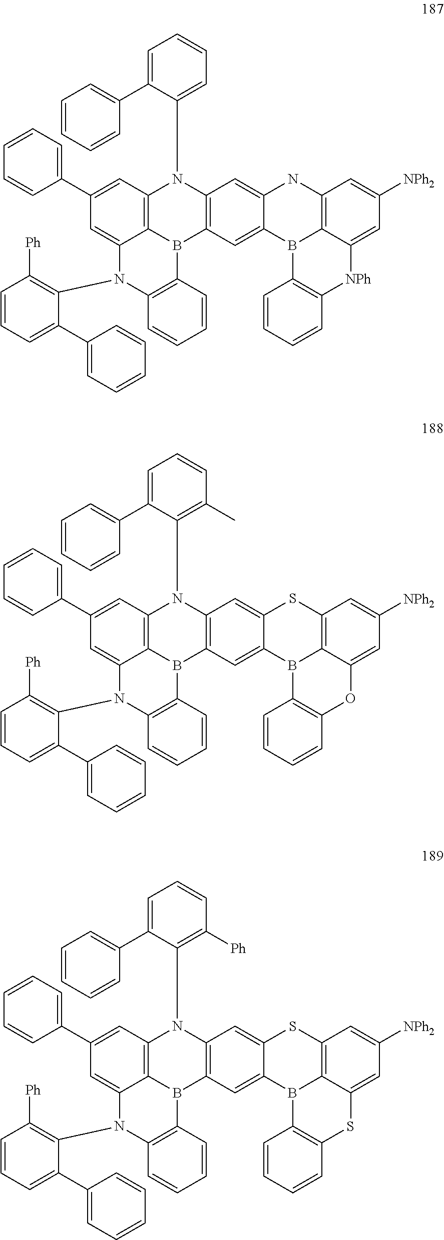

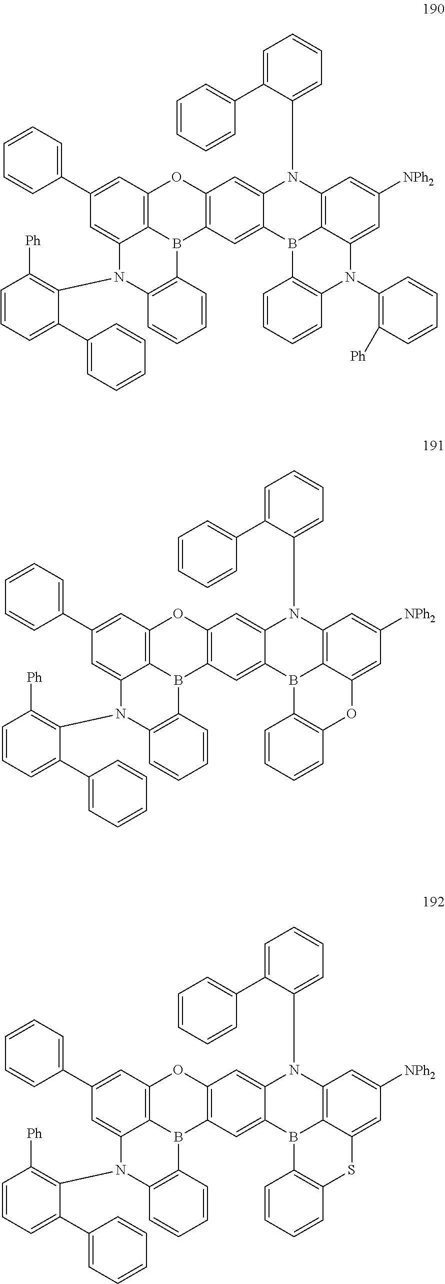

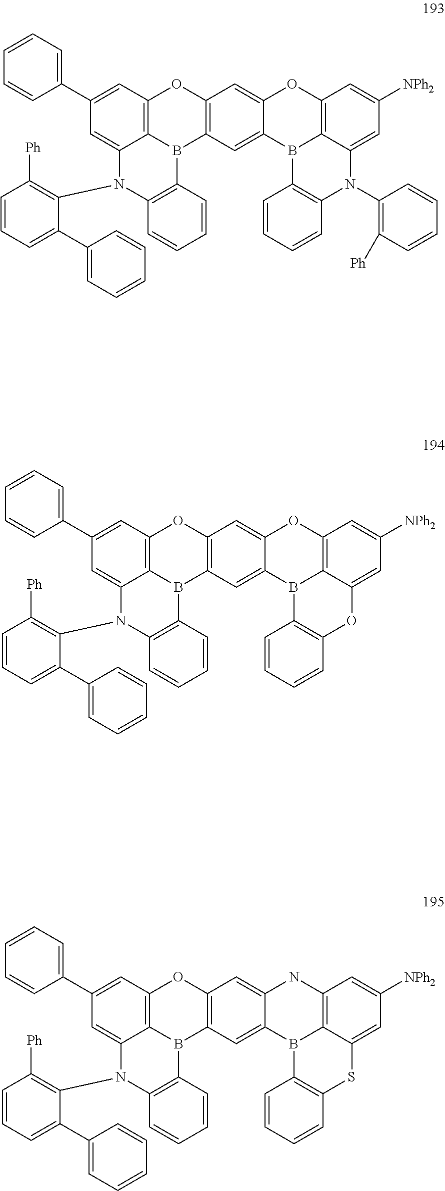

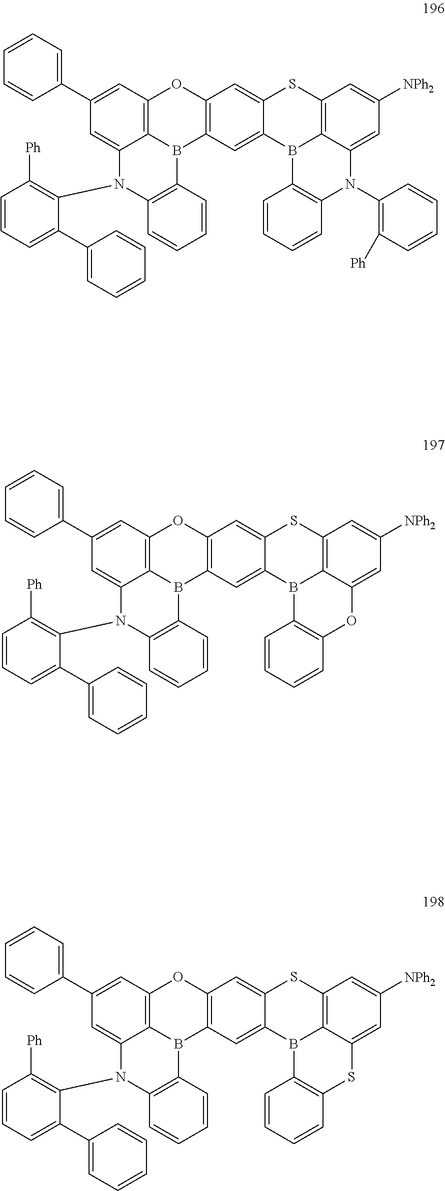

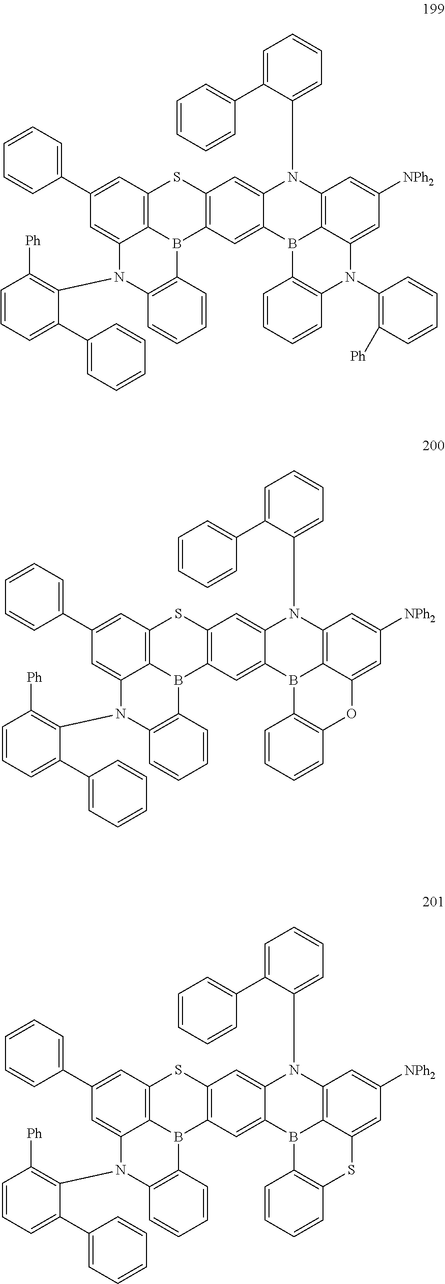

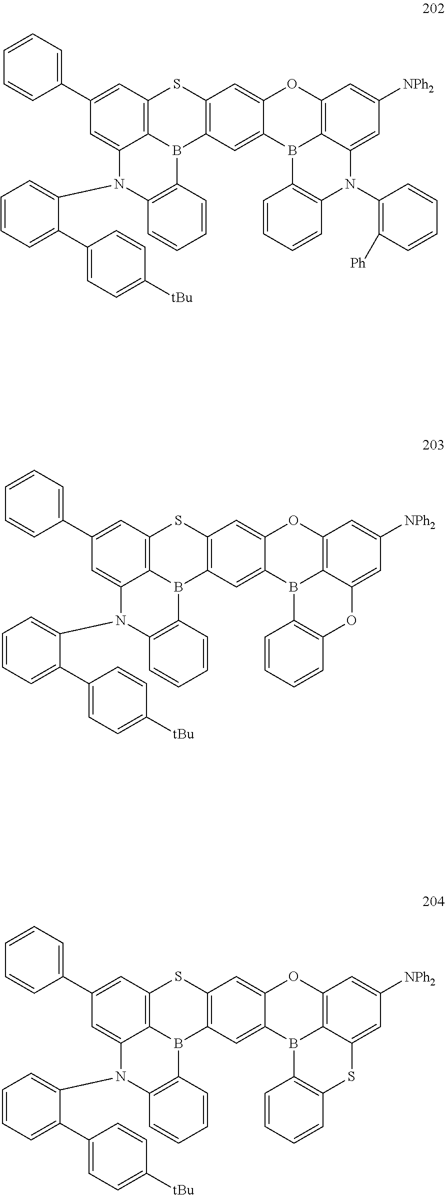

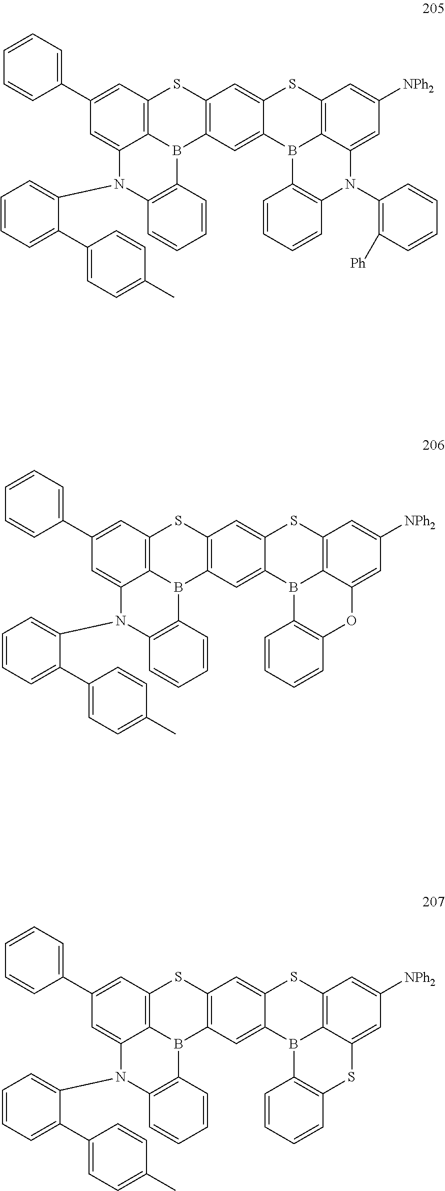

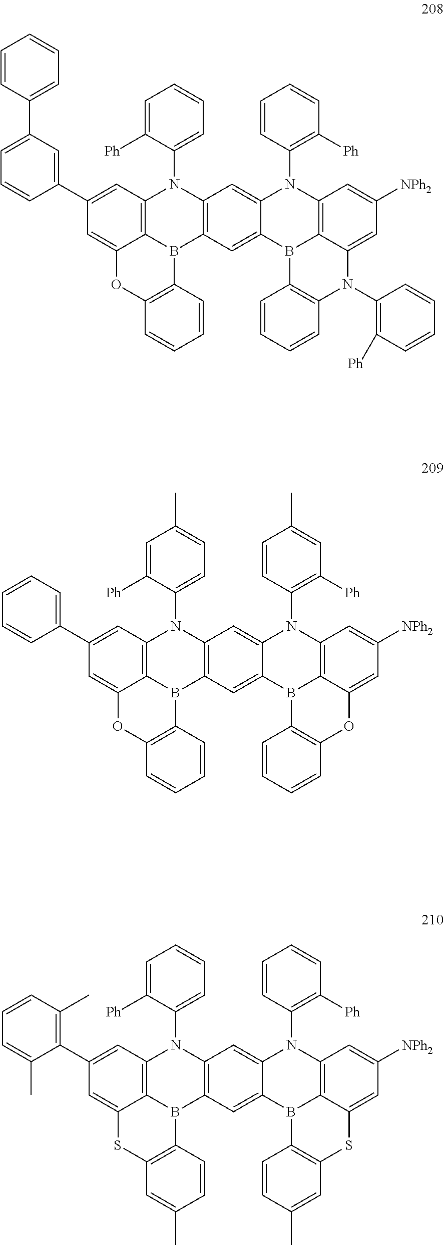

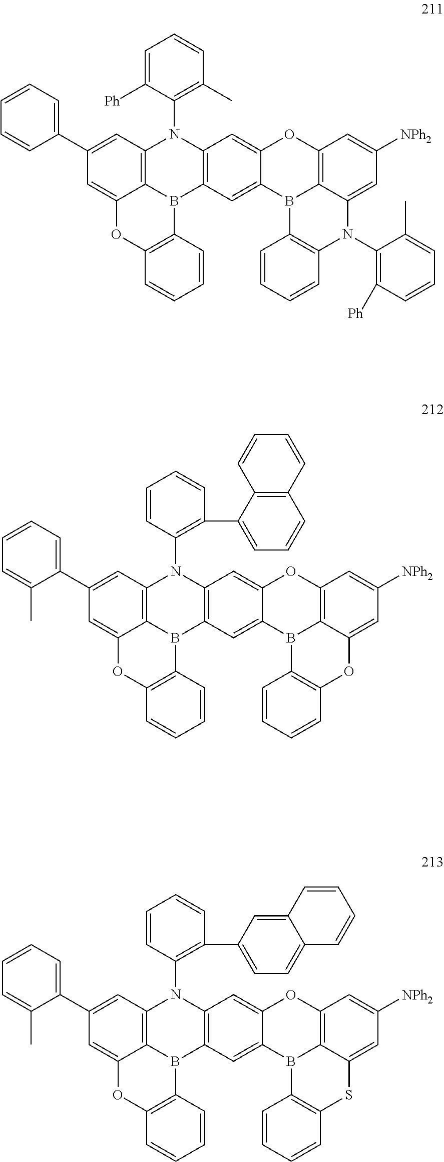

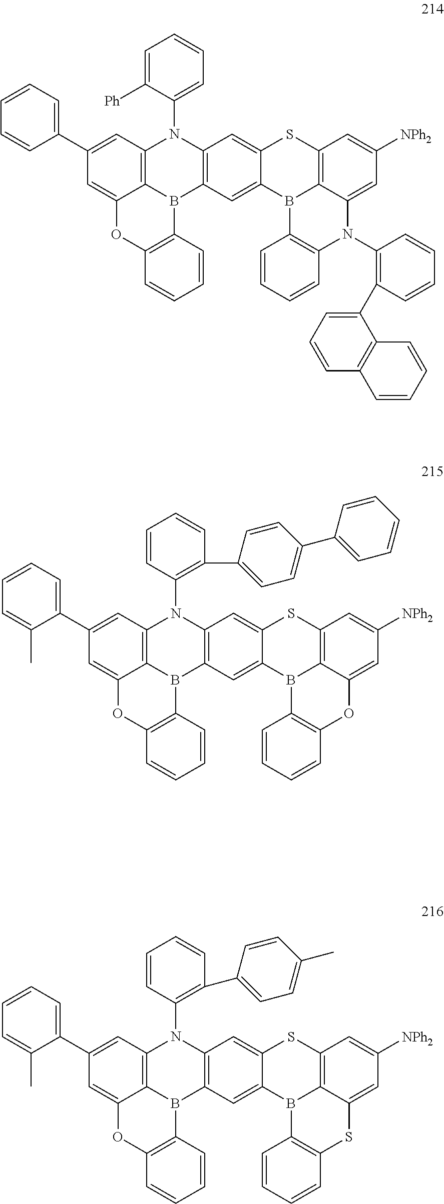

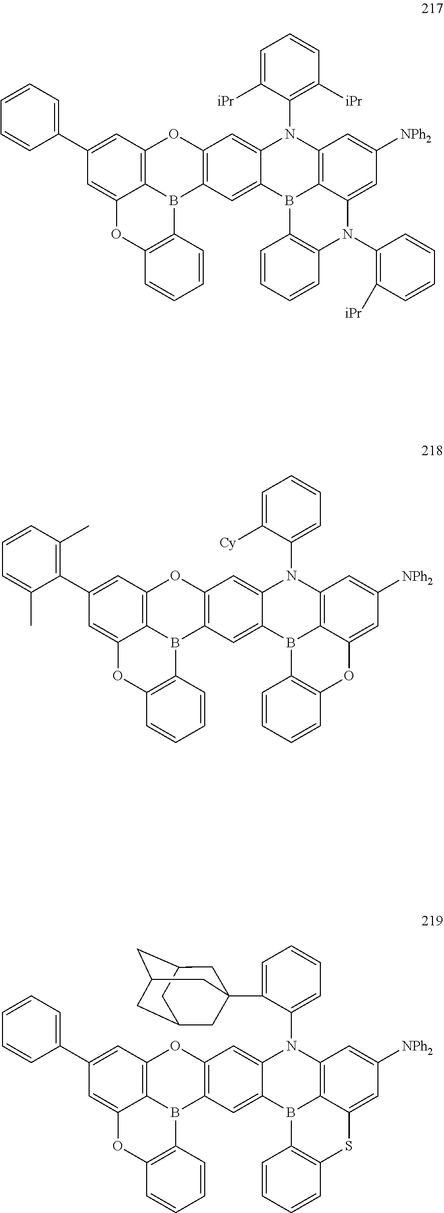

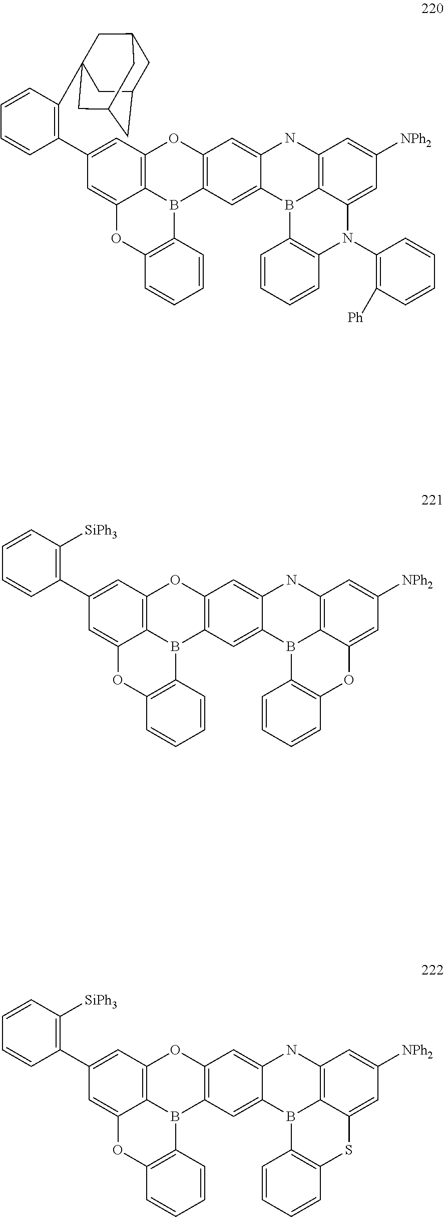

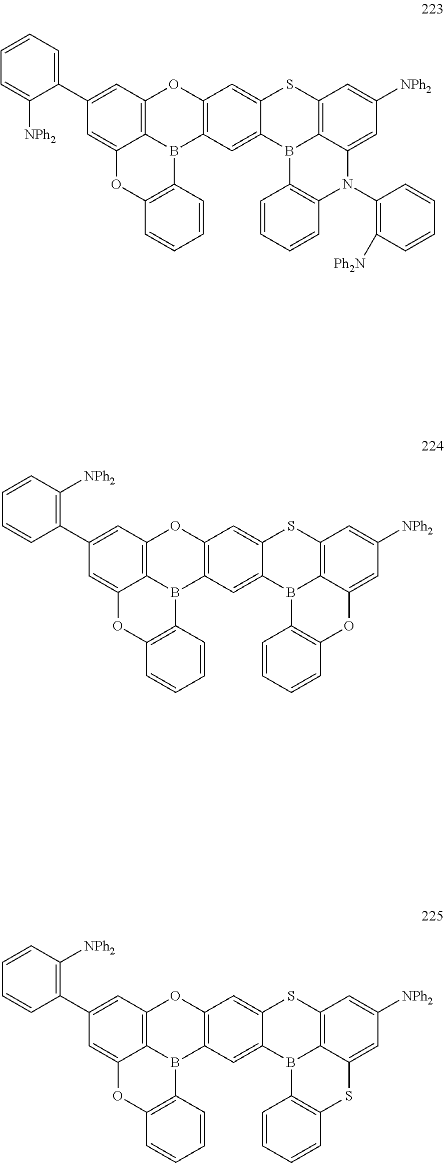

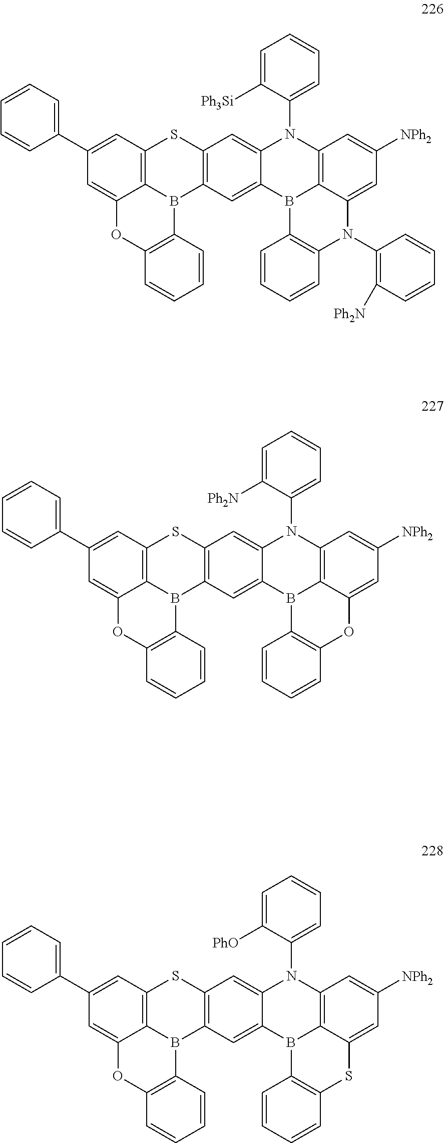

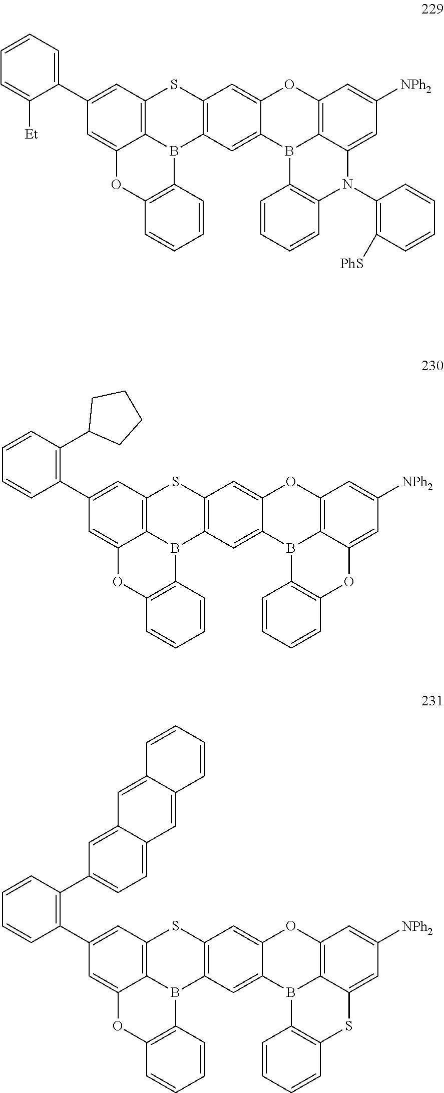

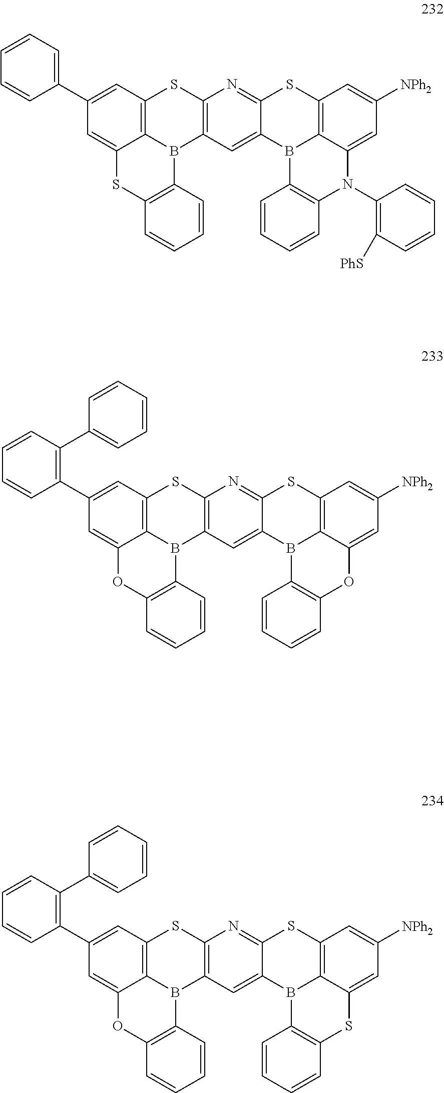

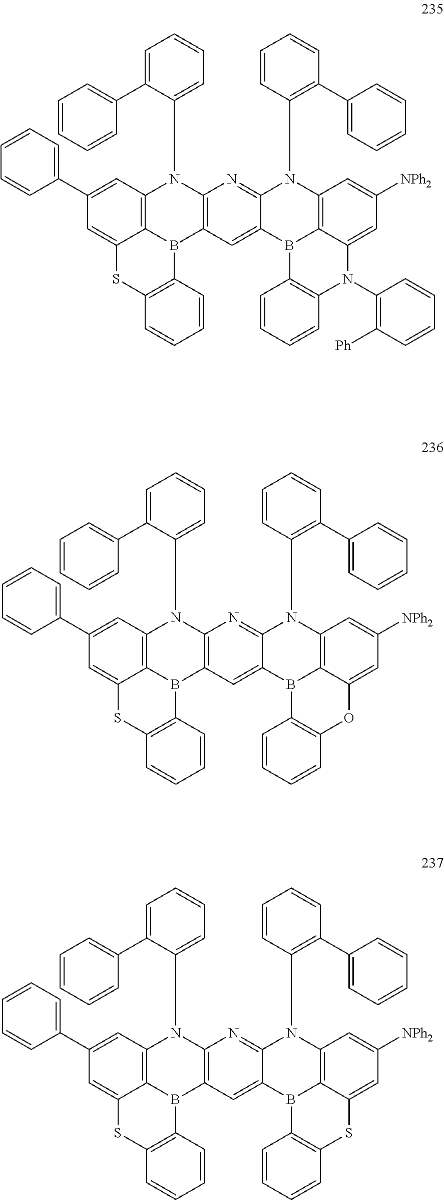

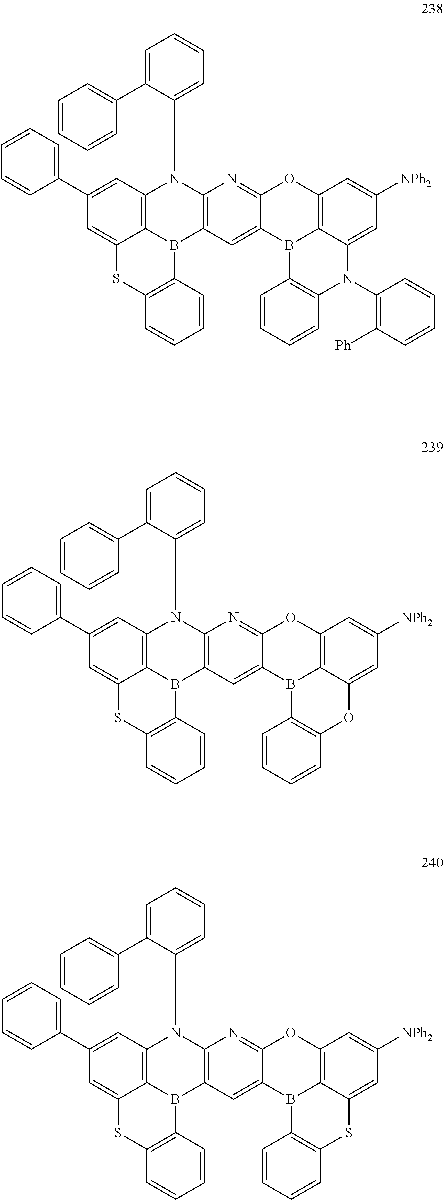

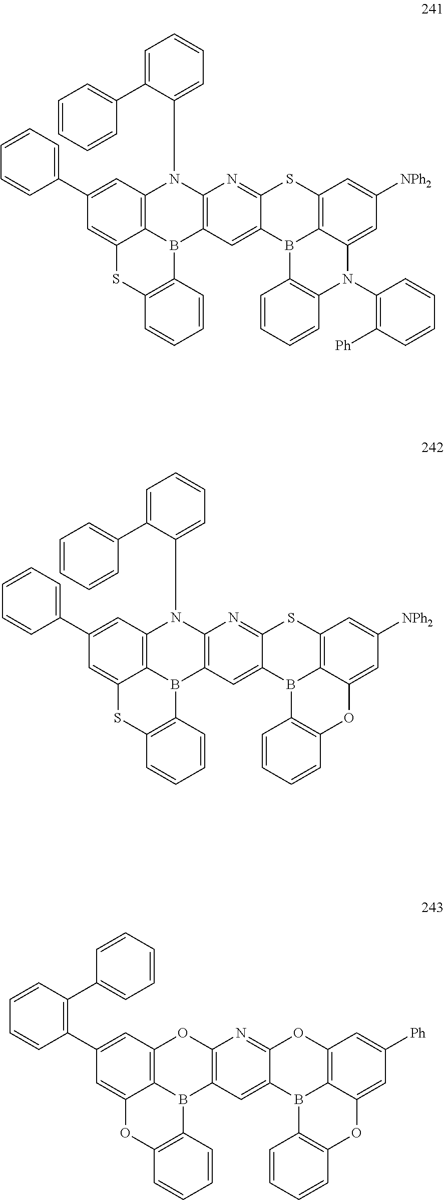

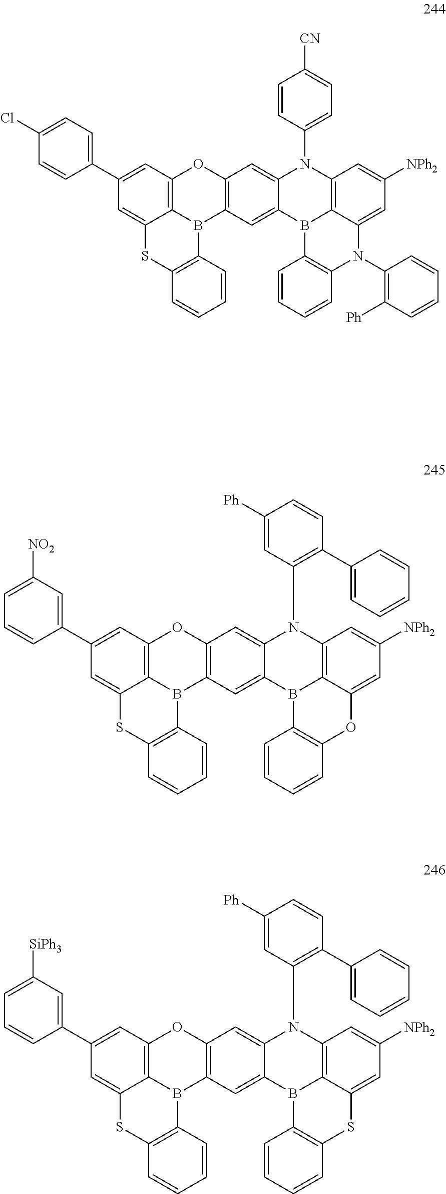

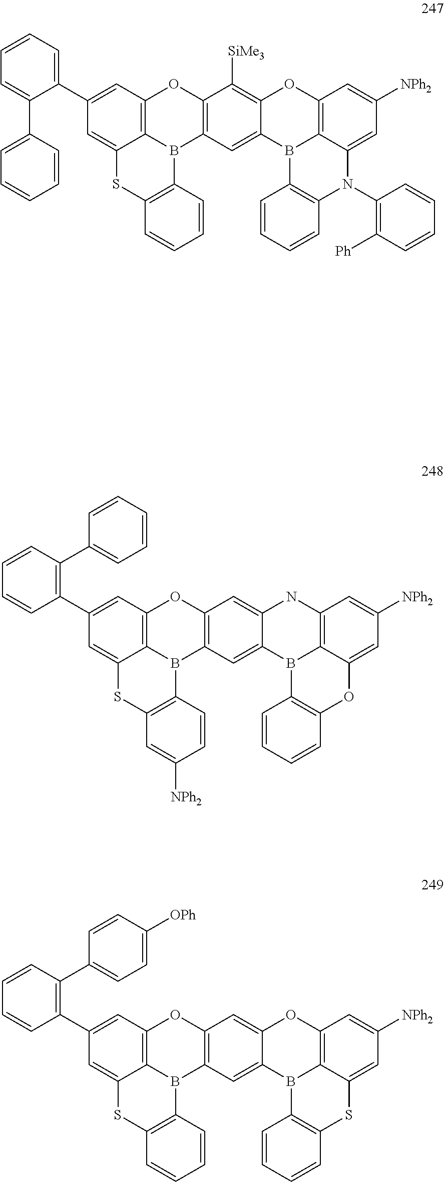

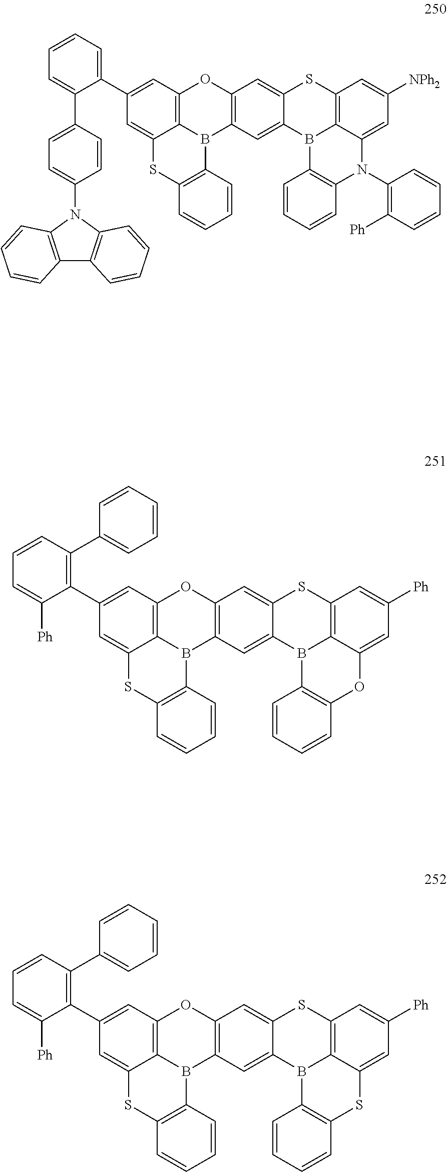

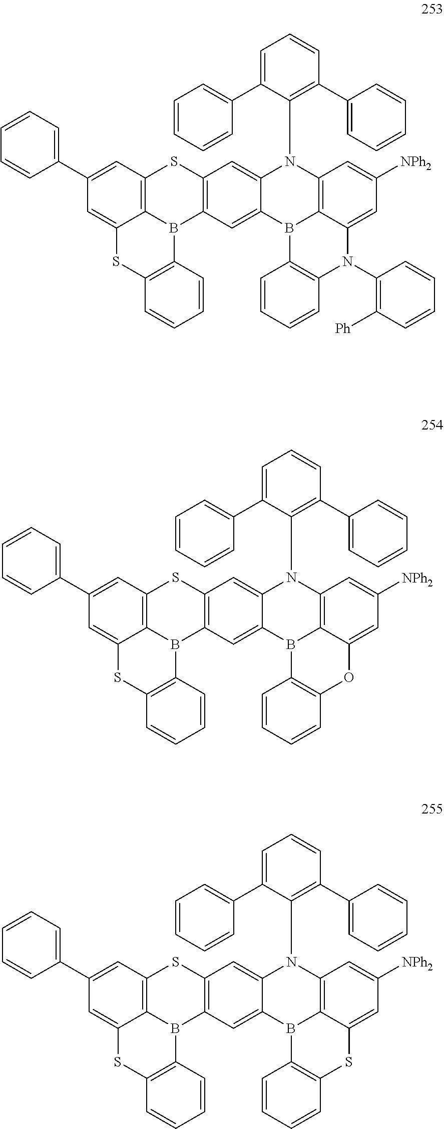

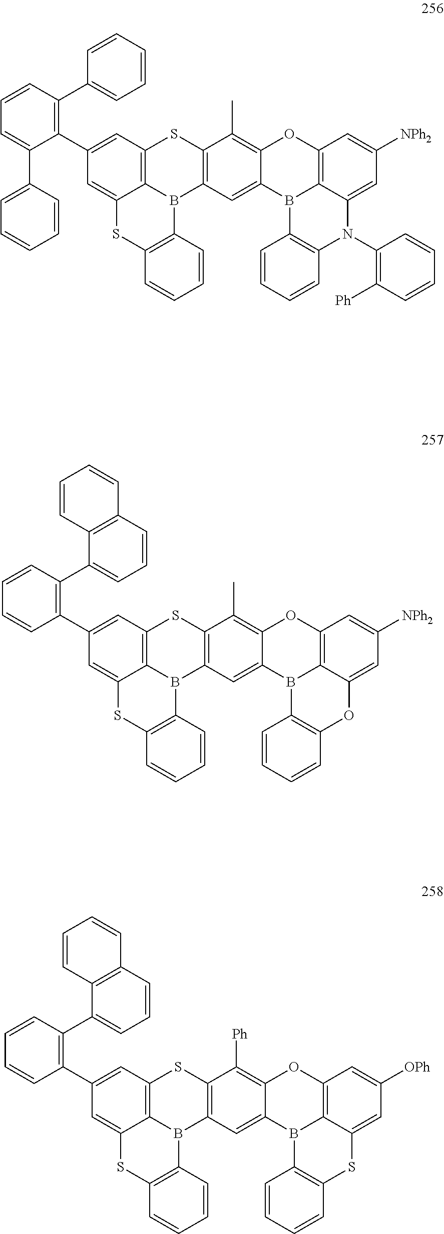

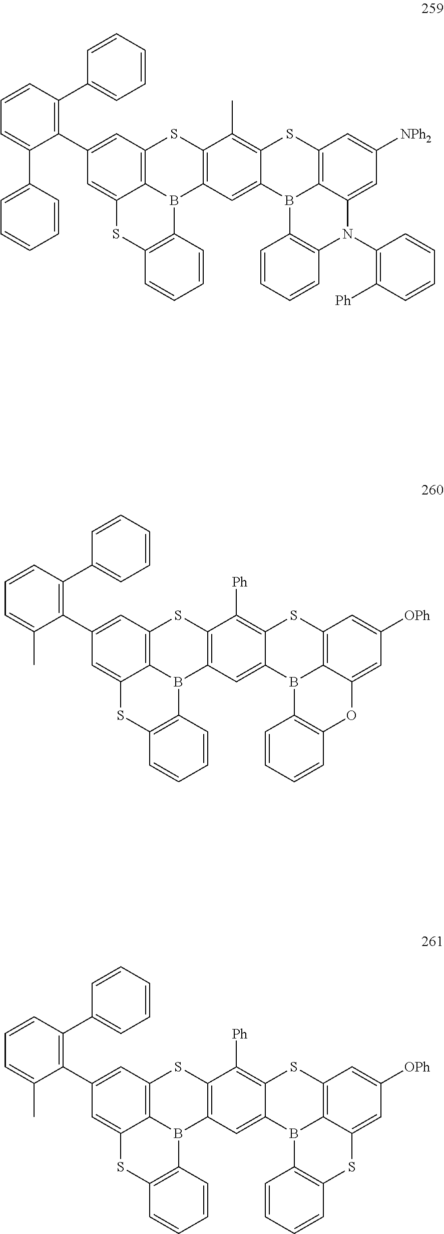

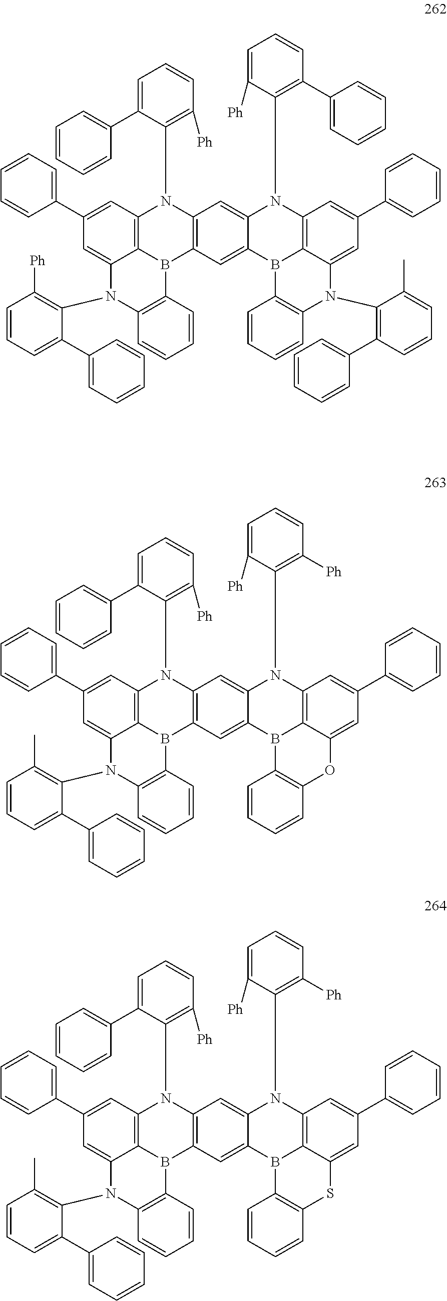

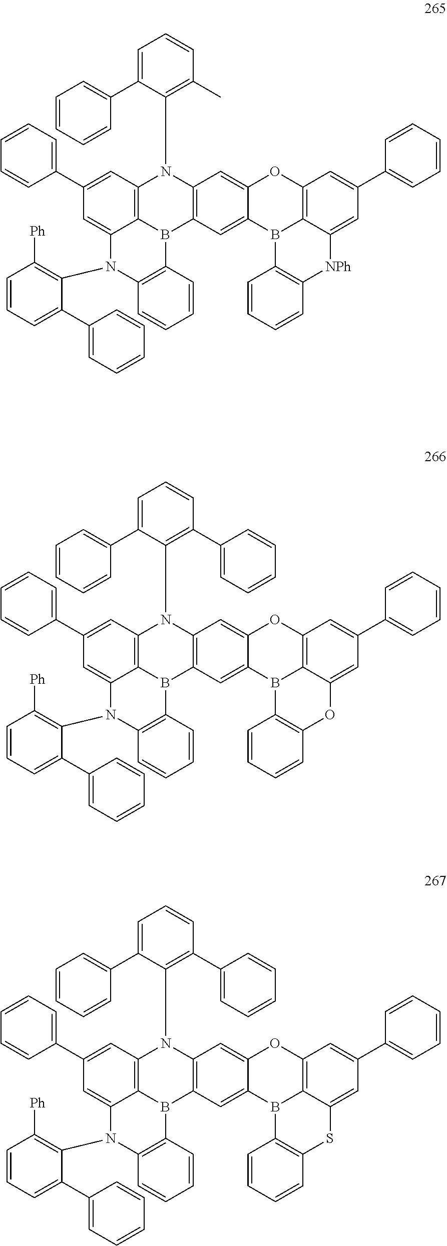

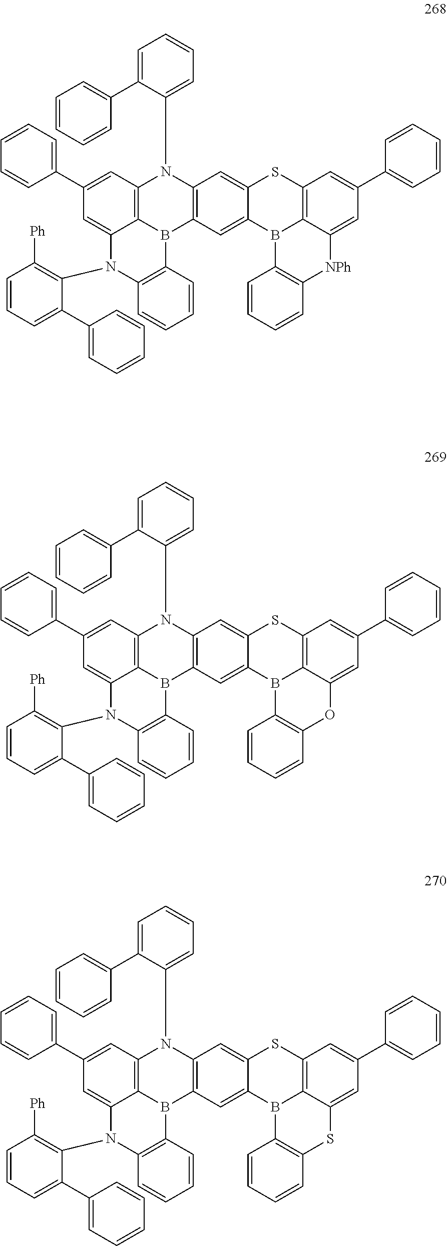

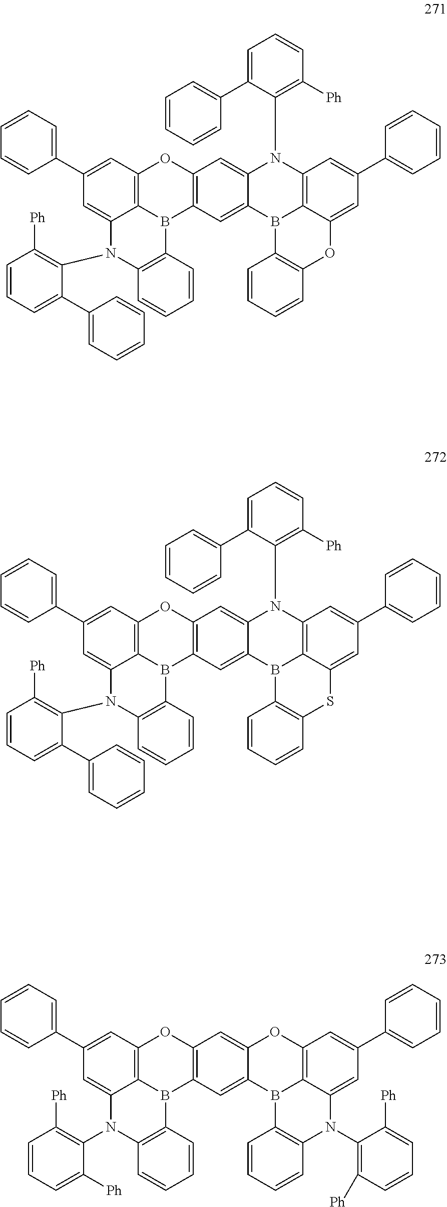 [SMILES: c1ccc(-c2cc3c4c(c2)N(c2c(-c5ccccc5)cccc2-c2ccccc2)c2ccccc2B4c2cc4c(cc2O3)N(c2c(-c3ccccc3)cccc2-c2ccccc2)c2cc(-c3ccccc3)cc3c2B4c2ccccc2O3)cc1 ; c1ccc(-c2cc3c4c(c2)N(c2c(-c5ccccc5)cccc2-c2ccccc2)c2ccccc2B4c2cc4c(cc2O3)N(c2c(-c3ccccc3)cccc2-c2ccccc2)c2cc(-c3ccccc3)cc3c2B4c2ccccc2S3)cc1 ; c1ccc(-c2cc3c4c(c2)N(c2c(-c5ccccc5)cccc2-c2ccccc2)c2ccccc2B4c2cc4c(cc2O3)Oc2cc(-c3ccccc3)cc3c2B4c2ccccc2N3c2c(-c3ccccc3)cccc2-c2ccccc2)cc1]

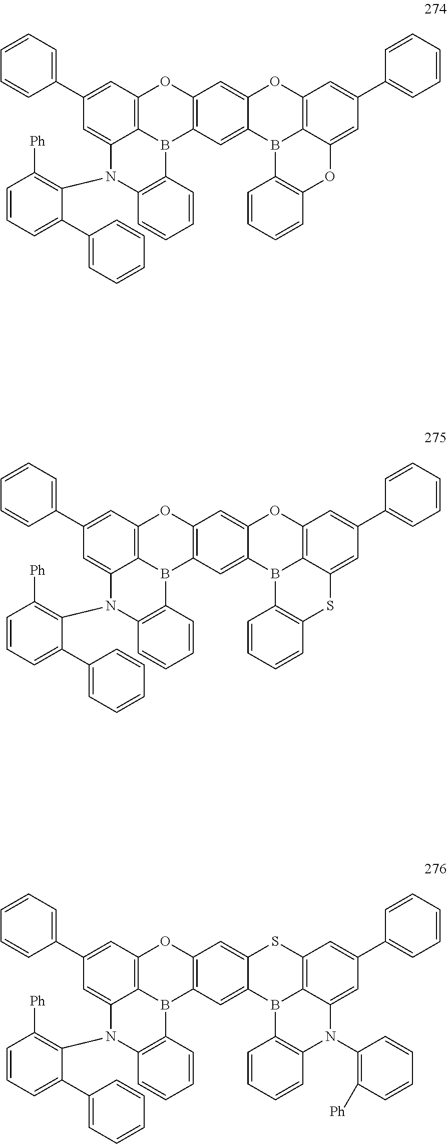 [SMILES: c1ccc(-c2cc3c4c(c2)Oc2cc5c(cc2B4c2ccccc2O3)B2c3ccccc3N(c3c(-c4ccccc4)cccc3-c3ccccc3)c3cc(-c4ccccc4)cc(c32)O5)cc1 ; c1ccc(-c2cc3c4c(c2)Sc2ccccc2B4c2cc4c(cc2O3)Oc2cc(-c3ccccc3)cc3c2B4c2ccccc2N3c2c(-c3ccccc3)cccc2-c2ccccc2)cc1 ; c1ccc(-c2cc3c4c(c2)N(c2c(-c5ccccc5)cccc2-c2ccccc2)c2ccccc2B4c2cc4c(cc2O3)Sc2cc(-c3ccccc3)cc3c2B4c2ccccc2N3c2ccccc2-c2ccccc2)cc1]

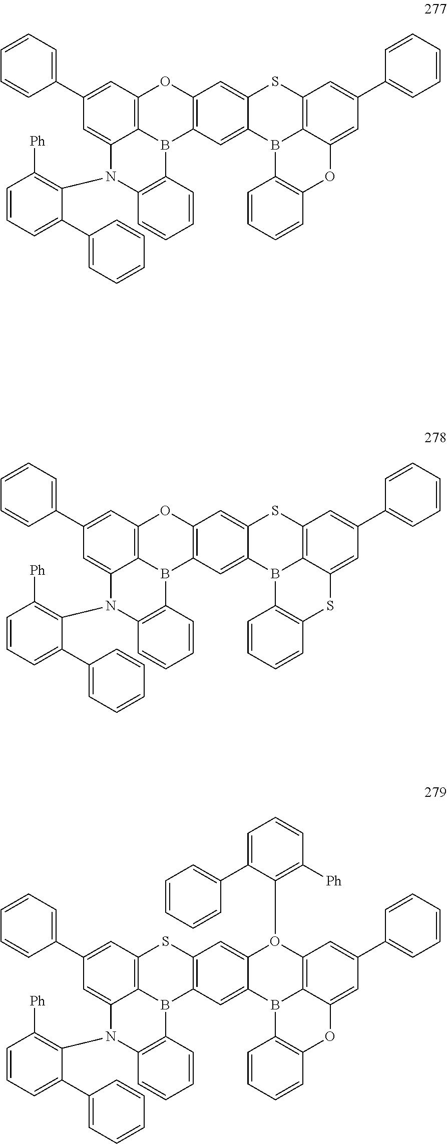

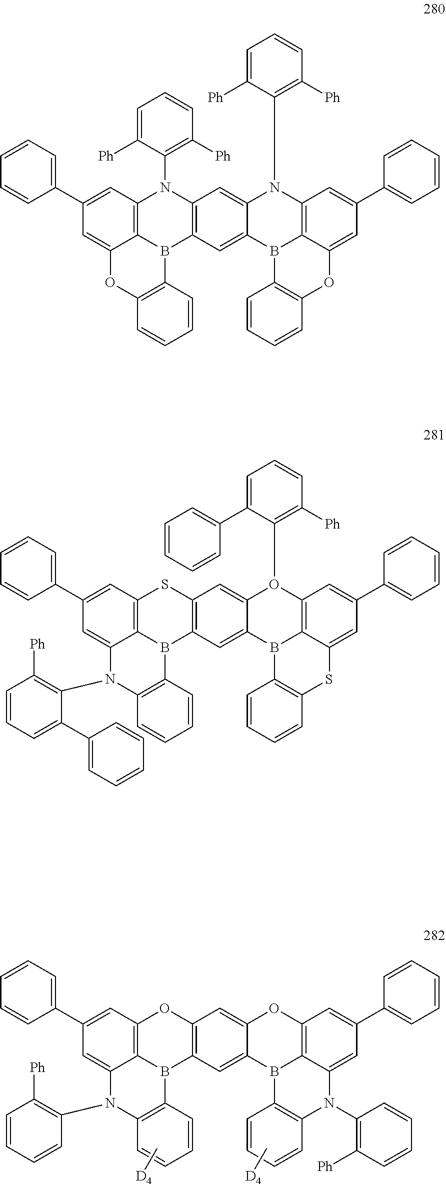

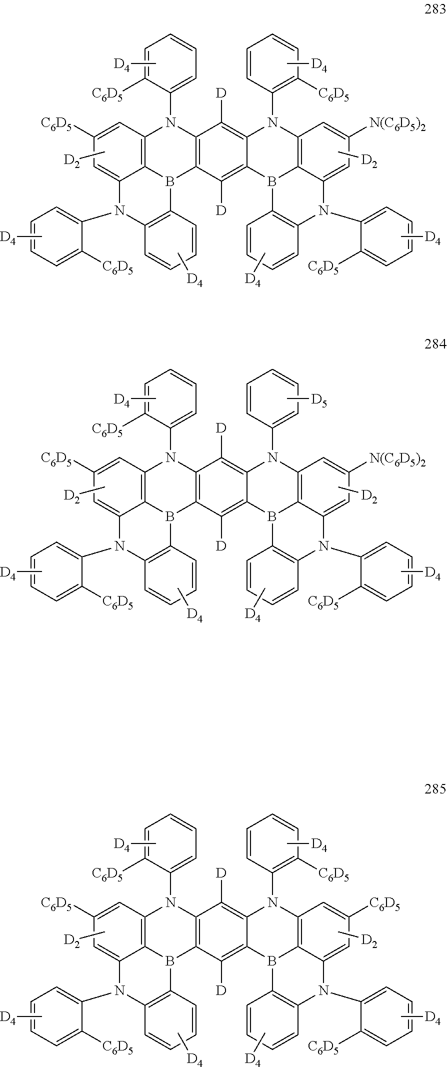

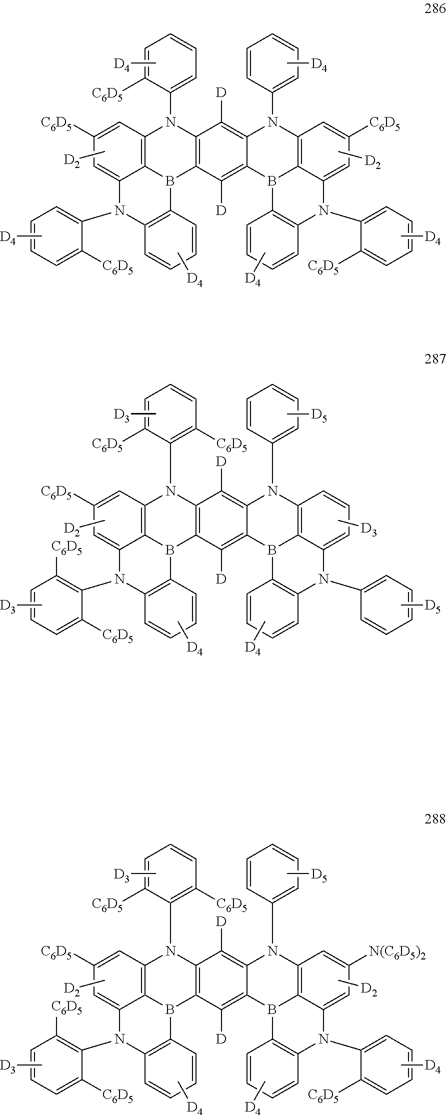

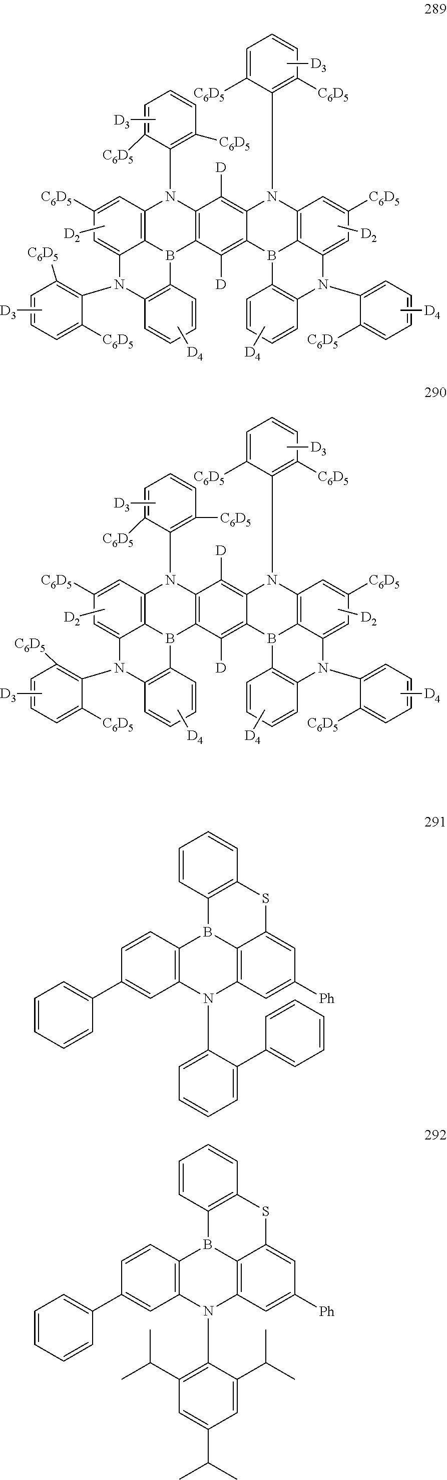

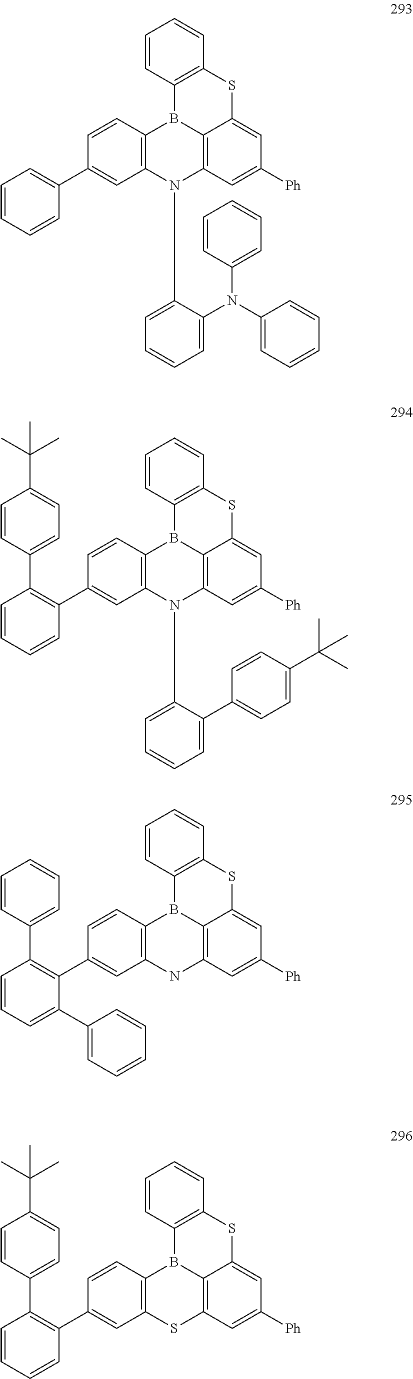

In the structure of the compounds, D may mean a deuterium atom, Ph may mean a substituted or unsubstituted phenyl group, Et may mean a substituted or unsubstituted ethyl group, tBu may mean a substituted or unsubstituted t-butyl group, and iPr may mean a substituted or unsubstituted isopropyl group. For example, Ph may be an unsubstituted phenyl group, Et may be an unsubstituted ethyl group, tBu may be an unsubstituted t-butyl group, and iPr may be an unsubstituted isopropyl group.

The fused polycyclic compound according to an embodiment has a structure in which at least one steric hindrance substituent is contained in a planar skeleton structure having at least one boron atom at the center thereof. For example, the fused polycyclic compound according to an embodiment may have a structure in which at least one among substituents represented by Formula 2 and Formula 3 is linked to the fused cyclic core containing a boron atom. The substituents represented by Formula 2 and Formula 3 may include a bulky substituent at the ortho position with respect to the carbon linked to the fused cyclic core. Because of the sterically large volume of the substituents represented by Formula 2 and Formula 3, the fused polycyclic compound of an embodiment may effectively protect the central core from water molecules and oxygen molecules present around the molecule in the molecular structure in an excited state. In the case of the compound exhibiting a delayed fluorescence phenomenon, water molecules or oxygen molecules around the compound may make the energy of excitons in a triplet state move to the oxygen to cause a quenching phenomenon and a reduction in service life. The fused polycyclic compound according to an embodiment includes at least one substituent having a sterically large volume, thus the quenching phenomenon caused by water molecules and oxygen molecules is inhibited, and thereby the fluorescence intensity may be enhanced, and the fused polycyclic compound may effectively protect the central core containing boron to inhibit decomposition, thereby exhibiting a high material stability. Therefore, the light emitting device ED of an embodiment including the fused polycyclic compound of an embodiment in the emission layer EML may exhibit improved luminous efficiency and service life characteristics. Moreover, in the case of introducing the substituents represented by Formula 2 and Formula 3 to the fused polycyclic compound of an embodiment, a more twisted structural shape may be formed, and thus the quenching phenomenon or crystallization caused by π-π stacking between adjacent molecules may be prevented, thereby further enhancing luminous efficiency and thin-film stability.

The emission spectrum of the fused polycyclic compound represented by Formula 1 of an embodiment has a half-width of about 10 nm to about 50 nm. In another embodiment, the emission spectrum of the fused polycyclic compound represented by Formula 1 may have a half-width of about 20 nm to about 40 nm. The emission spectrum of the fused polycyclic compound represented by Formula 1 of an embodiment has the above range of half-width, thereby improving luminous efficiency when applied to a device. In addition, when the fused polycyclic compound of an embodiment is used as a blue light emitting device material for the luminescence device, the service life of the device may be improved.

The fused polycyclic compound represented by Formula 1 of an embodiment may be a thermally activated delayed fluorescence emitting material. Furthermore, the fused polycyclic compound represented by Formula 1 of an embodiment may be a thermally activated delayed fluorescence dopant having the difference (ΔE_{ST}) between the lowest triplet exciton energy level (T1 level) and the lowest singlet exciton energy level (S1 level) of about 0.3 eV or less. For example, ΔE_{ST} of the fused polycyclic compound represented by Formula 1 of an embodiment may be about 0.1 eV or less.

The fused polycyclic compound represented by Formula 1 of an embodiment may be a luminescent material having a luminescence center wavelength in a wavelength region of about 430 nm to about 490 nm. For example, the fused polycyclic compound of an embodiment, represented by Formula 1 may be a blue thermally activated delayed fluorescence (TADF) dopant. However, the embodiment is not limited thereto. For example, in case of using the fused polycyclic compound of an embodiment as the light-emitting material, the fused polycyclic compound may be used as a dopant material emitting light in various wavelength regions, such as a red emitting dopant and a green emitting dopant.

The emission layer EML in the light emitting device ED of an embodiment may emit delayed fluorescence. For example, the emission layer EML may emit thermally activated delayed fluorescence (TADF).

In addition, the emission layer EML of the light emitting device ED may emit blue light. For example, the emission layer EML of the light emitting device ED of an embodiment may emit blue light in the region of about 490 nm or less. However, the embodiment is not limited thereto. For example, the emission layer EML may emit green light or red light.

Although not shown in the drawing, the light emitting device ED of an embodiment may include a plurality of emission layers. The plurality of emission layers may be sequentially stacked, and for example, the light emitting device ED including the plurality of emission layers may emit white light. The organic electroluminescence device including a plurality of emission layers may be an organic electroluminescence device having a tandem structure. When the light emitting device ED includes a plurality of emission layers, at least one emission layer EML may include the fused polycyclic compound of an embodiment as described above.

In an embodiment, the emission layer EML includes a host and a dopant, and may include the above-described fused polycyclic compound as a dopant. For example, the emission layer EML in the light emitting device ED of an embodiment may include a host for emitting delayed fluorescence and a dopant for emitting delayed fluorescence, and may include the above-described fused polycyclic compound as a dopant for emitting delayed fluorescence. The emission layer EML may include at least one among the fused polycyclic compounds represented by Compound Group 1 as described above as a thermally activated delayed fluorescence dopant.

In the light emitting device ED of an embodiment, the emission layer EML may include an anthracene derivative, a pyrene derivative, a fluoranthene derivative, a chrysene derivative, a dehydrobenzanthracene derivative, or a triphenylene derivative. For example, the emission layer EML may include the anthracene derivative or the pyrene derivative.

In each light emitting device ED of embodiments illustrated in FIGS. 3 to 6, the emission layer EML may further include a known host and dopant other than the above-described host and dopant, and the emission layer EML may include a compound represented by Formula E-1 below. The compound represented by Formula E-1 below may be used as a fluorescence host material.

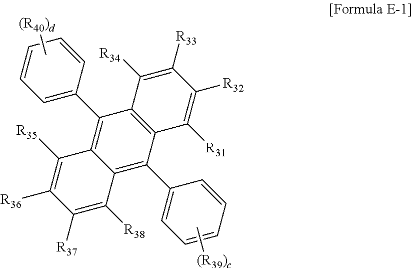

In Formula E-1, R₃₁ to R₄₀ may be each independently a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 1 to 10 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. R₃₁ to R₄₀ may be bonded to an adjacent group to form a saturated hydrocarbon ring or an unsaturated hydrocarbon ring, a saturated heterocycle, or an unsaturated heterocycle.

In Formula E-1, c and d may be each independently an integer of 0 to 5.

Formula E-1 may be represented by any one among Compound E1 to Compound E19 below:

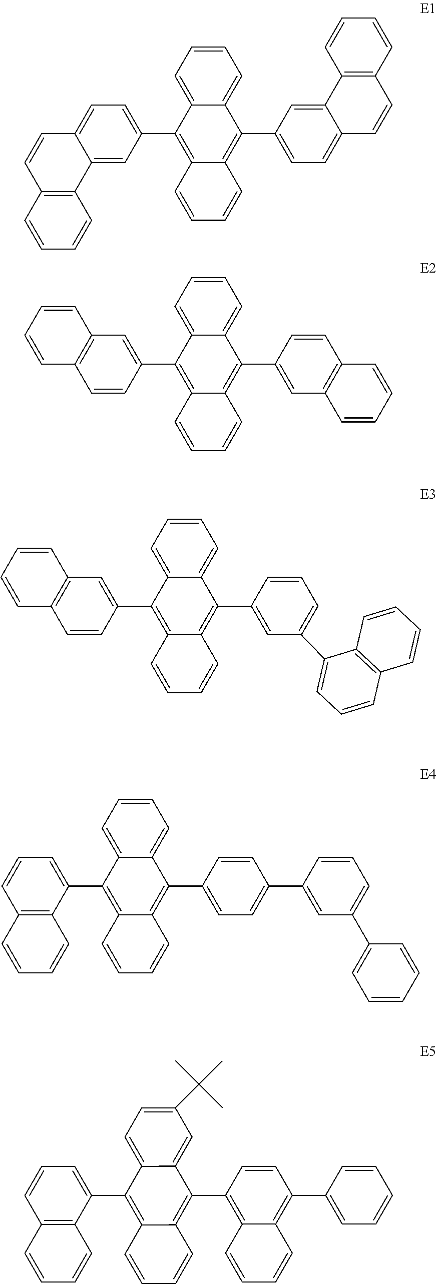

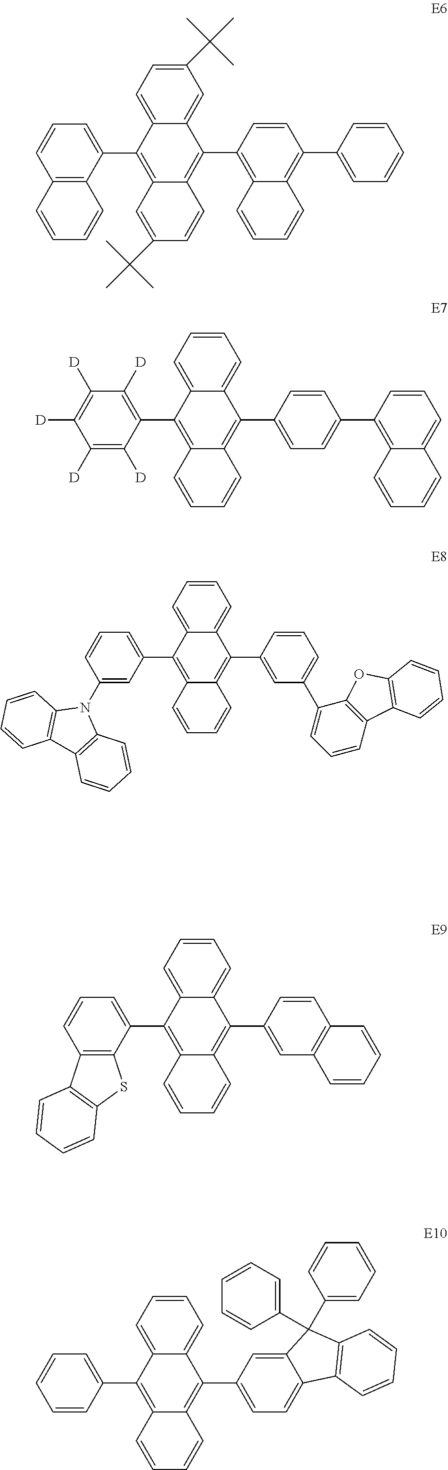

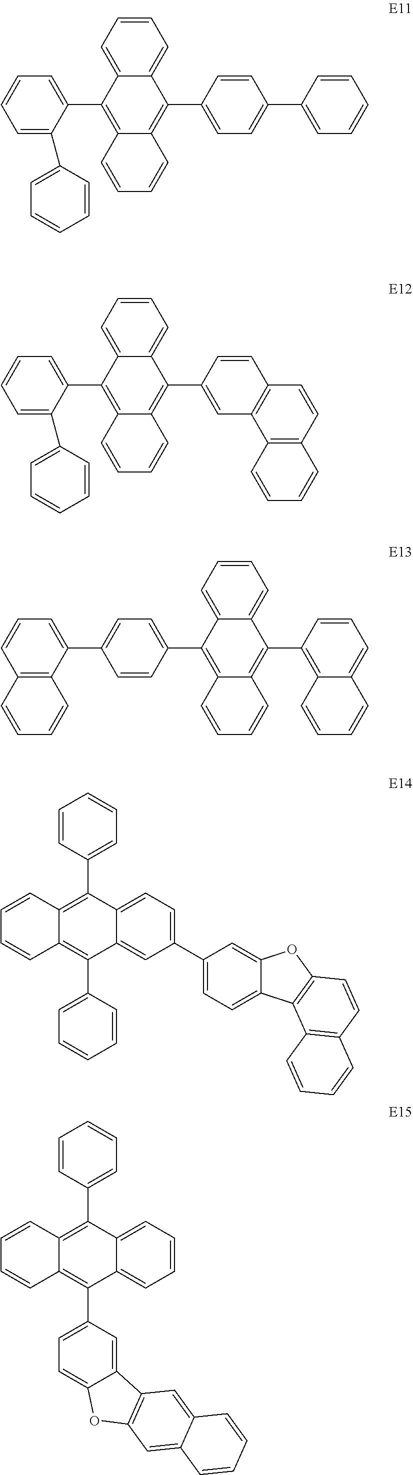

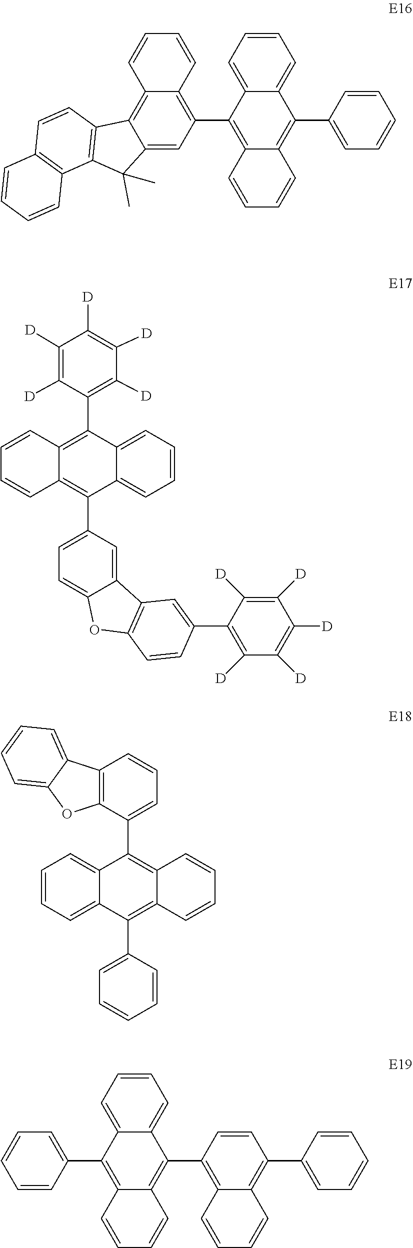

In an embodiment, the emission layer EML may include a compound represented by Formula E-2a or Formula E-2b below. The compound represented by Formula E-2a or Formula E-2b below may be used as a phosphorescence host material.

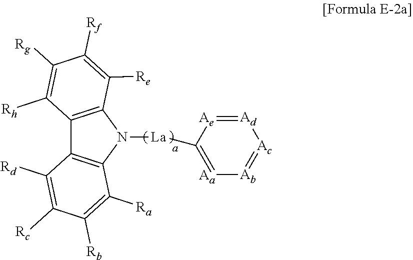

In Formula E-2a, and a may be an integer of 0 to 10, Lₐ may be a direct linkage, a substituted or unsubstituted arylene group having 6 to 30 ring-forming carbon atoms, or a substituted or unsubstituted heteroarylene group having 2 to 30 ring-forming carbon atoms. For example, when a is an integer of 2 or more, a plurality of Lₐ's may be each independently a substituted or unsubstituted arylene group having 6 to 30 ring-forming carbon atoms, or a substituted or unsubstituted heteroarylene group having 2 to 30 ring-forming carbon atoms.

In addition, in Formula E-2a, Aₐ to Aₑ may be each independently N or CRᵢ. Rₐ to Rᵢ may be each independently a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. Rₐ to Rᵢ may be bonded to an adjacent group to form a hydrocarbon ring or a heterocycle containing N, O, S, etc. as a ring-forming atom.

In Formula E-2a, two or three selected from among Aₐ to Aₑ may be N, and the rest may be CRᵢ.

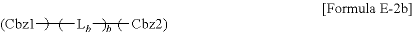

In Formula E-2b, Cbz1 and Cbz2 may be each independently an unsubstituted carbazole group, or a carbazole group substituted with an aryl group having 6 to 30 ring-forming carbon atoms. L_{b} is a direct linkage, a substituted or unsubstituted arylene group having 6 to 30 ring-forming carbon atoms, or a substituted or unsubstituted heteroarylene group having 2 to 30 ring-forming carbon atoms. For example, b is an integer of 0 to 10, and when b is an integer of 2 or more, a plurality of L_{b}'s may be each independently a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by any one among the compounds of Compound Group E-2 below. However, the compounds listed in Compound Group E-2 below are examples, and the compound represented by Formula E-2a or Formula E-2b is not limited to those represented by Compound Group E-2 below.

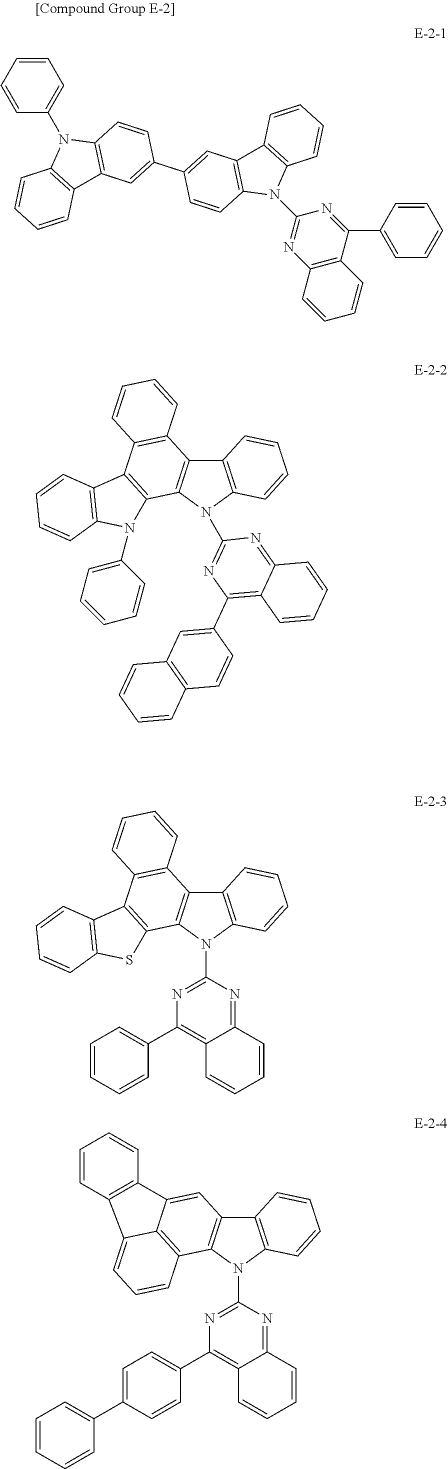

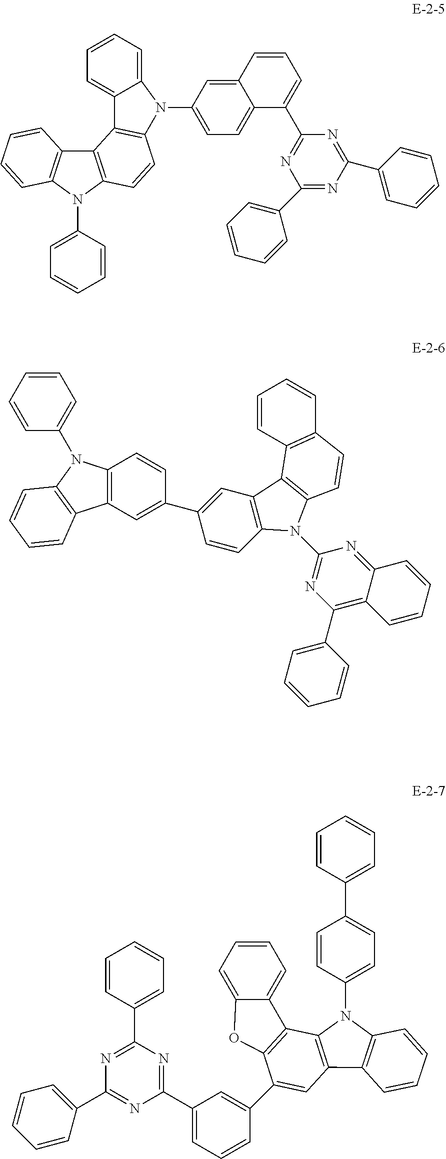 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1]

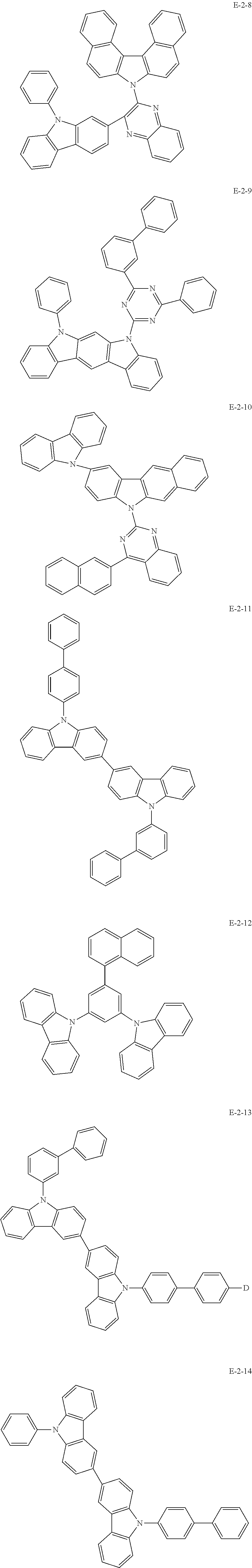

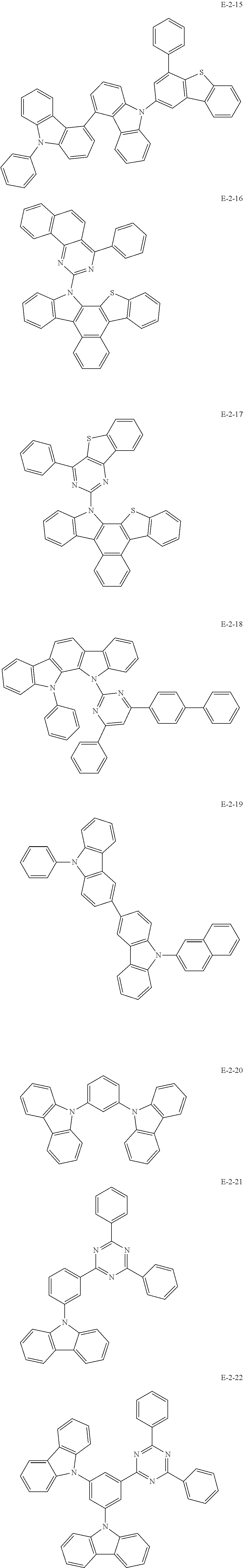

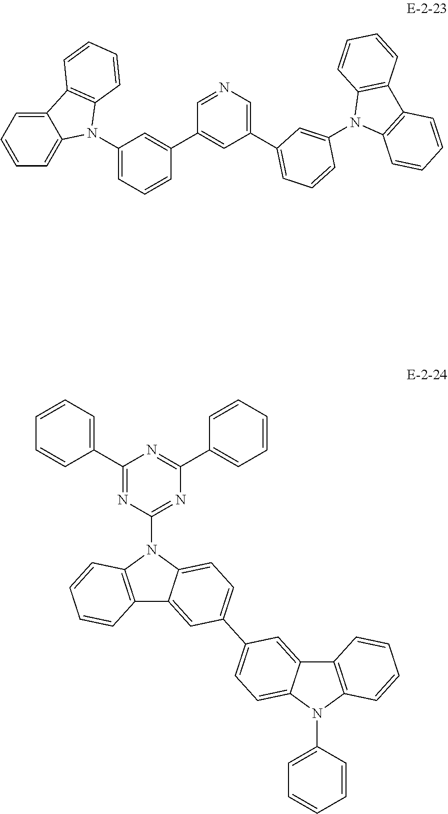 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a general material known in the art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, the embodiment is not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as a host material.

The emission layer EML may further include a compound represented by Formula M-a or Formula M-b below. The compound represented by Formula M-a or Formula M-b below may be used as a phosphorescence dopant material.

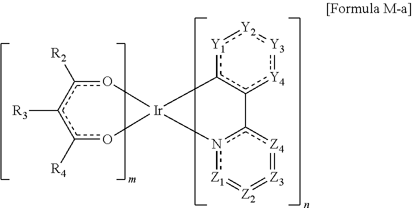

In Formula M-a above, Y₁ to Y₄ and Z₁ to Z₄ may be each independently CR₁ or N, R₁ to R₄ may be each independently a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula M-a, m is 0 or 1, and n is 2 or 3. In Formula M-a, when m is 0, n is 3, and when m is 1, n is 2.

The compound represented by Formula M-a may be used as a phosphorescence dopant.

The compound represented by Formula M-a may be represented by any one among Compound M-a1 to Compound M-a25 below. However, Compounds M-a1 to M-a25 below are examples, and the compound represented by Formula M-a is not limited to those represented by Compounds M-a1 to M-a25 below.

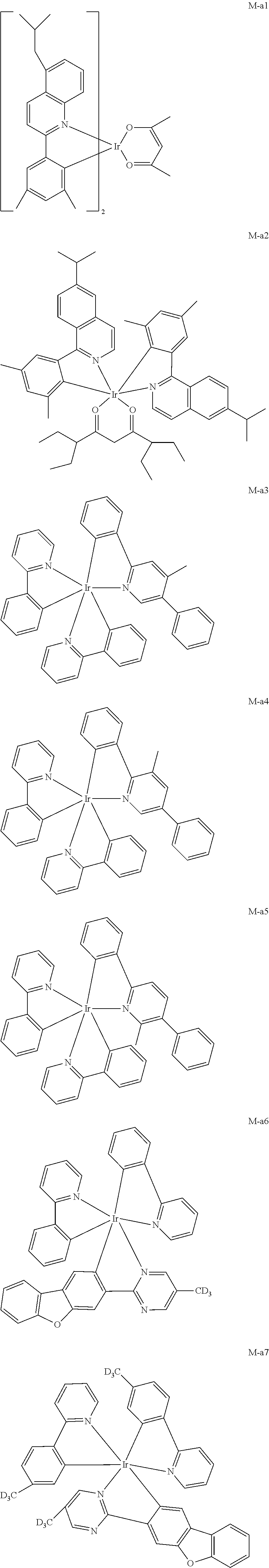

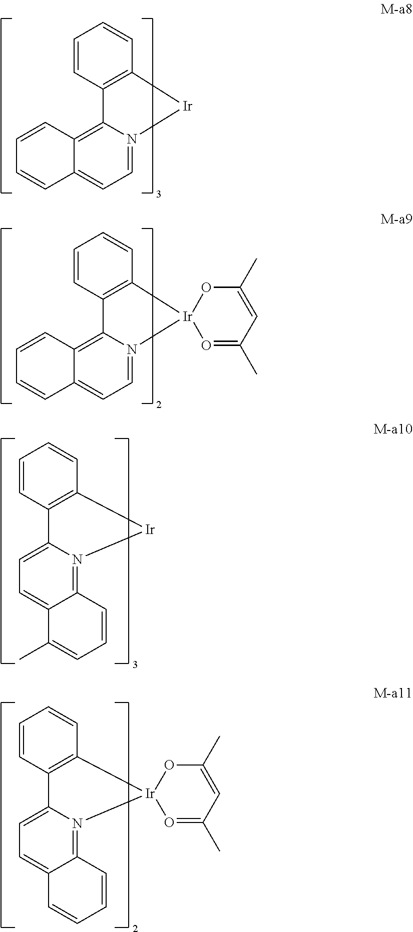

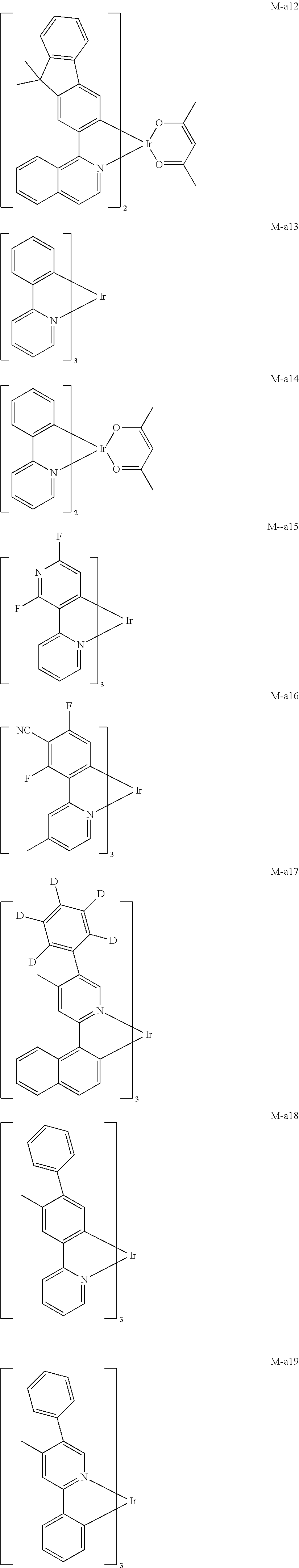

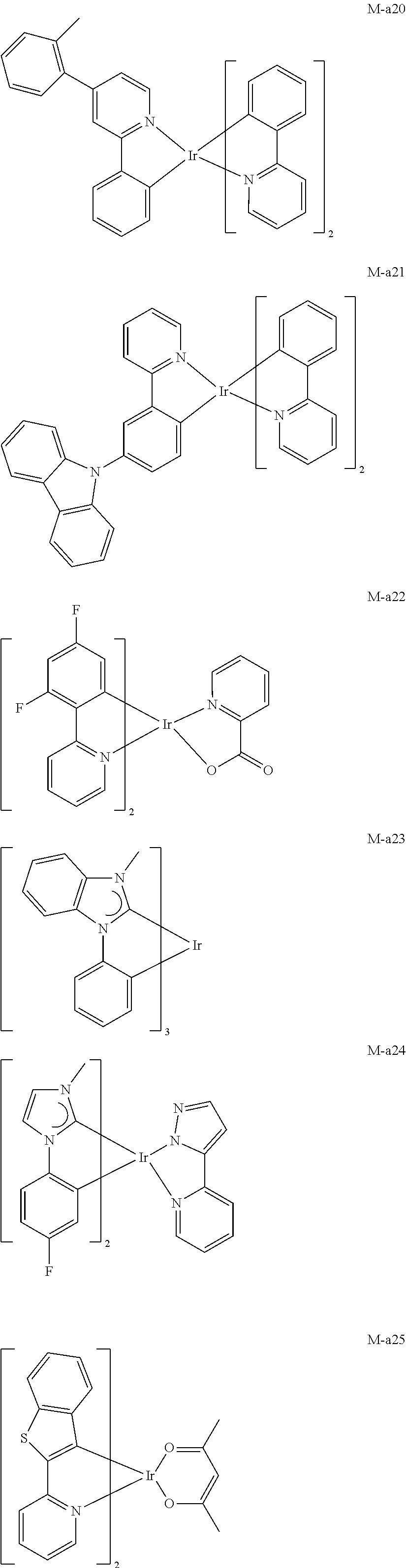

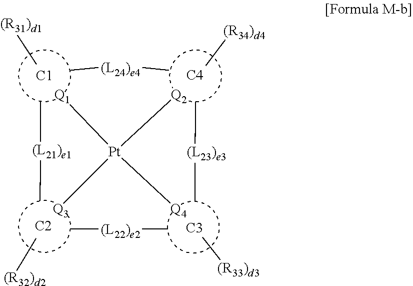

In Formula M-b, Q₁ to Q₄ are each independently C or N, and C1 to C4 are each independently a substituted or unsubstituted hydrocarbon ring having 5 to 30 ring-forming carbon atoms, or a substituted or unsubstituted heterocycle having 2 to 30 ring-forming carbon atoms. L₂₁ to L₂₄ are each independently a direct linkage,

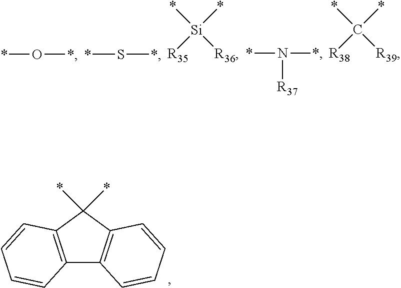

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, and e1 to e4 are each independently 0 or 1. R₃₁ to R₃₉ are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring, and d1 to d4 are each independently an integer of 0 to 4.

The compound represented by Formula M-b may be used as a blue phosphorescence dopant or a green phosphorescence dopant.

The compound represented by Formula M-b may be represented by any one among the compounds below. However, the compounds below are examples, and the compound represented by Formula M-b is not limited to those represented by the compounds below.

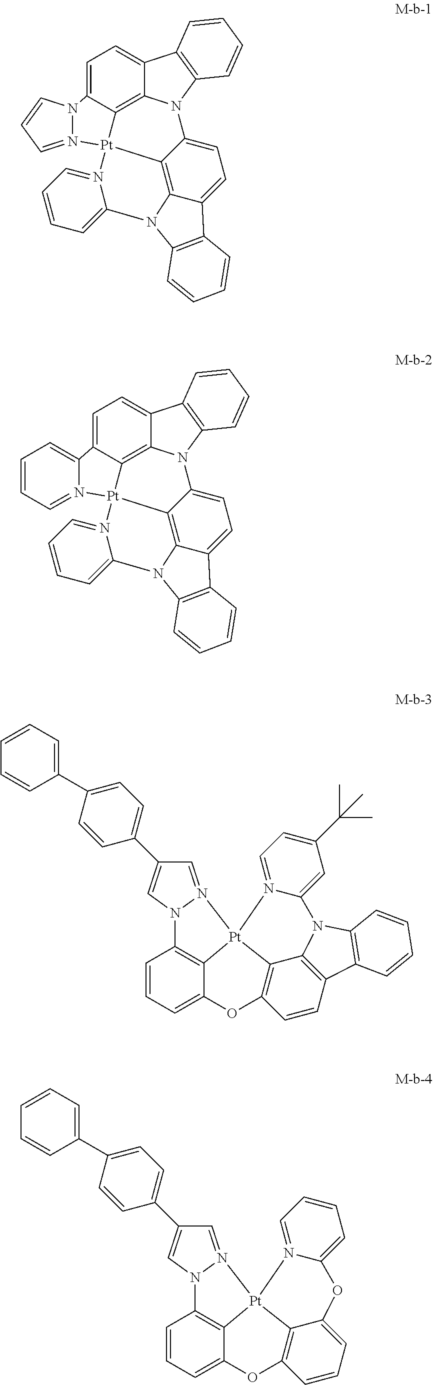

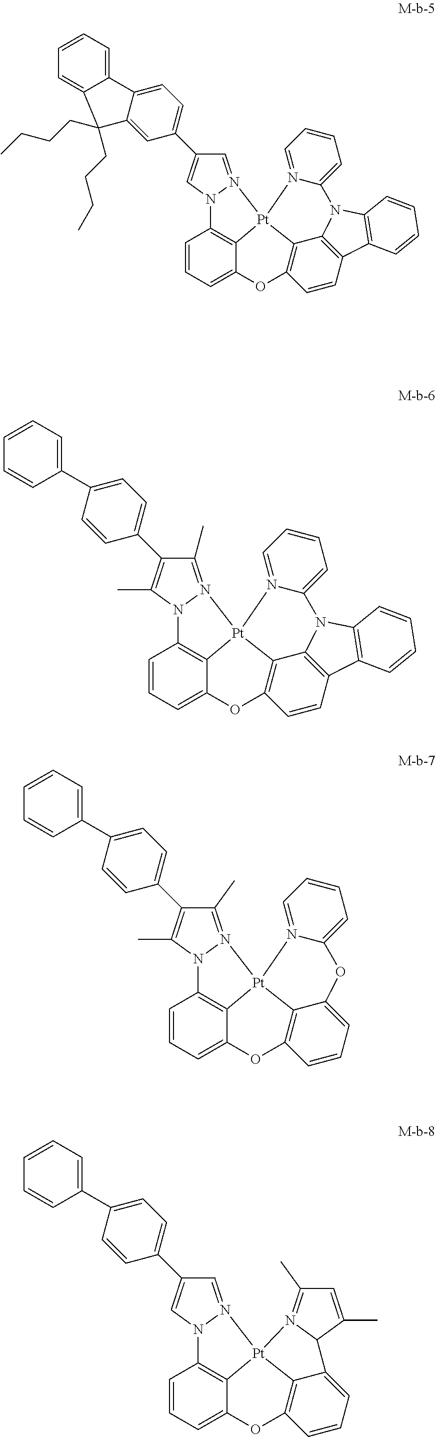

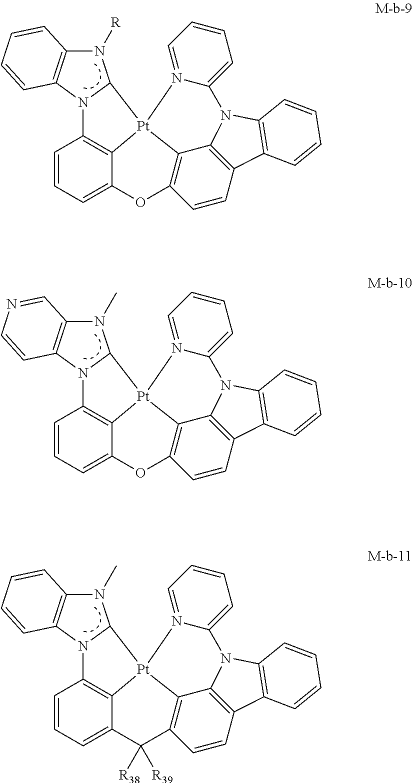

In the compounds, R, R₃₈, and R₃₉ may be each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

The emission layer EML may further include a compound represented by any one among Formula F-a to Formula F-c below. The compound represented by Formula F-a or Formula F-c below may be used as a fluorescence dopant material.

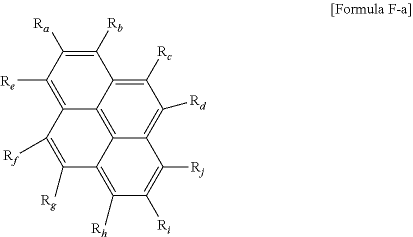

In Formula F-a, two selected from among Rₐ to Rⱼ may each independently be substituted with *—NAr₁Ar₂. The others, which are not substituted with *—NAr₁Ar₂, among Rₐ to Rⱼ may be each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In *—NAr₁Ar₂, Ar₁ and Ar₂ may be each independently a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O or S as a ring-forming atom.

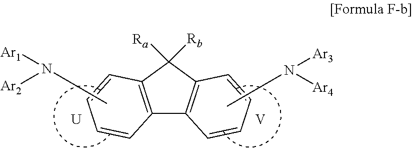

In Formula F-b above, Rₐ and R_{b} may be each independently a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In Formula F-b, U and V may be each independently a substituted or unsubstituted hydrocarbon ring having 5 to 30 ring-forming carbon atoms, or a substituted or unsubstituted heterocycle having 2 to 30 ring-forming carbon atoms. At least one among Ar₁ to Ar₄ may be a heteroaryl group containing O or S as a ring-forming atom.

In Formula F-b, the number of rings represented by U and V may be each independently 0 or 1. For example, in Formula F-b, it means that when the number of U or V is 1, one ring constitutes a condensed ring at a portion indicated by U or V, and when the number of U or V is 0, a ring indicated by U or V does not exist. For example, when the number of U is 0 and the number of V is 1, or when the number of U is 1 and the number of V is 0, the condensed ring having a fluorene core in Formula F-b may be a cyclic compound having four rings. In addition, when each number of U and V is 0, the condensed ring in Formula F-b may be a cyclic compound having three rings. In addition, when each number of U and V is 1, the condensed ring having a fluorene core in Formula F-b may be a cyclic compound having five rings.

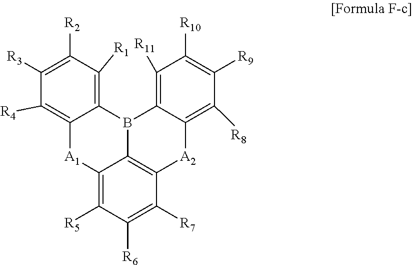

In Formula F-c, A₁ and A₂ may be each independently O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ are each independently a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring.

In Formula F-c, A₁ and A₂ may each independently be bonded to substituents of an adjacent ring to form a condensed ring. For example, when A₁ and A₂ are each independently NRₘ, A₁ may be bonded to R₄ or R₅ to form a ring. In addition, A₂ may be bonded to R₇ or R₈ to form a ring.

In an embodiment, the emission layer EML may further include styryl derivatives (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene and the derivatives thereof (e.g., 2,5,8,11-tetra-t-butylperylene (TBP)), pyrene and the derivatives thereof (e.g., 1,1-dipyrene, 1,4-dipyrenylbenzene, 1,4-bis(N,N-diphenylamino)pyrene), etc.

The emission layer EML may further include a known phosphorescence dopant material. For example, a metal complex including iridium (Ir), platinum (Pt), osmium (Os), aurum (Au), titanium (Ti), zirconium (Zr), hafnium (Hf), europium (Eu), terbium (Tb), or thulium (Tm) may be used as a phosphorescence dopant. For example, iridium(III) bis(4,6-difluorophenylpyridinato-N,C2′)picolinate (FIrpic), bis(2,4-difluorophenylpyridinato)-tetrakis(1-pyrazolyl)borate iridium(III) (Fir6), or platinum octaethyl porphyrin (PtOEP) may be used as a phosphorescence dopant. However, the embodiment is not limited thereto.

The emission layer EML may include a quantum dot material. The core of the quantum dot may be selected from a Group II-VI compound, a Group III-VI compound, a Group I-III-IV compound, a Group III-V compound, a Group III-II-V compound, a Group IV-VI compound, a Group IV element, a Group IV compound, or a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The Group III-VI compound may include a binary compound such as In₂S₃ and In₂Se₃, a ternary compound such as InGaS₃ and InGaSe₃, or any combination thereof.

The Group I-III-VI compound may be selected from a ternary compound selected from the group consisting of AgInS, AgInS₂, CuInS, CuInS₂, AgGaS₂, CuGaS₂ CuGaO₂, AgGaO₂, AgAlO₂, and a mixture thereof, or a quaternary compound such as AgInGaS₂ and CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. In another embodiment, the Group III-V compound may further include a Group II metal. For example, InZnP, etc. may be selected as a Group III-II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

In this case, a binary compound, a ternary compound, or a quaternary compound may be present in particles in a uniform concentration distribution, or may be present in the same particle in a partially different concentration distribution. In addition, a core/shell structure in which one quantum dot surrounds another quantum dot may also be possible. The core/shell structure may have a concentration gradient in which the concentration of elements present in the shell decreases toward the core.

In some embodiments, a quantum dot may have the above-described core-shell structure including a core containing nanocrystals and a shell surrounding the core. The shell of the quantum dot may serve as a protection layer to prevent the chemical deformation of the core so as to maintain semiconductor properties, and/or a charging layer to impart electrophoresis properties to the quantum dot. The shell may be a single layer or a multilayer. An example of the shell of the quantum dot may include a metal or non-metal oxide, a semiconductor compound, or a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO, or a ternary compound such as MgAl₂O₄, CoFe₂O₄, NiFe₂O₄, and CoMn₂O₄, but the embodiment is not limited thereto.

Also, the semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but the embodiment is not limited thereto.

The quantum dot may have a full width of half maximum (FWHM) of a light emission wavelength spectrum of about 45 nm or less. In another embodiment, the quantum dot may have a full width of half maximum (FWHM) of a light emission wavelength spectrum of about 40 nm or less. In another embodiment, the quantum dot may have a full width of half maximum (FWHM) of a light emission wavelength spectrum of about 30 nm or less. Color purity or color reproducibility may be improved in the above range. In addition, light emitted through such a quantum dot is emitted in all directions, and thus a wide viewing angle may be improved.

In addition, although the form of a quantum dot is not particularly limited as long as it is a form commonly used in the art. For example, a quantum dot in the form of spherical, pyramidal, multi-arm, or cubic nanoparticles, nanotubes, nanowires, nanofibers, nanoparticles, etc. may be used.

The quantum dot may control the color of emitted light according to the particle size thereof, and accordingly, the quantum dot may have various emission colors such as blue, red, and green.

In each light emitting device ED of embodiments illustrated in FIGS. 3 to 6, the electron transport region ETR is provided on the emission layer EML. The electron transport region ETR may include at least one of the hole blocking layer HBL, the electron transport layer ETL, or the electron injection layer EIL, but the embodiment is not limited thereto.

The electron transport region ETR may have a single layer formed of a single material, a single layer formed of a plurality of different materials, or a multilayer structure including a plurality of layers formed of a plurality of different materials.

For example, the electron transport region ETR may have a single layer structure of the electron injection layer EIL or the electron transport layer ETL, and may have a single layer structure formed of an electron injection material and an electron transport material. In addition, the electron transport region ETR may have a single layer structure formed of a plurality of different materials, or may have a structure in which an electron transport layer ETL/electron injection layer EIL, a hole blocking layer HBL/electron transport layer ETL/electron injection layer EIL are stacked in order from the emission layer EML, but the embodiment is not limited thereto. The electron transport region ETR may have a thickness, for example, from about 1,000 Å to about 1,500 Å.

The electron transport region ETR may be formed by using various methods such as a vacuum deposition method, a spin coating method, a cast method, a Langmuir-Blodgett (LB) method, an inkjet printing method, a laser printing method, a laser induced thermal imaging (LITI) method, etc.

The electron transport region ETR may include a compound represented by Formula ET-1 below:

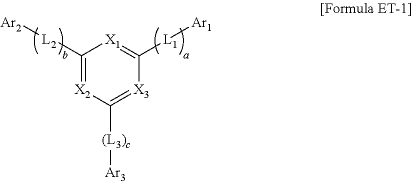

In Formula ET-1, at least one among X₁ to X₃ is N, and the rest are CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may be each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-1, a to c may be each independently an integer of 0 to 10. In Formula ET-1, L₁ to L₃ may be each independently a direct linkage, a substituted or unsubstituted arylene group having 6 to 30 ring-forming carbon atoms, or a substituted or unsubstituted heteroarylene group having 2 to 30 ring-forming carbon atoms. For example, when a to c are an integer of 2 or more, L₁ to L₃ may be each independently a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, the embodiment is not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalene-2-yl)anthracene (ADN), 1,3-Bis[3,5-di(pyridin-3-yl)phenyl]benzene (BmPyPhB), or a mixture thereof.

The electron transport region ETR may include at least one among Compound ET1 to Compound ET36 below:

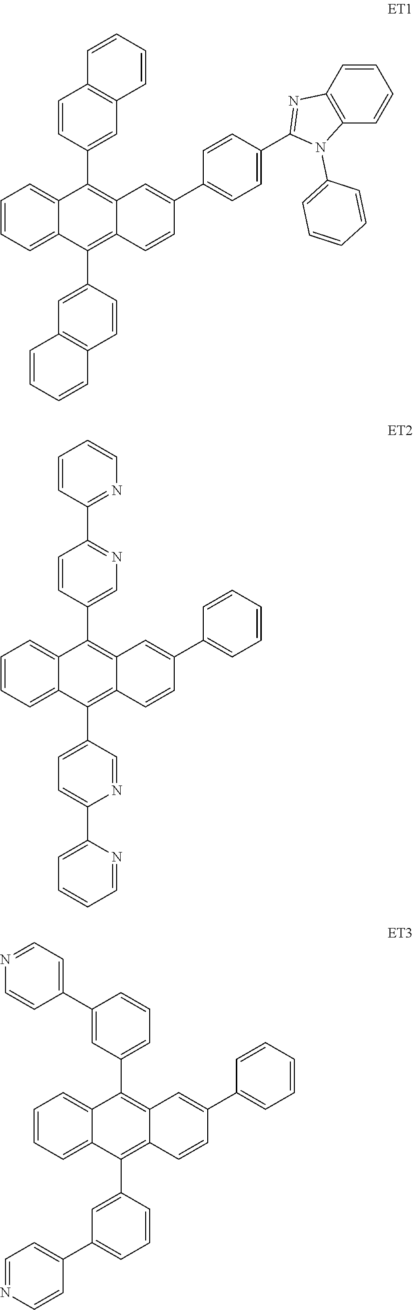 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

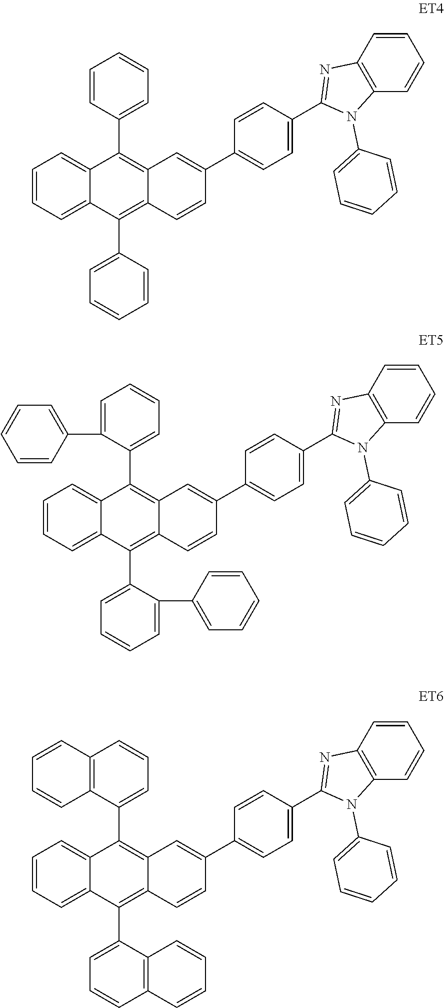 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

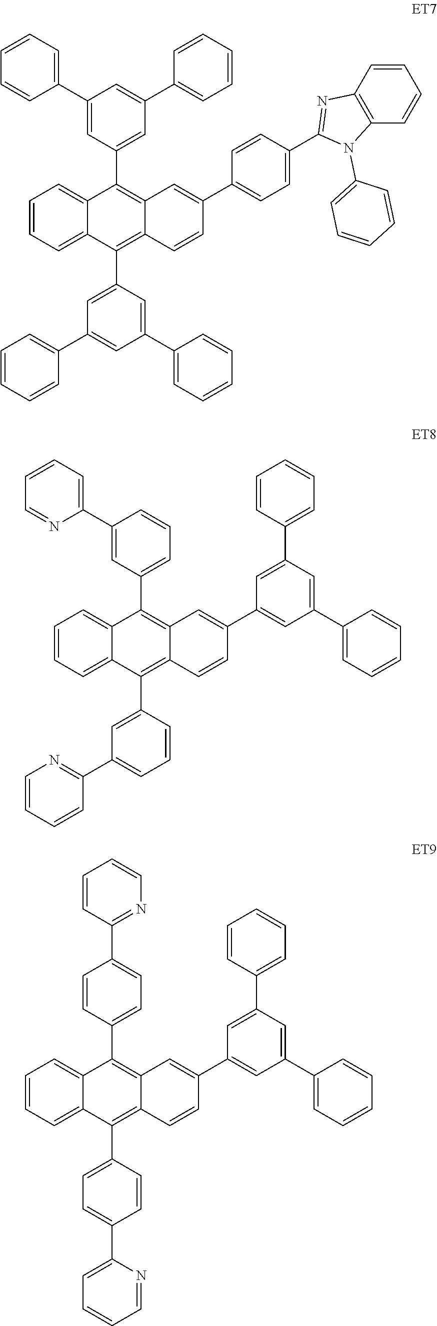 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

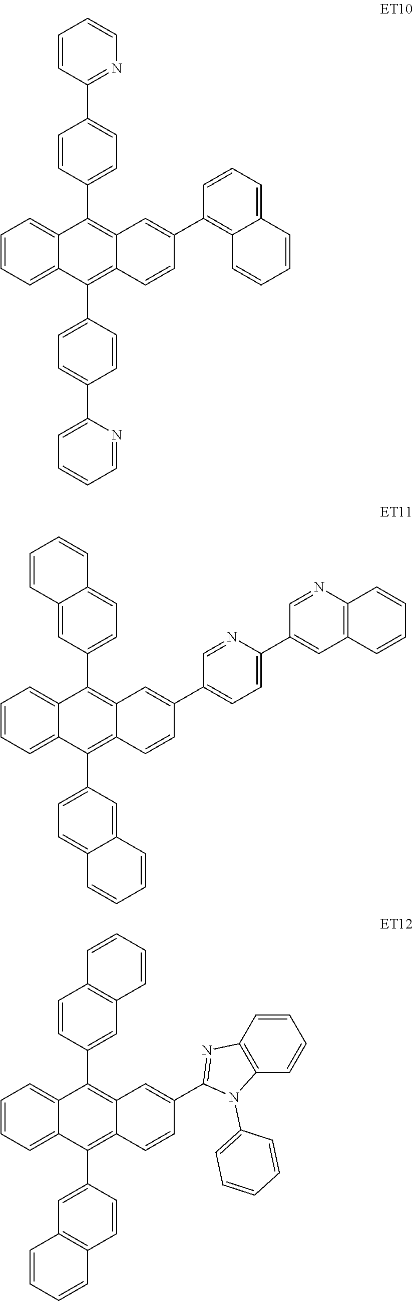

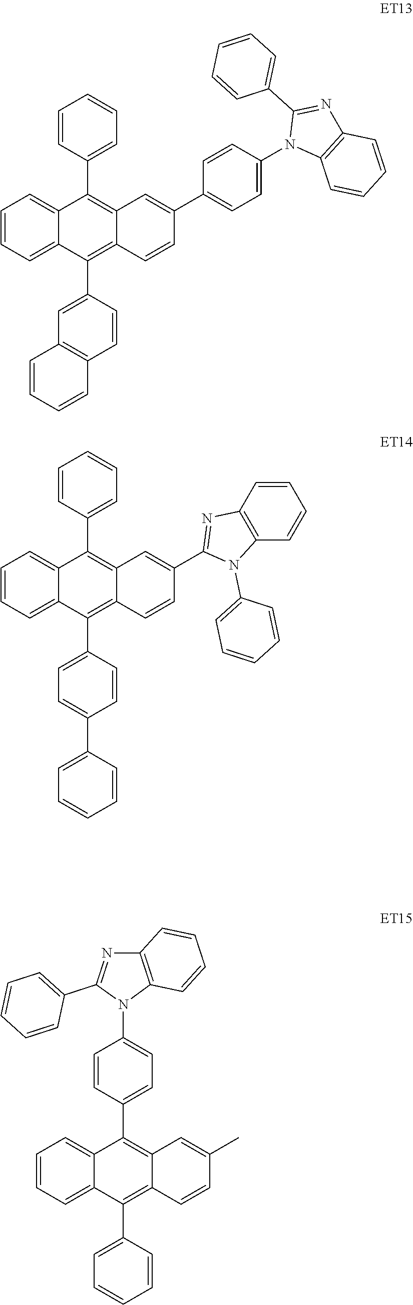 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

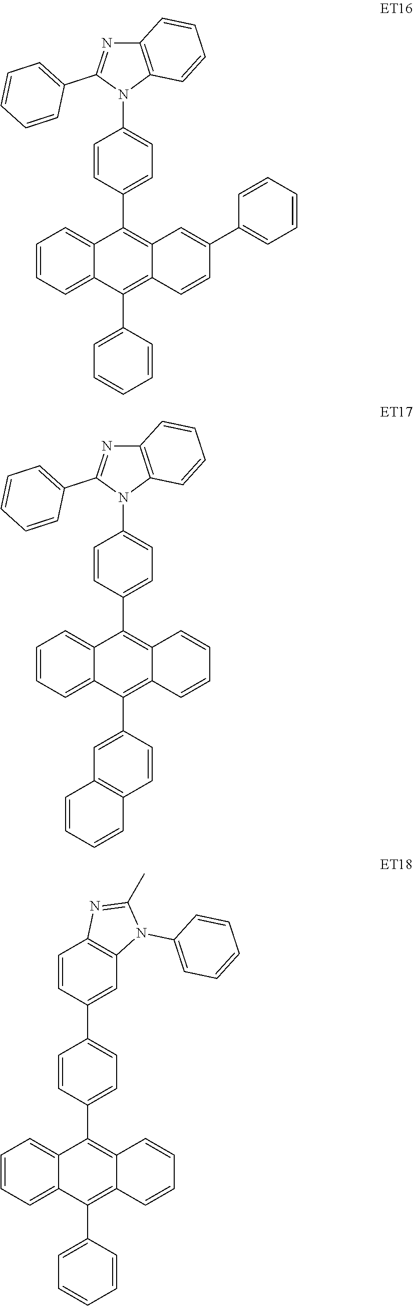

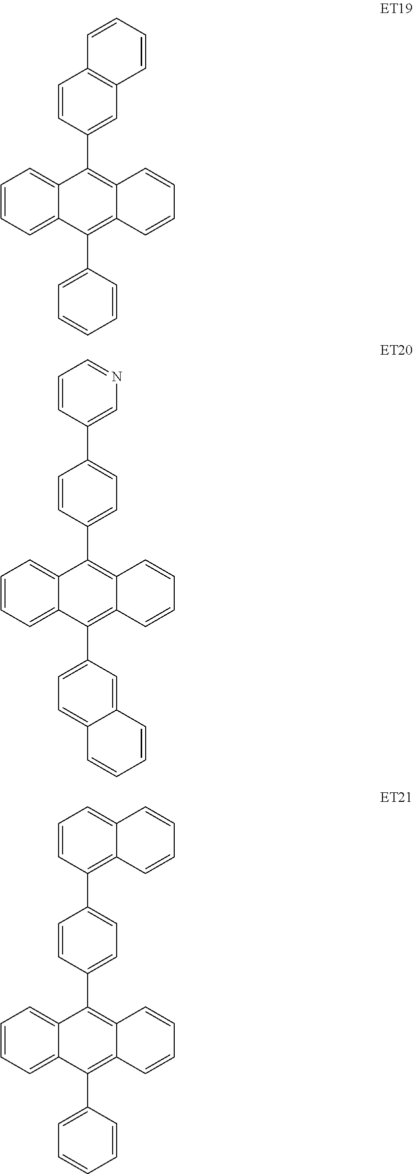

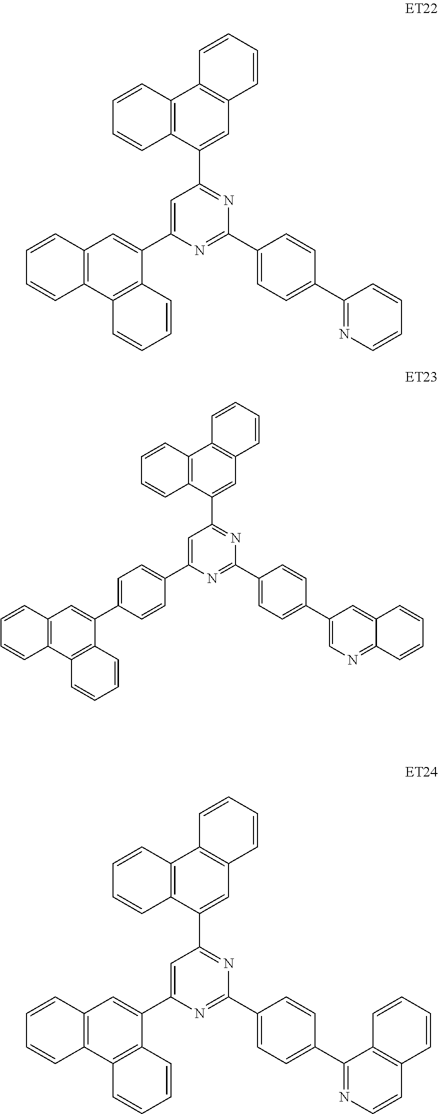 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

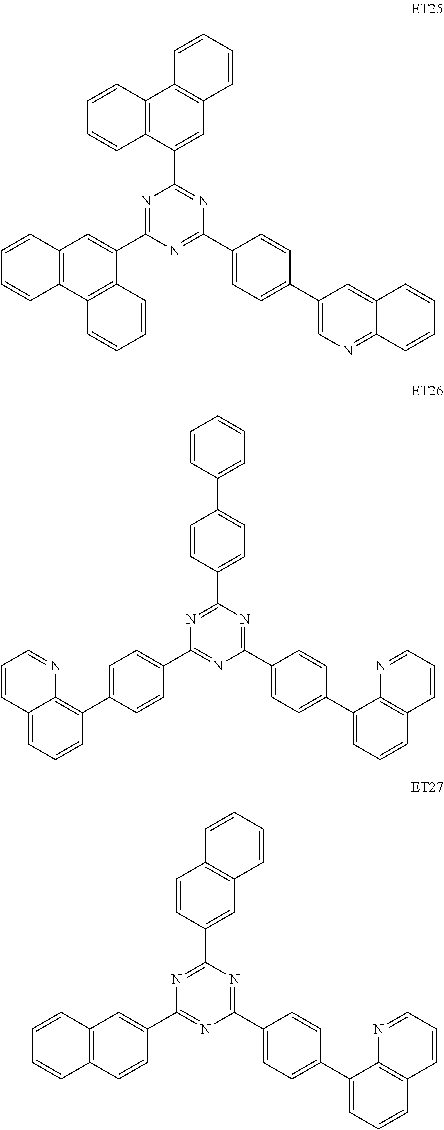 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

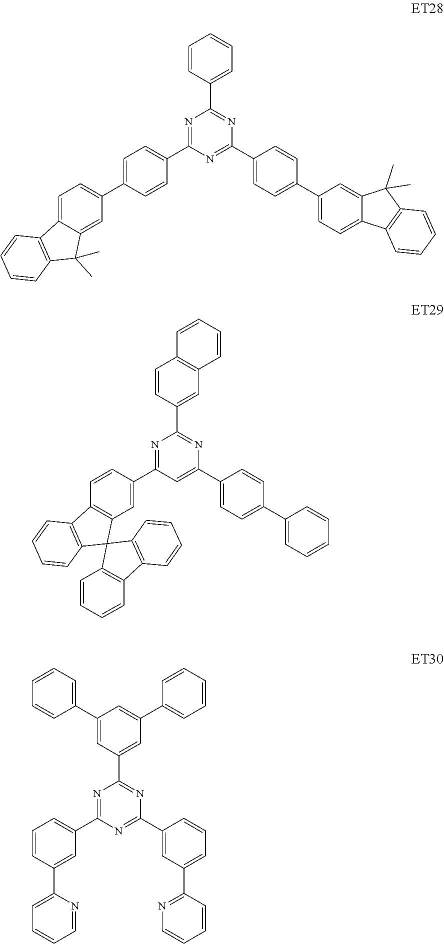 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

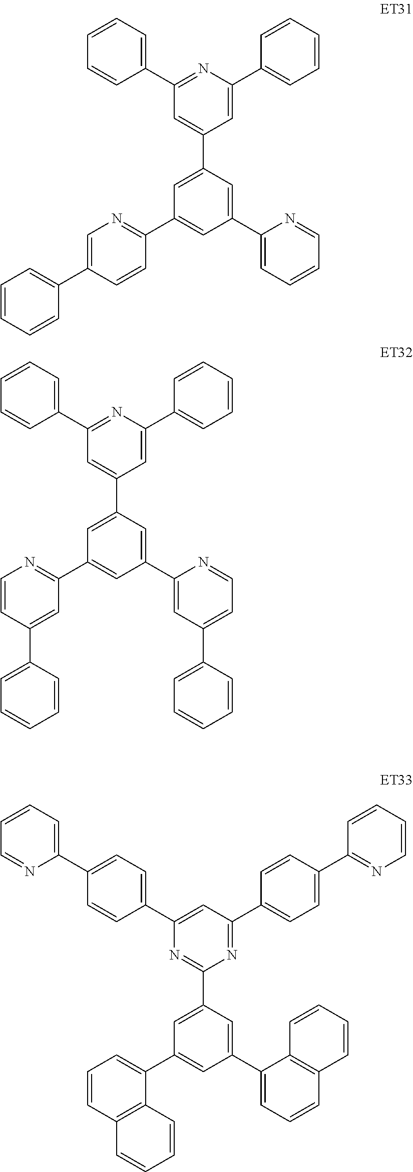

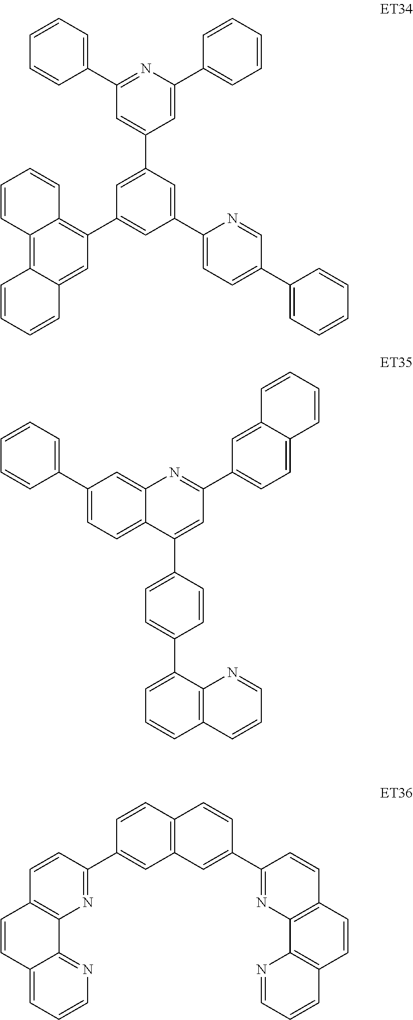 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In addition, the electron transport regions ETR may include a metal halide such as LiF, NaCl, CsF, RbCl, RbI, CuI, or KI, a lanthanide metal such as Yb, and a co-deposited material of the metal halide and the lanthanide metal. For example, the electron transport region ETR may include KI:Yb, RbI:Yb, LiF:Yb, etc. as a co-deposited material. Also, the electron transport region ETR may be formed using a metal oxide such as Li₂O or BaO, or 8-hydroxyl-lithium quinolate (Liq), etc., but the embodiment is not limited thereto. The electron transport region ETR may also be formed of a mixture material of an electron transport material and an insulating organometallic salt. The organometallic salt may be a material having an energy band gap of about 4 eV or more. For example, the organometallic salt may include, for example, a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the above-described materials, but the embodiment is not limited thereto.

The electron transport region ETR may include the above-described compounds of the hole transport region in at least one of the electron injection layer EIL, the electron transport layer ETL, or the hole blocking layer HBL.

When the electron transport region ETR includes the electron transport layer ETL, the electron transport layer ETL may have a thickness of about 100 Å to about 1,000 Å, for example, about 150 Å to about 500 Å. If the thickness of the electron transport layer ETL satisfies the aforementioned range, satisfactory electron transport characteristics may be obtained without a substantial increase in a driving voltage. When the electron transport region ETR includes the electron injection layer EIL, the electron injection layer EIL may have a thickness of about 1 Å to about 100 Å, for example, about 3 Å to about 90 Å. If the thickness of the electron injection layer EIL satisfies the above-described range, satisfactory electron injection characteristics may be obtained without a substantial increase in a driving voltage.

The second electrode EL2 is provided on the electron transport region ETR. The second electrode EL2 may be a common electrode. The second electrode EL2 may be a cathode or an anode, but the embodiment is not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, or a compound or mixture thereof (e.g., AgMg, AgYb, or MgYb). Alternatively, the second electrode EL2 may have a multilayer structure including a reflective film or a transflective film formed of the above-described materials, and a transparent conductive film formed of ITO, IZO, ZnO, ITZO, etc. For example, the second electrode EL2 may include the above-described metal materials, combinations of at least two metal materials of the above-described metal materials, oxides of the above-described metal materials, or the like.

Although not shown, the second electrode EL2 may be connected with an auxiliary electrode. If the second electrode EL2 is connected with the auxiliary electrode, the resistance of the second electrode EL2 may decrease.

A capping layer CPL may further be disposed on the second electrode EL2 of the light emitting device ED of an embodiment. The capping layer CPL may include a multilayer or a single layer.

In an embodiment, the capping layer CPL may be an organic layer or an inorganic layer. For example, when the capping layer CPL contains an inorganic material, the inorganic material may include an alkaline metal compound (for example, LiF), an alkaline earth metal compound (for example, MgF₂), SiON, SiNₓ, SiOy, etc.

For example, when the capping layer CPL contains an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol sol-9-yl)triphenylamine (TCTA), etc., or may include an epoxy resin, or an acrylate such as a methacrylate. However, the embodiment is not limited thereto, and the capping layer CPL may include at least one among Compounds P1 to P5 below:

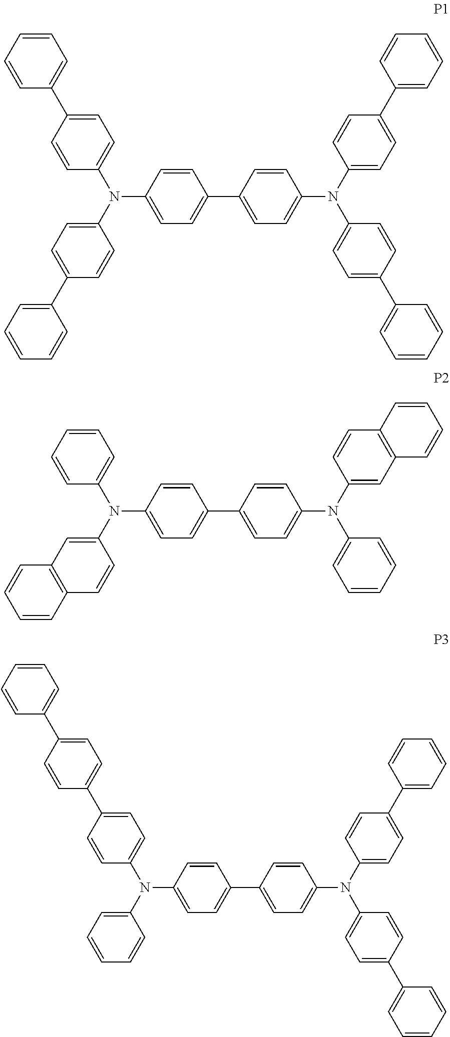 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

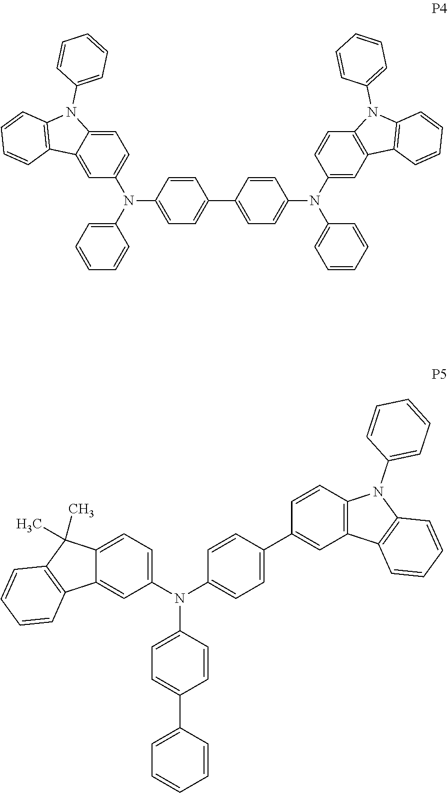 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

The refractive index of the capping layer CPL may be about 1.6 or more. For example, the refractive index of the capping layer CPL may be about 1.6 or more with respect to light in a wavelength range of about 550 nm to about 660 nm.

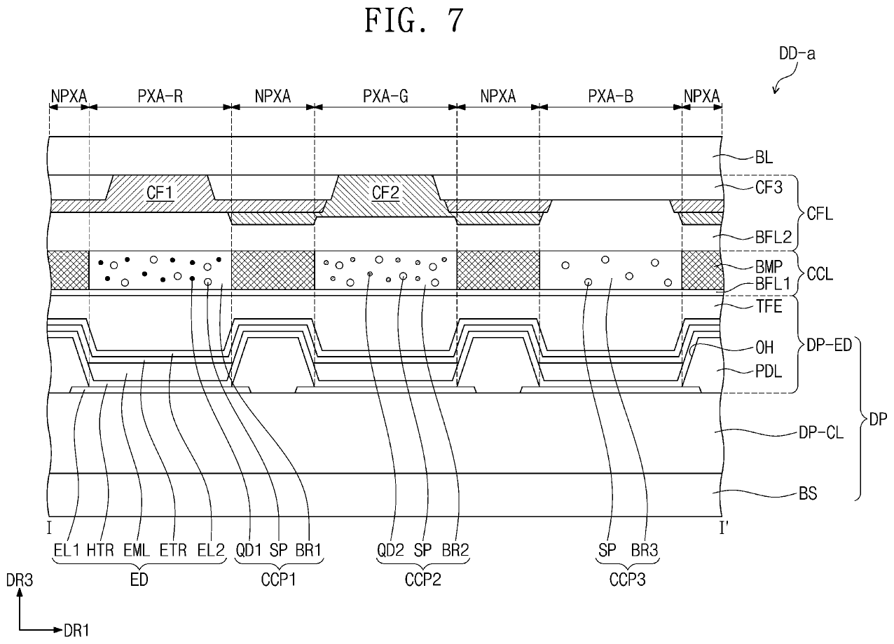

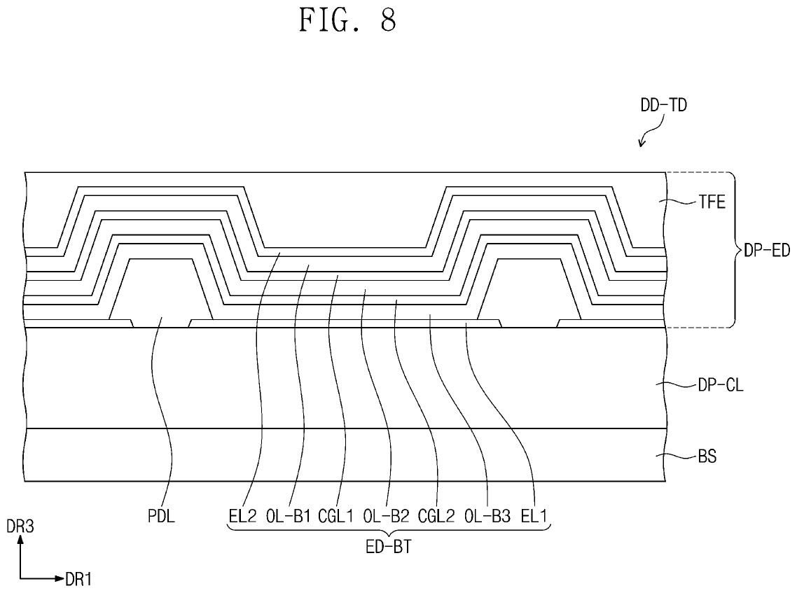

FIGS. 7 and 8 each are a cross-sectional view of a display apparatus according to an embodiment. Hereinafter, in describing the display apparatus of embodiments with reference to FIGS. 7 and 8, the duplicated features which have been described in FIGS. 1 to 6 are not described again, but their differences will be mainly described.

Referring to FIG. 7, the display apparatus DD according to an embodiment may include a display panel DP including a display device layer DP-ED, a light control layer CCL disposed on the display panel DP, and a color filter layer CFL.

In an embodiment illustrated in FIG. 7, the display panel DP may include a base layer BS, a circuit layer DP-CL provided on the base layer BS, and the display device layer DP-ED, and the display device layer DP-ED may include a light emitting device ED.

The light emitting device ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. The structures of the light emitting devices of FIGS. 3 to 6 as described above may be equally applied to the structure of the light emitting device ED shown in FIG. 7.

Referring to FIG. 7, the emission layer EML may be disposed in an opening OH defined in a pixel defining film PDL. For example, the emission layer EML which is divided by the pixel defining film PDL and provided corresponding to each light emitting regions PXA-R, PXA-G, and PXA-B may emit light in the same wavelength range. In the display apparatus DD of an embodiment, the emission layer EML may emit blue light. In another embodiment, the emission layer EML may be provided as a common layer in the entire light emitting regions PXA-R, PXA-G, and PXA-B.

The light control layer CCL may be disposed on the display panel DP. The light control layer CCL may include a light conversion body. The light conversion body may be a quantum dot, a phosphor, or the like. The light conversion body may emit provided light by converting the wavelength thereof. That is, the light control layer CCL may a layer containing the quantum dot or a layer containing the phosphor.

The light control layer CCL may include a plurality of light control parts CCP1, CCP2 and CCP3. The light control parts CCP1, CCP2, and CCP3 may be spaced apart from one another.

Referring to FIG. 7, divided patterns BMP may be disposed between the light control parts CCP1, CCP2 and CCP3 which are spaced apart from each other, but the embodiment is not limited thereto. FIG. 7 illustrates that the divided patterns BMP do not overlap the light control parts CCP1, CCP2 and CCP3, but at least a portion of the edges of the light control parts CCP1, CCP2 and CCP3 may overlap the divided patterns BMP.

The light control layer CCL may include a first light control part CCP1 containing a first quantum dot QD1 which converts first color light provided from the light emitting device ED into second color light, a second light control part CCP2 containing a second quantum dot QD2 which converts the first color light into third color light, and a third light control part CCP3 which transmits the first color light.

In an embodiment, the first light control part CCP1 may provide red light that is the second color light, and the second light control part CCP2 may provide green light that is the third color light. The third light control part CCP3 may provide blue light by transmitting the blue light that is the first color light provided from the light emitting device ED. For example, the first quantum dot QD1 may be a red quantum dot, and the second quantum dot QD2 may be a green quantum dot. The same as described above may be applied with respect to the quantum dots QD1 and QD2.

In addition, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include any quantum dot but include the scatterer SP.

The scatterer SP may be inorganic particles. For example, the scatterer SP may include at least one of TiO₂, ZnO, Al₂O₃, SiO₂, or hollow silica. The scatterer SP may include any one of TiO₂, ZnO, Al₂O₃, SiO₂, or hollow silica, or may be a mixture of at least two materials selected from among TiO₂, ZnO, Al₂O₃, SiO₂, and hollow silica.

The first light control part CCP1, the second light control part CCP2, and the third light control part CCP3 each may include base resins BR1, BR2, and BR3 in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3. The base resins BR1, BR2, and BR3 are media in which the quantum dots QD1 and QD2 and the scatterer SP are dispersed, and may be formed of various resin compositions, which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may be transparent resins. In an embodiment, the first base resin BR1, the second base resin BR2, and the third base resin BR3 each may be the same as or different from each other.

The light control layer CCL may include a barrier layer BFL1. The barrier layer BFL1 may serve to prevent the penetration of moisture and/or oxygen (hereinafter, referred to as ‘moisture/oxygen’). The barrier layer BFL1 may be disposed on the light control parts CCP1, CCP2, and CCP3 to block the light control parts CCP1, CCP2 and CCP3 from being exposed to moisture/oxygen. The barrier layer BFL1 may cover the light control parts CCP1, CCP2, and CCP3. The barrier layer BFL2 may be provided between the light control parts CCP1, CCP2, and CCP3 and the color filter layer CFL.

The barrier layers BFL1 and BFL2 may include at least one inorganic layer. That is, the barrier layers BFL1 and BFL2 may include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, etc. The barrier layers BFL1 and BFL2 may further include an organic film. The barrier layers BFL1 and BFL2 may be formed of a single layer or a plurality of layers.

In the display apparatus DD of an embodiment, the color filter layer CFL may be disposed on the light control layer CCL. For example, the color filter layer CFL may be directly disposed on the light control layer CCL. In this case, the barrier layer BFL2 may be omitted.

The color filter layer CFL may include a light shielding part BM and color filters CF1, CF2, and CF3. The color filter layer CFL may include a first filter CF1 configured to transmit the second color light, a second filter CF2 configured to transmit the third color light, and a third filter CF3 configured to transmit the first color light. For example, the first filter CF1 may be a red filter, the second filter CF2 may be a green filter, and the third filter CF3 may be a blue filter. The filters CF1, CF2, and CF3 each may include a polymeric photosensitive resin and a pigment or dye. The first filter CF1 may include a red pigment or dye, the second filter CF2 may include a green pigment or dye, and the third filter CF3 may include a blue pigment or dye. The embodiment is not limited thereto. For example, the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

Furthermore, in an embodiment, the first filter CF1 and the second filter CF2 may be a yellow filter. The first filter CF1 and the second filter CF2 may not be separated but be provided as one filter.

The light shielding part BM may be a black matrix. The light shielding part BM may include an organic light shielding material or an inorganic light shielding material containing a black pigment or dye. The light shielding part BM may prevent light leakage, and may separate boundaries between the adjacent filters CF1, CF2, and CF3. In addition, in an embodiment, the light shielding part BM may be formed of a blue filter.

The first to third filters CF1, CF2, and CF3 may be disposed corresponding to the red light emitting region PXA-R, the green light emitting region PXA-G, and the blue light emitting region PXA-B, respectively.

A base substrate BL may be disposed on the color filter layer CFL. The base substrate BL may be a member which provides a base surface in which the color filter layer CFL, the light control layer CCL, and the like are disposed. The base substrate BL may be a glass substrate, a metal substrate, a plastic substrate, etc. However, the embodiment is not limited thereto. For example, the base substrate BL may be an inorganic layer, an organic layer, or a composite material layer. In another embodiment, the base substrate BL may be omitted.

FIG. 8 is a cross-sectional view illustrating a part of a display apparatus according to an embodiment. In the display apparatus DD-TD of an embodiment, the light emitting device ED-BT may include a plurality of light emitting structures OL-B1, OL-B2, and OL-B3. The light emitting device ED-BT may include a first electrode EL1 and a second electrode EL2 which face each other, and the plurality of light emitting structures OL-B1, OL-B2, and OL-B3 sequentially stacked in the thickness direction between the first electrode EL1 and the second electrode EL2. The light emitting structures OL-B1, OL-B2, and OL-B3 each may include an emission layer EML (FIG. 7) and a hole transport region HTR and an electron transport region ETR disposed with the emission layer EML (FIG. 7) therebetween.

That is, the light emitting device ED-BT included in the display apparatus DD-TD of an embodiment may be a light emitting device having a tandem structure and including a plurality of emission layers.

In an embodiment illustrated in FIG. 8, all light beams respectively emitted from the light emitting structures OL-B1, OL-B2, and OL-B3 may be blue light. However, the embodiment is not limited thereto. For example, the light beams respectively emitted from the light emitting structures OL-B1, OL-B2, and OL-B3 may have wavelength ranges different from each other. For example, the light emitting device ED-BT including the plurality of light emitting structures OL-B1, OL-B2, and OL-B3 which emit light beams having wavelength ranges different from each other may emit white light.

A charge generation layers CGL1 and CGL2 may be disposed between two of the neighboring light emitting structures OL-B1, OL-B2, and OL-B3. The charge generation layers CGL1 and CGL2 may include a p-type charge generation layer and/or an n-type charge generation layer.

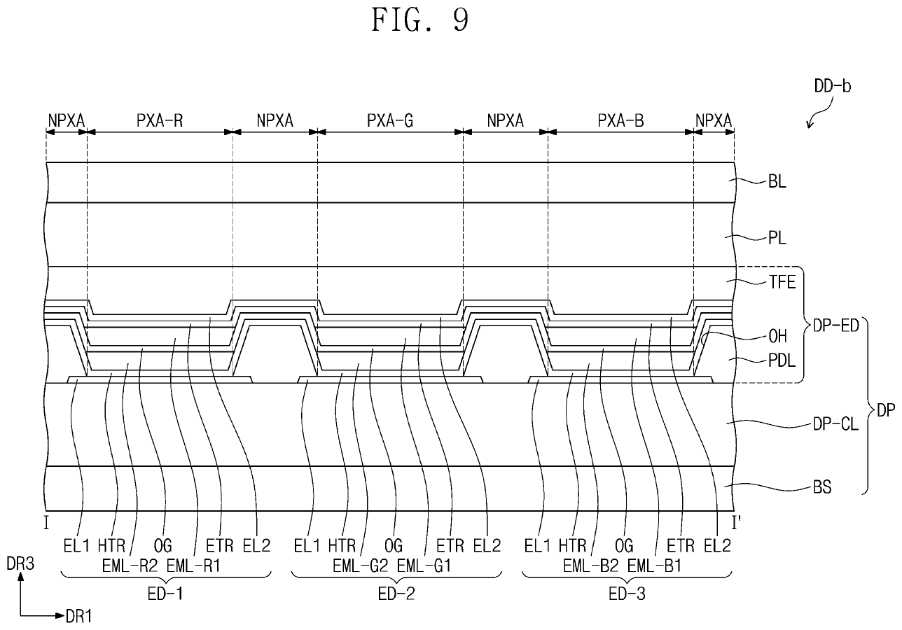

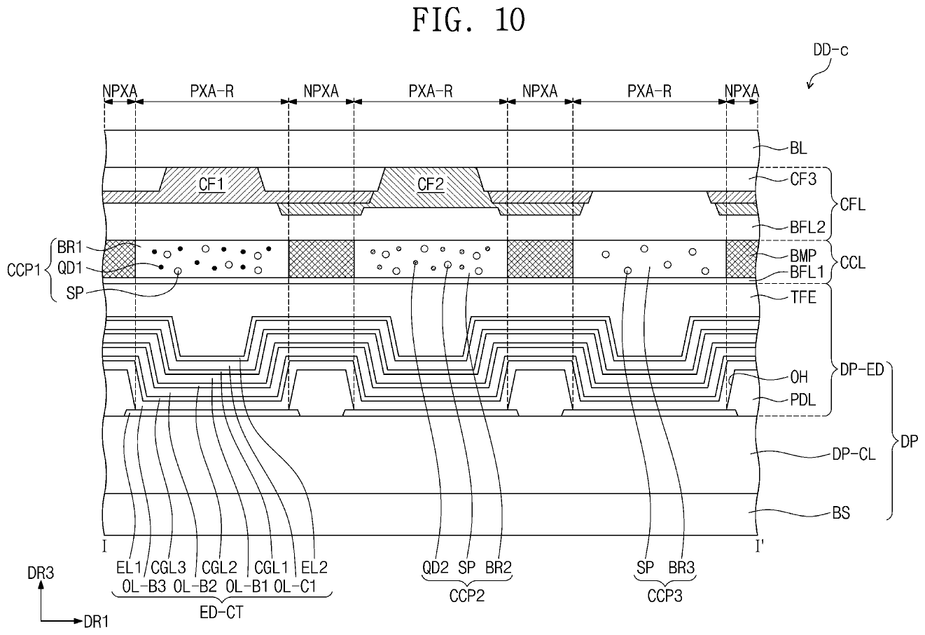

Referring to FIG. 9, the display apparatus DD-b according to an embodiment may include light emitting devices ED-1, ED-2, and ED-3 in which two emission layers are stacked. Compared to the display apparatus DD of an embodiment illustrated in FIG. 2, an embodiment illustrated in FIG. 9 has a difference in that the first to third light emitting devices ED-1, ED-2, and ED-3 each include two emission layers stacked in the thickness direction. In each of the first to third light emitting devices ED-1, ED-2, and ED-3, the two emission layers may emit light in the same wavelength region.

The first light emitting device ED-1 may include a first red emission layer EML-R1 and a second red emission layer EML-R2. The second light emitting device ED-2 may include a first green emission layer EML-G1 and a second green emission layer EML-G2. In addition, the third light emitting device ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generation layer. For example, the emission auxiliary part OG may include an electron transport region, a charge generation layer, and a hole transport region that are sequentially stacked. The emission auxiliary part OG may be provided as a common layer in the whole of the first to third light emitting devices ED-1, ED-2, and ED-3. However, the embodiment is not limited thereto, For example, the emission auxiliary part OG may be provided by being patterned within the openings OH defined in the pixel defining film PDL.

The first red emission layer EML-R1, the first green emission layer EML-G1, and the first blue emission layer EML-B1 may be disposed between the electron transport region ETR and the emission auxiliary part OG. The second red emission layer EML-R2, the second green emission layer EML-G2, and the second blue emission layer EML-B2 may be disposed between the emission auxiliary part OG and the hole transport region HTR.

That is, the first light emitting device ED-1 may include the first electrode EL1, the hole transport region HTR, the second red emission layer EML-R2, the emission auxiliary part OG, the first red emission layer EML-R1, the electron transport region ETR, and the second electrode EL2 that are sequentially stacked. The second light emitting device ED-2 may include the first electrode EL1, the hole transport region HTR, the second green emission layer EML-G2, the emission auxiliary part OG, the first green emission layer EML-G1, the electron transport region ETR, and the second electrode EL2 that are sequentially stacked. The third light emitting device ED-3 may include the first electrode EL1, the hole transport region HTR, the second blue emission layer EML-B2, the emission auxiliary part OG, the first blue emission layer EML-B1, the electron transport region ETR, and the second electrode EL2 that are sequentially stacked.

An optical auxiliary layer PL may be disposed on the display device layer DP-ED. The optical auxiliary layer PL may include a polarizing layer. The optical auxiliary layer PL may be disposed on the display panel DP and control reflected light in the display panel DP due to external light. In other embodiments, the optical auxiliary layer PL in the display apparatus according to an embodiment may be omitted.

FIG. 10 illustrates that a display apparatus DD-c includes four light emitting structures OL-B1, OL-B2, OL-B3, and OL-C1. A light emitting device ED-CT may include a first electrode EL1 and a second electrode EL2 which face each other, and first to fourth light emitting structures OL-B1, OL-B2, OL-B3, and OL-C1 that are sequentially stacked in the thickness direction between the first electrode EL1 and the second electrode EL2. Charge generation layers CGL1, CGL2, and CGL3 may be disposed between the first to fourth light emitting structures OL-B1, OL-B2, OL-B3, and OL-C1. Among the four light emitting structures, the first to third light emitting structures OL-B1, OL-B2, and OL-B3 may emit blue light, and the fourth light emitting structure OL-C1 may emit green light. However, the embodiment is not limited thereto. For example, the first to fourth light emitting structures OL-B1, OL-B2, OL-B3, and OL-C1 may emit light beams in different wavelength regions.

The charge generation layers CGL1, CGL2, and CGL3 disposed between adjacent light emitting structures OL-B1, OL-B2, OL-B3, and OL-C1 may include a p-type charge generation layer and/or an n-type charge generation layer.

At least one among the light emitting structures OL-B1, OL-B2, OL-B3, and OL-C1 included in the display apparatus DD-c of an embodiment may contain the above-described fused polycyclic compound of an embodiment.

Hereinafter, with reference to Examples and Comparative Examples, a condensed polycyclic according to an embodiment and a luminescence device of an embodiment will be described in detail. In addition, Examples disclosed below are only to help understanding of the invention. Embodiments of the invention are not limited thereto.

### Examples

1. Synthesis of Fused Polycyclic Compound

First, a synthetic method of the fused polycyclic compound according to the present embodiment will be described by illustrating synthetic methods of Compounds 179, 180, 93, 273, 106, 280, 291, and 293. In addition, the synthetic methods of the fused polycyclic compounds explained below are only examples, and the synthetic method of the fused polycyclic compound according to an embodiment is not limited to the following examples.

(1) Synthesis of Compound 179

Fused polycyclic compound 179 according to an example may be synthesized by, for example, the reaction below.

(Synthesis of Intermediate C1)

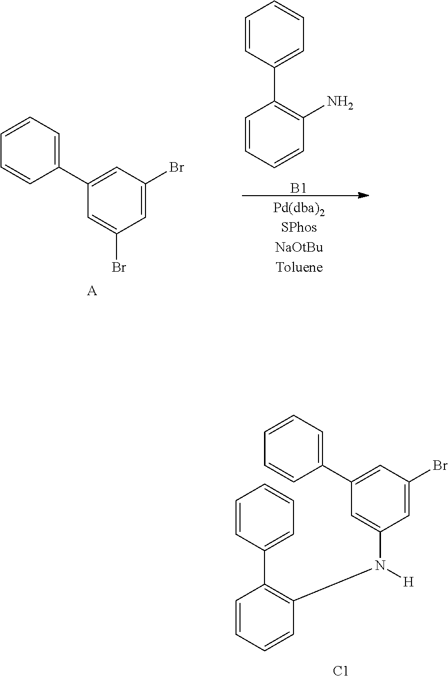

In an Ar atmosphere, Intermediate A (62.4 g), Intermediate B1 (33.8 g), bis(dibenzylideneacetone)palladium(0) (Pd(dba)₂, 4.6 g), 2-dicyclohexylphosphino-2′,6′-dimethoxybiphenyl (SPhos, 6.6 g), and sodium tert-butoxide (NaOtBu, 24.1 g) were dissolved in toluene (2 L) and heated under reflux for 6 hours. After the temperature was returned to room temperature, the resultant mixture was extracted with CH₂Cl₂ by adding water to obtain organic layers. The obtained organic layers were combined and dried over MgSO₄, and then the solvent was removed by distillation under reduced pressure. The resulting crude product was purified by silica gel column chromatography to obtain Intermediate C1 (68.8 g, yield 86%). The mass number of Intermediate C1 measured by FAB-MS measurement was 399.

(Synthesis of Intermediate D1)

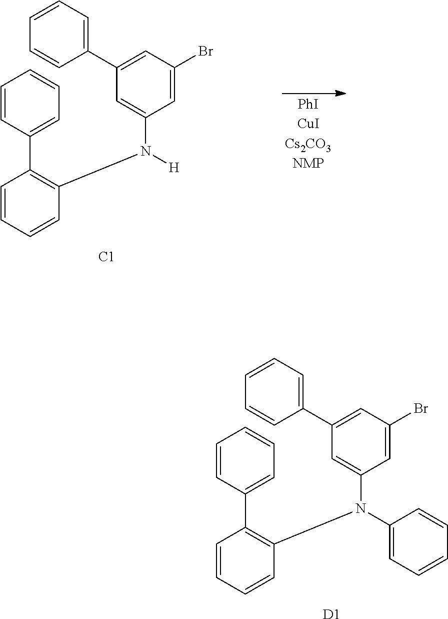 [SMILES: Brc1cc(Nc2ccccc2-c2ccccc2)cc(-c2ccccc2)c1 ; "C1" ; Brc1cc(-c2ccccc2)cc(N(c2ccccc2)c2ccccc2-c2ccccc2)c1 ; "D1"]

In an Ar atmosphere, Intermediate C1 (65.4 g), iodobenzene (170 g), CuI (31.1 g), and Cs₂CO₃ (107 g) were dissolved in N-methylpyrrolidone (NMP, 700 mL) and heated and stirred at 190° C. for 24 hours. After the temperature was returned to room temperature, the resultant mixture was extracted with CH₂Cl₂ by adding water to obtain organic layers. The obtained organic layers were combined and dried over MgSO₄, and then the solvent was removed by distillation under reduced pressure. The resulting crude product was purified by silica gel column chromatography to obtain Intermediate D1 (65.3 g, yield 84%). The mass number of Intermediate D1 measured by FAB-MS measurement was 475.

(Synthesis of Intermediate E1)

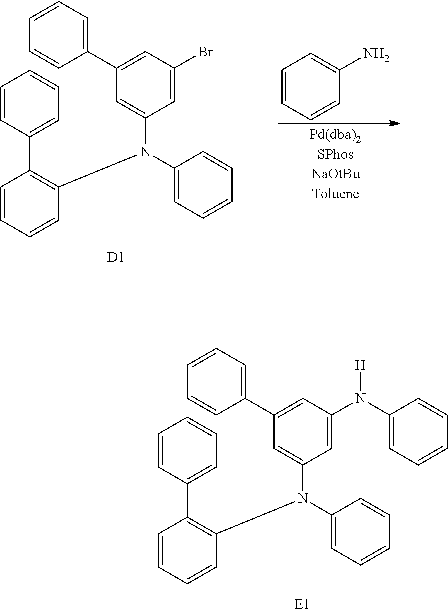 [SMILES: Brc1cc(-c2ccccc2)cc(N(c2ccccc2)c2ccccc2-c2ccccc2)c1 ; Nc1ccccc1 ; "D1" ; c1ccc(Nc2cc(-c3ccccc3)cc(N(c3ccccc3)c3ccccc3-c3ccccc3)c2)cc1 ; "E1"]

In an Ar atmosphere, Intermediate D1 (62.1 g), aniline (24.5 g), Pd(dba)₂ (3.0 g), SPhos (4.3 g), and NaOtBu (15.1 g) were dissolved in toluene (1300 mL) and heated under reflux for 6 hours. The resultant mixture was extracted with CH₂Cl₂ by adding water to obtain organic layers. The obtained organic layers were combined and dried over MgSO₄, and then the solvent was removed by distillation under reduced pressure. The resulting crude product was purified by silica gel column chromatography to obtain Intermediate E1 (58.0 g, yield 91%). The mass number of Intermediate E1 measured by FAB-MS measurement was 488.

(Synthesis of Intermediate G1)

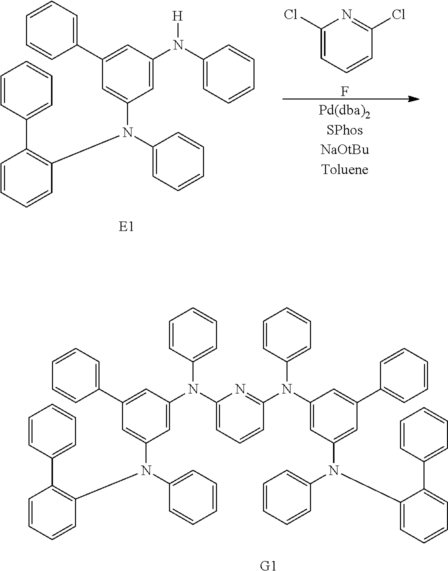

In an Ar atmosphere, Intermediate E1 (55.1 g), Intermediate F (8.3 g), Pd(dba)₂ (2.6 g), SPhos (3.7 g), and NaOtBu (13.1 g) were dissolved in toluene (1200 mL) and heated under reflux for 12 hours. The resultant mixture was extracted with CH₂Cl₂ by adding water to obtain organic layers. The obtained organic layers were combined and dried over MgSO₄, and then the solvent was removed by distillation under reduced pressure. The resulting crude product was purified by silica gel column chromatography to obtain Intermediate G1 (12.2 g, yield 21%). The mass number of Intermediate G1 measured by FAB-MS measurement was 1051.

(Synthesis of Compound 179)

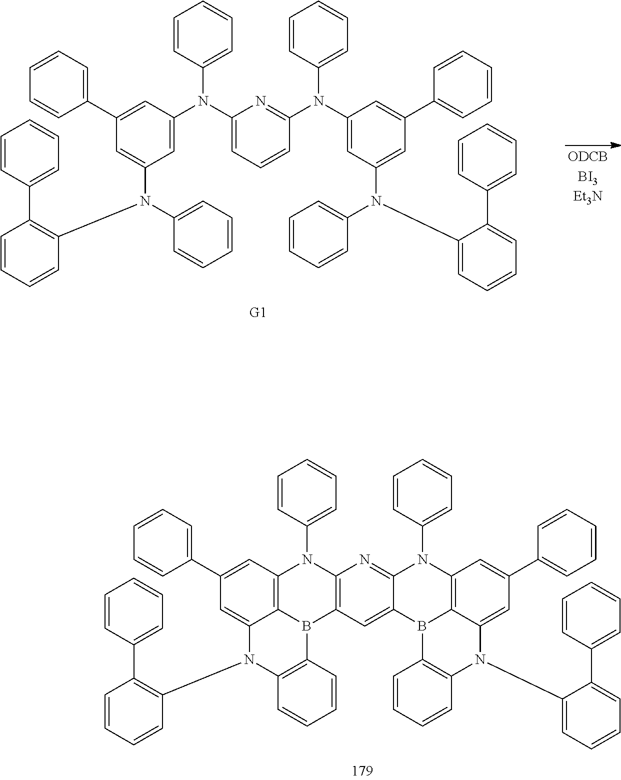 [SMILES: c1ccc(-c2cc(N(c3ccccc3)c3cccc(N(c4ccccc4)c4cc(-c5ccccc5)cc(N(c5ccccc5)c5ccccc5-c5ccccc5)c4)n3)cc(N(c3ccccc3)c3ccccc3-c3ccccc3)c2)cc1 ; c1ccc(-c2cc3c4c(c2)N(c2ccccc2)c2nc5c(cc2B4c2ccccc2N3c2ccccc2-c2ccccc2)B2c3ccccc3N(c3ccccc3-c3ccccc3)c3cc(-c4ccccc4)cc(c32)N5c2ccccc2)cc1]

In an Ar atmosphere, Intermediate G1 (11.6 g) was dissolved in o-dichlorobenzene (ODCB, 130 mL) and cooled to 0° C. in an ice bath, and boron triiodide (BI₃, 40 g) was added thereto, and then the resulting mixture was heated and stirred at 190° C. for 18 hours and then cooled to 0° C. in the ice bath, and triethylamine (25 mL) was added thereto. After the temperature was returned to room temperature, the reaction solution was filtered with a silica gel, and the residual solvent was removed by distillation under reduced pressure. The resulting crude product was purified by being recrystallized from toluene and cleaned with hexane to obtain Compound 179 (1.5 g, yield 13%). The molecular weight of Compound 179 measured by FAB-MS measurement was 1067.

(2) Synthesis of Compound 180

Fused polycyclic compound 180 according to an example may be synthesized by, for example, the reaction below.

(Synthesis of Intermediate C2)

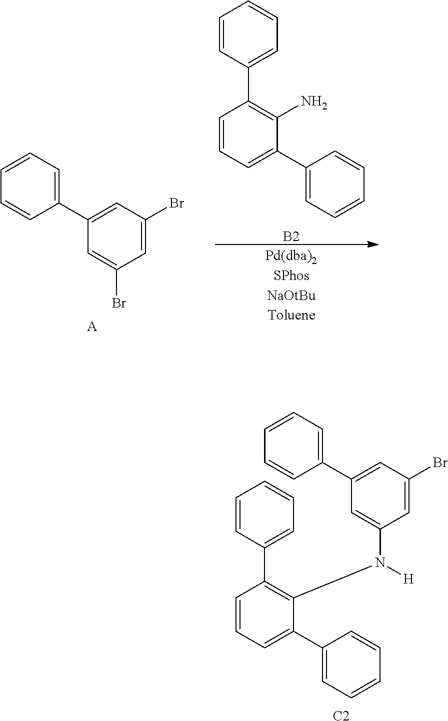

In an Ar atmosphere, Intermediate A (62.4 g), Intermediate B2 (49.0 g), Pd(dba)₂ (4.6 g), SPhos (6.6 g), and NaOtBu (24.1 g) were dissolved in toluene (2 L) and heated under reflux for 6 hours. After the temperature was returned to room temperature, the resultant mixture was extracted with CH₂Cl₂ by adding water to obtain organic layers. The obtained organic layers were combined and dried over MgSO₄, and then the solvent was removed by distillation under reduced pressure. The resulting crude product was purified by silica gel column chromatography to obtain Intermediate C2 (77.1 g, yield 81%). The mass number of Intermediate C2 measured by FAB-MS measurement was 475.

(Synthesis of Intermediate D2)

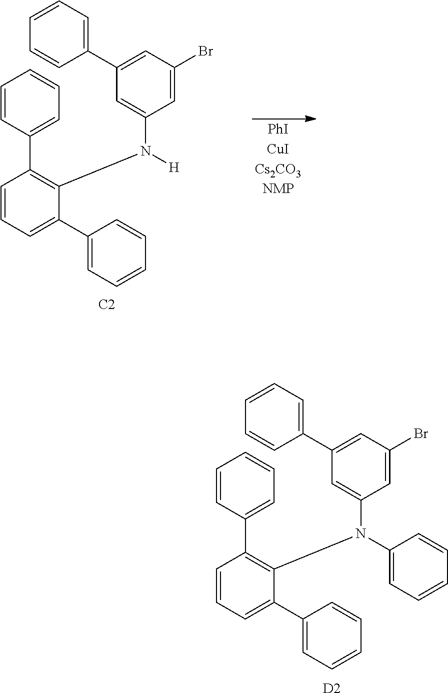

In an Ar atmosphere, Intermediate C2 (73.3 g), iodobenzene (170 g), CuI (31.1 g), and Cs₂CO₃ (107 g) were dissolved in NMP (700 mL) and heated and stirred at 190° C. for 24 hours. After the temperature was returned to room temperature, the resultant mixture was extracted with CH₂Cl₂ by adding water to obtain organic layers. The obtained organic layers were combined and dried over MgSO₄, and then the solvent was removed by distillation under reduced pressure. The resulting crude product was purified by silica gel column chromatography to obtain Intermediate D2 (43.4 g, yield 51%). The mass number of Intermediate D2 measured by FAB-MS measurement was 551.

(Synthesis of Intermediate E2)

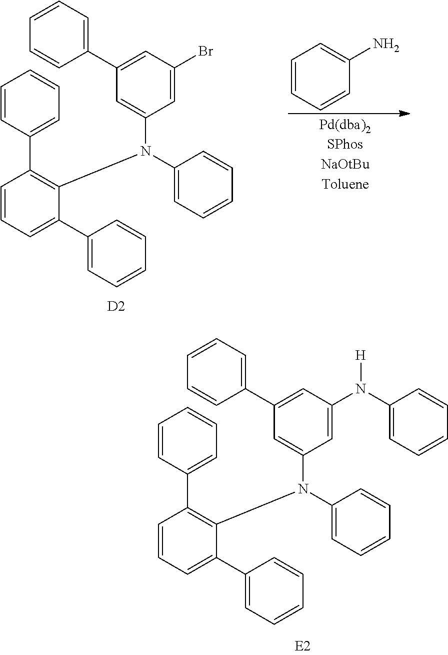

In an Ar atmosphere, Intermediate D2 (41.2 g), aniline (24.5 g), Pd(dba)₂ (3.0 g), SPhos (4.3 g), and NaOtBu (15.1 g) were dissolved in toluene (1300 mL) and heated under reflux for 6 hours. The resultant mixture was extracted with CH₂Cl₂ by adding water to obtain organic layers. The obtained organic layers were combined and dried over MgSO₄, and then the solvent was removed by distillation under reduced pressure. The resulting crude product was purified by silica gel column chromatography to obtain Intermediate E2 (34.5 g, yield 82%). The mass number of Intermediate E2 measured by FAB-MS measurement was 564.

(Synthesis of Intermediate G2)

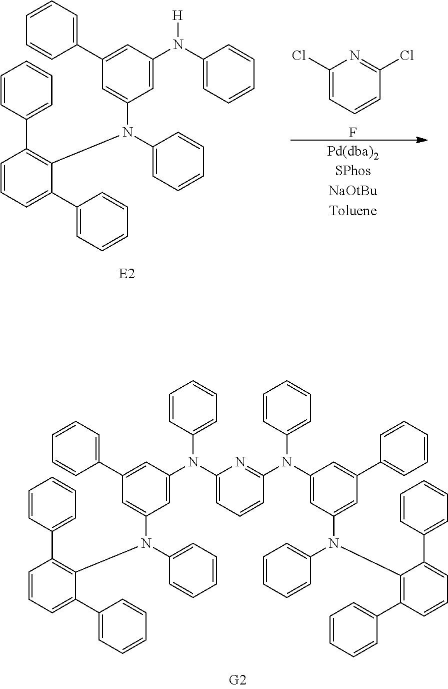

In an Ar atmosphere, Intermediate E2 (32.8 g), Intermediate F (8.3 g), Pd(dba)₂ (2.6 g), SPhos (3.7 g), and NaOtBu (13.1 g) were dissolved in toluene (1200 mL) and heated under reflux for 12 hours. The resultant mixture was extracted with CH₂Cl₂ by adding water to obtain organic layers. The obtained organic layers were combined and dried over MgSO₄, and then the solvent was removed by distillation under reduced pressure. The resulting crude product was purified by silica gel column chromatography to obtain Intermediate G2 (9.5 g, yield 27%). The mass number of Intermediate G2 measured by FAB-MS measurement was 1203.

(Synthesis of Compound 180)

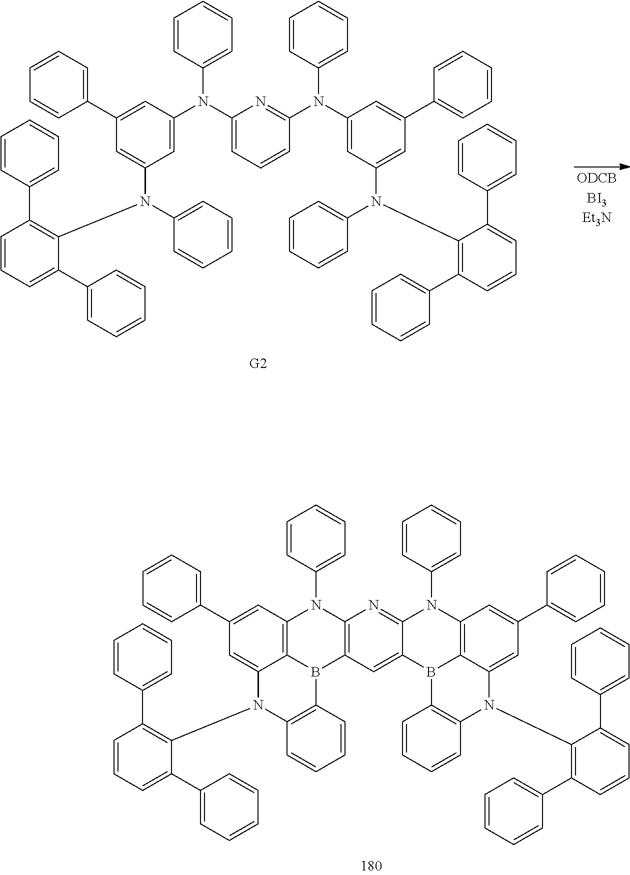 [SMILES: c1ccc(-c2cc(N(c3ccccc3)c3cccc(N(c4ccccc4)c4cc(-c5ccccc5)cc(N(c5ccccc5)c5c(-c6ccccc6)cccc5-c5ccccc5)c4)n3)cc(N(c3ccccc3)c3c(-c4ccccc4)cccc3-c3ccccc3)c2)cc1 ; c1ccc(-c2cc3c4c(c2)N(c2c(-c5ccccc5)cccc2-c2ccccc2)c2ccccc2B4c2cc4c(nc2N3c2ccccc2)N(c2ccccc2)c2cc(-c3ccccc3)cc3c2B4c2ccccc2N3c2c(-c3ccccc3)cccc2-c2ccccc2)cc1]

In an Ar atmosphere, Intermediate G2 (9.0 g) was dissolved in ODCB (130 mL) and cooled to 0° C. in an ice bath, and BI₃ (40 g) was added thereto, and then the resulting mixture was heated and stirred at 190° C. for 18 hours and then cooled to 0° C. in the ice bath, and triethylamine (25 mL) was added thereto. After the temperature was returned to room temperature, the reaction solution was filtered with a silica gel, and the residual solvent was removed by distillation under reduced pressure. The resulting crude product was purified by being recrystallized from toluene and cleaned with hexane to obtain Compound 180 (1.0 g, yield 11%). The molecular weight of Compound 180 measured by FAB-MS measurement was 1219.

(3) Synthesis of Compound 93

Fused polycyclic compound 93 according to an example may be synthesized by, for example, the reaction below.

(Synthesis of Intermediate H1)

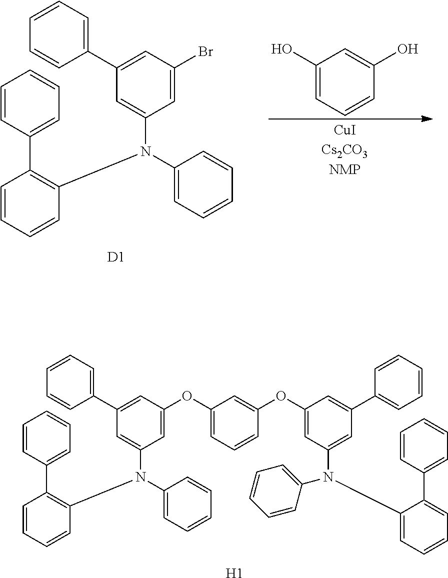 [SMILES: Brc1cc(-c2ccccc2)cc(N(c2ccccc2)c2ccccc2-c2ccccc2)c1 ; Oc1cccc(O)c1 ; "D1" ; c1ccc(-c2cc(Oc3cccc(Oc4cc(-c5ccccc5)cc(N(c5ccccc5)c5ccccc5-c5ccccc5)c4)c3)cc(N(c3ccccc3)c3ccccc3-c3ccccc3)c2)cc1 ; "H1"]

In an Ar atmosphere, Intermediate D1 (31.1 g), 1,3-benzenediol (3.6 g), CuI (12.4 g), and Cs₂CO₃ (43 g) were dissolved in NMP (300 mL) and heated and stirred at 190° C. for 24 hours. After the temperature was returned to room temperature, the resultant mixture was extracted with CH₂Cl₂ by adding water to obtain organic layers. The obtained organic layers were combined and dried over MgSO₄, and then the solvent was removed by distillation under reduced pressure. The resulting crude product was purified by silica gel column chromatography to obtain Intermediate H1 (12.1 g, yield 41%). The mass number of Intermediate H1 measured by FAB-MS measurement was 900.

(Synthesis of Compound 93)

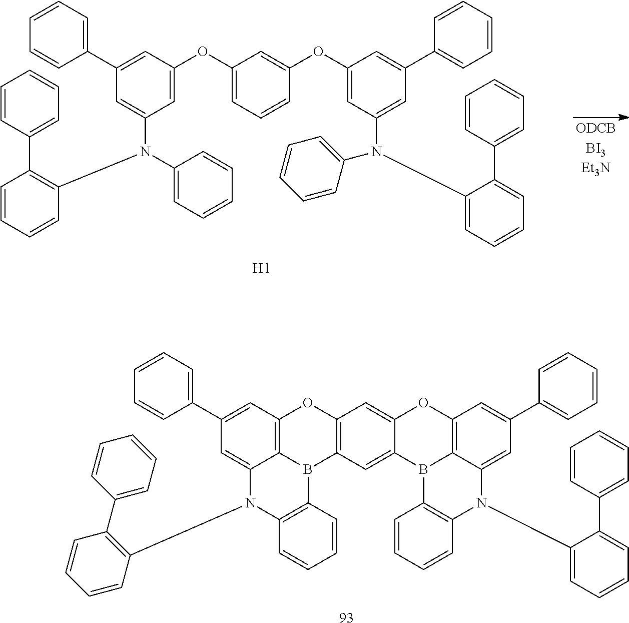 [SMILES: c1ccc(-c2cc(Oc3cccc(Oc4cc(-c5ccccc5)cc(N(c5ccccc5)c5ccccc5-c5ccccc5)c4)c3)cc(N(c3ccccc3)c3ccccc3-c3ccccc3)c2)cc1 ; "H1" ; c1ccc(-c2cc3c4c(c2)N(c2ccccc2-c2ccccc2)c2ccccc2B4c2cc4c(cc2O3)Oc2cc(-c3ccccc3)cc3c2B4c2ccccc2N3c2ccccc2-c2ccccc2)cc1 ; "93"]

In an Ar atmosphere, Intermediate H1 (11.5 g) was dissolved in ODCB (130 mL) and cooled to 0° C. in an ice bath, and BI₃ (35 g) was added thereto, and then the resulting mixture was heated and stirred at 190° C. for 18 hours and then cooled to 0° C. in the ice bath, and triethylamine (25 mL) was added thereto. After the temperature was returned to room temperature, the reaction solution was filtered with a silica gel, and the residual solvent was removed by distillation under reduced pressure. The resulting crude product was purified by being recrystallized from toluene and cleaned with hexane to obtain Compound 93 (1.9 g, yield 16%). The molecular weight of Compound 93 measured by FAB-MS measurement was 916.

(4) Synthesis of Compound 273

Fused polycyclic compound 273 according to an example may be synthesized by, for example, the reaction below.

(Synthesis of Intermediate H2)

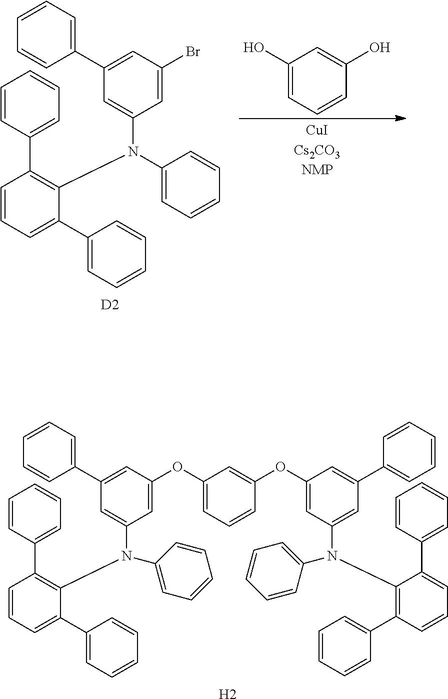

In an Ar atmosphere, Intermediate D2 (31.1 g), 1,3-benzenediol (3.6 g), CuI (12.4 g), and Cs₂CO₃ (43 g) were dissolved in NMP (300 mL) and heated and stirred at 190° C. for 24 hours. After the temperature was returned to room temperature, the resultant mixture was extracted with CH₂Cl₂ by adding water to obtain organic layers. The obtained organic layers were combined and dried over MgSO₄, and then the solvent was removed by distillation under reduced pressure. The resulting crude product was purified by silica gel column chromatography to obtain Intermediate H2 (8.6 g, yield 29%). The mass number of Intermediate H2 measured by FAB-MS measurement was 1052.

(Synthesis of Compound 273)

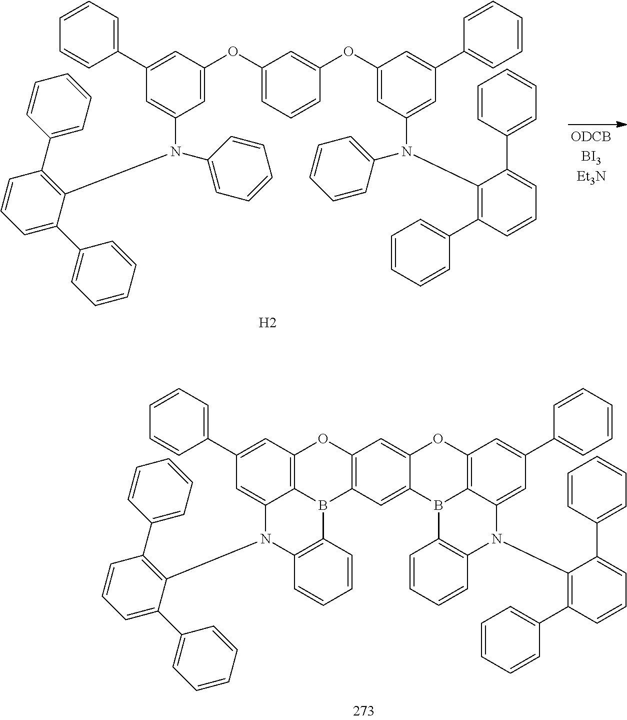 [SMILES: c1ccc(-c2cc(Oc3cccc(Oc4cc(-c5ccccc5)cc(N(c5ccccc5)c5c(-c6ccccc6)cccc5-c5ccccc5)c4)c3)cc(N(c3ccccc3)c3c(-c4ccccc4)cccc3-c3ccccc3)c2)cc1 ; "H2" ; c1ccc(-c2cc3c4c(c2)N(c2c(-c5ccccc5)cccc2-c2ccccc2)c2ccccc2B4c2cc4c(cc2O3)Oc2cc(-c3ccccc3)cc3c2B4c2ccccc2N3c2c(-c3ccccc3)cccc2-c2ccccc2)cc1]

In an Ar atmosphere, Intermediate H2 (8.2 g) was dissolved in ODCB (130 mL) and cooled to 0° C. in an ice bath, and BI₃ (35 g) was added thereto, and then the resulting mixture was heated and stirred at 190° C. for 18 hours and then cooled to 0° C. in the ice bath, and triethylamine (25 mL) was added thereto. After the temperature was returned to room temperature, the reaction solution was filtered with a silica gel, and the residual solvent was removed by distillation under reduced pressure. The resulting crude product was purified by being recrystallized from toluene and cleaned with hexane to obtain Compound 273 (1.3 g, yield 16%). The molecular weight of Compound 273 measured by FAB-MS measurement was 1068.

(5) Synthesis of Compound 106

Fused polycyclic compound 106 according to an example may be synthesized by, for example, the reaction below.

(Synthesis of Intermediate K1)

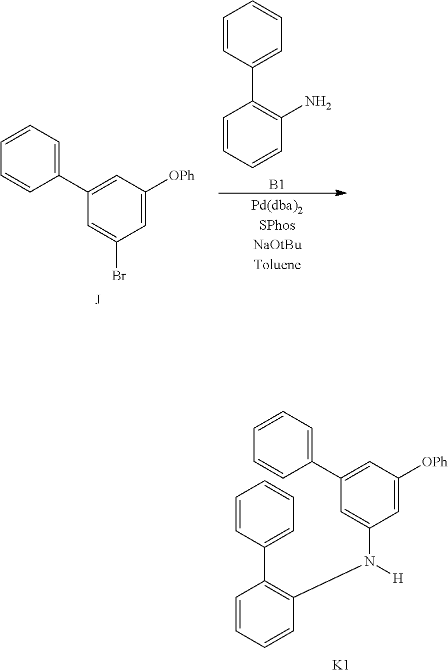

In an Ar atmosphere, Intermediate J (65 g), Intermediate B1 (33.8 g), Pd(dba)₂ (4.6 g), SPhos (6.6 g), and NaOtBu (23.5 g) were dissolved in toluene (2 L) and heated under reflux for 6 hours. After the temperature was returned to room temperature, the resultant mixture was extracted with CH₂Cl₂ by adding water to obtain organic layers. The obtained organic layers were combined and dried over MgSO₄, and then the solvent was removed by distillation under reduced pressure. The resulting crude product was purified by silica gel column chromatography to obtain Intermediate K1 (76.2 g, yield 92%). The mass number of Intermediate K1 measured by FAB-MS measurement was 413.

(Synthesis of Intermediate L1)

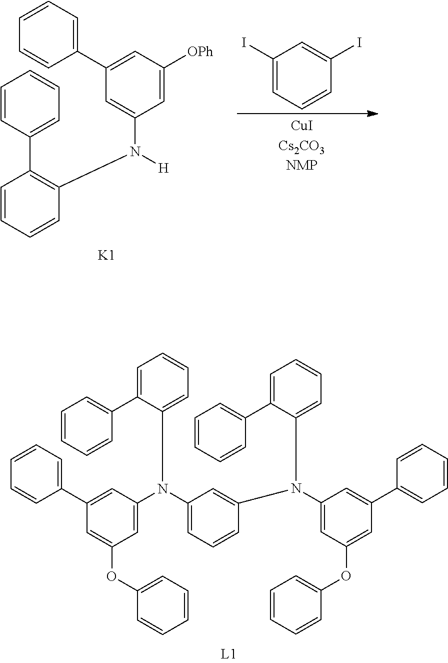 [SMILES: c1ccc(Oc2cc(Nc3ccccc3-c3ccccc3)cc(-c3ccccc3)c2)cc1 ; Ic1cccc(I)c1 ; "K1" ; c1ccc(Oc2cc(-c3ccccc3)cc(N(c3cccc(N(c4cc(Oc5ccccc5)cc(-c5ccccc5)c4)c4ccccc4-c4ccccc4)c3)c3ccccc3-c3ccccc3)c2)cc1]

In an Ar atmosphere, Intermediate K1 (72.4 g), 1,3-iodobenzene (28.8 g), CuI (33.4 g), and Cs₂CO₃ (120 g) were dissolved in NMP (750 mL) and heated and stirred at 190° C. for 36 hours. After the temperature was returned to room temperature, the resultant mixture was extracted with CH₂Cl₂ by adding water to obtain organic layers. The obtained organic layers were combined and dried over MgSO₄, and then the solvent was removed by distillation under reduced pressure. The resulting crude product was purified by silica gel column chromatography to obtain Intermediate L1 (66.1 g, yield 84%). The mass number of Intermediate L1 measured by FAB-MS measurement was 900.

(Synthesis of Compound 106)

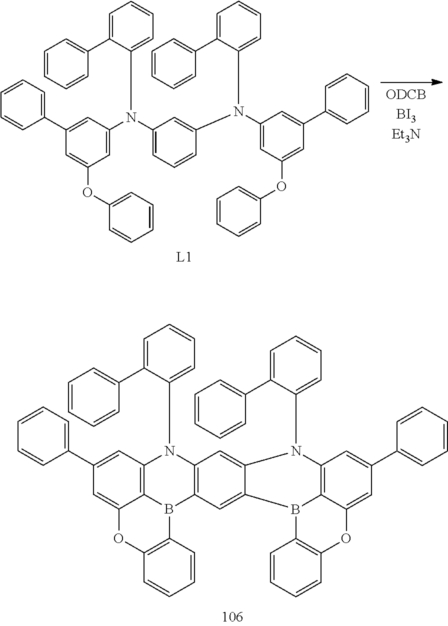 [SMILES: c1ccc(Oc2cc(-c3ccccc3)cc(N(c3cccc(N(c4cc(Oc5ccccc5)cc(-c5ccccc5)c4)c4ccccc4-c4ccccc4)c3)c3ccccc3-c3ccccc3)c2)cc1 ; c1ccc(-c2cc3c4c(c2)N(c2ccccc2-c2ccccc2)c2cc5c(cc2B4c2ccccc2O3)B2c3ccccc3Oc3cc(-c4ccccc4)cc(c32)N5c2ccccc2-c2ccccc2)cc1]

In an Ar atmosphere, Intermediate L1 (33.1 g) was dissolved in ODCB (370 mL) and cooled to 0° C. in an ice bath, and BI₃ (115 g) was added thereto, and then the resulting mixture was heated and stirred at 190° C. for 18 hours and then cooled to 0° C. in the ice bath, and triethylamine (100 mL) was added thereto. After the temperature was returned to room temperature, the reaction solution was filtered with a silica gel, and the residual solvent was removed by distillation under reduced pressure. The resulting crude product was purified by being recrystallized from toluene and cleaned with hexane to obtain Compound 106 (5.4 g, yield 16%). The molecular weight of Compound 106 measured by FAB-MS measurement was 916.

(6) Synthesis of Compound 280

Fused polycyclic compound 280 according to an example may be synthesized by, for example, the reaction below.

(Synthesis of Intermediate K2)

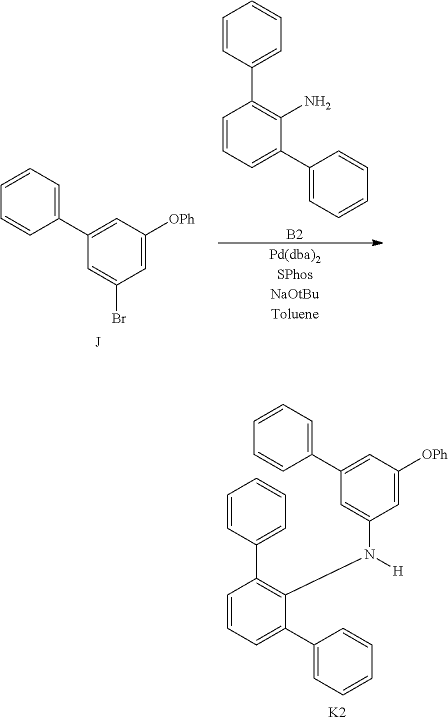

In an Ar atmosphere, Intermediate J (65 g), Intermediate B2 (49.0 g), Pd(dba)₂ (4.6 g), SPhos (6.6 g), and NaOtBu (23.5 g) were dissolved in toluene (2 L) and heated under reflux for 6 hours. After the temperature was returned to room temperature, the resultant mixture was extracted with CH₂Cl₂ by adding water to obtain organic layers. The obtained organic layers were combined and dried over MgSO₄, and then the solvent was removed by distillation under reduced pressure. The resulting crude product was purified by silica gel column chromatography to obtain Intermediate K2 (73.5 g, yield 75%). The mass number of Intermediate K2 measured by FAB-MS measurement was 489.

(Synthesis of Intermediate L2)

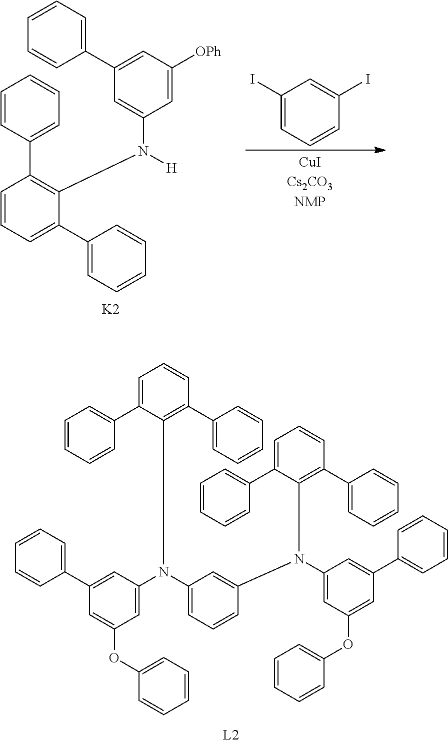

In an Ar atmosphere, Intermediate K2 (69.8 g), 1,3-iodobenzene (28.8 g), CuI (33.4 g), and Cs₂CO₃ (120 g) were dissolved in NMP (750 mL) and heated and stirred at 190° C. for 36 hours. After the temperature was returned to room temperature, the resultant mixture was extracted with CH₂Cl₂ by adding water to obtain organic layers. The obtained organic layers were combined and dried over MgSO₄, and then the solvent was removed by distillation under reduced pressure. The resulting crude product was purified by silica gel column chromatography to obtain Intermediate L2 (53.3 g, yield 71%). The mass number of Intermediate L2 measured by FAB-MS measurement was 1052.

(Synthesis of Compound 280)

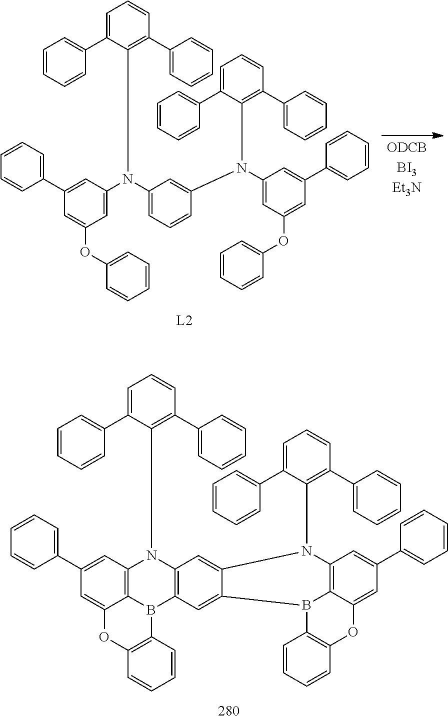 [SMILES: c1ccc(Oc2cc(-c3ccccc3)cc(N(c3cccc(N(c4cc(Oc5ccccc5)cc(-c5ccccc5)c4)c4c(-c5ccccc5)cccc4-c4ccccc4)c3)c3c(-c4ccccc4)cccc3-c3ccccc3)c2)cc1 ; c1ccc(-c2cc3c4c(c2)N(c2c(-c5ccccc5)cccc2-c2ccccc2)c2cc5c(cc2B4c2ccccc2O3)B2c3ccccc3Oc3cc(-c4ccccc4)cc(c32)N5c2c(-c3ccccc3)cccc2-c2ccccc2)cc1]

In an Ar atmosphere, Intermediate L2 (26.6 g) was dissolved in ODCB (370 mL) and cooled to 0° C. in an ice bath, and BI₃ (115 g) was added thereto, and then the resulting mixture was heated and stirred at 190° C. for 18 hours and then cooled to 0° C. in the ice bath, and triethylamine (100 mL) was added thereto. After the temperature was returned to room temperature, the reaction solution was filtered with a silica gel, and the residual solvent was removed by distillation under reduced pressure. The resulting crude product was purified by being recrystallized from toluene and cleaned with hexane to obtain Compound 280 (3.0 g, yield 11%). The molecular weight of Compound 280 measured by FAB-MS measurement was 1068.

(7) Synthesis of Compound 291

Fused polycyclic compound 291 according to an example may be synthesized by, for example, the reaction below.

(Synthesis of Intermediate M2)

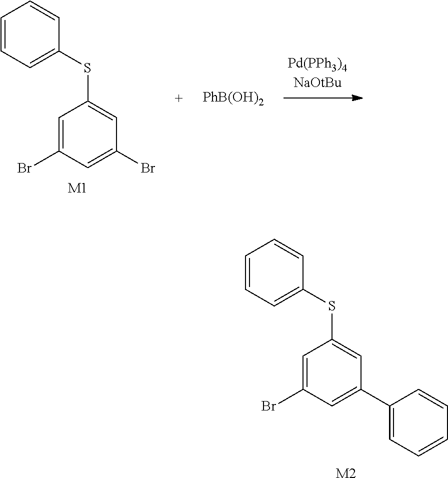

Intermediate M2 was synthesized with reference to the patent document (CN105418485 A). In an Ar atmosphere, Intermediate M1 (103 g), PhB(OH)₂ (48.8 g), Pd(PPh₃)₄ (1.1 g), and NaOtBu (38.4 g) were added in a 2000 mL three-neck flask and dissolved in a mixed solvent of toluene/H₂O (1000 mL/100 mL), and then the resultant mixture was heated under reflux for 5 hours. After the temperature was returned to room temperature, the resultant mixture was extracted with CH₂Cl₂ by adding water to obtain organic layers. The obtained organic layers were combined and dried over MgSO₄, and then the solvent was removed by distillation under reduced pressure. The resulting crude product was purified by silica gel column chromatography to obtain Intermediate M2 (74.6 g, yield 73%). The mass number of Intermediate M2 measured by FAB-MS measurement was 340.

(Synthesis of Intermediate M4)

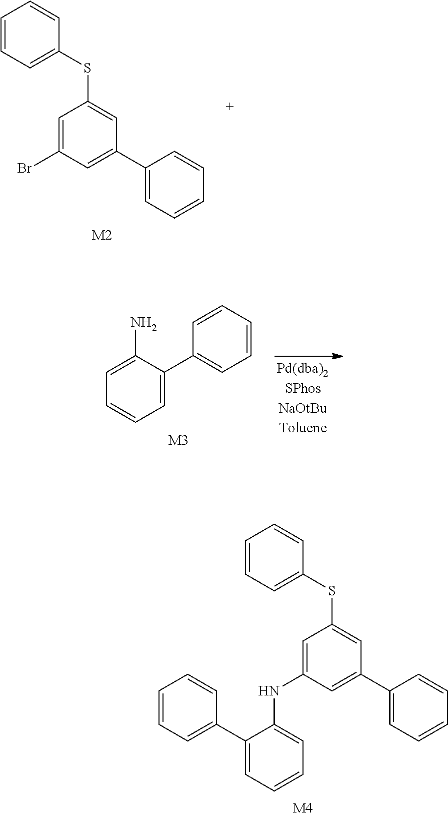

In an Ar atmosphere, Intermediate M2 (34.1 g), Intermediate M3 (17.0 g), Pd(dba)₂ (2.12 g), SPhos (1.56 g), and NaOtBu (110 g) were added in a 2000 mL three-neck flask and dissolved in 1000 mL of toluene and heated under reflux for 6 hours. After the temperature was returned to room temperature, the resultant mixture was extracted with CH₂Cl₂ by adding water to obtain organic layers. The obtained organic layers were combined and dried over MgSO₄, and then the solvent was removed by distillation under reduced pressure. The resulting crude product was purified by silica gel column chromatography to obtain Intermediate M4 (31.8 g, yield 74%). The mass number of Intermediate M4 measured by FAB-MS measurement was 429.

(Synthesis of Intermediate M8)

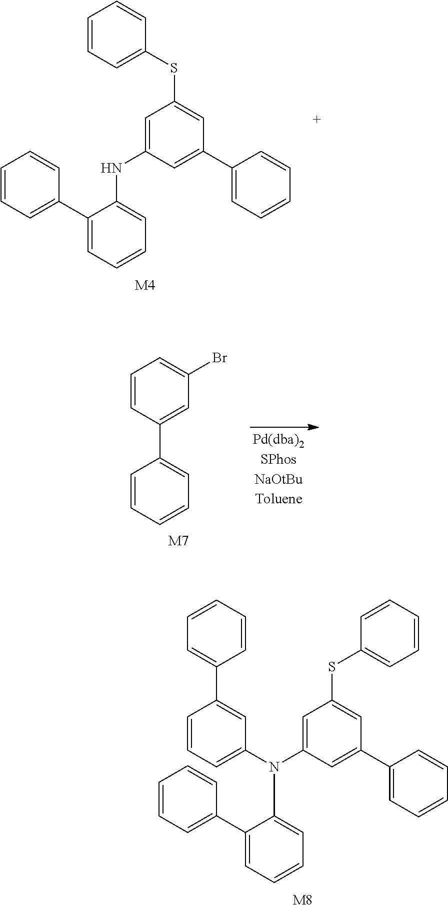

In an Ar atmosphere, Intermediate M4 (21.5 g), Intermediate M7 (12.5 g), Pd(dba)₂ (1.0 g), SPhos (0.78 g), and NaOtBu (48 g) were added in a 2000 mL three-neck flask and dissolved in 700 mL of toluene and heated under reflux 8 hours. After the temperature was returned to room temperature, the resultant mixture was extracted with CH₂Cl₂ by adding water to obtain organic layers. The obtained organic layers were combined and dried over MgSO₄, and then the solvent was removed by distillation under reduced pressure. The resulting crude product was purified by silica gel column chromatography to obtain Intermediate M8 (20.1 g, yield 69%). The mass number of Intermediate M8 measured by FAB-MS measurement was 581.

(Synthesis of Compound 291)

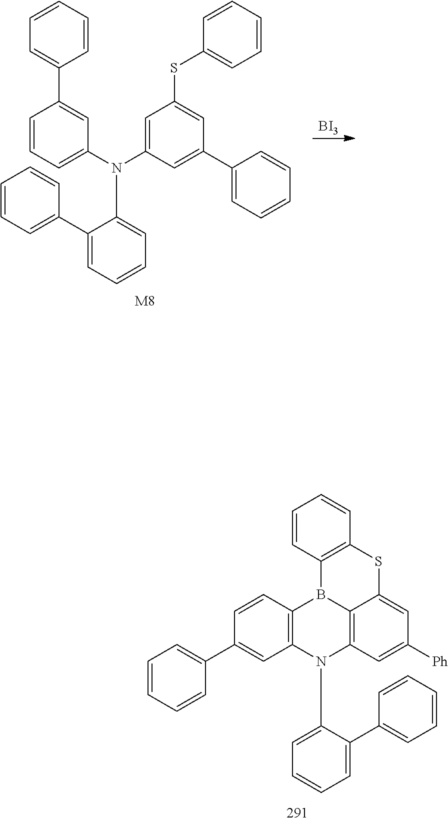

In an Ar atmosphere, Intermediate M8 (20.1 g) was dissolved in ODCB (270 mL) and cooled to 0° C. in an ice bath, and BI₃ (55 g) was added thereto, and then the resulting mixture was heated and stirred at 190° C. for 36 hours and then cooled to 0° C. in the ice bath, and triethylamine (70 mL) was added thereto. After the temperature was returned to room temperature, the reaction solution was filtered with a silica gel, and the residual solvent was removed by distillation under reduced pressure. The resulting crude product was purified by being recrystallized from toluene and cleaned with hexane to obtain Compound 291 (1.5 g, yield 7%). The mass number of Compound 291 measured by FAB-MS measurement was 589.

(8) Synthesis of Compound 293

Fused polycyclic compound 293 according to an example may be synthesized by, for example, the reaction below.

(Synthesis of Intermediate M6)

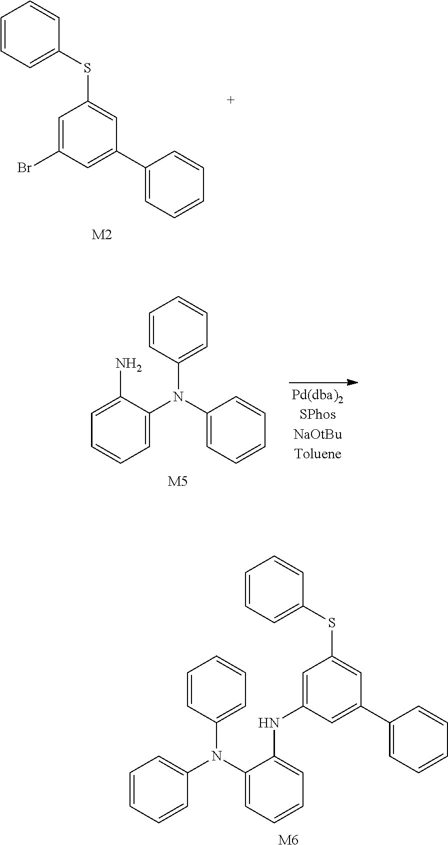

In an Ar atmosphere, Intermediate M2 (34.1 g), Intermediate M5 (26.2 g), Pd(dba)₂ (2.12 g), SPhos (1.56 g), and NaOtBu (110 g) were added in a 2000 mL three-neck flask and dissolved in 1000 mL of toluene and heated under reflux for 6 hours. After the temperature was returned to room temperature, the resultant mixture was extracted with CH₂Cl₂ by adding water to obtain organic layers. The obtained organic layers were combined and dried over MgSO₄, and then the solvent was removed by distillation under reduced pressure. The resulting crude product was purified by silica gel column chromatography to obtain Intermediate M6 (41.1 g, yield 79%). The mass number of Intermediate M6 measured by FAB-MS measurement was 520.

(Synthesis of Intermediate M9)

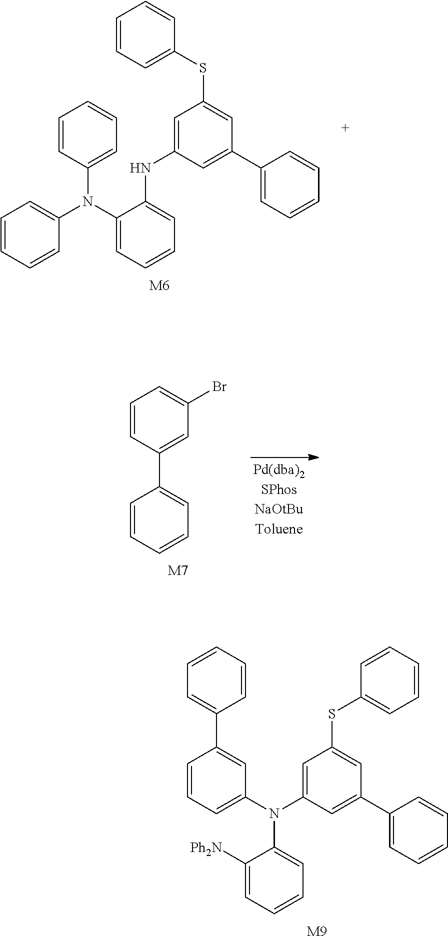

In an Ar atmosphere, Intermediate M6 (26.1 g), Intermediate M7 (12.5 g), Pd(dba)₂ (1.0 g), SPhos (0.78 g), and NaOtBu (48 g) were added in a 2000 mL three-neck flask and dissolved in 700 mL of toluene and heated under reflux for 8 hours. After the temperature was returned to room temperature, the resultant mixture was extracted with CH₂Cl₂ by adding water to obtain organic layers. The obtained organic layers were combined and dried over MgSO₄, and then the solvent was removed by distillation under reduced pressure. The resulting crude product was purified by silica gel column chromatography to obtain Intermediate M8 (22.9 g, yield 68%). The mass number of Intermediate M9 measured by FAB-MS measurement was 672.

(Synthesis of Compound 293)

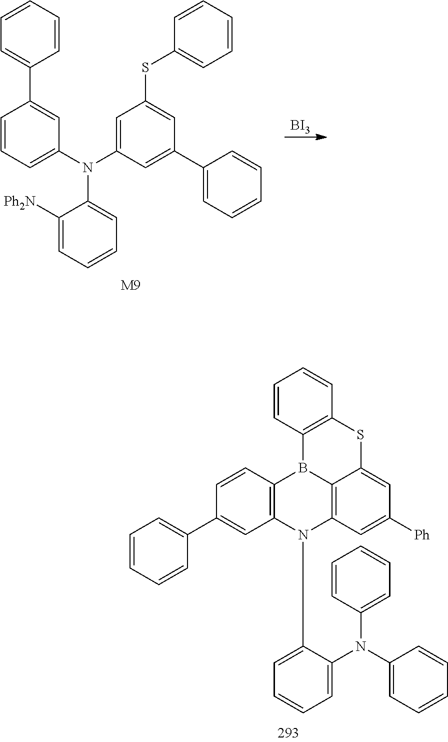

In an Ar atmosphere, Intermediate M9 (22.9 g) was dissolved in ODCB (270 mL) and cooled to 0° C. in an ice bath, and BI₃ (53.3 g) was added thereto, and then the resulting mixture was heated and stirred at 190° C. for 36 hours and then cooled to 0° C. in the ice bath, and triethylamine (70 mL) was added thereto. After the temperature was returned to room temperature, the reaction solution was filtered with a silica gel, and the residual solvent was removed by distillation under reduced pressure. The resulting crude product was purified by being recrystallized from toluene and cleaned with hexane to obtain Compound 293 (2.1 g, yield 9%). The molecular weight of Compound 293 measured by FAB-MS measurement was 681.

2. Manufacture and Evaluation of Light Emitting Device Including Fused Polycyclic Compound

(Manufacture of Light Emitting Device)

Compounds 179, 180, 93, 273, 106, 280, 291, and 293 as described above were used as a dopant material of the emission layer to manufacture the light emitting devices of Examples 1 to 8, respectively.

### Example Compounds

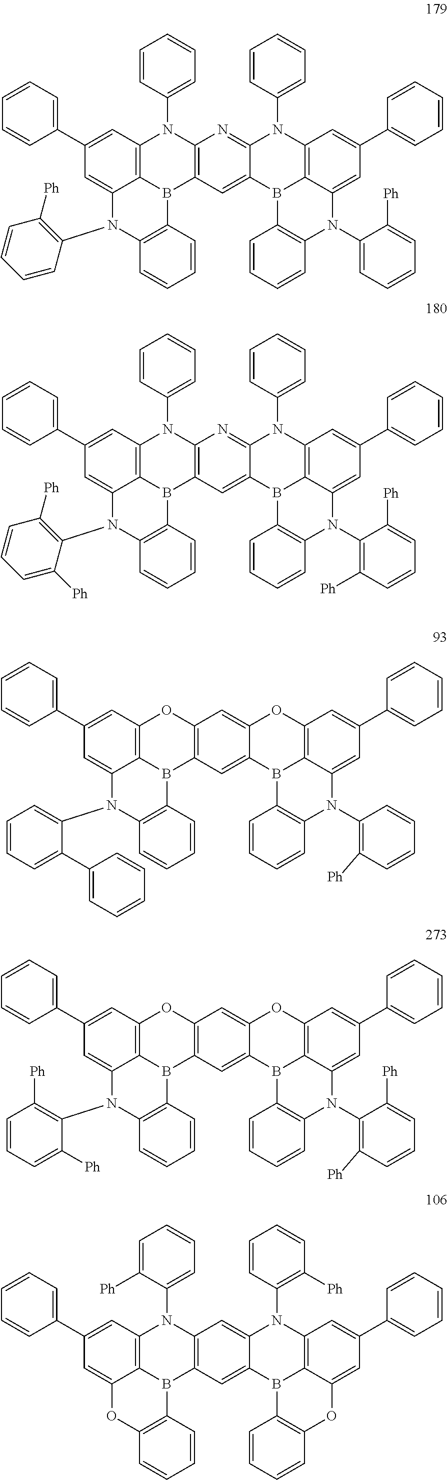

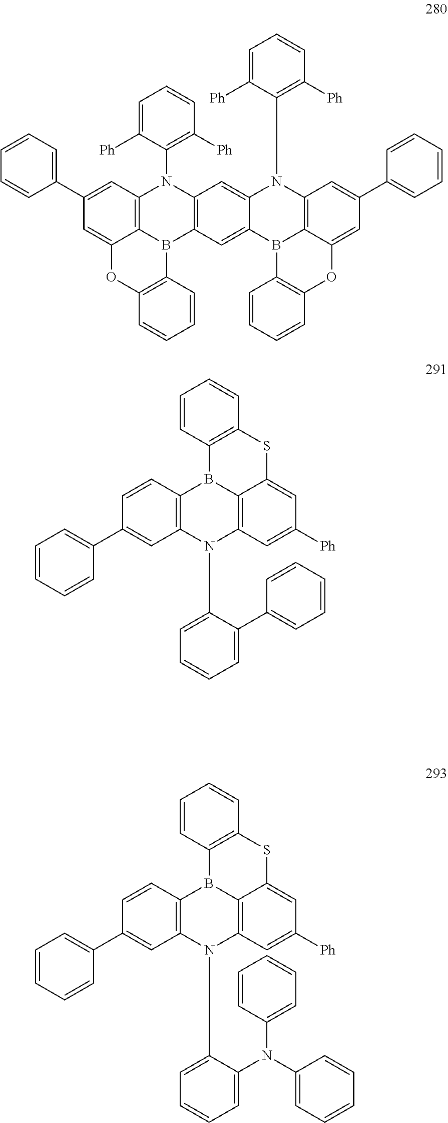 [SMILES: c1ccc(-c2cc3c4c(c2)N(c2c(-c5ccccc5)cccc2-c2ccccc2)c2cc5c(cc2B4c2ccccc2O3)B2c3ccccc3Oc3cc(-c4ccccc4)cc(c32)N5c2c(-c3ccccc3)cccc2-c2ccccc2)cc1 ; c1ccc(-c2ccc3c(c2)N(Cc2ccccc2-c2ccccc2)c2cc(-c4ccccc4)cc4c2B3c2ccccc2S4)cc1 ; c1ccc(-c2ccc3c(c2)N(Cc2ccccc2N(c2ccccc2)c2ccccc2)c2cc(-c4ccccc4)cc4c2B3c2ccccc2S4)cc1]

Comparative Example Compounds X-1 to X-4 below were used to manufacture devices of Comparative Examples 1 to 4, respectively.

### Comparative Example Compounds

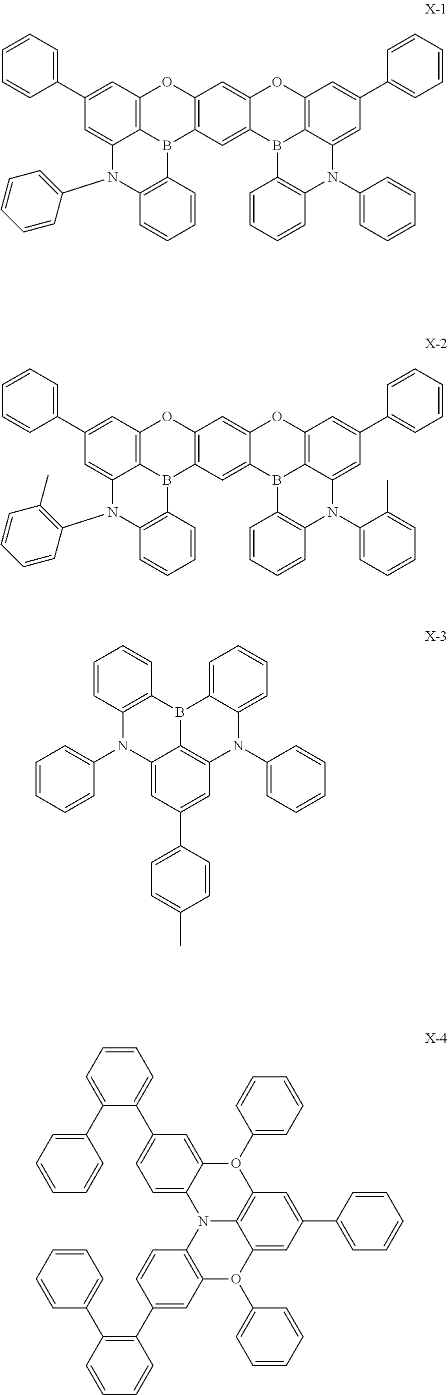

The light emitting device of an example including the fused polycyclic compound of an example in an emission layer was manufactured as follows. Examples 1 to 8 correspond to the light emitting devices manufactured by using Compounds 179, 180, 93, 273, 106, 280, 291, and 293 as described above as a luminescent material, respectively. Comparative Examples 1 to 4 correspond to the light emitting devices manufactured by using Comparative Example Compounds X-1 to X-4 as a luminescent material, respectively.

ITO was used to form a 150 nm-thick first electrode, dipyrazino[2,3-f: 2′,3′-h] quinoxaline-2,3,6,7,10,11-hexacarbonitrile (HATCN) was used to form a 10 nm-thick hole injection layer on the first electrode, N,N-di(1-naphthyl)-N,N′-diphenyl-(1,1′-biphenyl)-4,4′-diamine (NPD) was used to form a 80 nm-thick hole transport layer on the hole injection layer, 1,3-bis(N-carbazolyl)benzene (mCP) was used to form a 5 nm-thick emission auxiliary layer on the hole transport layer, Example Compound or Comparative Example Compound was doped by 1% to 3,3′-di(9H-carbazol-9-yl)-1,1′-biphenyl (mCBP) to form a 20 nm-thick emission layer on the emission auxiliary layer, 2,2′,2″-(1,3,5-benzinetriyl)-tris(1-phenyl-1-H-benzimidazole) (TPBi) was used to form a 30 nm-thick electron transport layer on the emission layer, LiF was used to form a 0.5 nm-thick electron injection layer on the electron transport layer, and Al was used to form a 300 nm-thick second electrode on the electron injection layer. Each layer was formed by a deposition method in a vacuum atmosphere.

Compounds used for manufacturing the light emitting devices of Examples and Comparative Examples are disclosed below. The compounds below are known materials, and commercial products were subjected to sublimation purification and used to manufacture the devices.

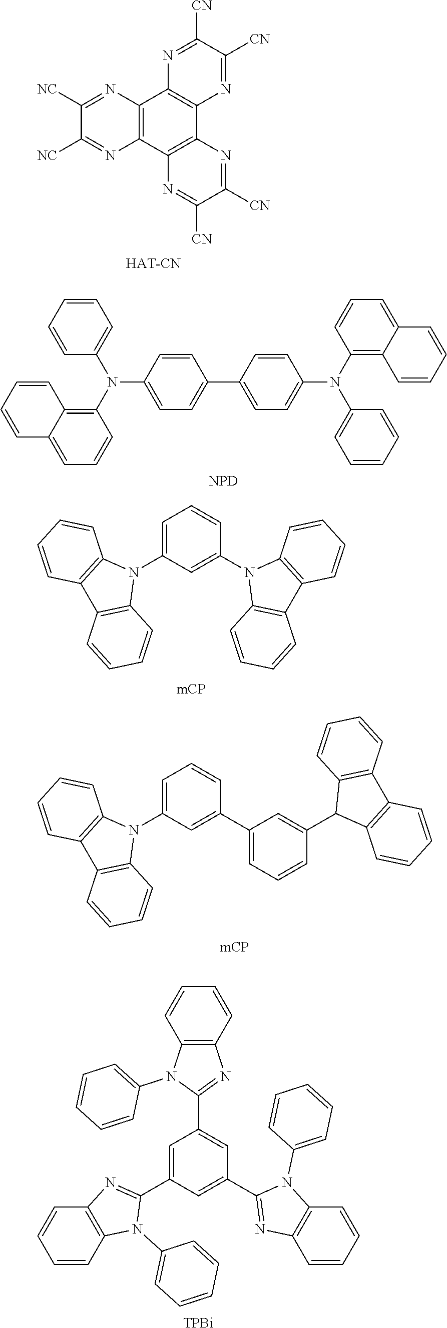

### Experimental Example

Efficiencies of the devices manufactured with Experimental Example Compounds 179, 180, 93, 273, 106, 280, 291, and 293, and Comparative Example Compounds X-1 to X-4 as described above were evaluated. The evaluation results are shown in Table 1 below. In the evaluation of the device, luminous efficiencies and device service lives of the light emitting devices were measured at a current density of 10 mA/cm² and listed.

TABLE 1

| Device | | Device service | EQE1000 |
|---|---|---|---|
| manufacturing | | life | nit |
| examples | Dopant | LT₅₀(h) | (%) |
| Example 1 | Example Compound 179 | 1.9 | 8 |
| Example 2 | Example Compound 180 | 2.2 | 10 |
| Example 3 | Example Compound 93 | 2.1 | 6 |
| Example 4 | Example Compound 273 | 2.7 | 8 |
| Example 5 | Example Compound 106 | 1.1 | 7 |
| Example 6 | Example Compound 280 | 1.4 | 9 |
| Example 7 | Example Compound 291 | 0.9 | 4 |
| Example 8 | Example Compound 293 | 0.9 | 4 |
| Comparative | Comparative Example | 0.7 | 3 |
| Example 1 | Compound X-1 | | |
| Comparative | Comparative Example | 0.8 | 3 |
| Example 2 | Compound X-2 | | |
| Comparative | Comparative Example | 0.7 | 2 |
| Example 3 | Compound X-3 | | |
| Comparative | Comparative Example | 0.3 | 2 |
| Example 4 | Compound X-4 | | |

Referring to the results of Table 1, it may be confirmed that Examples of the light emitting devices in which the fused polycyclic compounds are used as a luminescent material have improved luminous efficiencies and device service lives compared to Comparative Examples. Example Compounds have a wide planar skeleton structure having at least one boron atom and at least two heteroatoms at the center thereof to form an expanded conjugation structure, thereby stabilizing the structure of the polycyclic aromatic ring and enhancing multiple resonance effects to facilitate reverse intersystem crossing. Accordingly, when the compounds of Examples are used as thermally activated delayed fluorescence dopants, a half-width and wavelength range are suitable for a blue luminescent material and the luminous efficiency is improved. In addition, Example Compounds have a structure in which the steric hindrance substituent is linked to the fused cyclic core, thus may effectively protect the boron from water molecules and oxygen molecules in the molecular structure in an excited state, and thus the stability of materials may be increased, thereby improving device service lives and the quenching phenomenon may be inhibited by oxygen, thereby enhancing the luminous efficiencies. Moreover, Example Compounds have a relatively more twisted structural shape than Comparative Example Compounds due to the steric hindrance substituent, and thus a non-radiative transition due to intermoclecular interaction may be prevented, thereby further enhancing the luminous efficiencies. The light emitting device of an example includes the fused polycyclic compound of an example as a dopant of a thermally activated delayed fluorescence (TADF) light emitting device, and thus may achieve high device efficiency in a blue wavelength region, particularly, a deep blue wavelength region.

It may be confirmed that Comparative Example Compounds X-1 and X-2 contained in Comparative Examples 1 and 2, respectively, include a wide planar skeleton structure having two boron atoms at the center thereof, but do not include a steric hindrance substituent in the planar skeleton, and thus the luminous efficiencies and service lives of Comparative Examples 1 and 2 are reduced compared to Examples. It is believed that Comparative Example Compounds X-1 and X-2 have a structure in which a hydrogen atom or a methyl group is substituted at the ortho position of a phenyl group linked to the nitrogen atom linking a fused ring, but the hydrogen atom or the methyl group has insufficient steric hindrance effects, and thus the luminous efficiencies and service lives of Comparative Examples 1 and 2 are reduced compared to using Example Compounds.

It may be confirmed that Comparative Example Compound X-3 contained in Comparative Example 3 includes a planar skeleton having one boron atom at the center thereof, but does not include a steric hindrance substituent in the planar skeleton, and thus the luminous efficiency and service life of Comparative Example 3 are reduced compared to Examples.

It is believed that Comparative Example Compound X-4 contained in Comparative Example 4 includes a planar skeleton containing one nitrogen atom and two oxygen atoms, but does not include a boron atom, and thus the multiple resonance effects is not efficiently exhibited, and the luminous efficiency and service life of Comparative Example 4 are reduced compared to using Example Compounds.

The light emitting device of an embodiment may exhibit improved device characteristics with high efficiency and a long service life.

The fused polycyclic compound of an embodiment may be included in an emission layer of the light emitting device to contribute to high efficiency and a long service life of the organic electroluminescence device.

It should be understood that the embodiments of the invention are not limited to the ones discloses herein, and that various changes and modifications may be made by those skilled in the art without departing from the spirit and scope of the inventive concept.

Accordingly, the technical scope of the inventive concept is not intended to be limited to the contents set forth in the detailed description of the specification, but is intended to be defined by the appended claims.

What is claimed is:

1. A fused polycyclic compound represented by Formula 1: 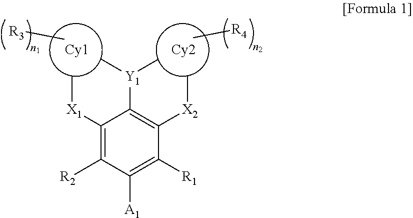
wherein in Formula 1,
Y₁ is P, B, or N,
X₁ and X₂ are each independently O, S, CR₅R₆, PR₇, SiR₈R₉, NR₁₀, or BR₁₁, or are represented by Formula 2,
Cy1 and Cy2 are each independently a substituted or unsubstituted monocyclic aromatic hydrocarbon ring having 6 to 30 ring-forming carbon atoms, or a substituted or unsubstituted monocyclic aromatic heterocycle having 2 to 30 ring-forming carbon atoms,
A₁ is a hydrogen atom, a deuterium atom, a substituted or unsubstituted amine group, a substituted or unsubstituted oxy group, a substituted or unsubstituted silyl group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or is represented by Formula 3,
R₁, R₂, and R₅ to R₁₁ are each independently a hydrogen atom, a deuterium atom, a halogen atom, a cyano group, a nitro group, a substituted or unsubstituted amine group, a substituted or unsubstituted silyl group, a substituted or unsubstituted boron group, a substituted or unsubstituted oxy group, a substituted or unsubstituted thio group, a substituted or unsubstituted phosphine group, a substituted or unsubstituted alkyl group having 1 to 30 carbon atoms, a substituted or unsubstituted alkenyl group having 2 to 30 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring,
R₃ and R₄ are each independently a hydrogen atom, a deuterium atom, a halogen atom, a cyano group, a nitro group, a substituted or unsubstituted amine group, a substituted or unsubstituted silyl group, a substituted or unsubstituted boron group, a substituted or unsubstituted oxy group, a substituted or unsubstituted thio group, a substituted or unsubstituted phosphine group, a substituted or unsubstituted alkyl group having 1 to 30 carbon atoms, a substituted or unsubstituted alkenyl group having 2 to 30 carbon atoms, a substituted or unsubstituted aryl group having 6 to 60 ring-forming carbon atoms, or a substituted or unsubstituted heteroaryl group having 2 to 60 ring-forming carbon atoms, or are represented by Formula 3, or are bonded to an adjacent group to form a ring,
at least one of X₁ or X₂ is represented by Formula 2, or at least one of A₁, R₃, or R₄ is represented by Formula 3, or at least one of X₁ or X₂ is represented by Formula 2, and at least one of A₁, R₃, or R₄ is represented by Formula 3,
when each of R₃ and R₄ is bonded to an adjacent group to form a ring, the formed ring does not include Si as a ring-forming atom,
when neither R₃ nor R₄ is bonded to an adjacent group to form a ring, at least one of X₁ or X₂ is S, and
n₁ and n₂ are each independently an integer of 0 to 4, and 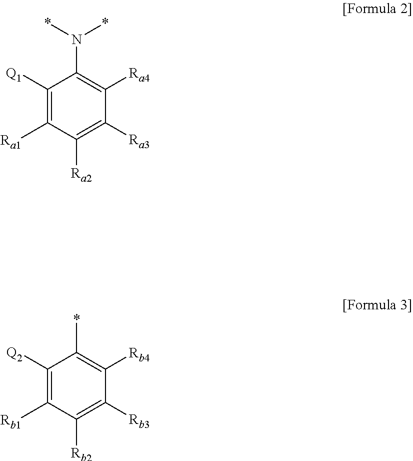
wherein in Formula 2 and Formula 3,
Q₁ and Q₂ are each independently a substituted or unsubstituted arylamine group, a substituted or unsubstituted arylsilyl group, a substituted or unsubstituted arylthio group, a substituted or unsubstituted aryloxy group, a substituted or unsubstituted alkyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and
Rₐ₁ to Rₐ₄ and R_{b1} to R_{b4} are each independently a hydrogen atom, a deuterium atom, a halogen atom, a cyano group, a nitro group, a substituted or unsubstituted amine group, a substituted or unsubstituted silyl group, a substituted or unsubstituted boron group, a substituted or unsubstituted oxy group, a substituted or unsubstituted thio group, a substituted or unsubstituted phosphine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

2. The fused polycyclic compound of claim 1, wherein when at least one of X₁ or X₂ is represented by Formula 2, the at least one of X₁ or X₂ represented by Formula 2 is represented by Formula 2-1 or Formula 2-2: 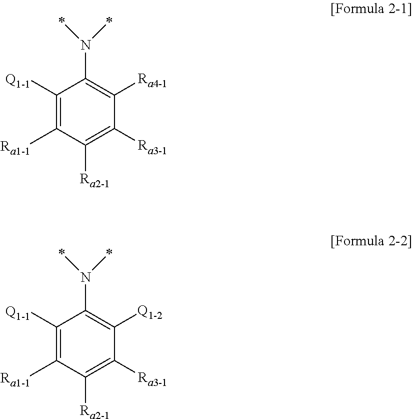
wherein in Formula 2-1 and Formula 2-2,
Q₁₋₁ and Q₁₋₂ are each independently a substituted or unsubstituted arylamine group, a substituted or unsubstituted arylsilyl group, a substituted or unsubstituted arylthio group, a substituted or unsubstituted aryloxy group, a substituted or unsubstituted alkyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and
Rₐ₁₋₁ to Rₐ₄₋₁ are each independently a hydrogen atom, a deuterium atom, a substituted or unsubstituted alkyl group having 1 to 20 carbon atoms, or a substituted or unsubstituted aryl group having 6 to 30 ring-forming carbon atoms.

3. The fused polycyclic compound of claim 1, wherein when A₁ is represented by Formula 3, A₁ is represented by one of Formula 3-1 to 3-5: 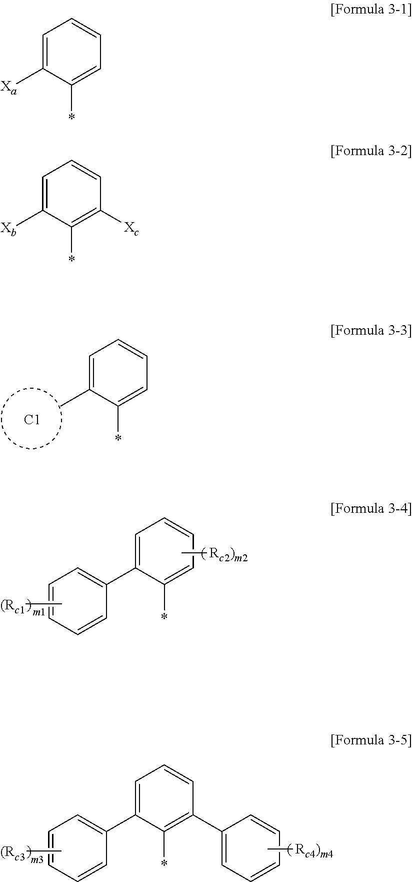
wherein in Formula 3-1 to Formula 3-5,
Xₐ to X_{c} are each independently NR_{c5}R_{c6}, SR_{c7}, OR_{c8}, SiR_{c9}R_{c10}R_{c11}, or a substituted or unsubstituted alkyl group having 2 to 10 carbon atoms,
C1 is a substituted or unsubstituted cycloalkyl group having 3 to 10 carbon atoms,
R_{c1} to R_{c4} are each independently a hydrogen atom, a deuterium atom, a halogen atom, a substituted or unsubstituted alkyl group having 1 to 20 carbon group, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring,
R_{c5} to R_{c11} are each independently a substituted or unsubstituted phenyl group,
m1, m3 and m4 are each independently an integer of 0 to 5, and
m2 is an integer of 0 to 4.

4. The fused polycyclic compound of claim 1, wherein the fused polycyclic compound represented by Formula 1 is represented by Formula 1-1: 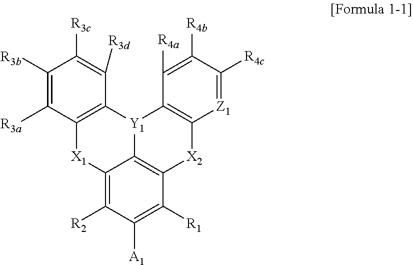
wherein in Formula 1-1,
Z₁ is CR_{4d} or N,
R₃ₐ to R_{3d}, and R₄ₐ to R_{4d} are each independently a hydrogen atom, a deuterium atom, a halogen atom, a cyano group, a nitro group, a substituted or unsubstituted amine group, a substituted or unsubstituted silyl group, a substituted or unsubstituted boron group, a substituted or unsubstituted oxy group, a substituted or unsubstituted thio group, a substituted or unsubstituted phosphine group, a substituted or unsubstituted alkyl group having 1 to 30 carbon atoms, a substituted or unsubstituted alkenyl group having 2 to 30 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring,
at least one of X₁ or X₂ is represented by Formula 2, or at least one among A₁, R₃ₐ to R_{3d} and R₄ₐ to R_{4c} is represented by Formula 3, or at least one of X₁ or X₂ is represented by Formula 2, and at least one among A₁, R₃ₐ to R_{3d} and R₄ₐ to R_{4c} is represented by Formula 3,
when each of R₃ₐ to R_{3d} and R₄ₐ to R_{4c} is bonded to an adjacent group to form a ring, the formed ring does not include Si as a ring-forming atom,
when none of R₃ₐ to R_{3d} and R₄ₐ to R_{4c} is bonded to an adjacent group to form a ring, at least one of X₁ or X₂ is S, and
X₁, X₂, Y₁, A₁, R₁, and R₂ are the same as defined in Formula 1.

5. The fused polycyclic compound of claim 4, wherein the fused polycyclic compound represented by Formula 1-1 is represented by Formula 1-2: 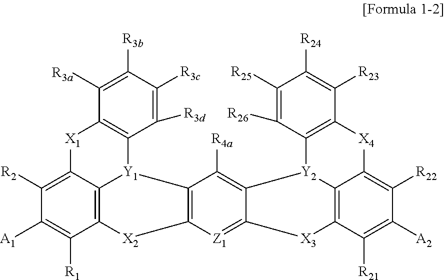
wherein in Formula 1-2,
Y₂ is P, B, or N,
X₃ and X₄ are each independently O, S, CR₂₇R₂₈, PR₂₉, NR₃₀, or BR₃₁, or are represented by Formula 2,
A₂ is a hydrogen atom, a deuterium atom, a substituted or unsubstituted amine group, a substituted or unsubstituted oxy group, a substituted or unsubstituted silyl group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or is represented by Formula 3,
R₂₁ and R₃₁ are each independently a hydrogen atom, a deuterium atom, a halogen atom, a cyano group, a nitro group, a substituted or unsubstituted amine group, a substituted or unsubstituted silyl group, a substituted or unsubstituted boron group, a substituted or unsubstituted oxy group, a substituted or unsubstituted thio group, a substituted or unsubstituted phosphine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring, and
X₁, X₂, Y₁, Z₁, A₁, R₁, R₂, R₃ₐ to R_{3d}, and R₄ₐ are the same as defined in Formula 1 and Formula 1-1.

6. The fused polycyclic compound of claim 5, wherein A₁ and A₂ are each independently a substituted or unsubstituted alkyl group having 1 to 10 carbon atoms, or are represented by Formula 3 or one of Formula 4-1 to Formula 4-5: 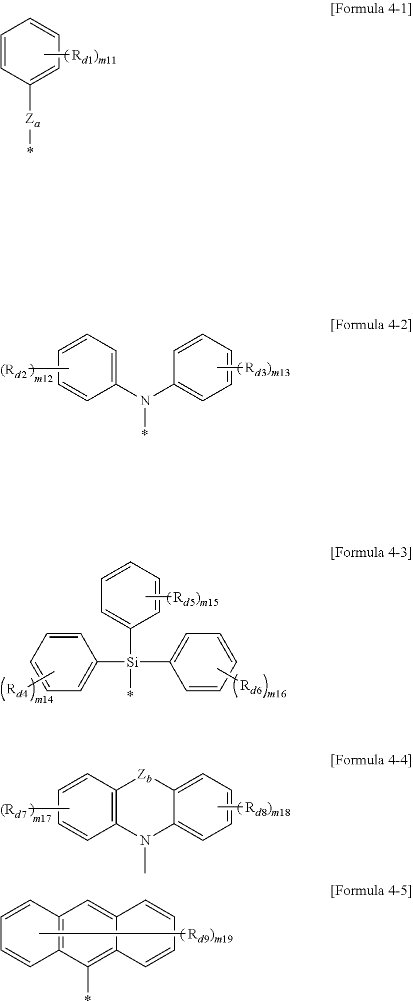
wherein in Formula 4-1 to Formula 4-5,
Zₐ is a direct linkage or O,
Z_{b} is a direct linkage, CR_{d10}R_{d11}, or SiR_{d12}R_{d13},
R_{d1} is a hydrogen atom, a deuterium atom, a halogen atom, a nitro group, a substituted or unsubstituted alkyl group having 1 to 10 carbon atoms, a substituted or unsubstituted silyl group, or a substituted or unsubstituted phenyl group,
R_{d2} to R_{d13} are each independently a hydrogen atom, a deuterium atom, a halogen atom, a substituted or unsubstituted alkyl group having 1 to 20 carbon group, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring,
m11 to m16 are each independently an integer of 0 to 5,
m17 and m18 are each independently an integer of 0 to 4, and
m19 is an integer of 0 to 9.

7. The fused polycyclic compound of claim 5, wherein the fused polycyclic compound represented by Formula 1-2 is represented by one of Formula 5-1 to Formula 5-10: 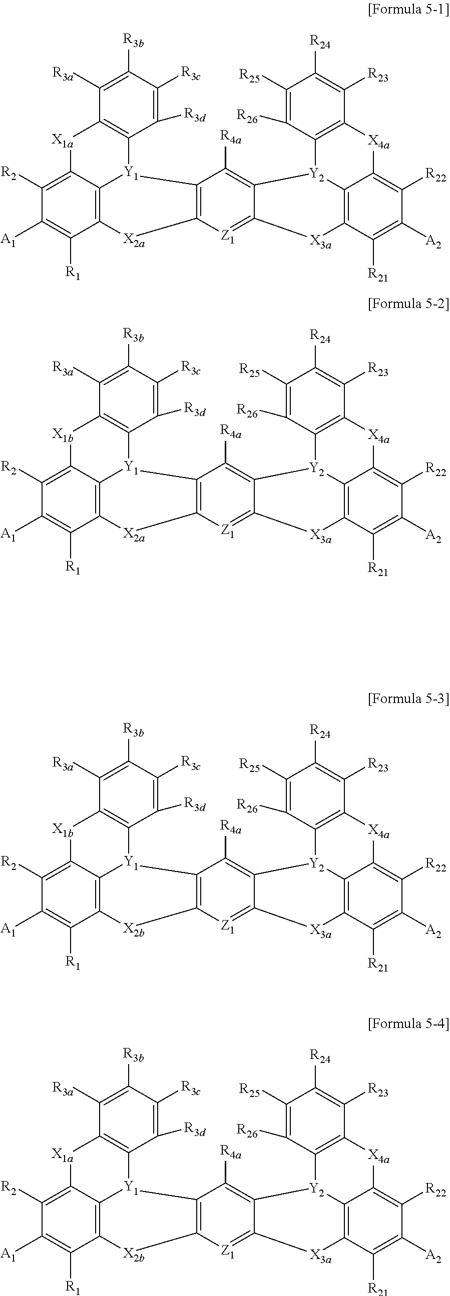 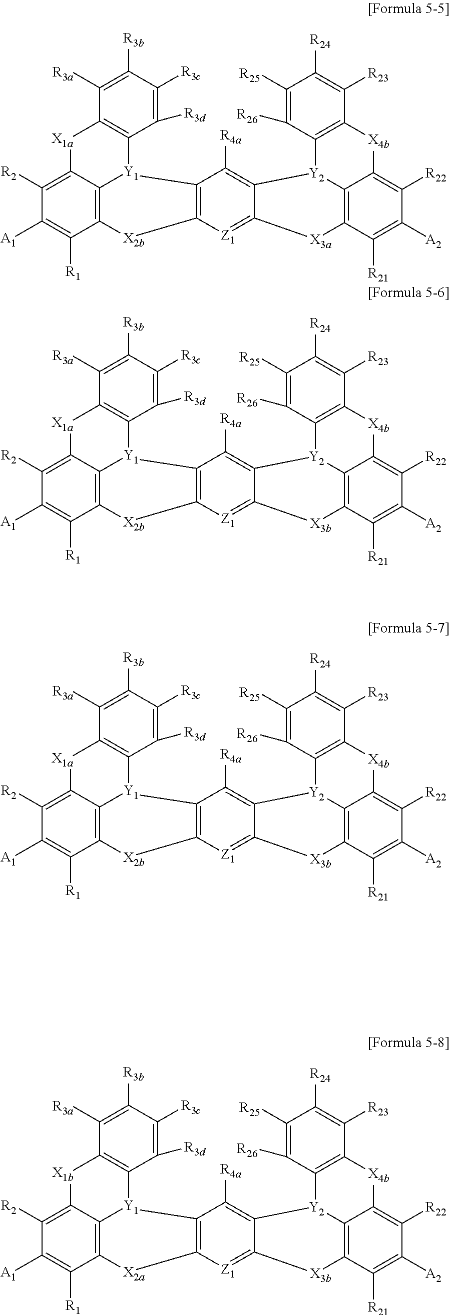 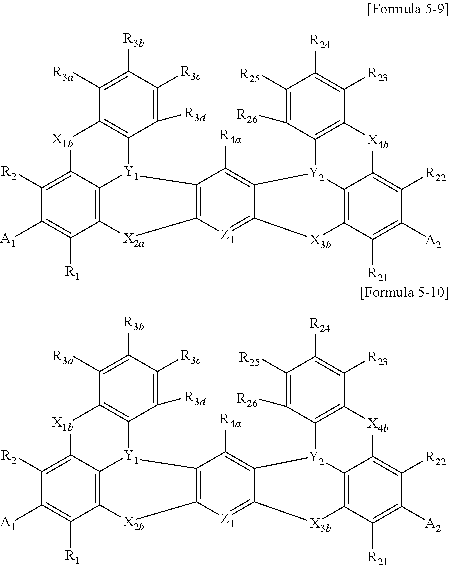
wherein in Formula 5-1 to Formula 5-10,
X₁ₐ to X₄ₐ are each independently represented by Formula 2,
X_{1b} to X_{4b} are each independently O, S, CR₄₁R₄₂, PR₄₃, NR₄₄, or BR₄₅,
R₄₁ to R₄₅ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
Z₁, A₁, A₂, Y₁, Y₂, R₁, R₂, R₃ₐ to R_{3d}, R₄ₐ, and R₂₁ to R₂₆ are the same as defined in Formula 1, Formula 1-1, and Formula 1-2.

8. The fused polycyclic compound of claim 5, wherein the fused polycyclic compound represented by Formula 1-2 is represented by one of Formula 6-1 to Formula 6-4: 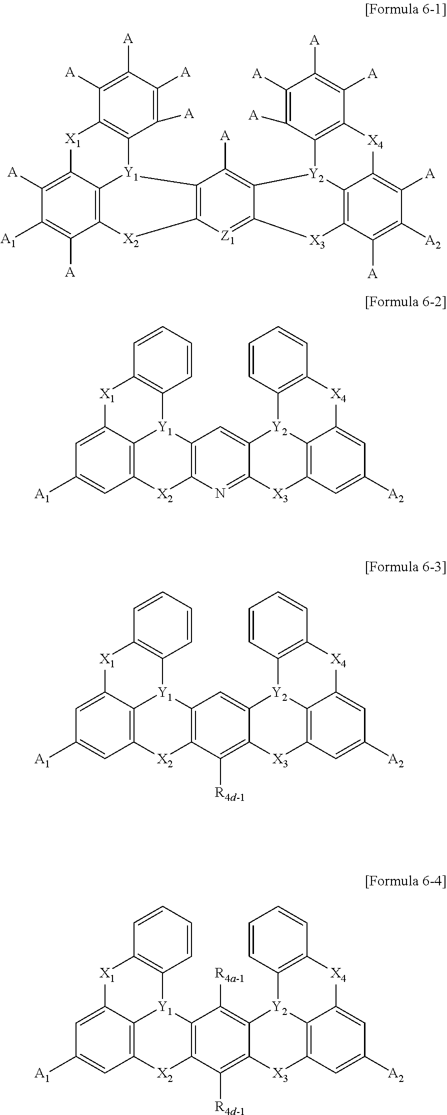
wherein in Formula 6-1 to Formula 6-4,
A is a hydrogen atom or a deuterium atom,
R₄ₐ₋₁ and R_{4d-1} are each independently a substituted or unsubstituted silyl group, a substituted or unsubstituted alkyl group having 1 to 20 carbon atoms, or a substituted or unsubstituted aryl group having 6 to 30 ring-forming carbon atoms, and
X₁ to X₄, Y₁, Y₂, A₁, and A₂ are the same as defined in Formula 1 and Formula 1-2.

9. The fused polycyclic compound of claim 5, wherein the fused polycyclic compound represented by Formula 1-2 is represented by one of Formula 7-1 to Formula 7-5: 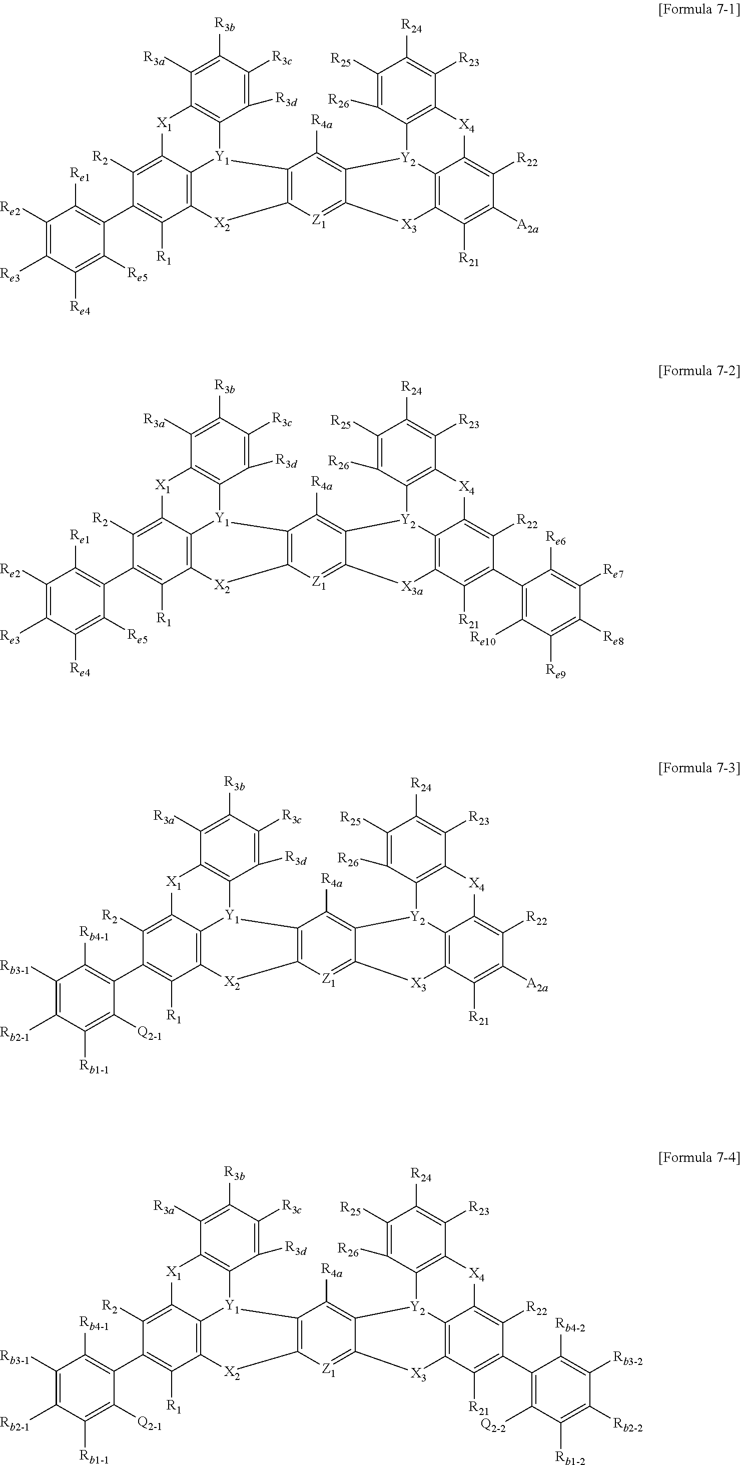
wherein in Formula 7-1 to Formula 7-4,
A₂ₐ is a hydrogen atom, a deuterium atom, a substituted or unsubstituted amine group, a substituted or unsubstituted oxy group, a substituted or unsubstituted silyl group, a substituted or unsubstituted alkyl group having 1 to 20 carbon atoms, or a substituted or unsubstituted heteroaryl group containing N as a ring-forming atom,
Rₑ₁ to Rₑ₁₀ are each independently a hydrogen atom, a deuterium atom, a halogen atom, a nitro group, a substituted or unsubstituted silyl group, a substituted or unsubstituted methyl group, a substituted or unsubstituted alkenyl group having 2 to 20 carbon atoms, or a substituted or unsubstituted phenyl group, or are bonded to an adjacent group to form a ring,
Q₂₋₁ and Q₂₋₂ are each independently a substituted or unsubstituted arylamine group, a substituted or unsubstituted arylsilyl group, a substituted or unsubstituted arylthio group, a substituted or unsubstituted aryloxy group, a substituted or unsubstituted alkyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
R_{b1-1} to R_{b4-1} and R_{b1-2} to R_{b4-2} are each independently a hydrogen atom, a deuterium atom, a substituted or unsubstituted alkyl group having 1 to 20 carbon atoms, or a substituted or unsubstituted aryl group having 6 to 30 ring-forming carbon atoms, and
X₁ to X₄, Y₁, Y₂, Z₁, R₁, R₂, R₃ₐ to R_{3d}, R₄ₐ, and R₂₁ to R₂₆ are the same as defined in Formula 1, Formula 1-1, and Formula 1-2.

10. The fused polycyclic compound of claim 1, wherein the fused polycyclic compound represented by Formula 1 comprises at least one among compounds represented by Compound Group 1:

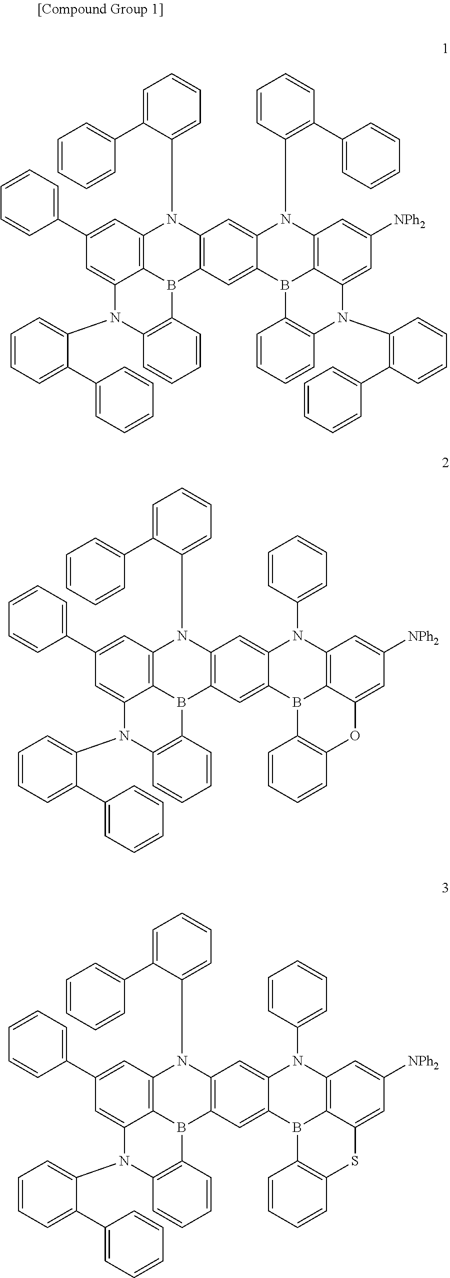

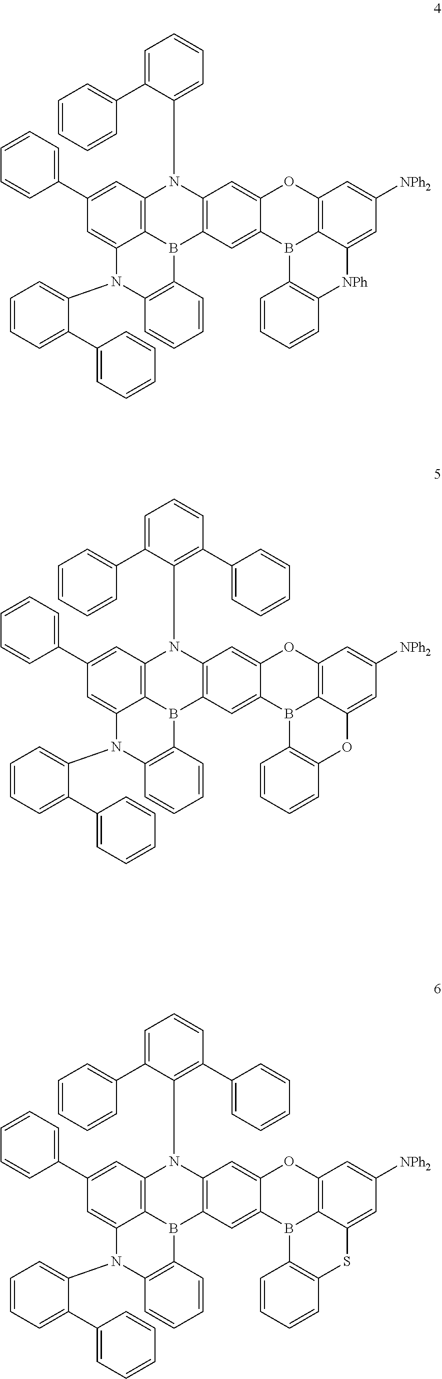

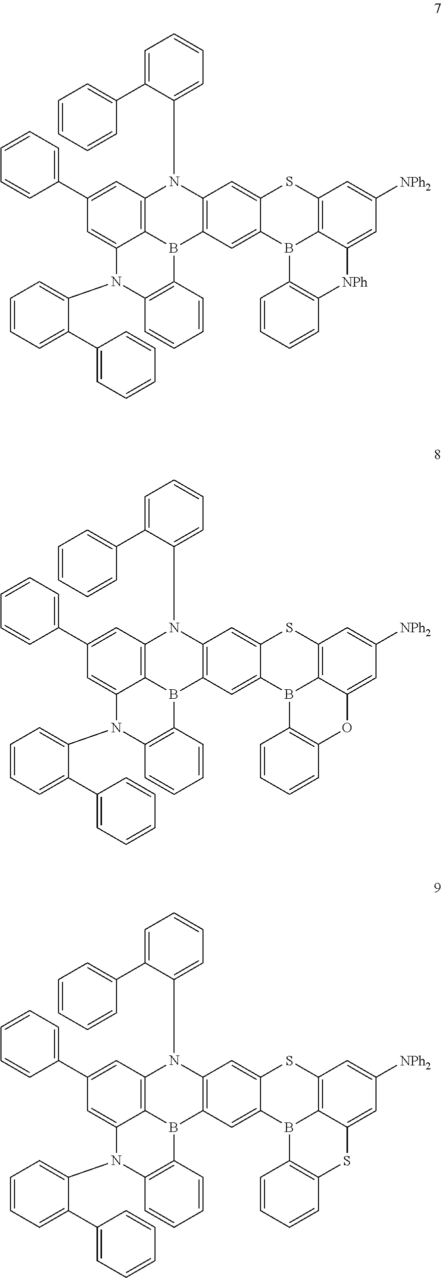

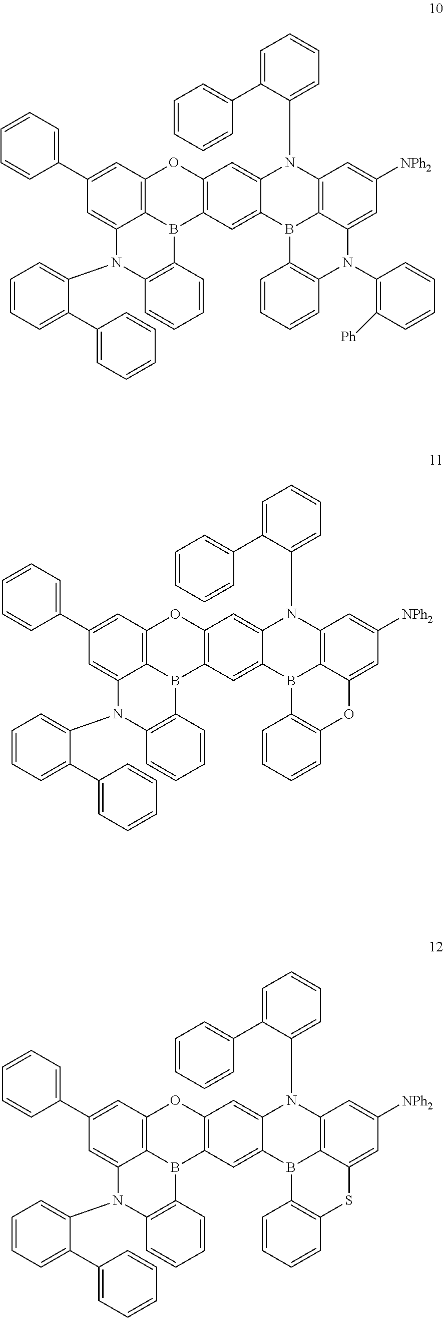

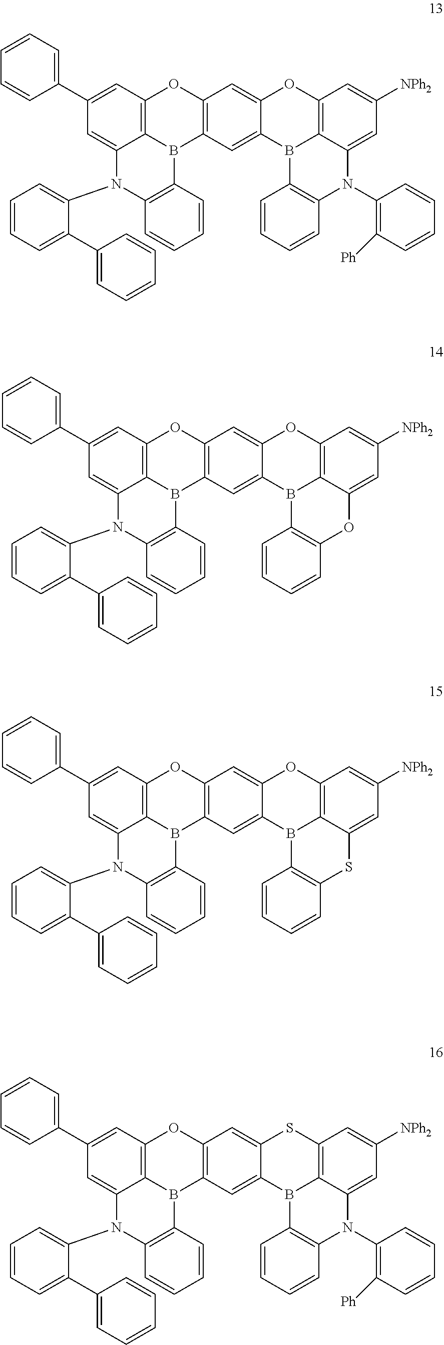

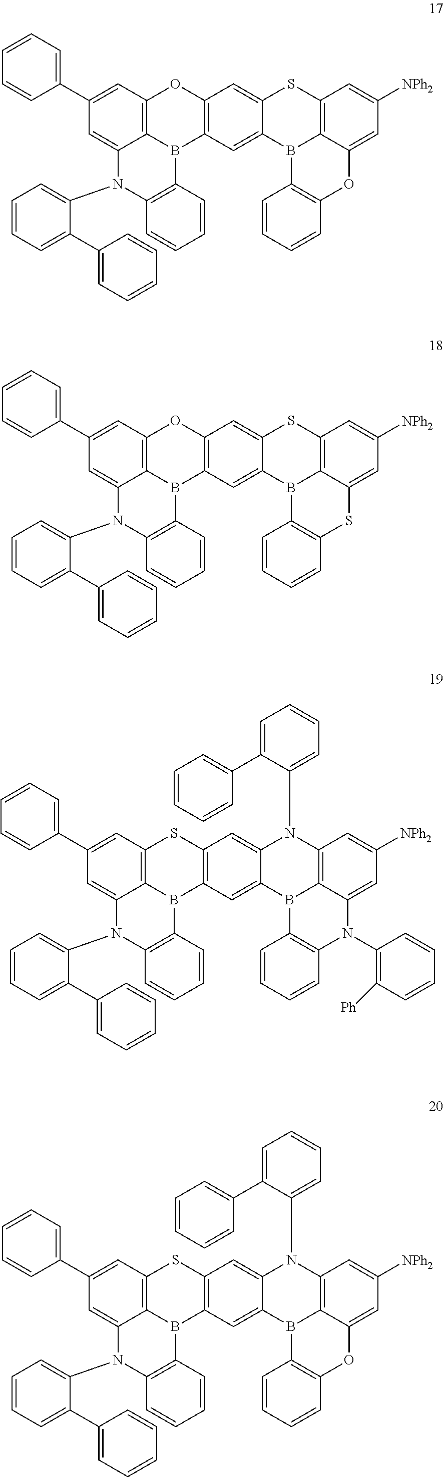

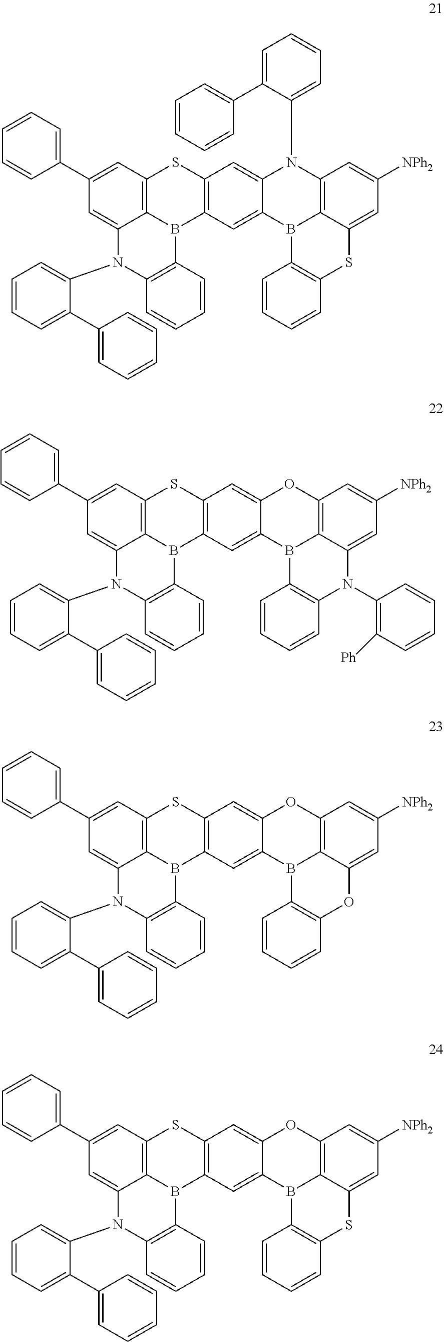

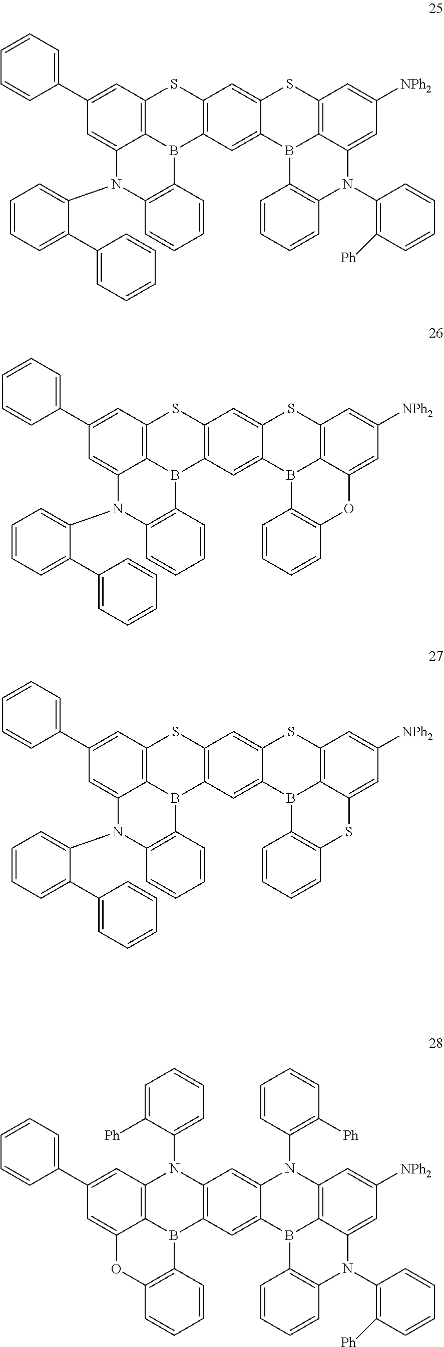

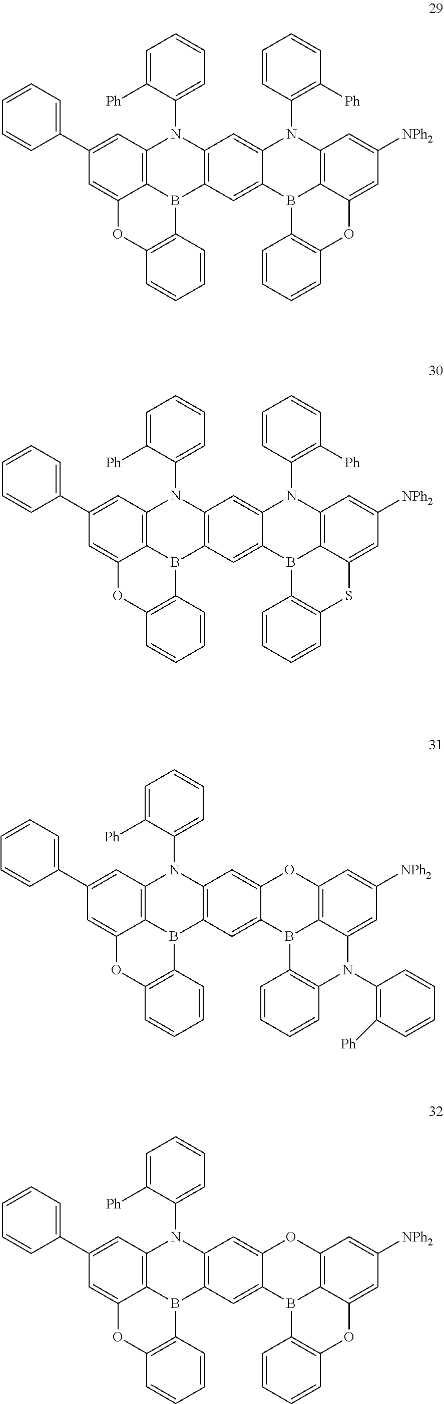

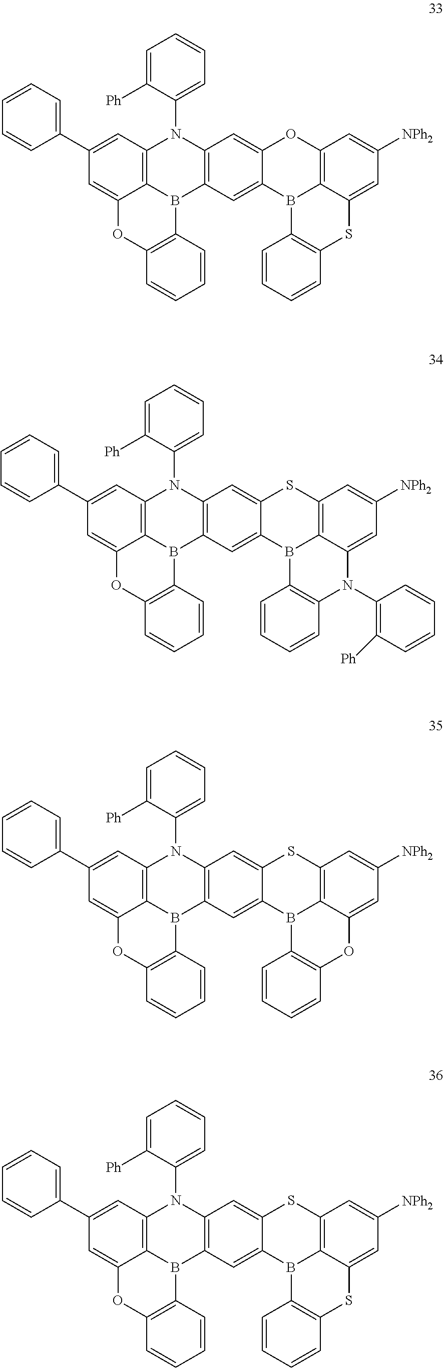

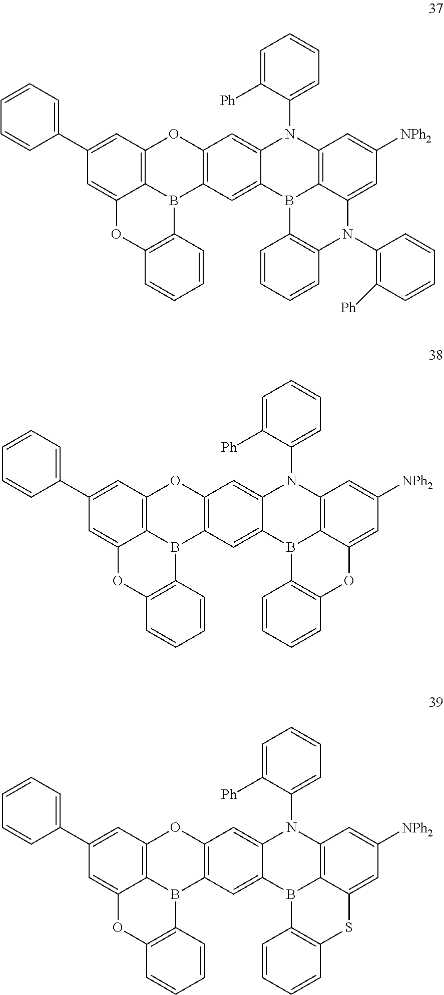

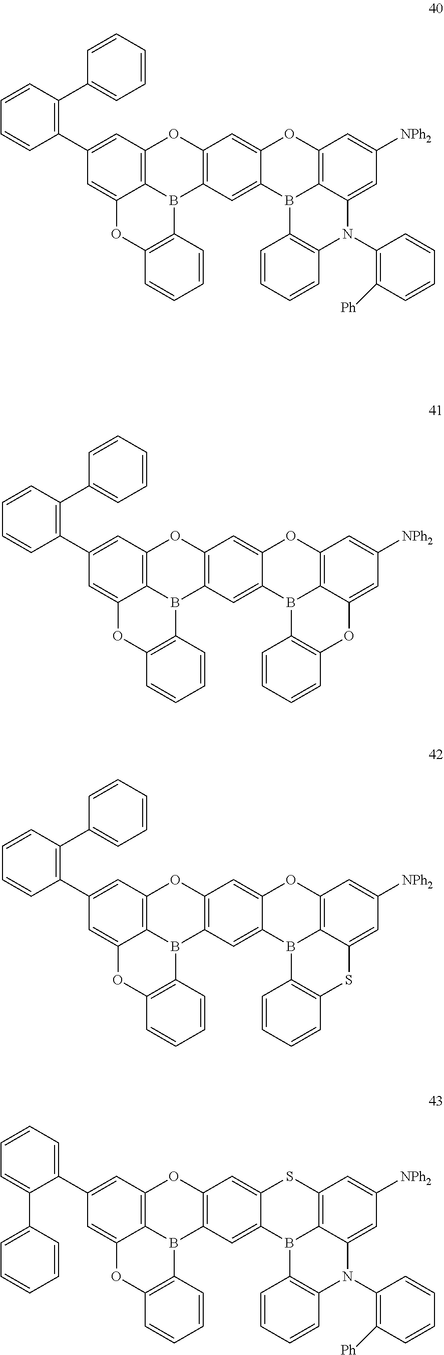

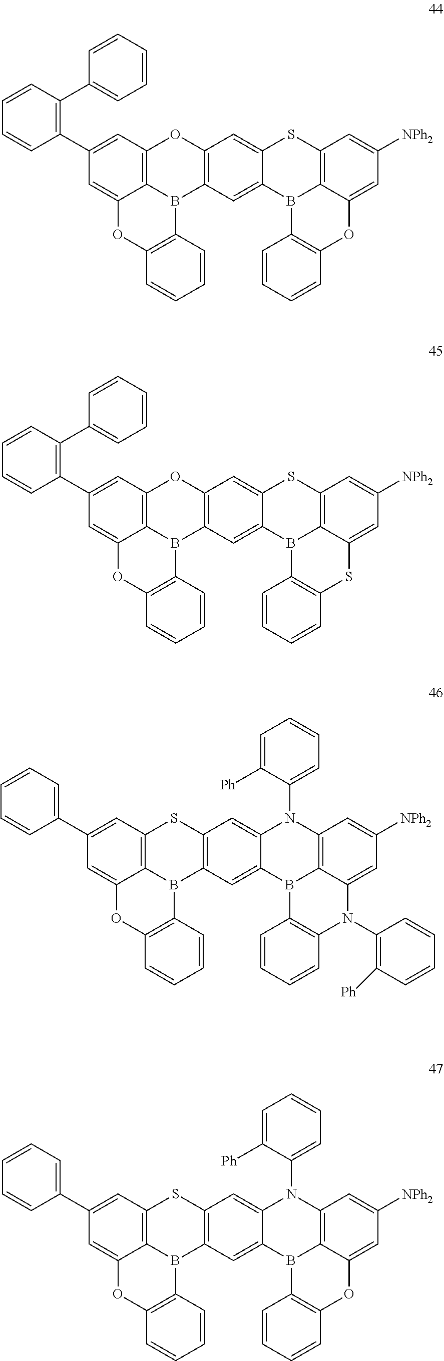

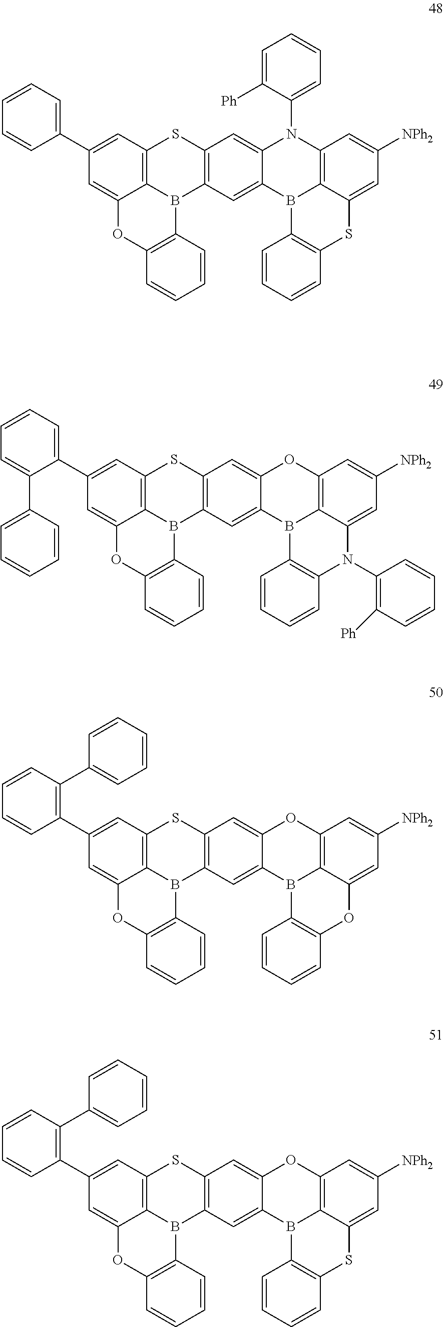

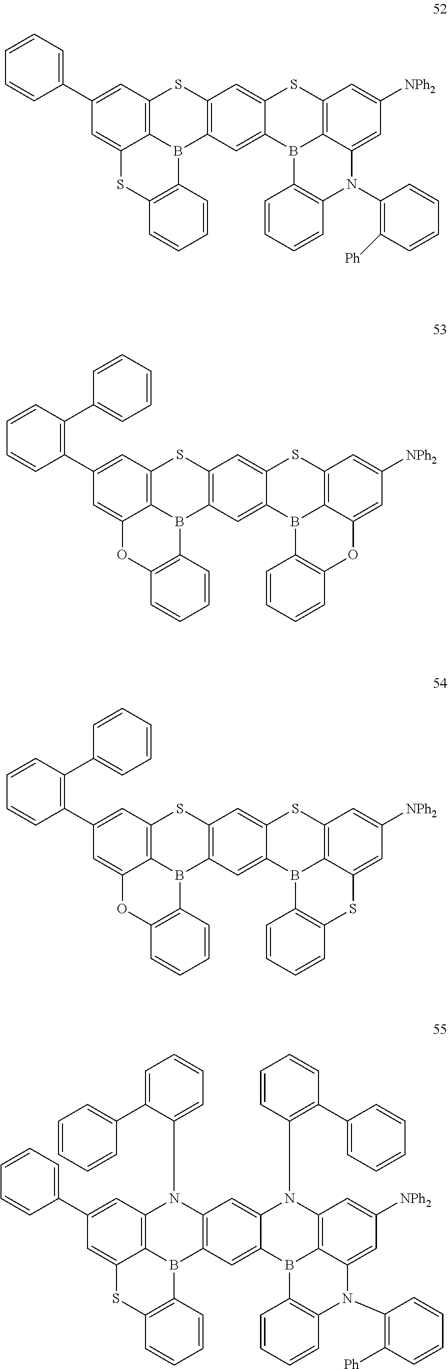

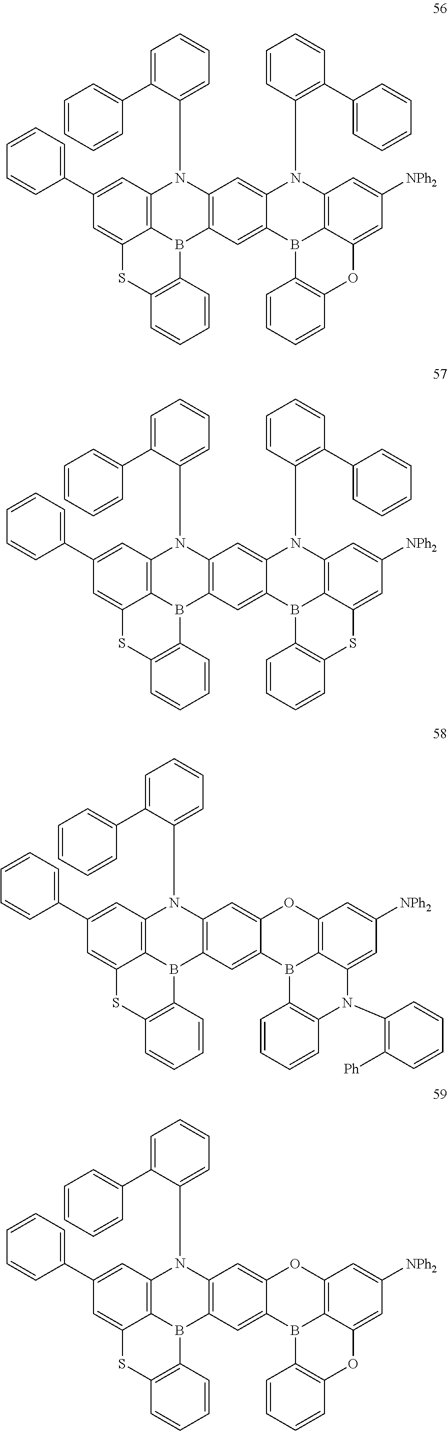

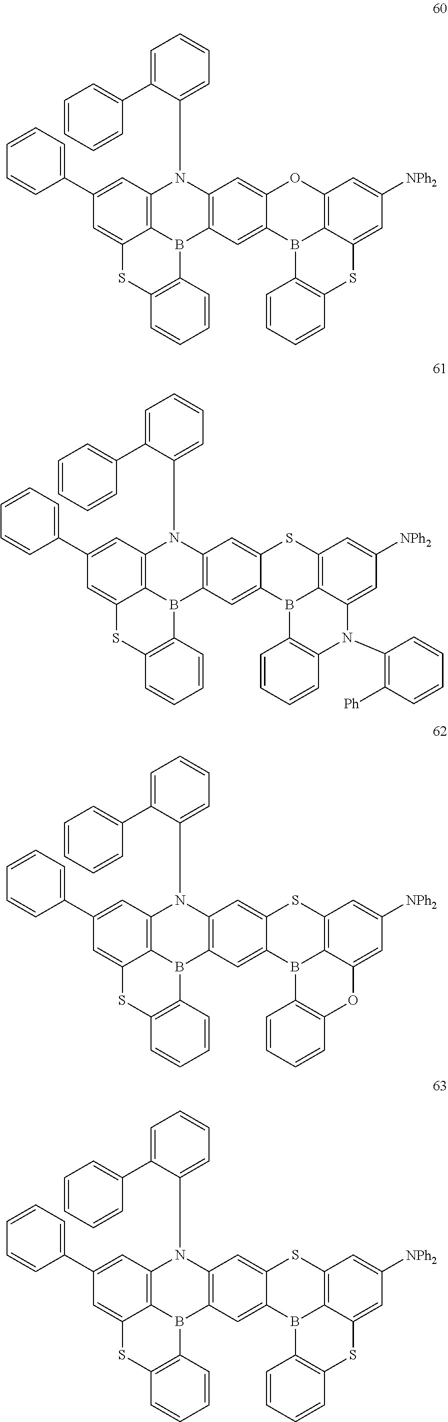

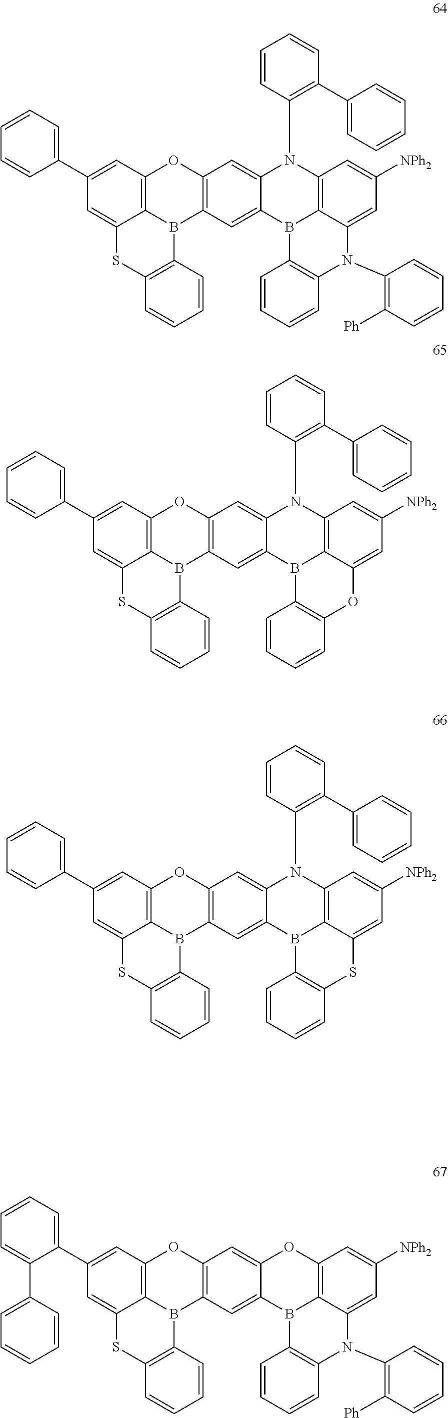

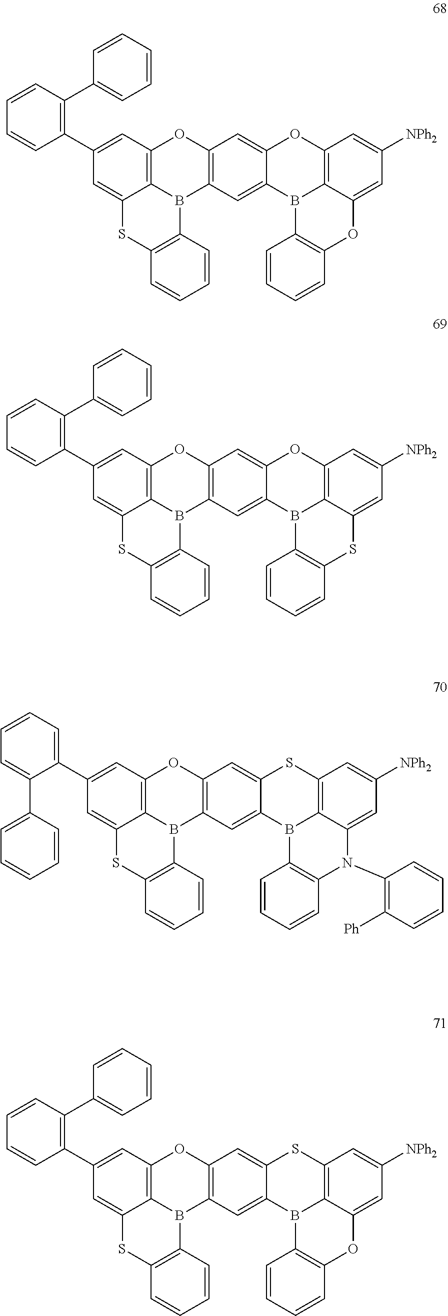

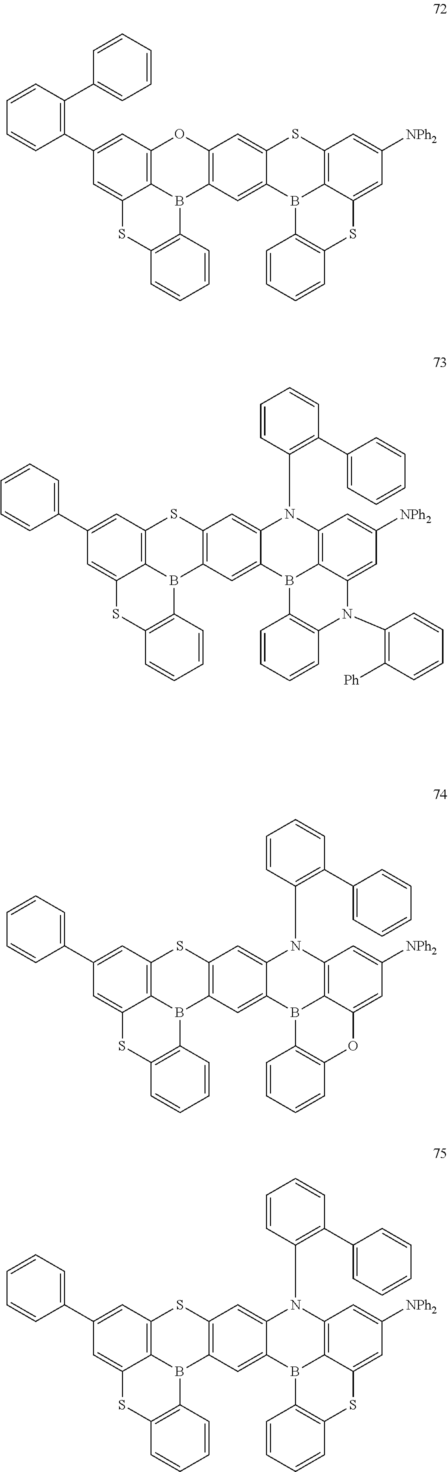

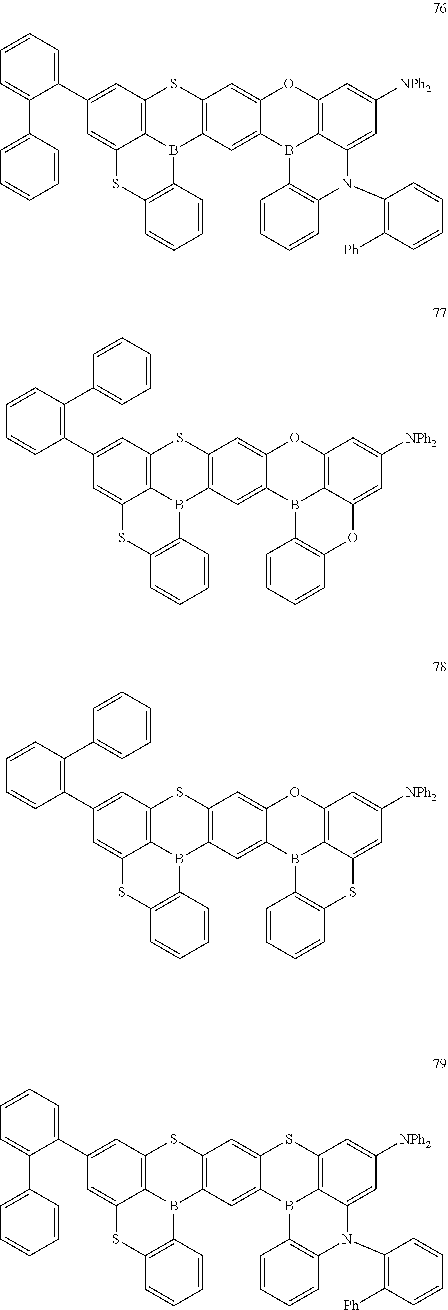

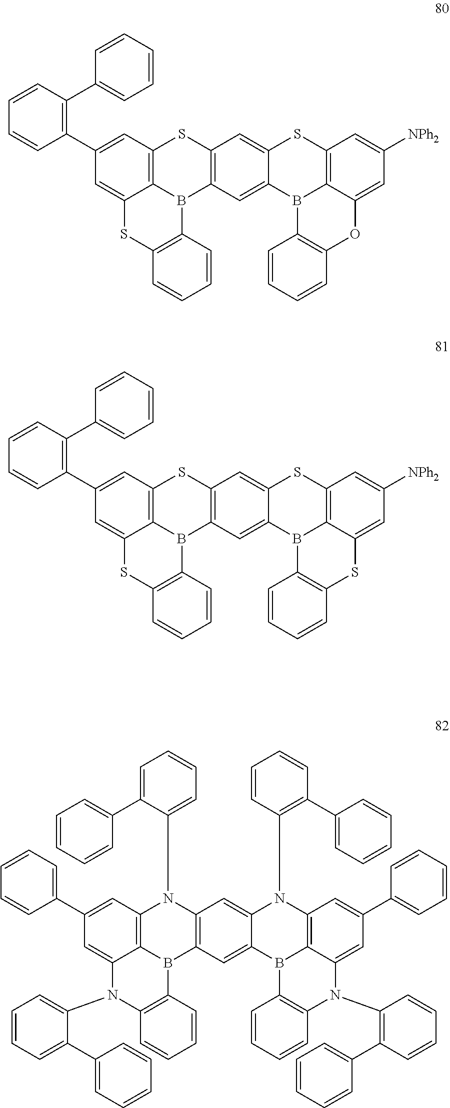

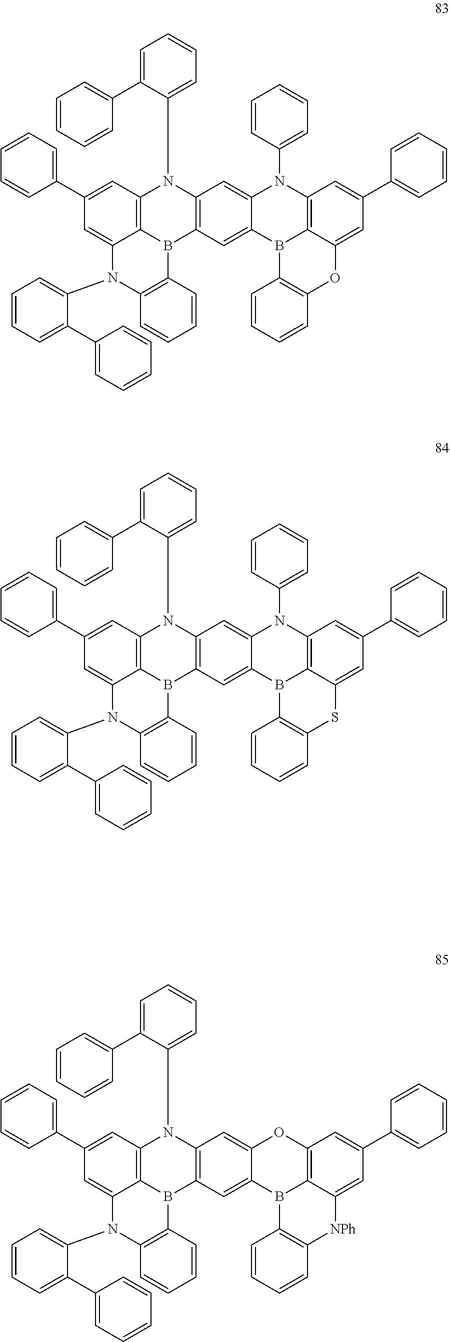

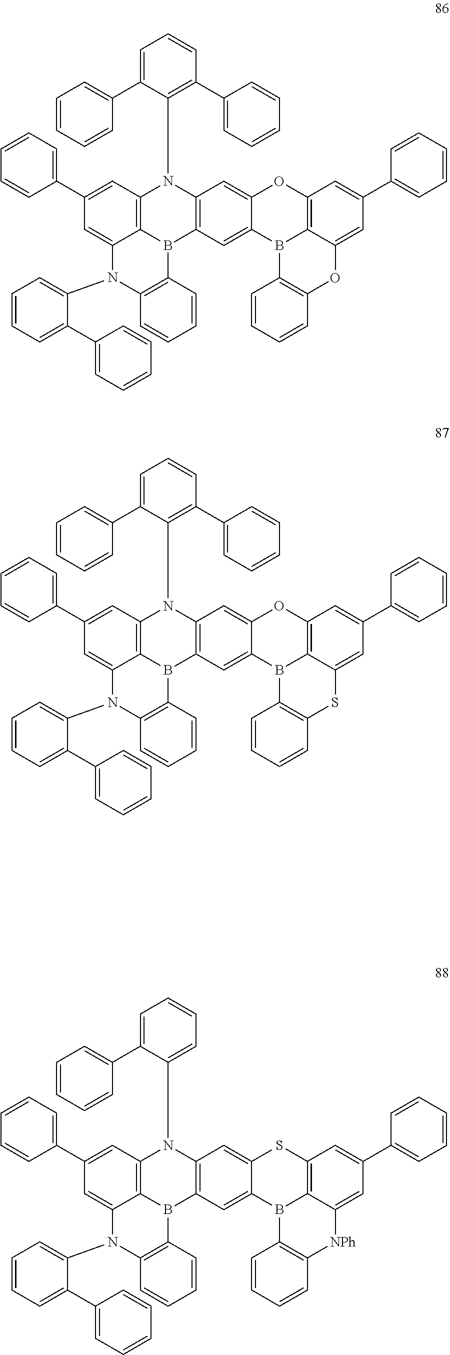

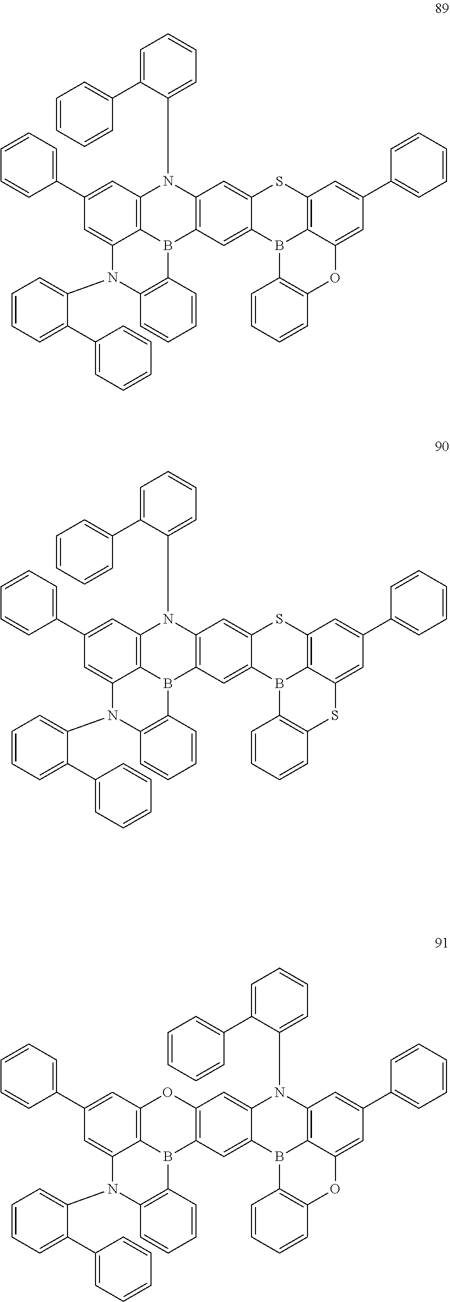 [SMILES: c1ccc(-c2cc3c4c(c2)Sc2cc5c(cc2B4c2ccccc2O3)B2c3ccccc3N(c3ccccc3-c3ccccc3)c3cc(-c4ccccc4)cc(c32)N5c2ccccc2-c2ccccc2)cc1 ; c1ccc(-c2cc3c4c(c2)Sc2cc5c(cc2B4c2ccccc2S3)B2c3ccccc3N(c3ccccc3-c3ccccc3)c3cc(-c4ccccc4)cc(c32)N5c2ccccc2-c2ccccc2)cc1 ; c1ccc(-c2cc3c4c(c2)N(c2ccccc2-c2ccccc2)c2ccccc2B4c2cc4c(cc2O3)N(c2ccccc2-c2ccccc2)c2cc(-c3ccccc3)cc3c2B4c2ccccc2O3)cc1]

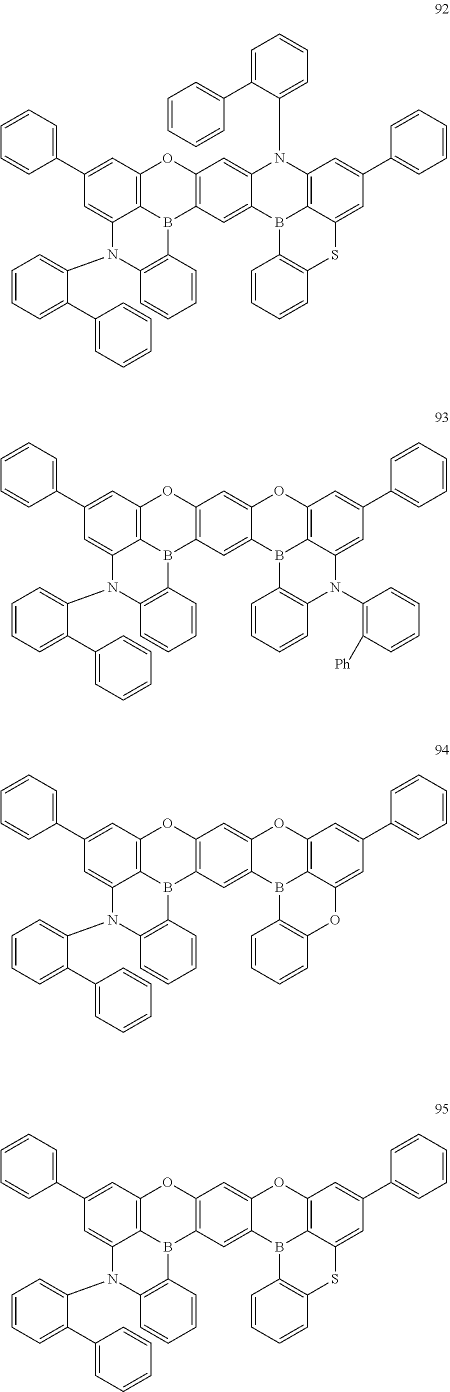 [SMILES: c1ccc(-c2cc3c4c(c2)N(c2ccccc2-c2ccccc2)c2ccccc2B4c2cc4c(cc2O3)N(c2ccccc2-c2ccccc2)c2cc(-c3ccccc3)cc3c2B4c2ccccc2S3)cc1 ; c1ccc(-c2cc3c4c(c2)N(c2ccccc2-c2ccccc2)c2ccccc2B4c2cc4c(cc2O3)Oc2cc(-c3ccccc3)cc3c2B4c2ccccc2N3c2ccccc2-c2ccccc2)cc1 ; c1ccc(-c2cc3c4c(c2)Oc2cc5c(cc2B4c2ccccc2O3)B2c3ccccc3N(c3ccccc3-c3ccccc3)c3cc(-c4ccccc4)cc(c32)O5)cc1 ; c1ccc(-c2cc3c4c(c2)Sc2ccccc2B4c2cc4c(cc2O3)Oc2cc(-c3ccccc3)cc3c2B4c2ccccc2N3c2ccccc2-c2ccccc2)cc1]

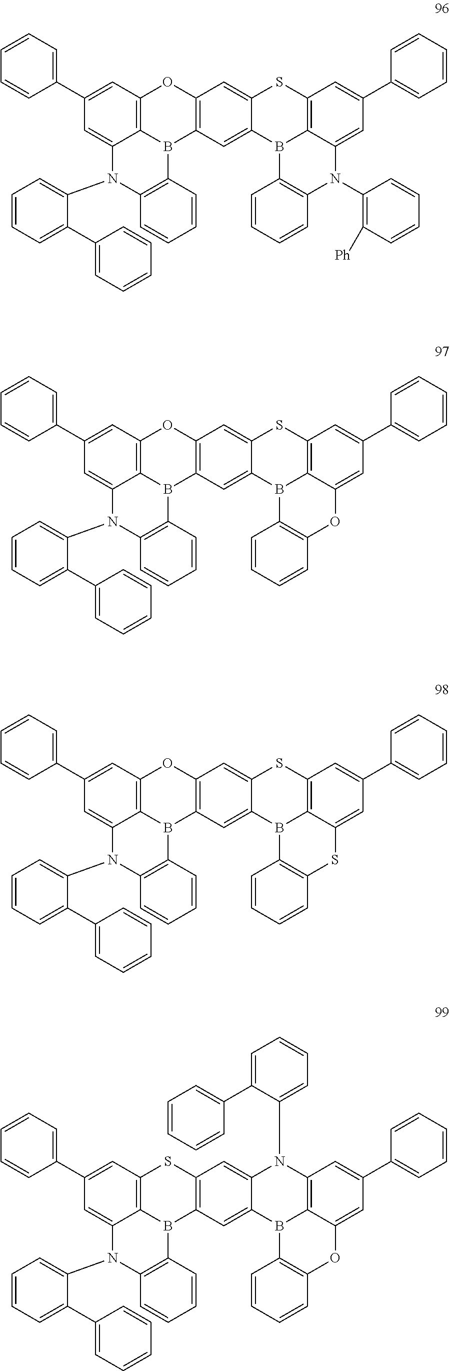 [SMILES: c1ccc(-c2cc3c4c(c2)N(c2ccccc2-c2ccccc2)c2ccccc2B4c2cc4c(cc2O3)Sc2cc(-c3ccccc3)cc3c2B4c2ccccc2N3c2ccccc2-c2ccccc2)cc1 ; c1ccc(-c2cc3c4c(c2)Sc2cc5c(cc2B4c2ccccc2O3)B2c3ccccc3N(c3ccccc3-c3ccccc3)c3cc(-c4ccccc4)cc(c32)O5)cc1 ; c1ccc(-c2cc3c4c(c2)Sc2cc5c(cc2B4c2ccccc2S3)B2c3ccccc3N(c3ccccc3-c3ccccc3)c3cc(-c4ccccc4)cc(c32)O5)cc1 ; c1ccc(-c2cc3c4c(c2)N(c2ccccc2-c2ccccc2)c2cc5c(cc2B4c2ccccc2O3)B2c3ccccc3N(c3ccccc3-c3ccccc3)c3cc(-c4ccccc4)cc(c32)S5)cc1]

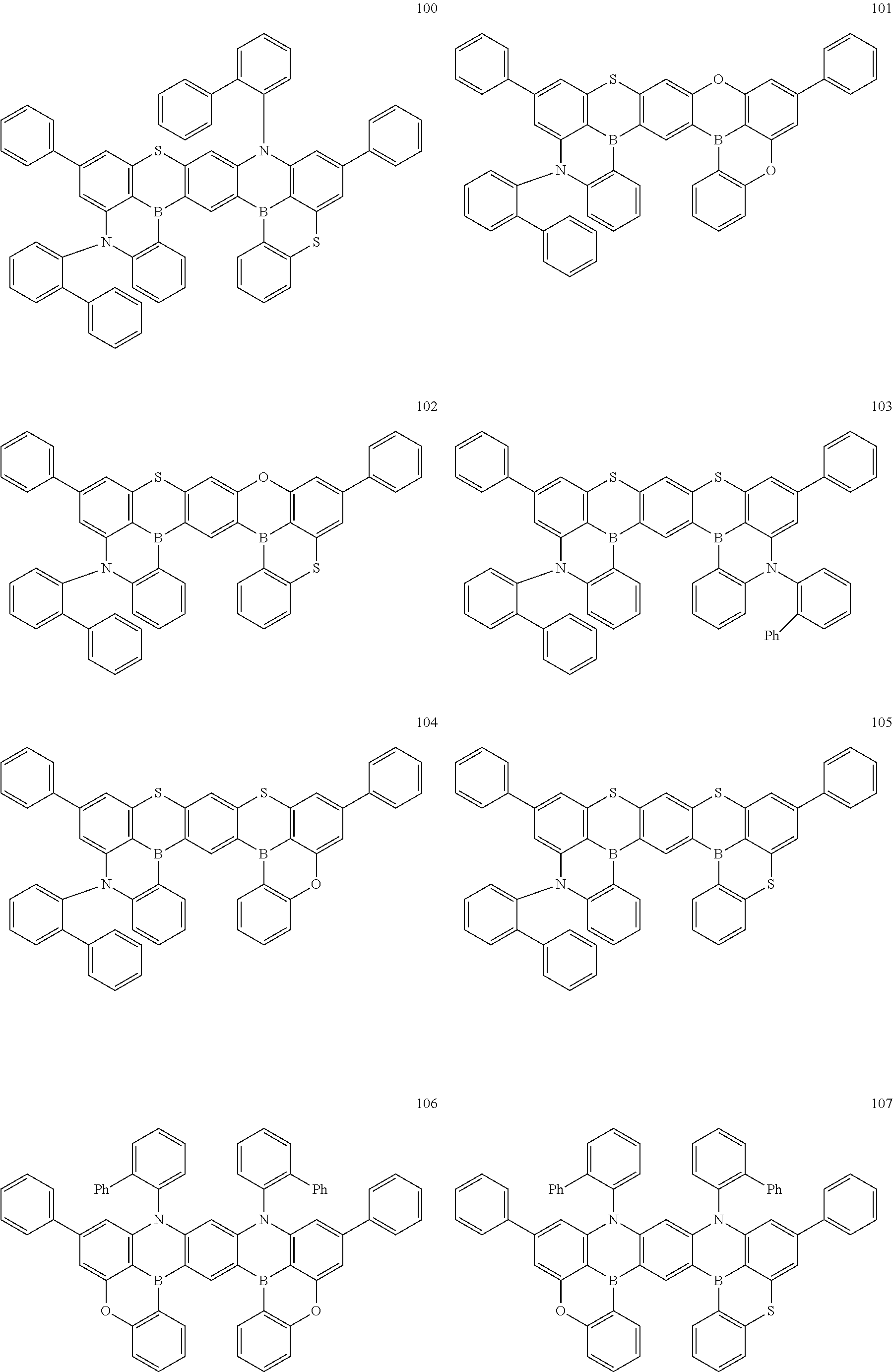

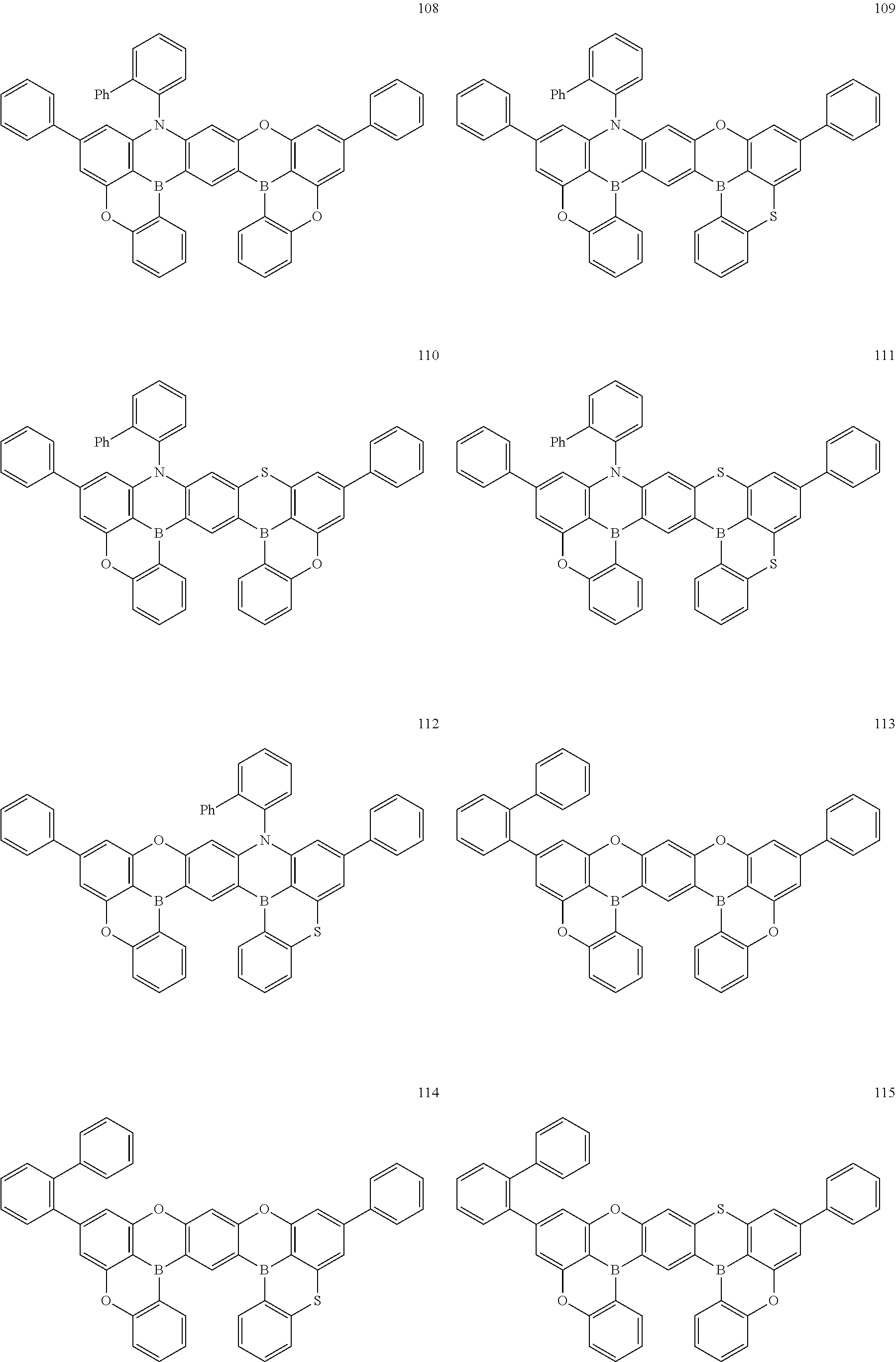

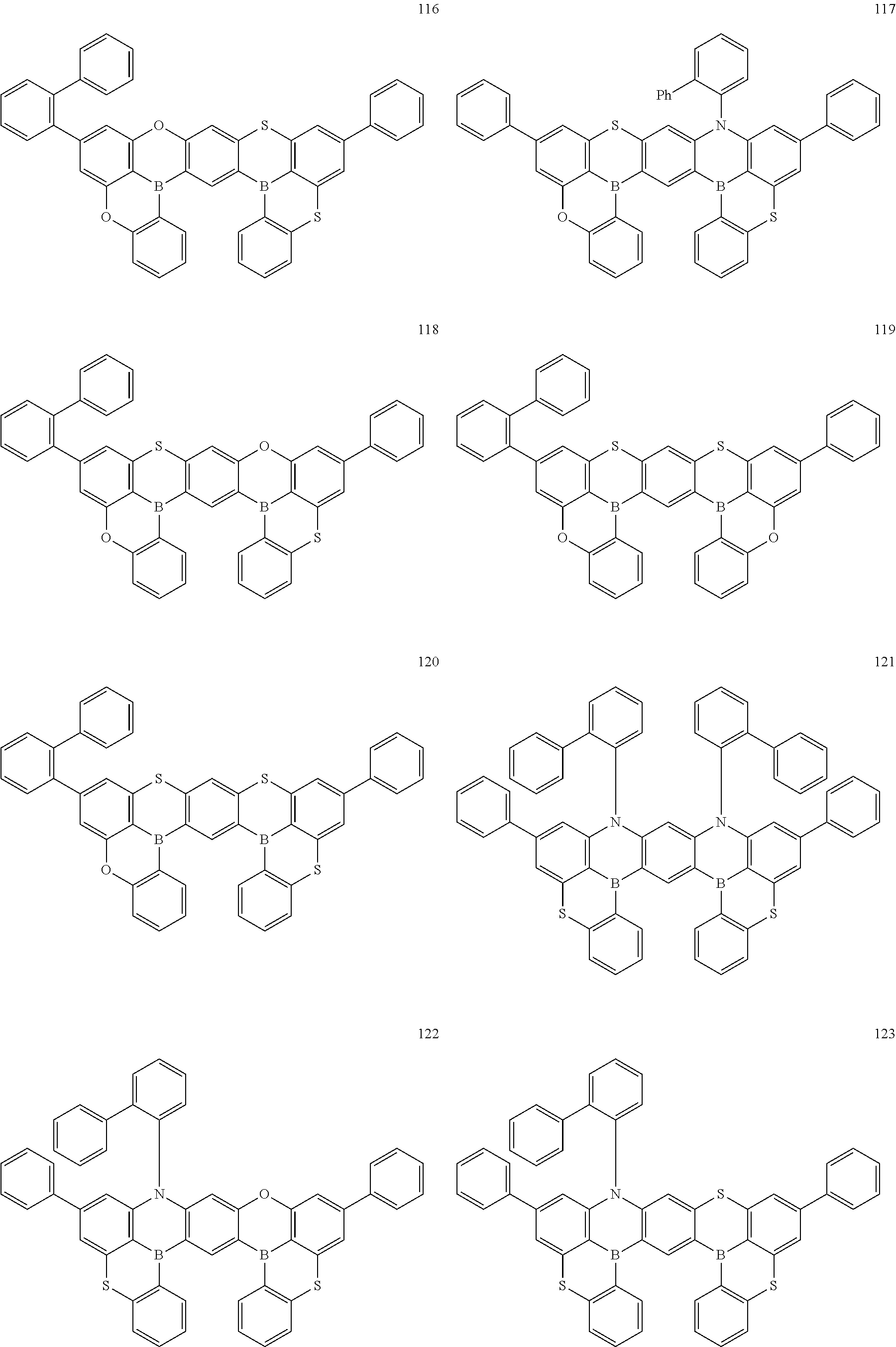

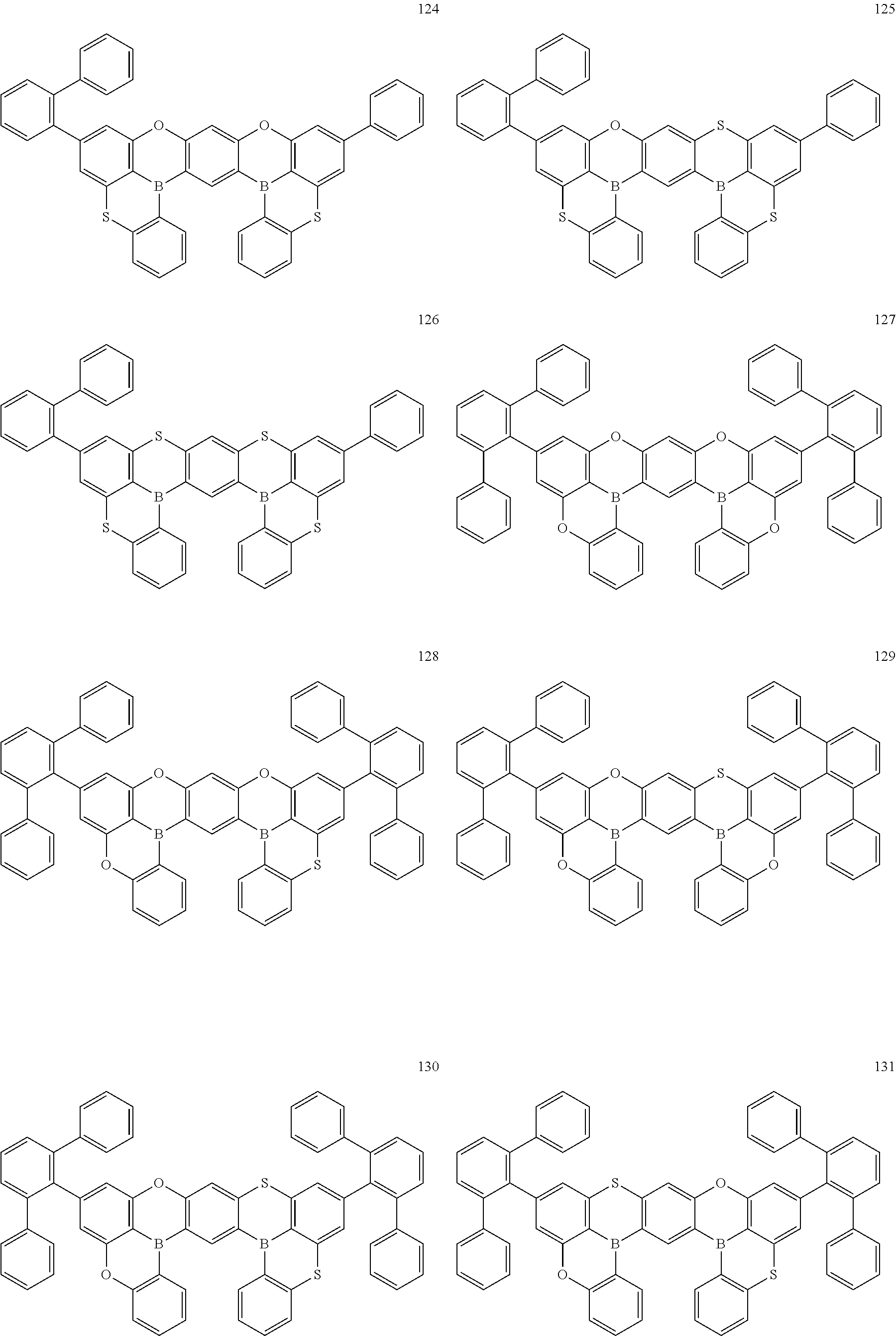

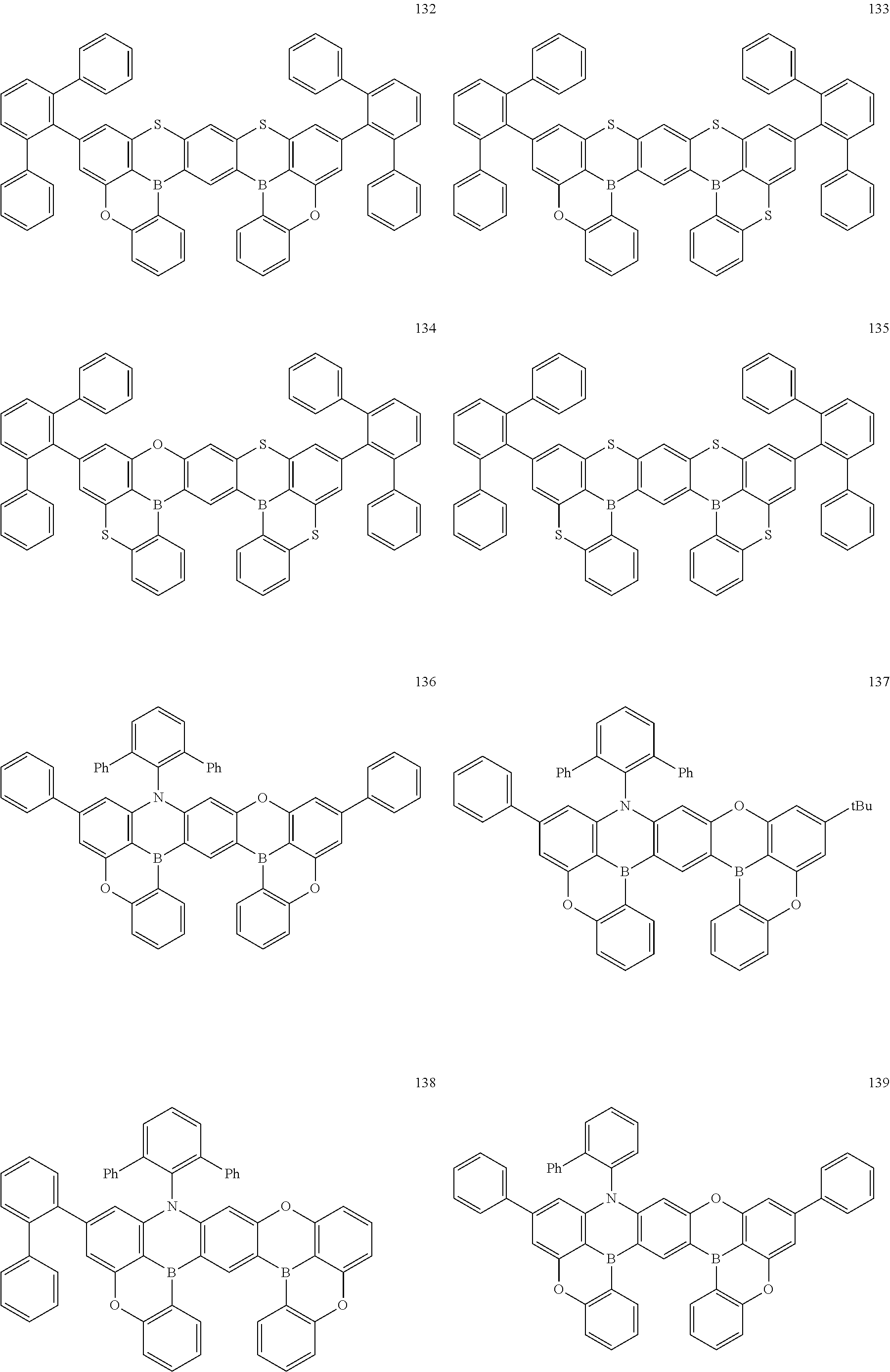

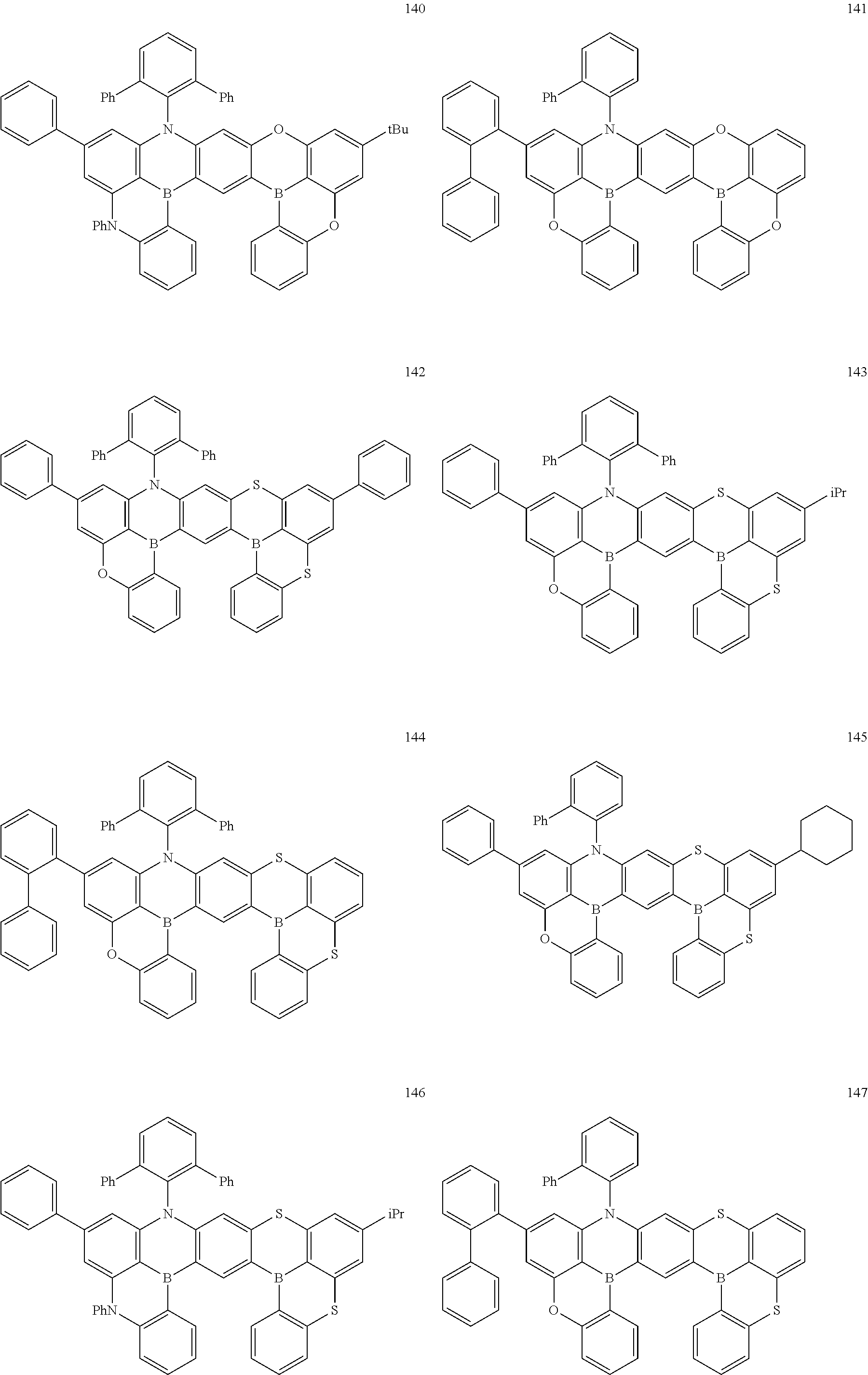

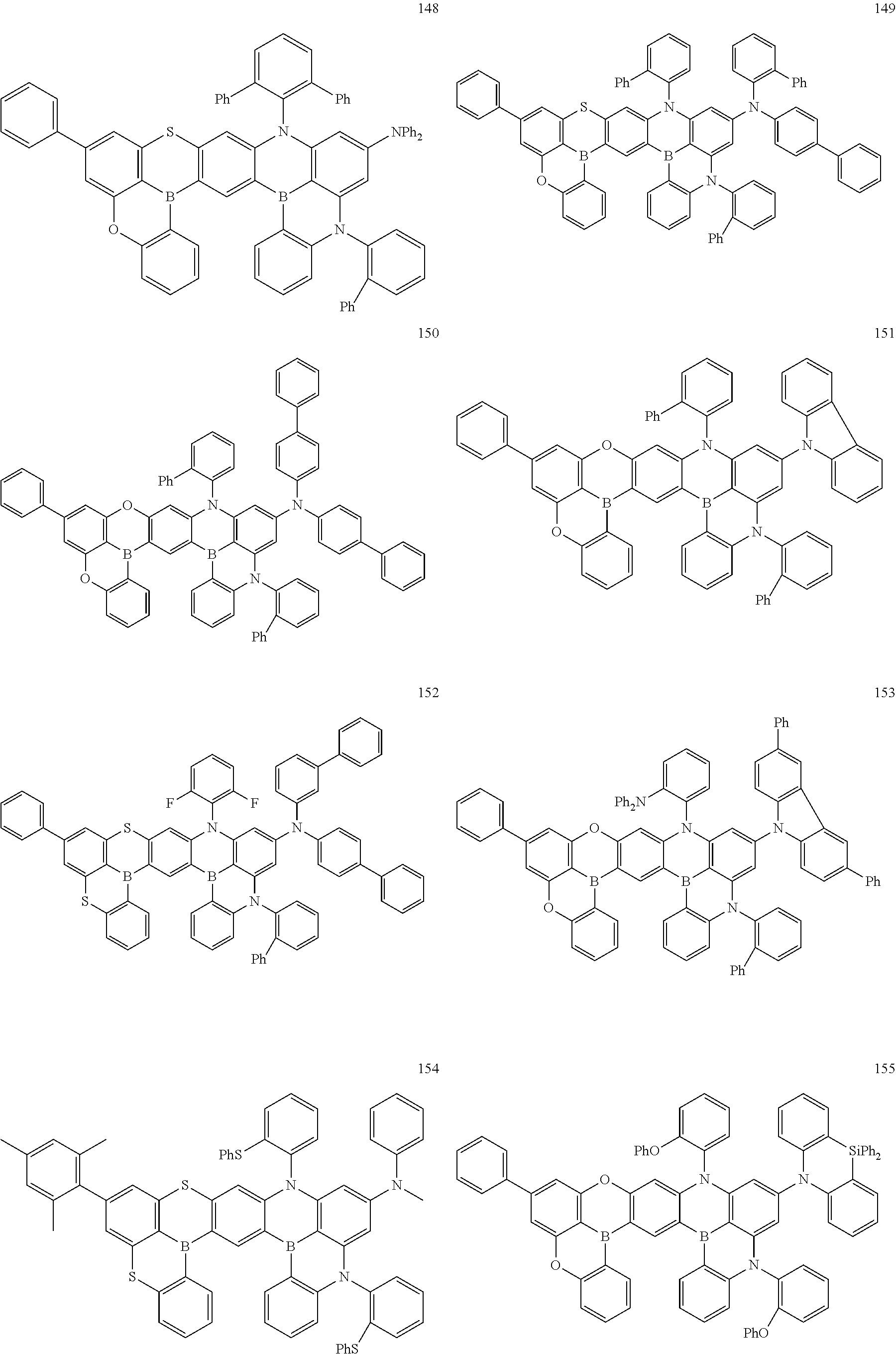

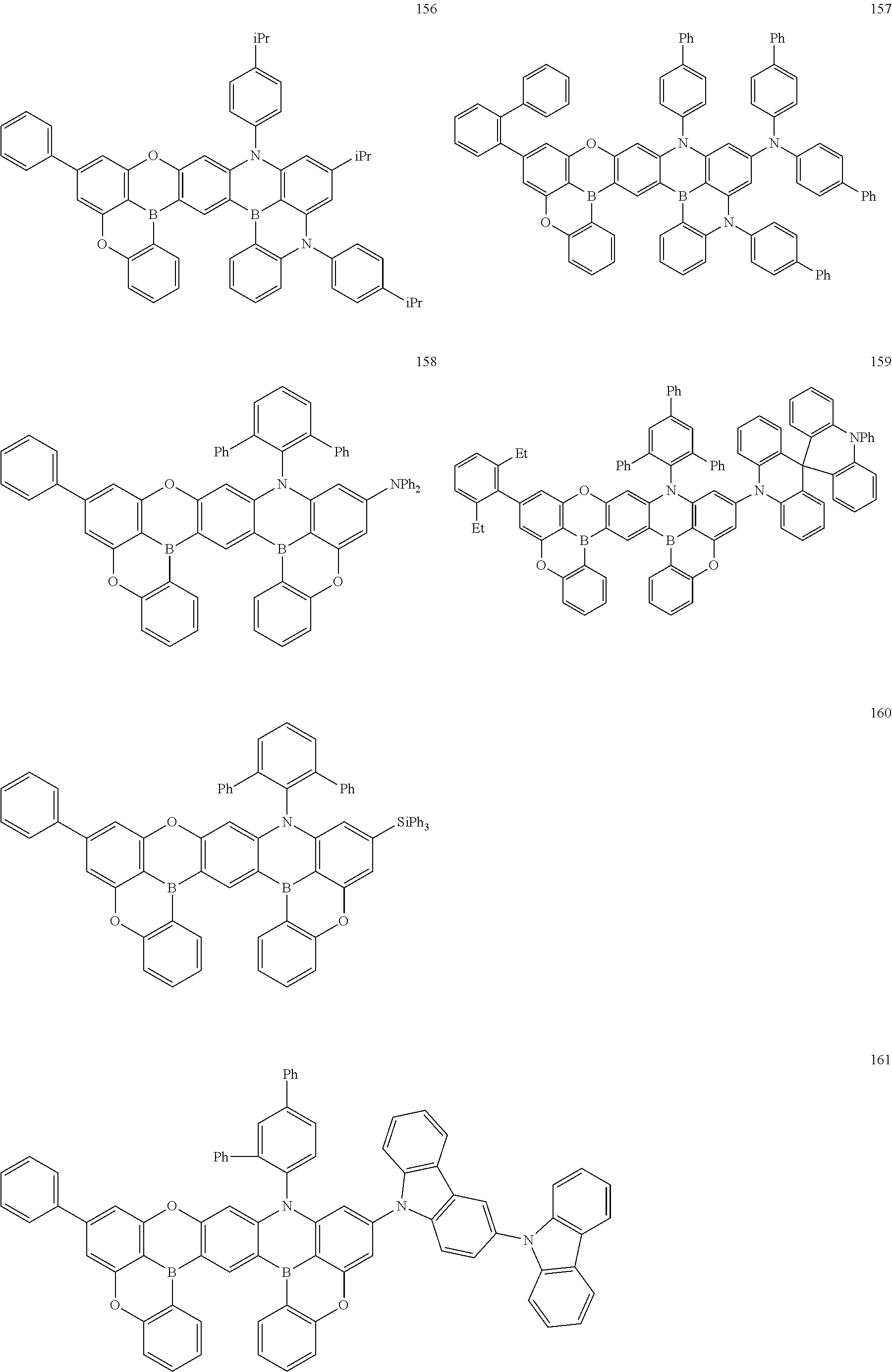

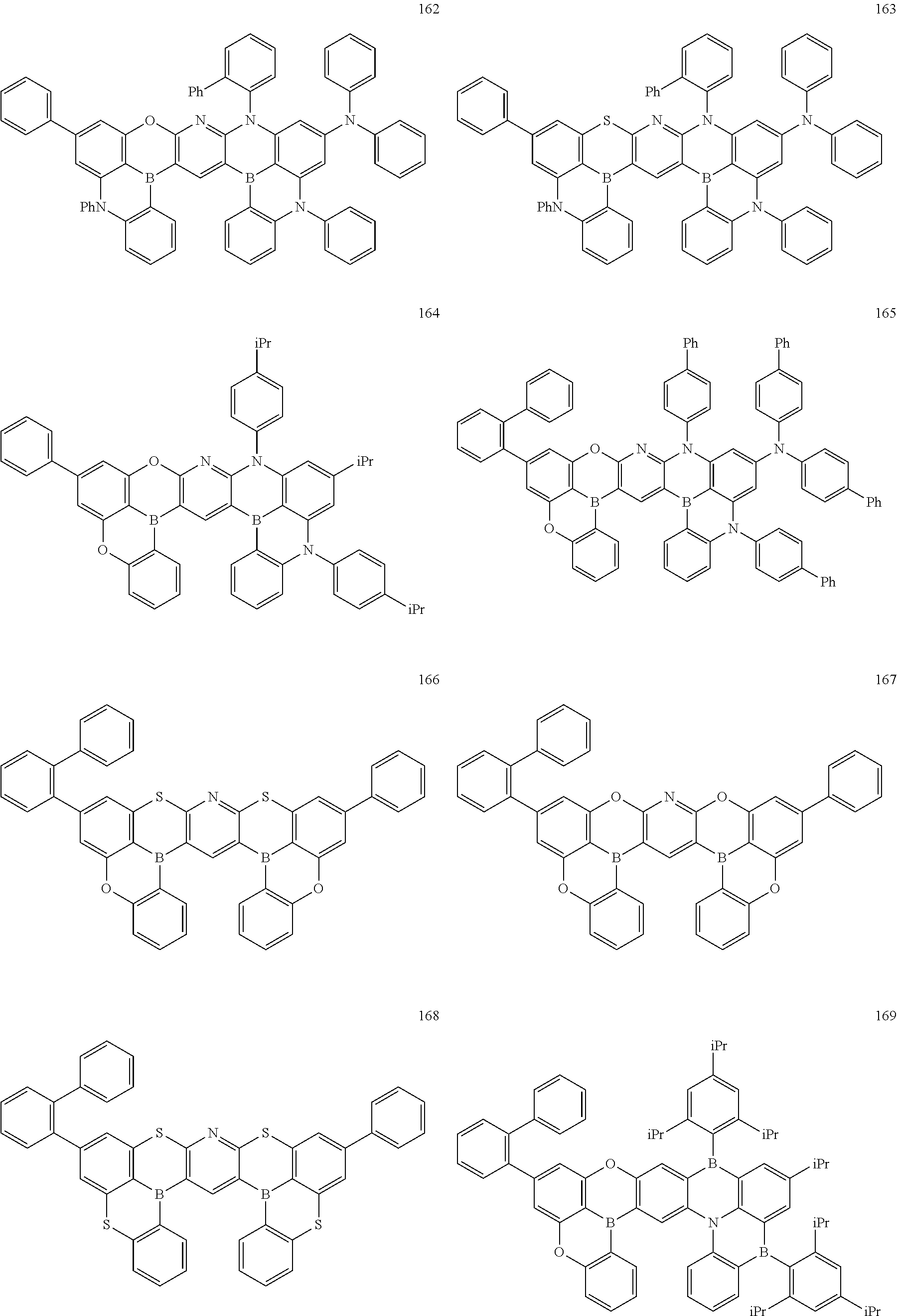

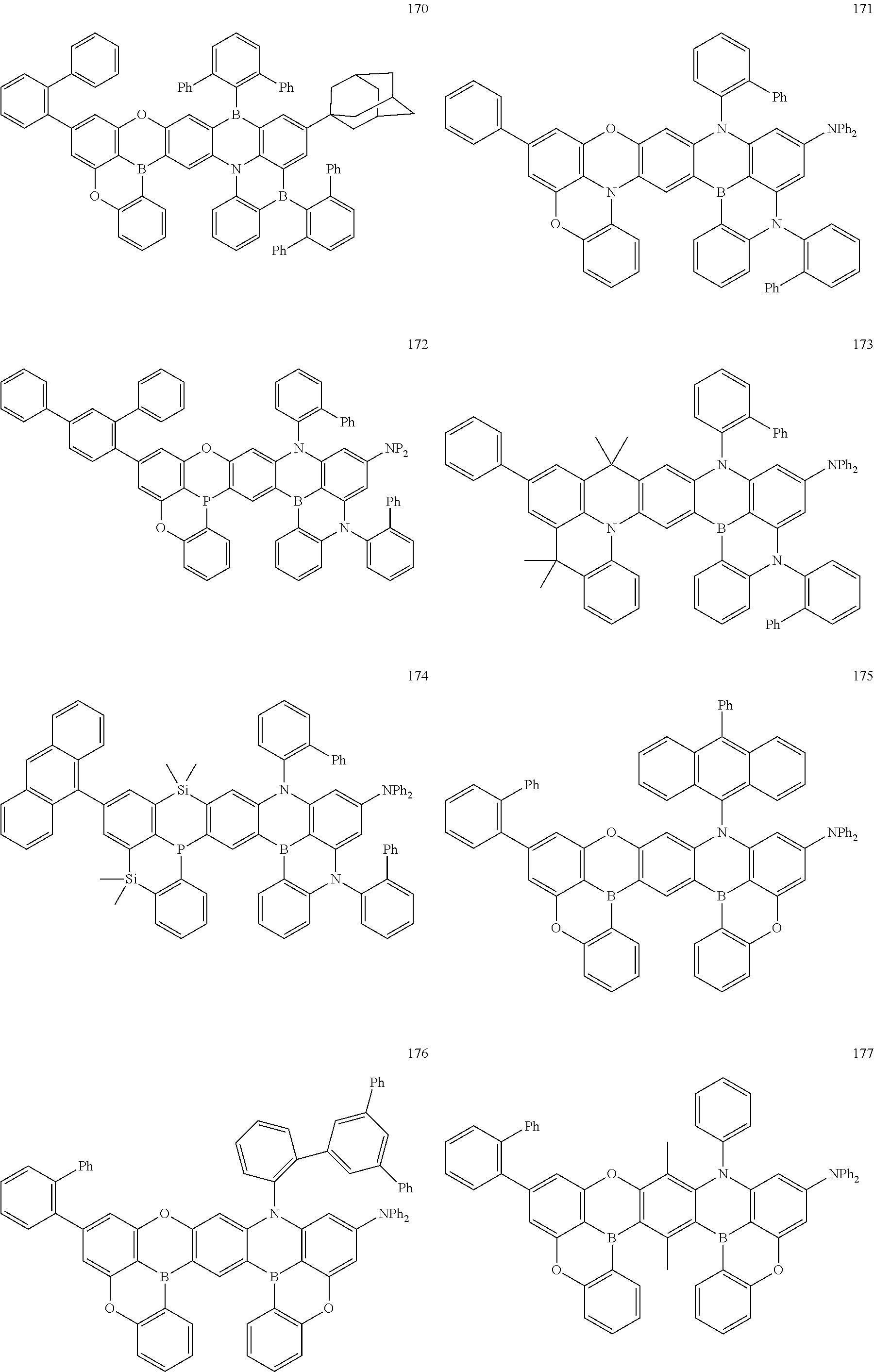

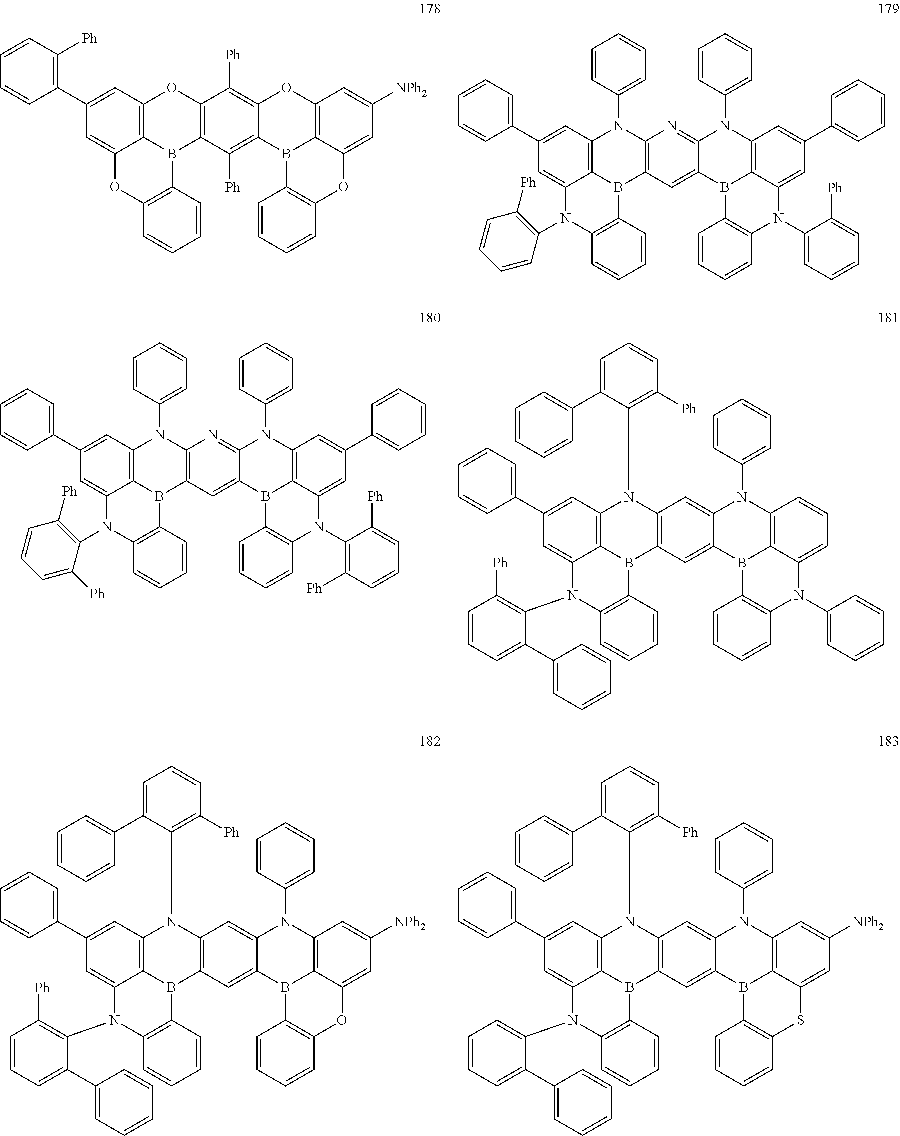

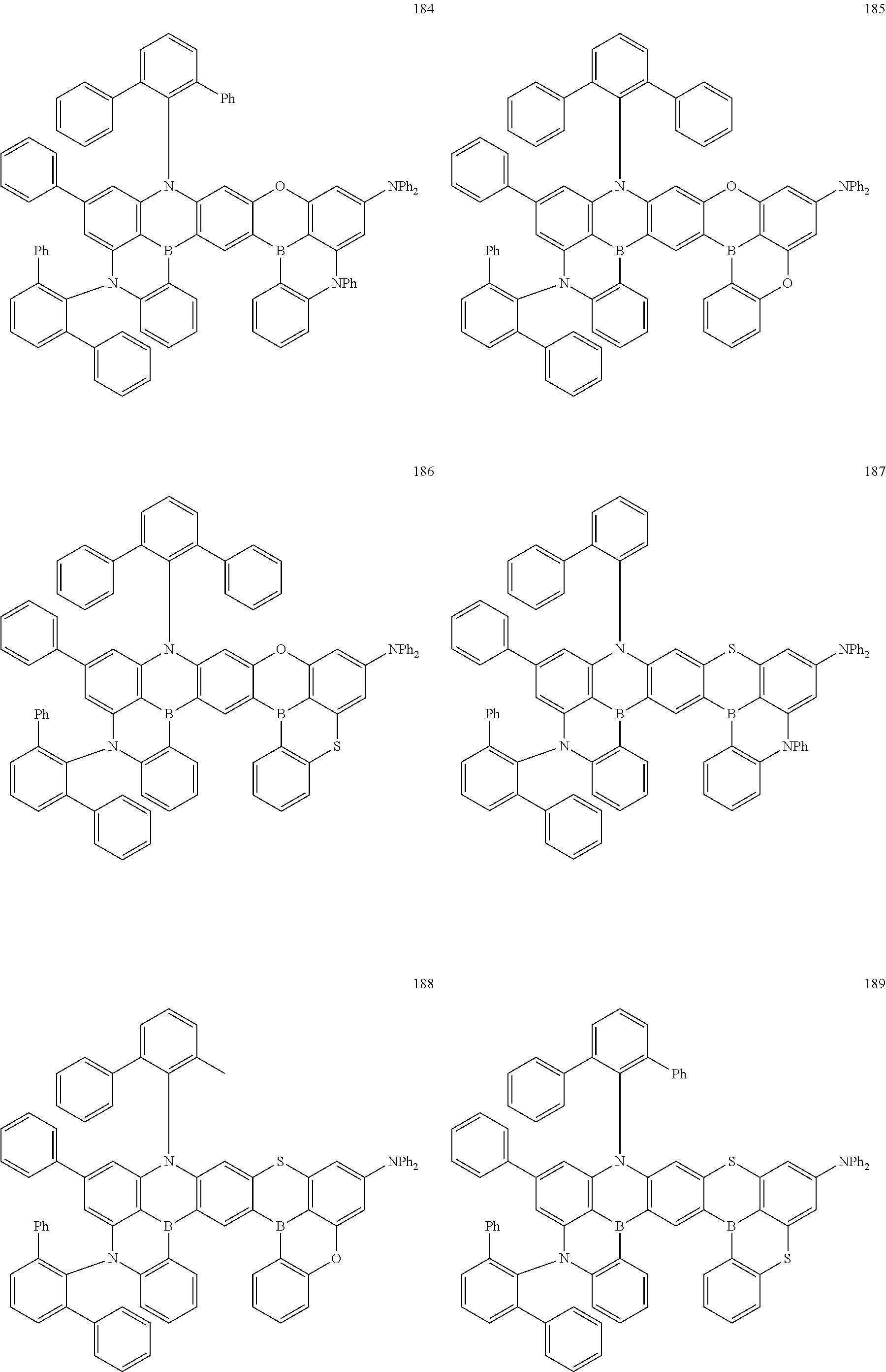

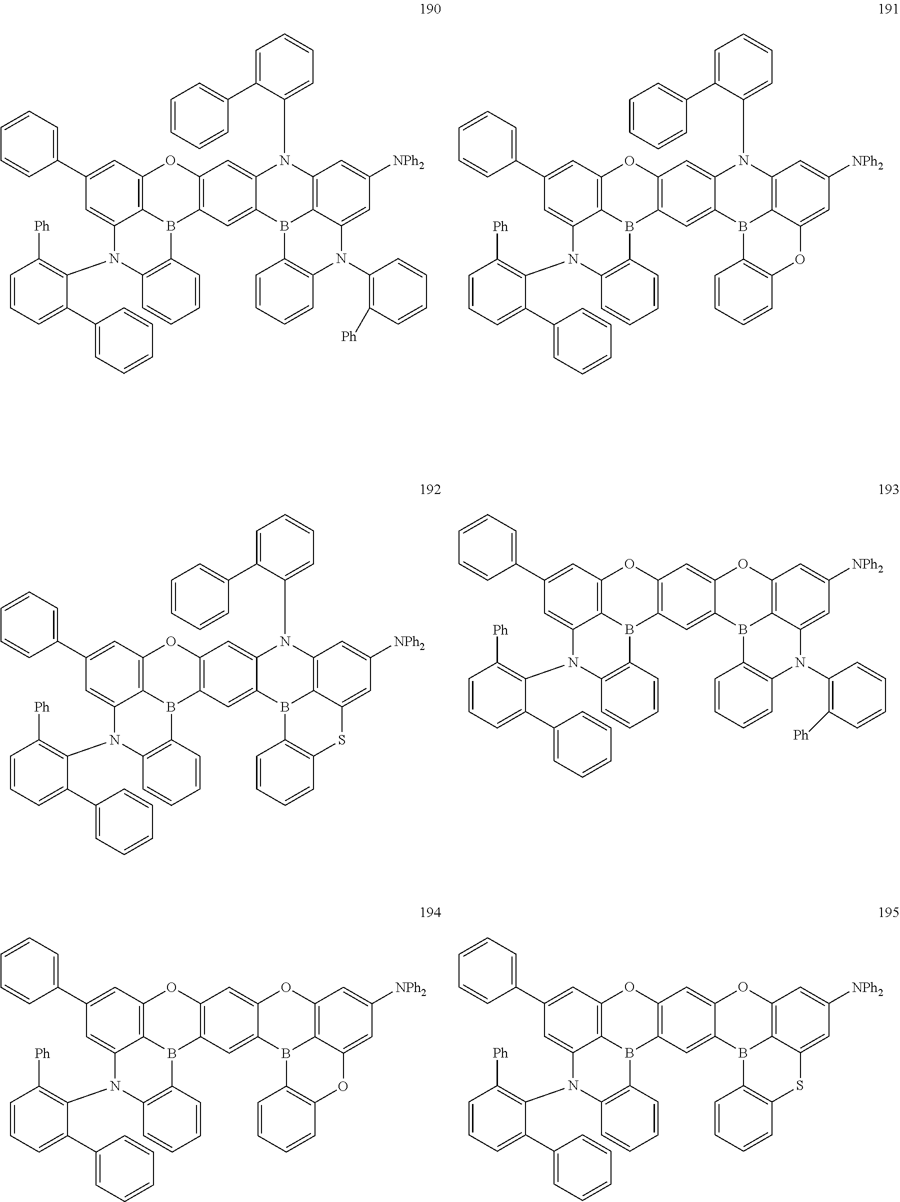

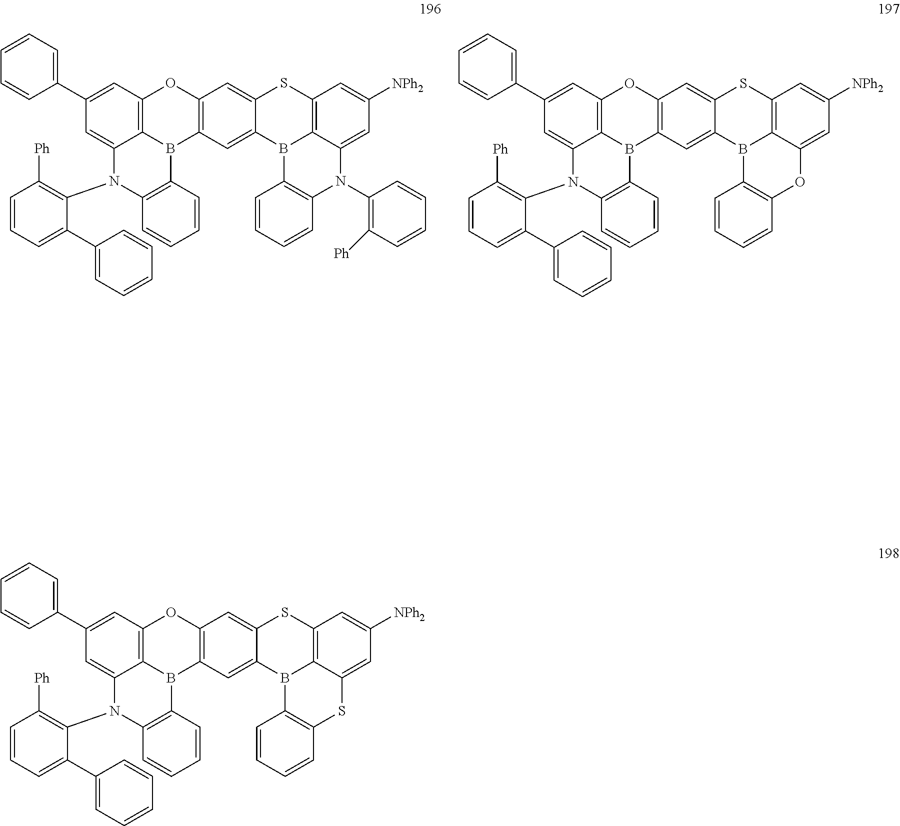

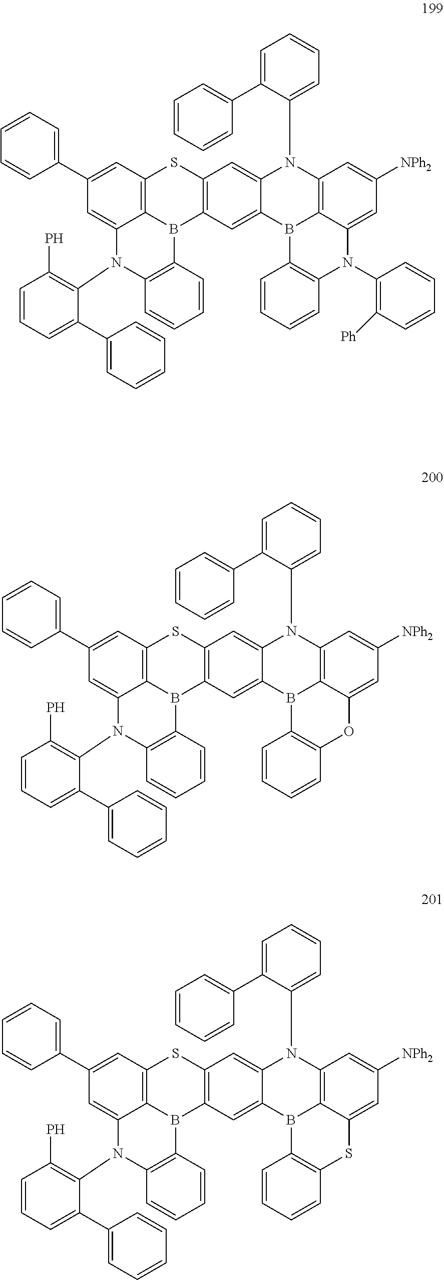

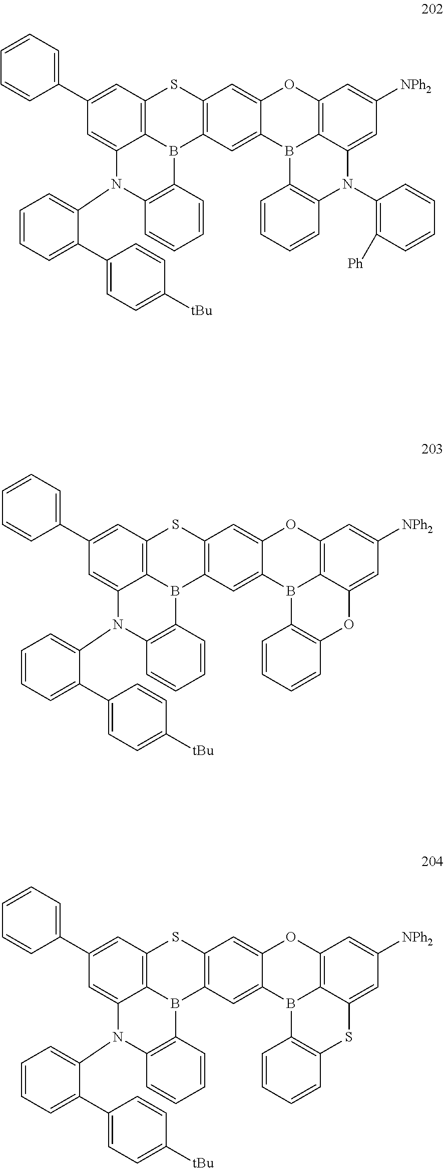

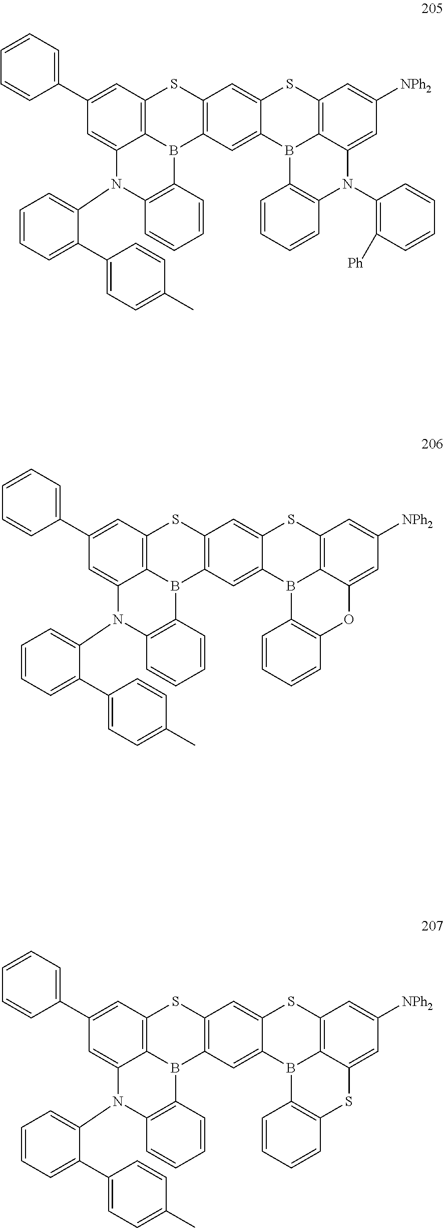

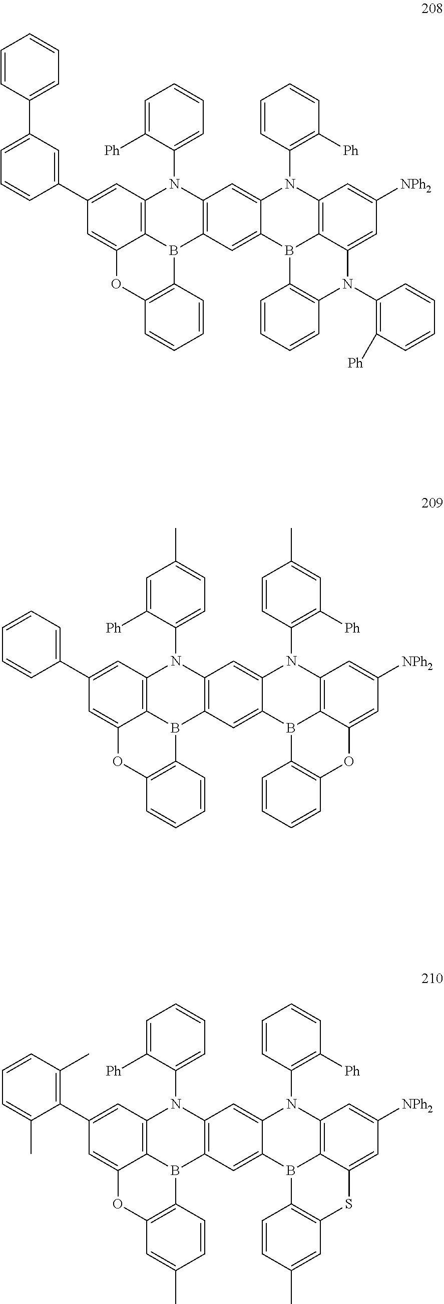

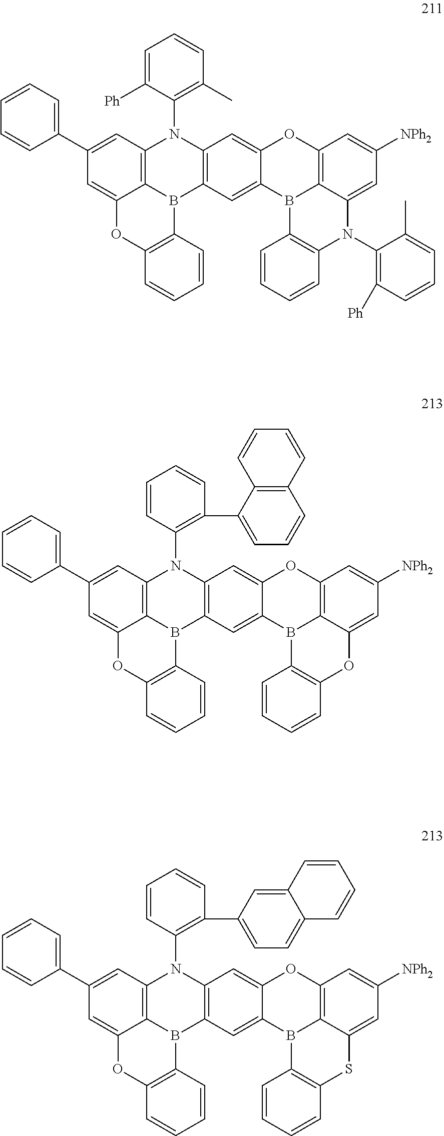

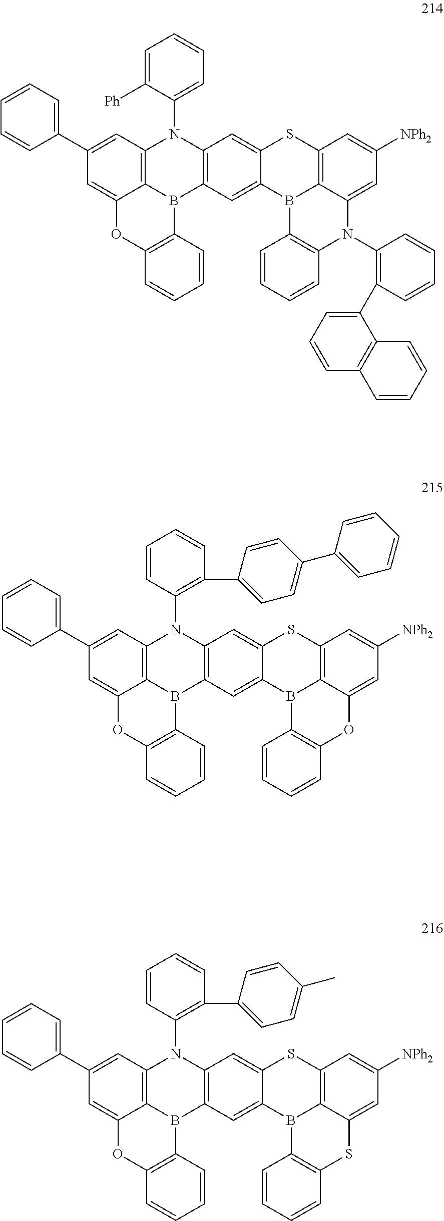

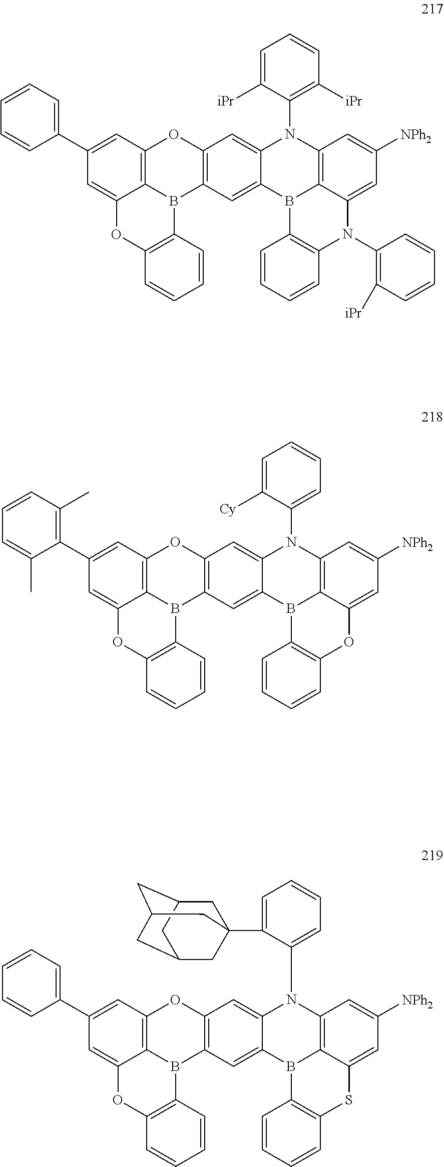

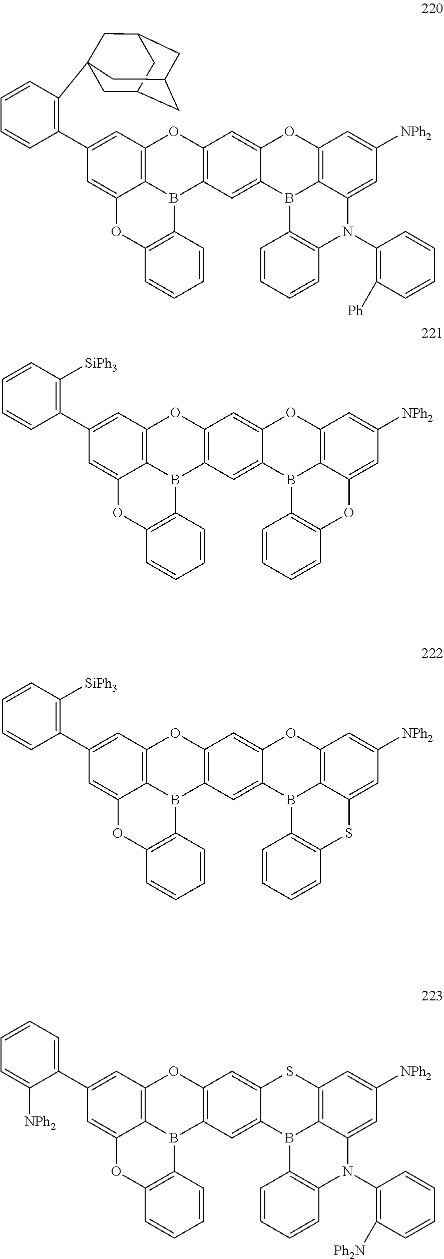

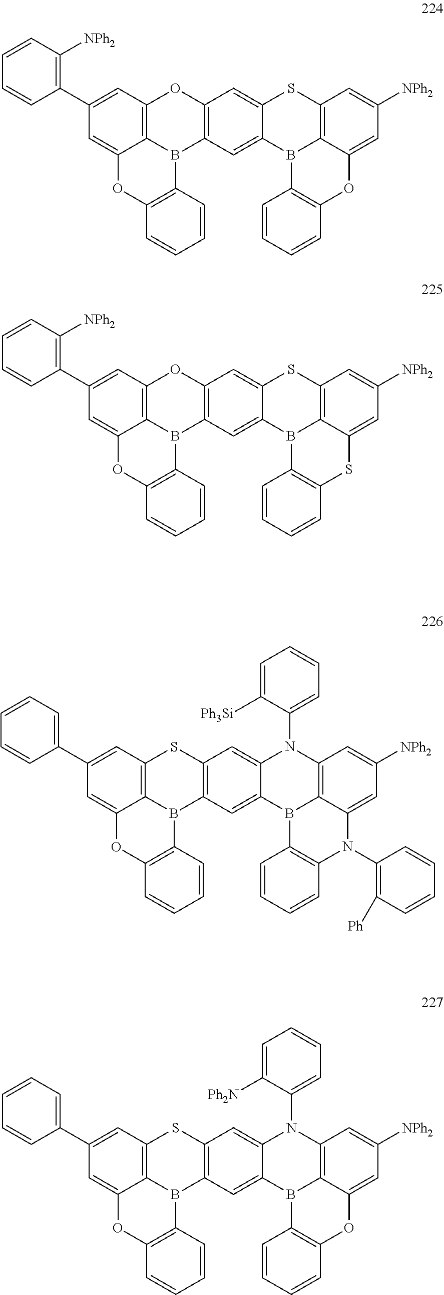

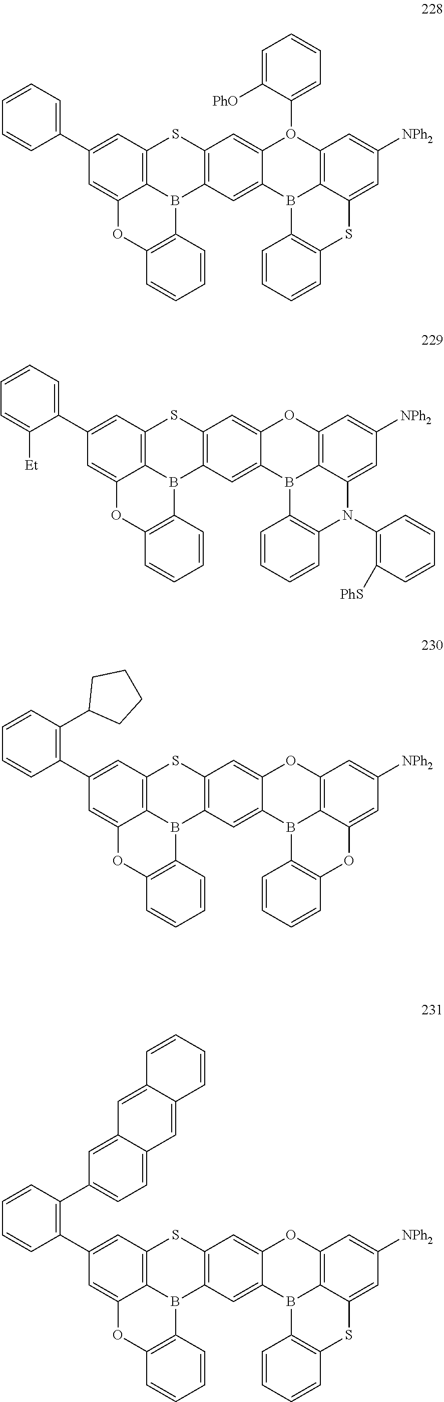

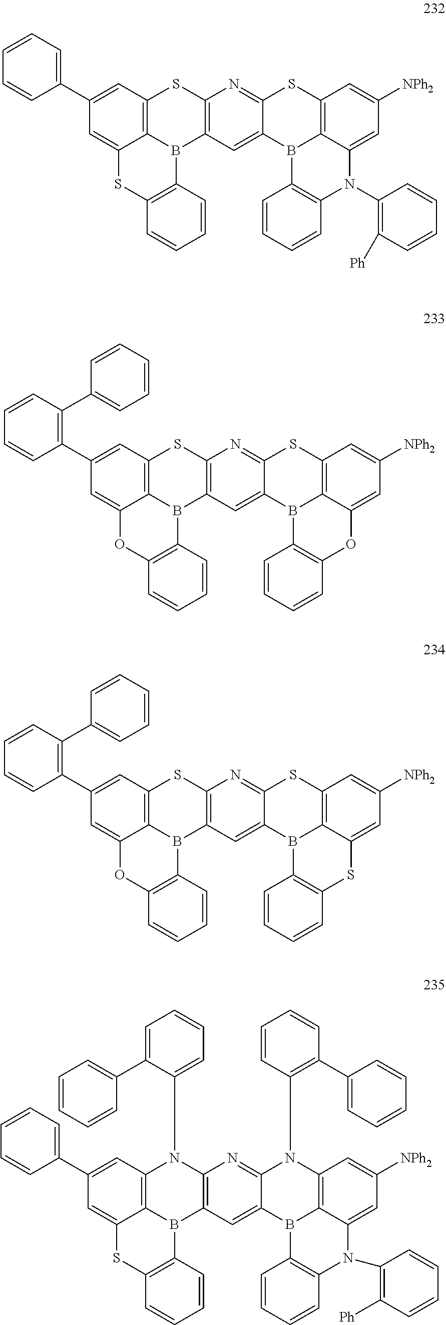

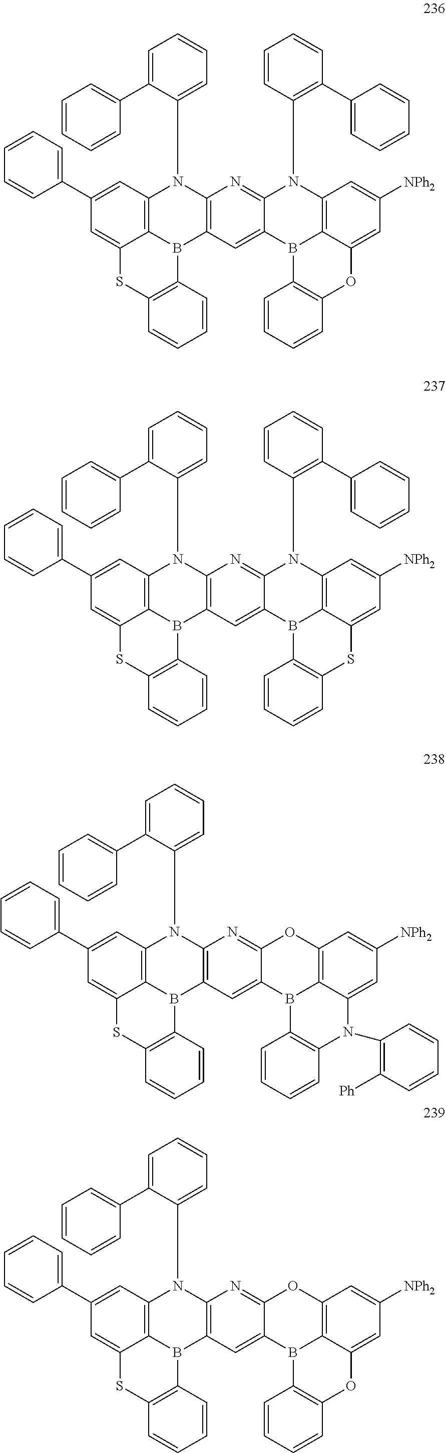

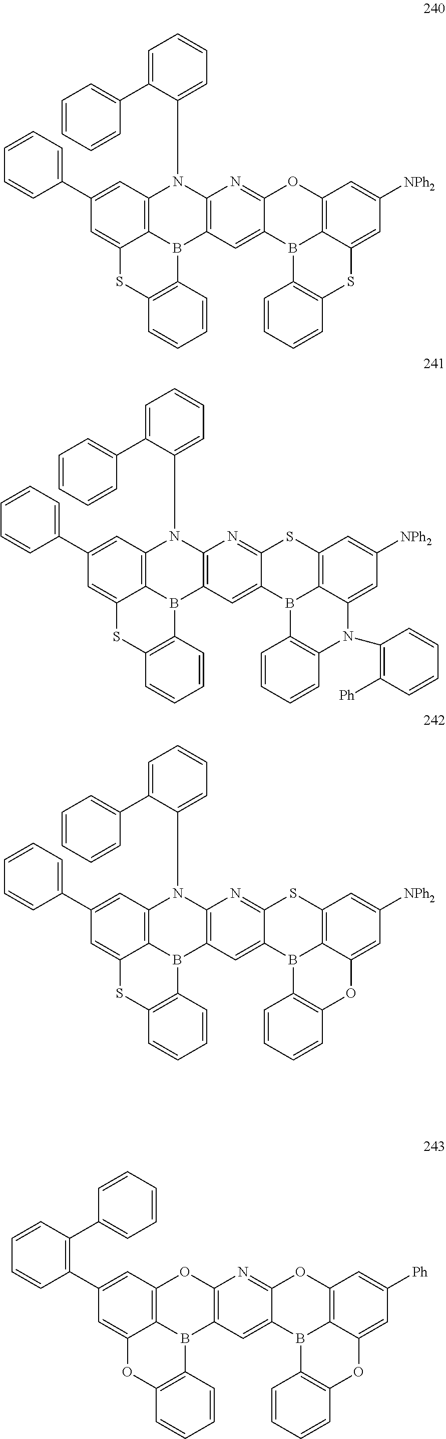

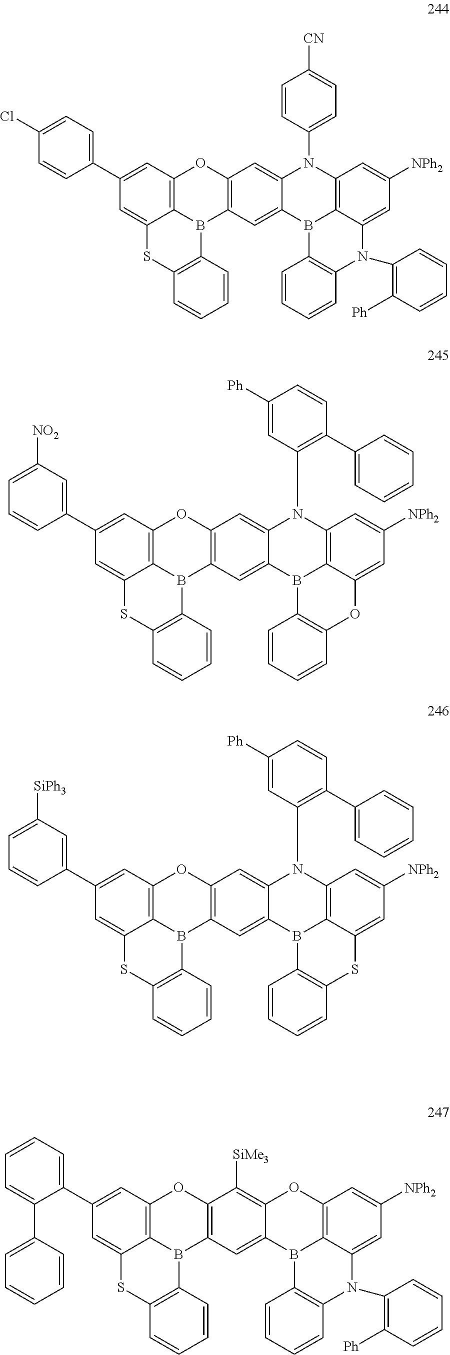

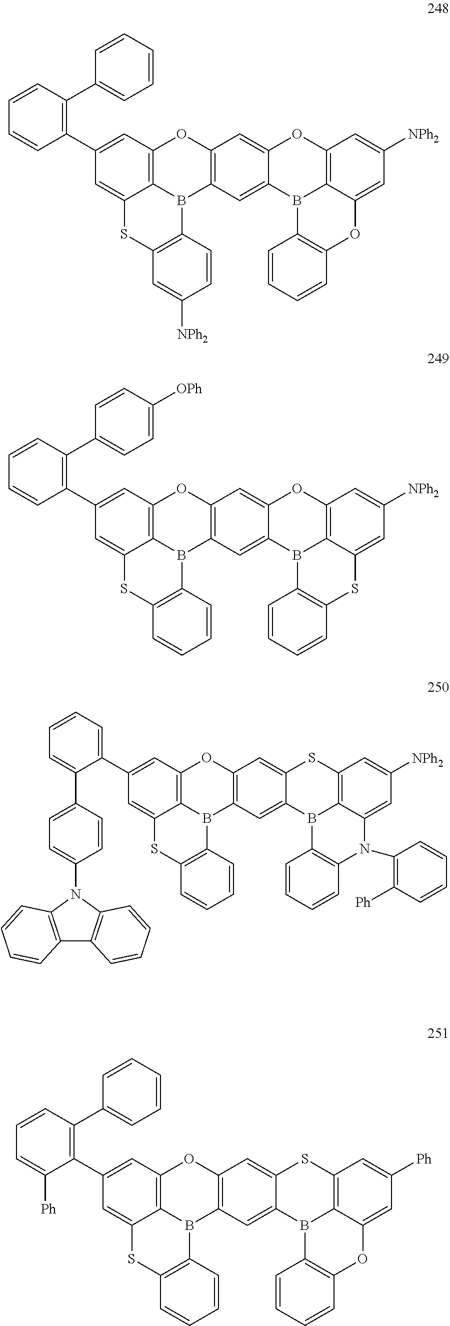

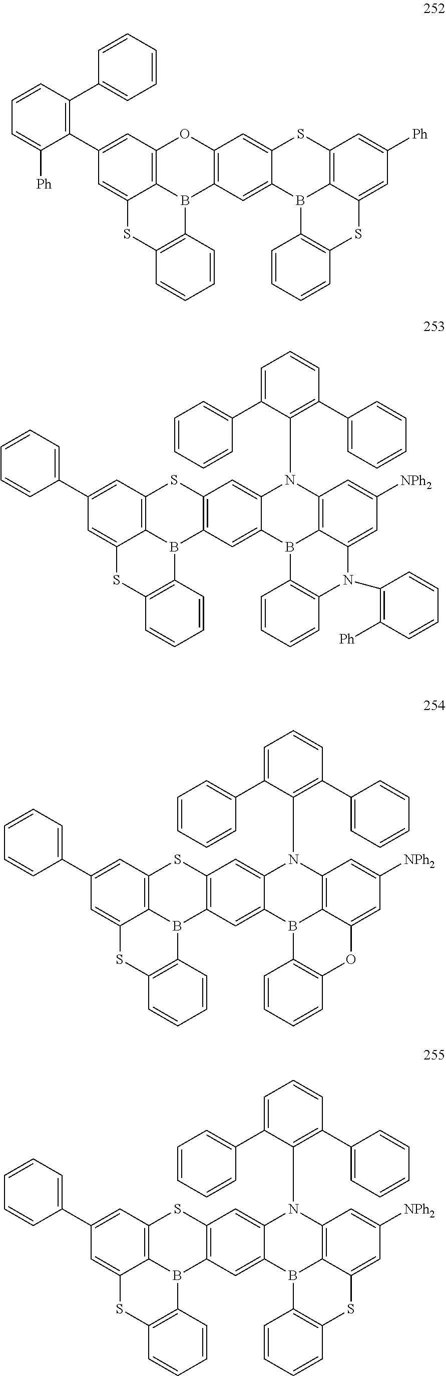

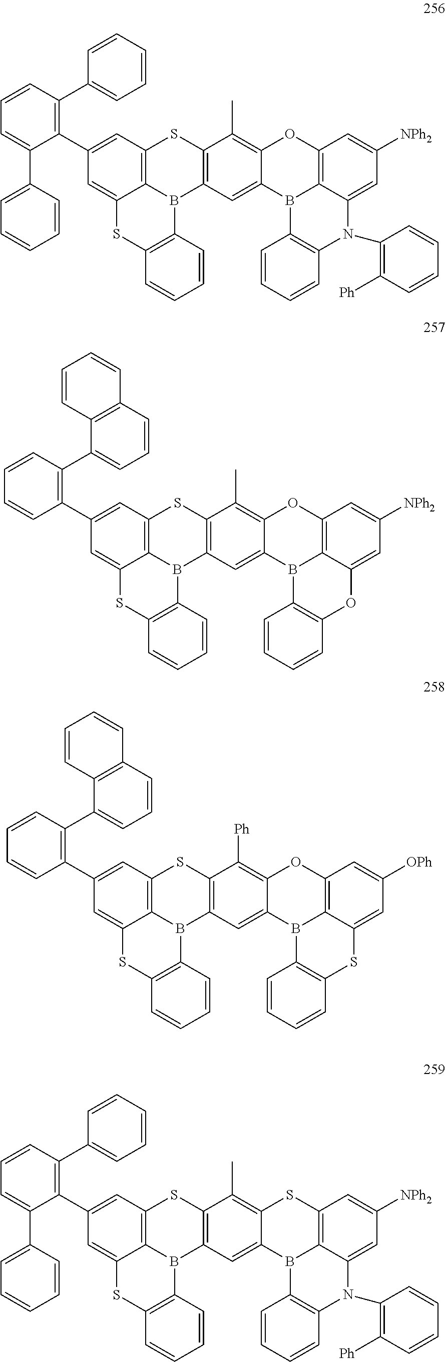

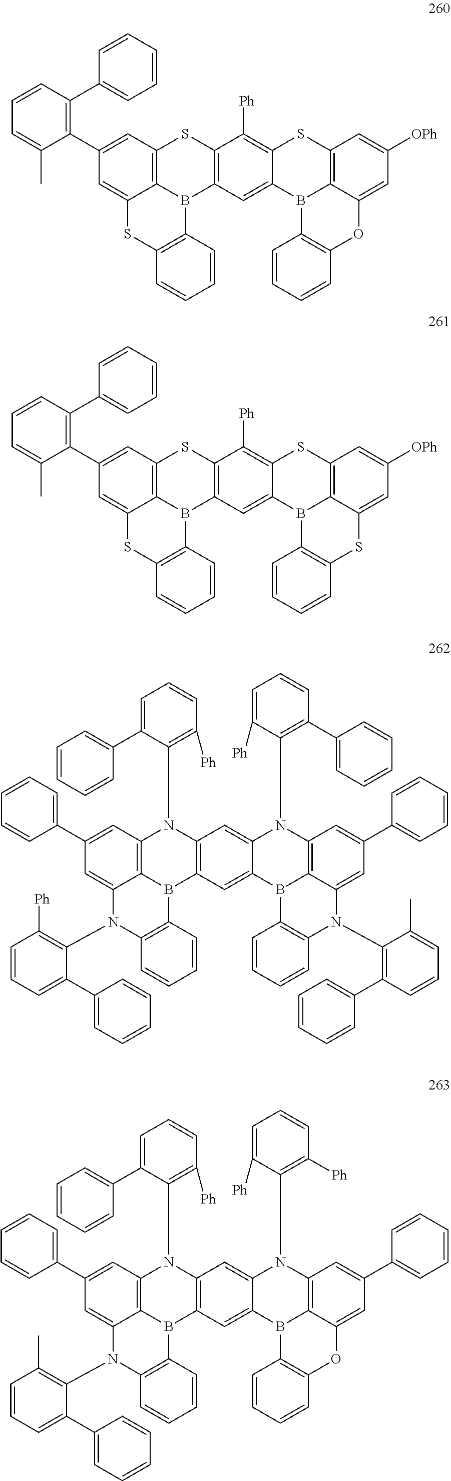

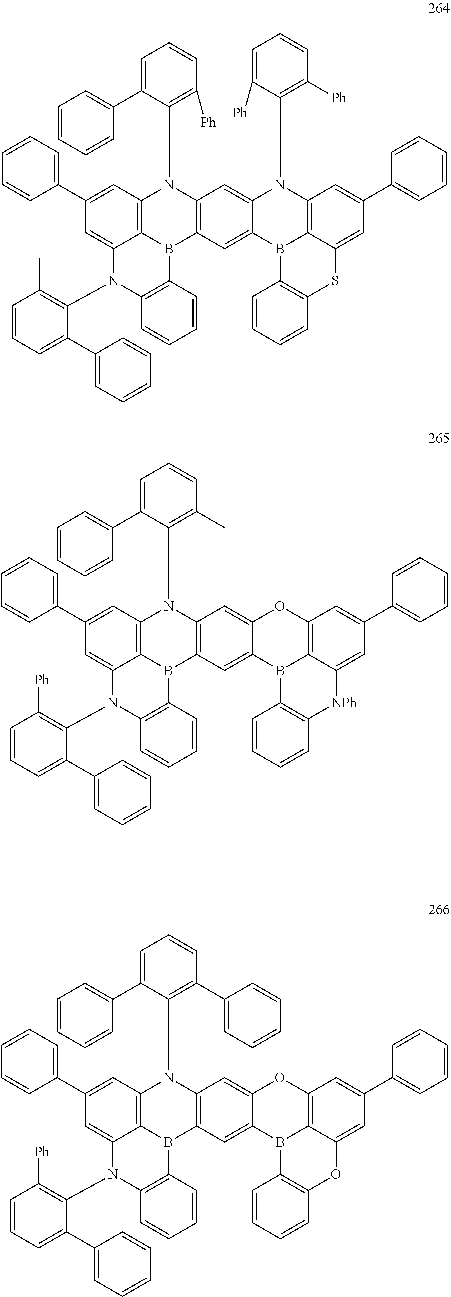

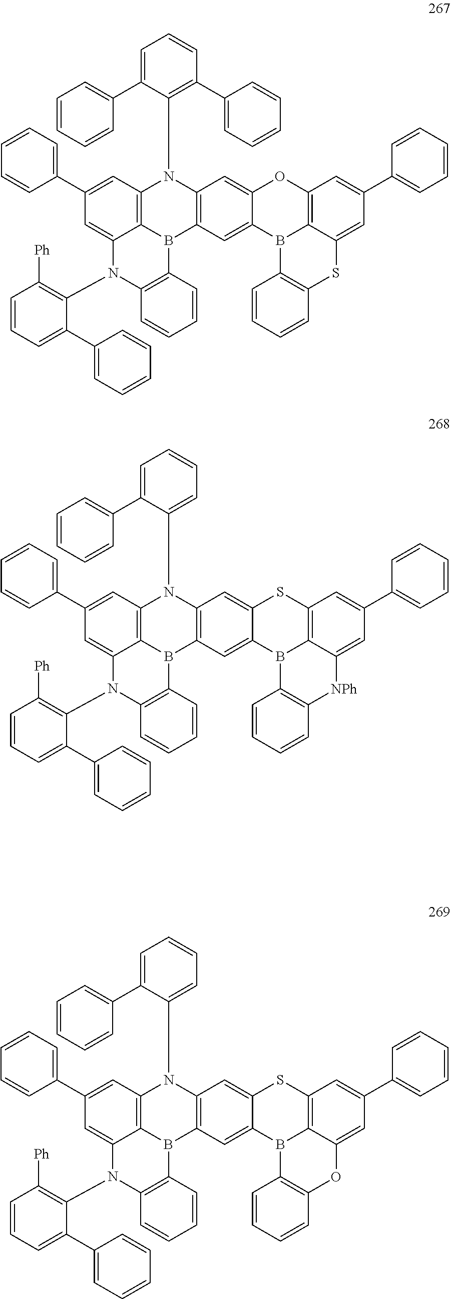

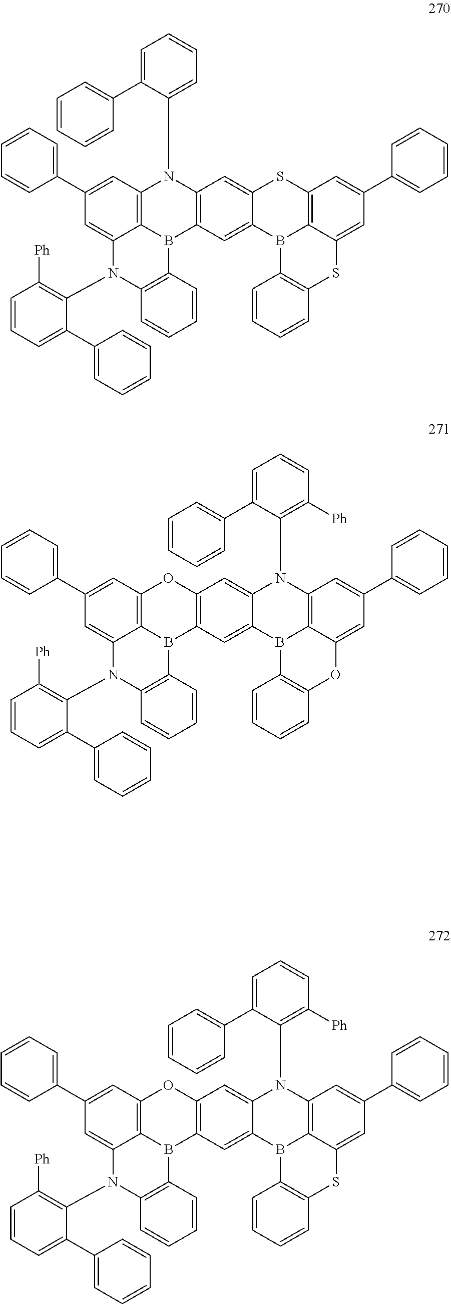 [SMILES: c1ccc(-c2cc3c4c(c2)Sc2cc5c(cc2B4c2ccccc2S3)B2c3ccccc3N(c3c(-c4ccccc4)cccc3-c3ccccc3)c3cc(-c4ccccc4)cc(c32)N5c2ccccc2-c2ccccc2)cc1 ; c1ccc(-c2cc3c4c(c2)N(c2c(-c5ccccc5)cccc2-c2ccccc2)c2ccccc2B4c2cc4c(cc2O3)N(c2c(-c3ccccc3)cccc2-c2ccccc2)c2cc(-c3ccccc3)cc3c2B4c2ccccc2O3)cc1 ; c1ccc(-c2cc3c4c(c2)N(c2c(-c5ccccc5)cccc2-c2ccccc2)c2ccccc2B4c2cc4c(cc2O3)N(c2c(-c3ccccc3)cccc2-c2ccccc2)c2cc(-c3ccccc3)cc3c2B4c2ccccc2S3)cc1]

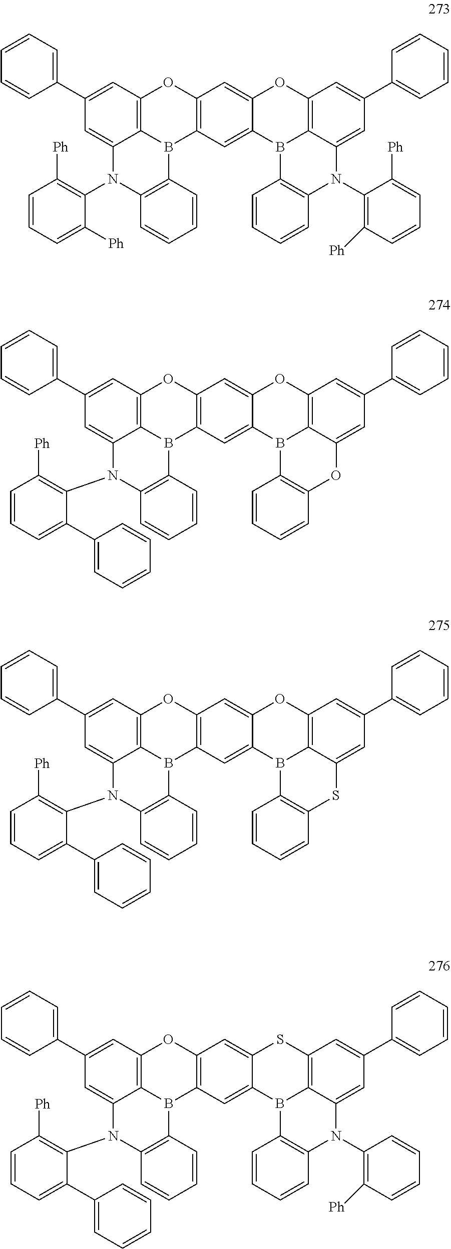 [SMILES: c1ccc(-c2cc3c4c(c2)N(c2c(-c5ccccc5)cccc2-c2ccccc2)c2ccccc2B4c2cc4c(cc2O3)Oc2cc(-c3ccccc3)cc3c2B4c2ccccc2N3c2c(-c3ccccc3)cccc2-c2ccccc2)cc1 ; c1ccc(-c2cc3c4c(c2)Oc2cc5c(cc2B4c2ccccc2O3)B2c3ccccc3N(c3c(-c4ccccc4)cccc3-c3ccccc3)c3cc(-c4ccccc4)cc(c32)O5)cc1 ; c1ccc(-c2cc3c4c(c2)Sc2ccccc2B4c2cc4c(cc2O3)Oc2cc(-c3ccccc3)cc3c2B4c2ccccc2N3c2c(-c3ccccc3)cccc2-c2ccccc2)cc1 ; c1ccc(-c2cc3c4c(c2)N(c2c(-c5ccccc5)cccc2-c2ccccc2)c2ccccc2B4c2cc4c(cc2O3)Sc2cc(-c3ccccc3)cc3c2B4c2ccccc2N3c2ccccc2-c2ccccc2)cc1]

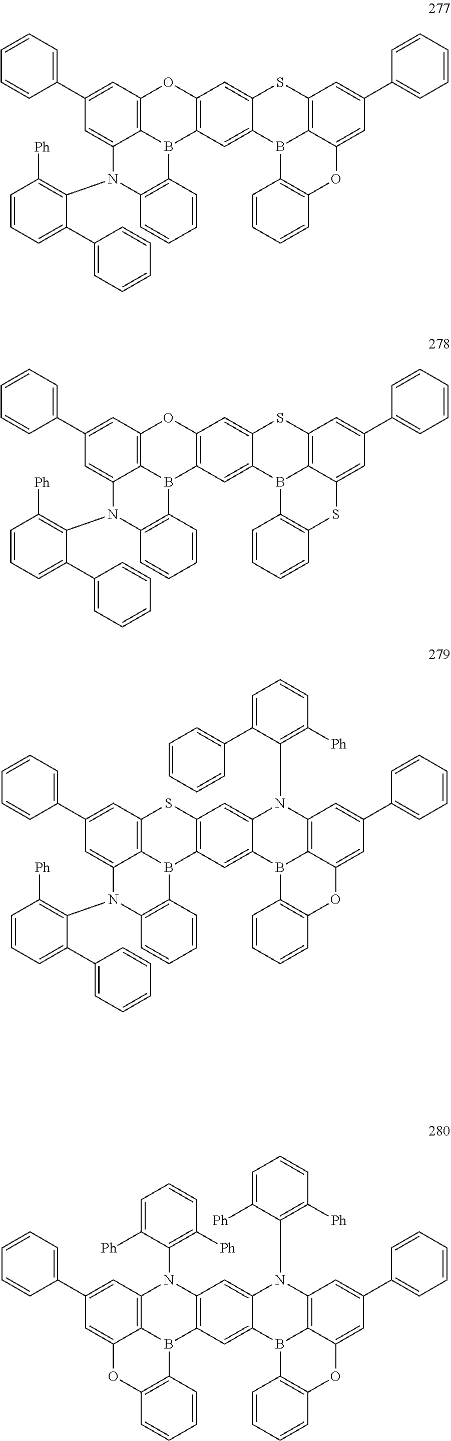

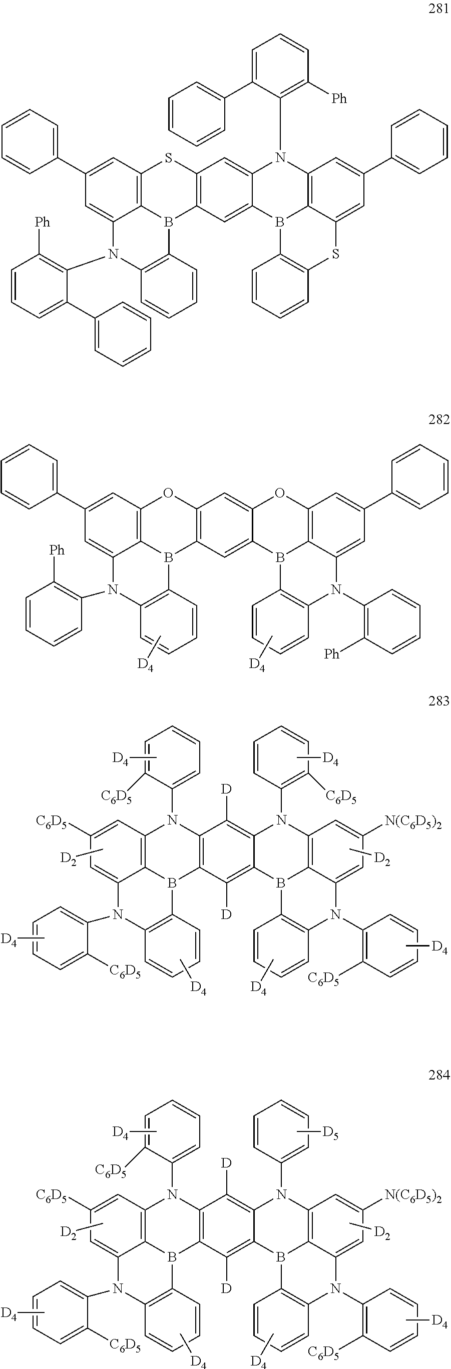

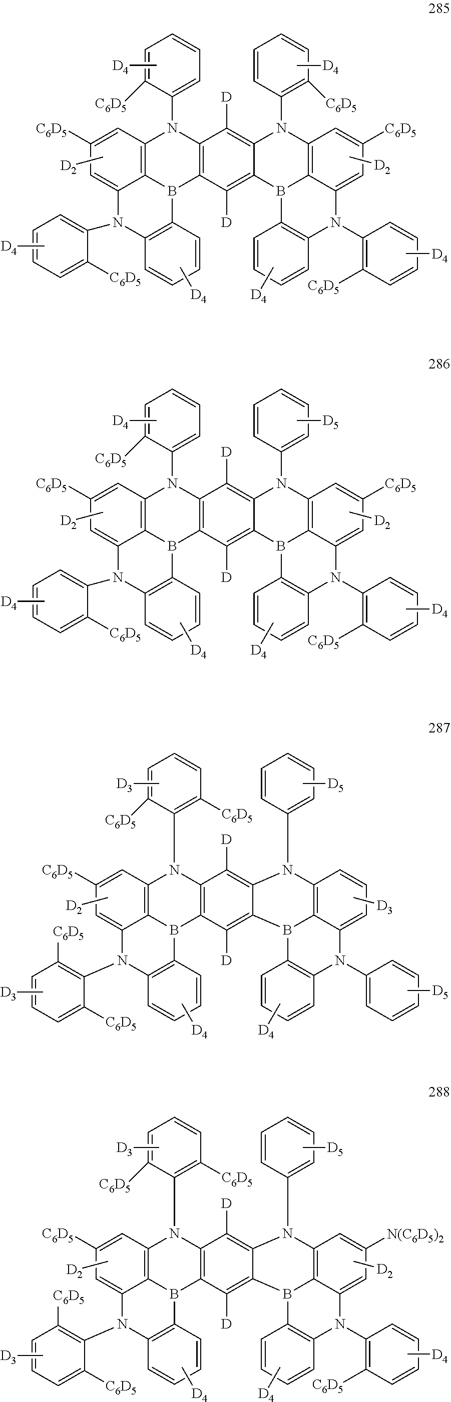

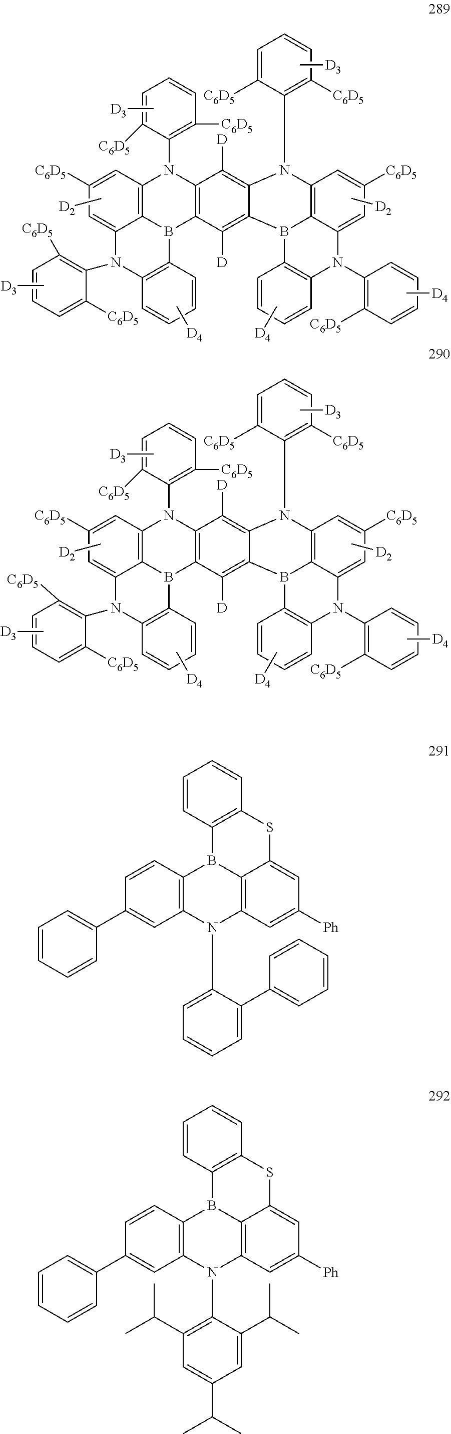

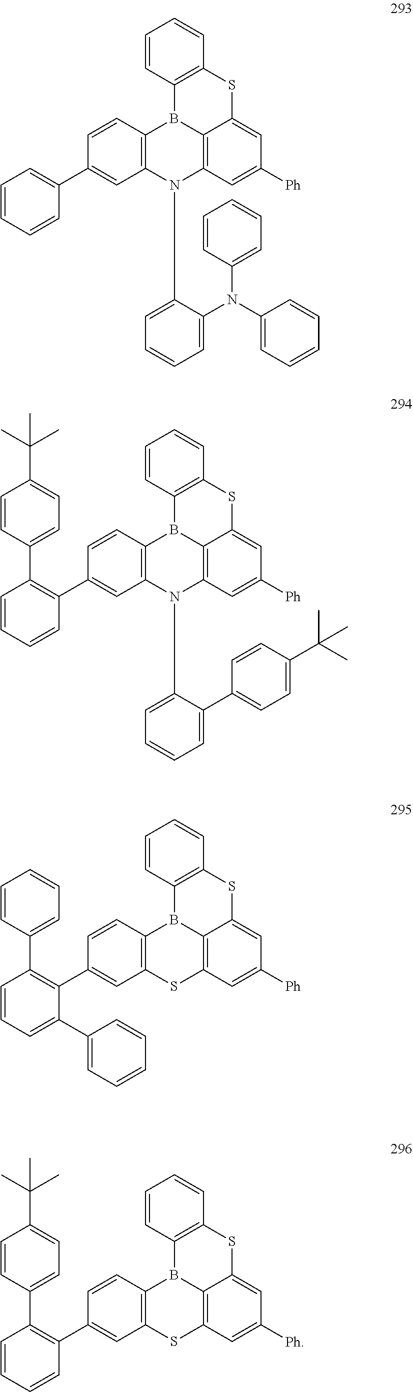 [SMILES: c1ccc(-c2ccc3c(c2)N(c2ccccc2N(c2ccccc2)c2ccccc2)c2cc(-c4ccccc4)cc4c2B3c2ccccc2S4)cc1 ; CC(C)(C)c1ccc(-c2ccccc2-c2ccc3c(c2)N(c2ccccc2-c2ccc(C(C)(C)C)cc2)c2cc(-c4ccccc4)cc4c2B3c2ccccc2S4)cc1 ; c1ccc(-c2cc3c4c(c2)Sc2cc(-c5c(-c6ccccc6)cccc5-c5ccccc5)ccc2B4c2ccccc2S3)cc1 ; CC(C)(C)c1ccc(-c2ccccc2-c2ccc3c(c2)Sc2cc(-c4ccccc4)cc4c2B3c2ccccc2S4)cc1]

11. A light emitting device comprising:
a first electrode;
a second electrode facing the first electrode; and
an emission layer disposed between the first electrode and the second electrode, wherein
the emission layer comprises a host and a delayed fluorescence dopant,
the host comprises a compound represented by Formula E-2a or Formula E-2b, and
the delayed fluorescence dopant comprises a fused polycyclic compound represented by Formula 1: 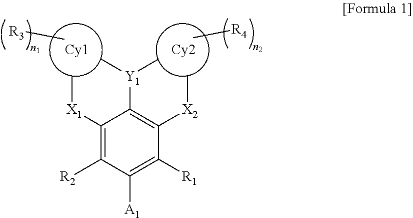
wherein in Formula 1,
Y₁ is P, B, or N,
X₁ and X₂ are each independently O, S, CR₅R₆, PR₇, SiR₈R₉, NR₁₀, or BR₁₁, or are represented by Formula 2,
Cy1 and Cy2 are each independently a substituted or unsubstituted monocyclic aromatic hydrocarbon ring having 6 to 30 ring-forming carbon atoms, or a substituted or unsubstituted monocyclic aromatic heterocycle having 2 to 30 ring-forming carbon atoms,
A₁ is a hydrogen atom, a deuterium atom, a substituted or unsubstituted amine group, a substituted or unsubstituted oxy group, a substituted or unsubstituted silyl group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or is represented by Formula 3,
R₁, R₂, and R₅ to R₁₁ are each independently a hydrogen atom, a deuterium atom, a halogen atom, a cyano group, a nitro group, a substituted or unsubstituted amine group, a substituted or unsubstituted silyl group, a substituted or unsubstituted boron group, a substituted or unsubstituted oxy group, a substituted or unsubstituted thio group, a substituted or unsubstituted phosphine group, a substituted or unsubstituted alkyl group having 1 to 30 carbon atoms, a substituted or unsubstituted alkenyl group having 2 to 30 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring,
R₃ and R₄ are each independently a hydrogen atom, a deuterium atom, a halogen atom, a cyano group, a nitro group, a substituted or unsubstituted amine group, a substituted or unsubstituted silyl group, a substituted or unsubstituted boron group, a substituted or unsubstituted oxy group, a substituted or unsubstituted thio group, a substituted or unsubstituted phosphine group, a substituted or unsubstituted alkyl group having 1 to 30 carbon atoms, a substituted or unsubstituted alkenyl group having 2 to 30 carbon atoms, a substituted or unsubstituted aryl group having 6 to 60 ring-forming carbon atoms, or a substituted or unsubstituted heteroaryl group having 2 to 60 ring-forming carbon atoms, or are represented by Formula 3, or are bonded to an adjacent group to form a ring,
at least one of X₁ or X₂ is represented by Formula 2, or at least one of A₁, R₃, or R₄ is represented by Formula 3, or at least one of X₁ or X₂ is represented by Formula 2, and at least one of A₁, R₃, or R₄ is represented by Formula 3,
when each of R₃ and R₄ is bonded to an adjacent group to form a ring, the formed ring does not include Si as a ring-forming atom,
when neither R₃ nor R₄ is bonded to an adjacent group to form a ring, at least one of X₁ or X₂ is S, and
n₁ and n₂ are each independently an integer of 0 to 4, 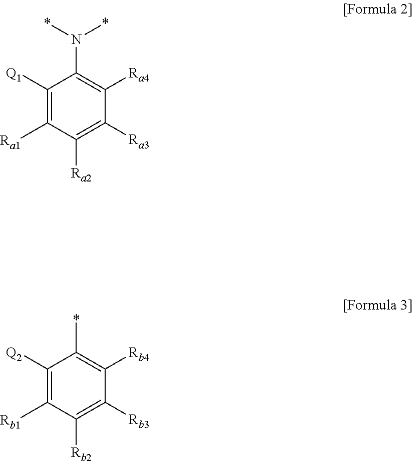
wherein in Formula 2 and Formula 3,
Q₁ and Q₂ are each independently a substituted or unsubstituted arylamine group, a substituted or unsubstituted arylsilyl group, a substituted or unsubstituted arylthio group, a substituted or unsubstituted aryloxy group, a substituted or unsubstituted alkyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and
Rₐ₁ to Rₐ₄ and R_{b1} to R_{b4} are each independently a hydrogen atom, a deuterium atom, a halogen atom, a cyano group, a nitro group, a substituted or unsubstituted amine group, a substituted or unsubstituted silyl group, a substituted or unsubstituted boron group, a substituted or unsubstituted oxy group, a substituted or unsubstituted thio group, a substituted or unsubstituted phosphine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, 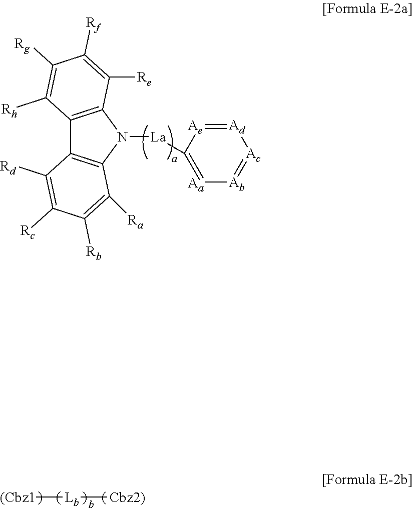
wherein in Formula E-2a,
a is an integer of 0 to 10,
Lₐ is a direct linkage, a substituted or unsubstituted arylene group having 6 to 30 ring-forming carbon atoms, or a substituted or unsubstituted heteroarylene group having 2 to 30 ring-forming carbon atoms,
Aₐ to Aₑ are each independently N or CRi,
Rₐ to Rᵢ are each independently a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring, and
two or three selected from among Aₐ to Aₑ are N, and the others are CRᵢ, and
wherein in Formula E-2b,
Cbz1 and Cbz2 are each independently an unsubstituted carbazole group, or a carbazole group substituted with an aryl group having 6 to 30 ring-forming carbon atoms,
L_{b} is a direct linkage, a substituted or unsubstituted arylene group having 6 to 30 ring-forming carbon atoms, or a substituted or unsubstituted heteroarylene group having 2 to 30 ring-forming carbon atoms, and
b is an integer of 0 to 10.

12. The light emitting device of claim 11, wherein when at least one of X₁ or X₂ is represented by Formula 2, the at least one of X₁ or X₂ represented by Formula 2 is represented by Formula 2-1 or Formula 2-2: 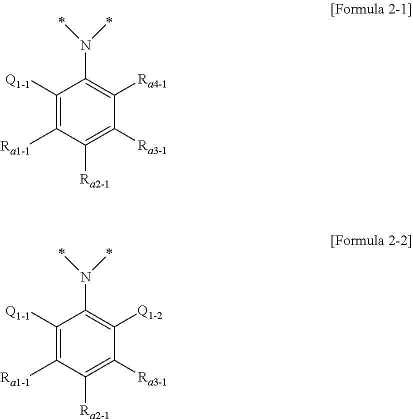
wherein in Formula 2-1 and Formula 2-2,
Q₁₋₁ and Q₁₋₂ are each independently a substituted or unsubstituted arylamine group, a substituted or unsubstituted arylsilyl group, a substituted or unsubstituted arylthio group, a substituted or unsubstituted aryloxy group, a substituted or unsubstituted alkyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and
Rₐ₁₋₁ to Rₐ₄₋₁ are each independently a hydrogen atom, a deuterium atom, a substituted or unsubstituted alkyl group having 1 to 20 carbon atoms, or a substituted or unsubstituted aryl group having 6 to 30 ring-forming carbon atoms.

13. The light emitting device of claim 11, wherein when A₁ is represented by Formula 3, A₁ is represented by one of Formula 3-1 to 3-5: 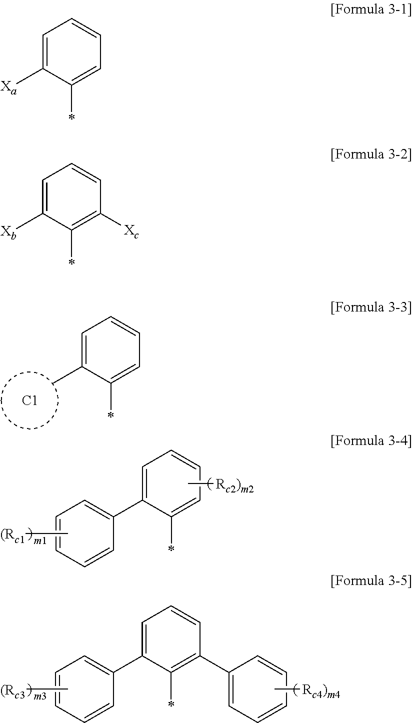
wherein in Formula 3-1 to Formula 3-5,
Xₐ to X_{c} are each independently NR_{c5}R_{c6}, SR_{c7}, OR_{c8}, SiR_{c9}R_{c10}R_{c11}, or a substituted or unsubstituted alkyl group having 2 to 10 carbon atoms,
C1 is a substituted or unsubstituted cycloalkyl group having 3 to 10 carbon atoms,
R_{c1} to R_{c4} are each independently a hydrogen atom, a deuterium atom, a halogen atom, a substituted or unsubstituted alkyl group having 1 to 20 carbon group, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring,
R_{c5} to R_{c11} are each independently a substituted or unsubstituted phenyl group,
m1, m3 and m4 are each independently an integer of 0 to 5, and
m2 is an integer of 0 to 4.

14. The light emitting device of claim 11, wherein the fused polycyclic compound represented by Formula 1 is represented by Formula 1-1: 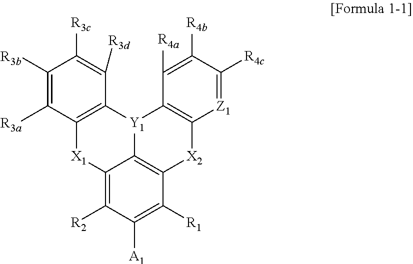
wherein in Formula 1-1,
Z₁ is CR_{4d} or N,
R₃ₐ to R_{3d}, and R₄ₐ to R_{4d} are each independently a hydrogen atom, a deuterium atom, a halogen atom, a cyano group, a nitro group, a substituted or unsubstituted amine group, a substituted or unsubstituted silyl group, a substituted or unsubstituted boron group, a substituted or unsubstituted oxy group, a substituted or unsubstituted thio group, a substituted or unsubstituted phosphine group, a substituted or unsubstituted alkyl group having 1 to 30 carbon atoms, a substituted or unsubstituted alkenyl group having 2 to 30 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring,
at least one of X₁ or X₂ is represented by Formula 2, or at least one among A₁, R₃ₐ to R_{3d} and R₄ₐ to R_{4c} is represented by Formula 3, or at least one of X₁ or X₂ is represented by Formula 2, and at least one among A₁, R₃ₐ to R_{3d} and R₄ₐ to R_{4c} is represented by Formula 3,
when each of R₃ₐ to R_{3d} and R₄ₐ to R_{4c} is bonded to an adjacent group to form a ring, the formed ring does not include Si as a ring-forming atom,
when none of R₃ₐ to R_{3d} and R₄ₐ to R_{4c} is bonded to an adjacent group to form a ring, at least one of X₁ or X₂ is S, and
X₁, X₂, Y₁, A₁, R₁, and R₂ are the same as defined in Formula 1.

15. The light emitting device of claim 14, wherein the fused polycyclic compound represented by Formula 1-1 is represented by Formula 1-2: 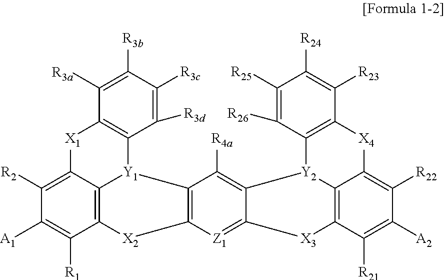
wherein in Formula 1-2,
Y₂ is P, B, or N,
X₃ and X₄ are each independently O, S, CR₂₇R₂₈, PR₂₉, NR₃₀, or BR₃₁, or are represented by Formula 2,
A₂ is a hydrogen atom, a deuterium atom, a substituted or unsubstituted amine group, a substituted or unsubstituted oxy group, a substituted or unsubstituted silyl group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or is represented by Formula 3,
R₂₁ and R₃₁ are each independently a hydrogen atom, a deuterium atom, a halogen atom, a cyano group, a nitro group, a substituted or unsubstituted amine group, a substituted or unsubstituted silyl group, a substituted or unsubstituted boron group, a substituted or unsubstituted oxy group, a substituted or unsubstituted thio group, a substituted or unsubstituted phosphine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring, and
X₁, X₂, Y₁, Z₁, A₁, R₁, R₂, R₃ₐ to R_{3d}, and R₄ₐ are the same as defined in Formula 1 and Formula 1-1.

16. The light emitting device of claim 15, wherein A₁ and A₂ are each independently a substituted or unsubstituted alkyl group having 1 to 10 carbon atoms, or are represented by Formula 3 or one of Formula 4-1 to Formula 4-5: 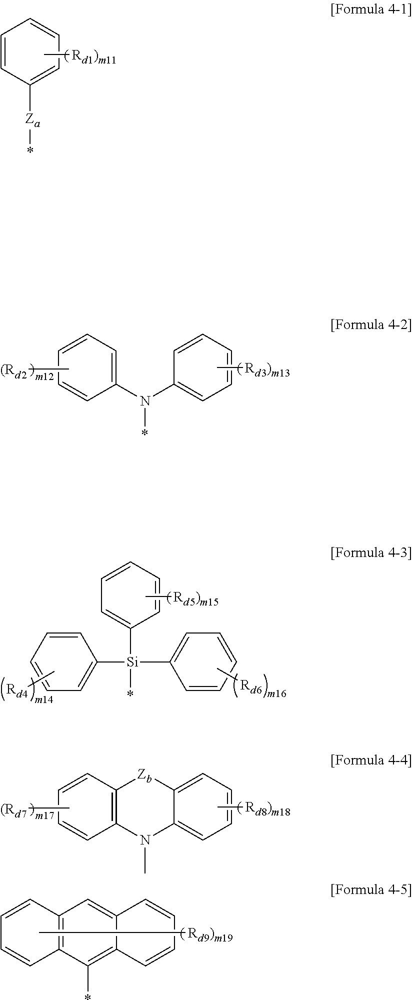
wherein in Formula 4-1 to Formula 4-5,
Zₐ is a direct linkage or O,
Z_{b} is a direct linkage, CR_{d10}R_{d11}, or SiR_{d12}R_{d13},
R_{d1} is a hydrogen atom, a deuterium atom, a halogen atom, a nitro group, a substituted or unsubstituted alkyl group having 1 to 10 carbon atoms, a substituted or unsubstituted silyl group, or a substituted or unsubstituted phenyl group,
R_{d2} to R_{d13} are each independently a hydrogen atom, a deuterium atom, a halogen atom, a substituted or unsubstituted alkyl group having 1 to 20 carbon group, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring,
m11 to m16 are each independently an integer of 0 to 5,
m17 and m18 are each independently an integer of 0 to 4, and
m19 is an integer of 0 to 9.

17. The light emitting device of claim 15, wherein the fused polycyclic compound represented by Formula 1-2 is represented by one of Formula 5-1 to Formula 5-10: 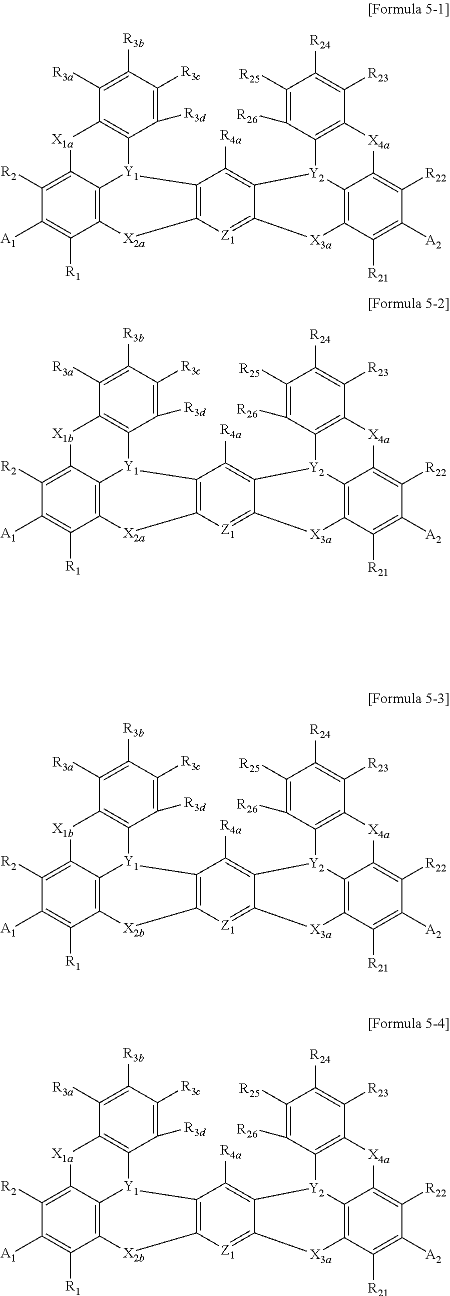 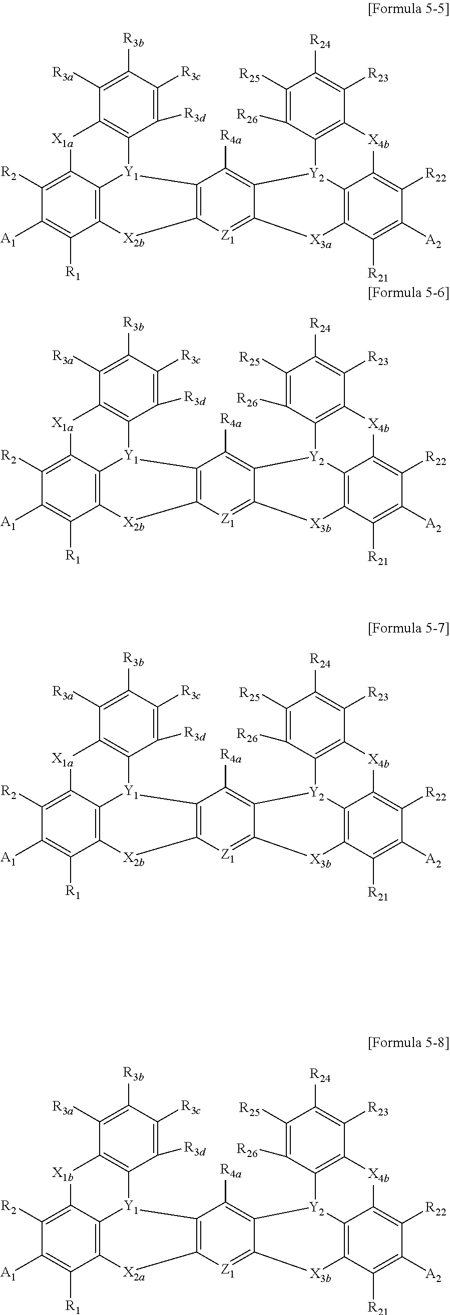 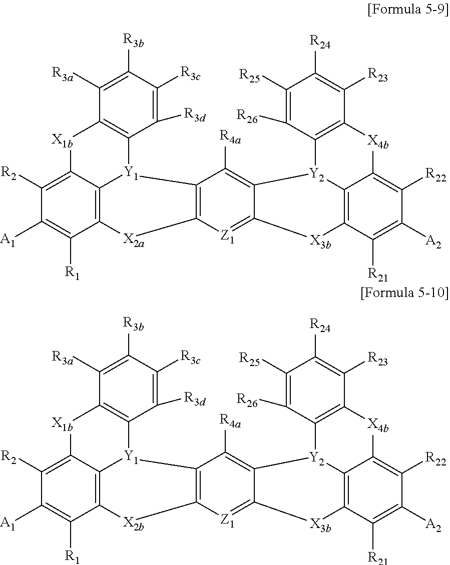
wherein in Formula 5-1 to Formula 5-10,
X₁ₐ to X₄ₐ are each independently represented by Formula 2,
X_{1b} to X_{4b} are each independently O, S, CR₄₁R₄₂, PR₄₃, NR₄₄, or BR₄₅,
R₄₁ to R₄₅ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
Z₁, A₁, A₂, Y₁, Y₂, R₁, R₂, R₃ₐ to R_{3d}, R₄ₐ, and R₂₁ to R₂₆ are the same as defined in Formula 1, Formula 1-1, and Formula 1-2.

18. The light emitting device of claim 15, wherein the fused polycyclic compound represented by Formula 1-2 is represented by one of Formula 6-1 to Formula 6-4: 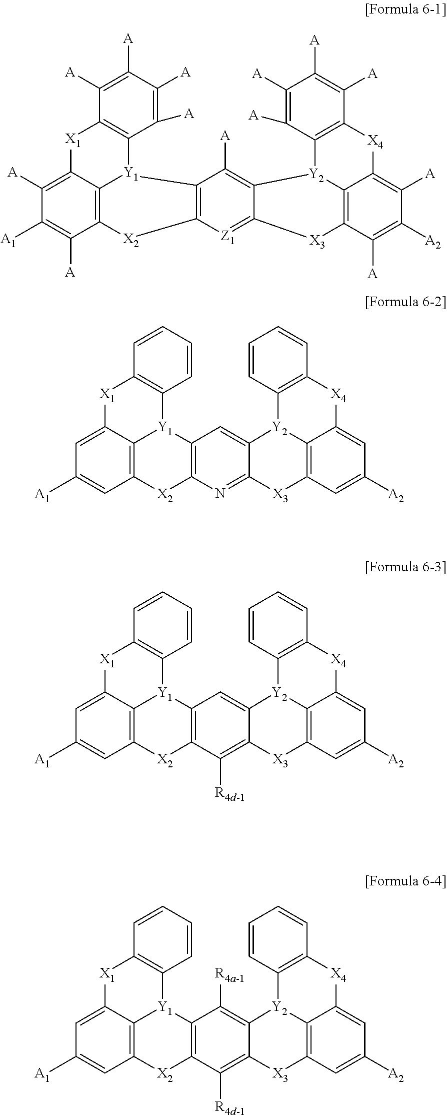
wherein in Formula 6-1 to Formula 6-4,
A is a hydrogen atom or a deuterium atom,
R₄ₐ₋₁ and R_{4d-1} are each independently a substituted or unsubstituted silyl group, a substituted or unsubstituted alkyl group having 1 to 20 carbon atoms, or a substituted or unsubstituted aryl group having 6 to 30 ring-forming carbon atoms, and
X₁ to X₄, Y₁, Y₂, A₁, and A₂ are the same as defined in Formula 1 and Formula 1-2.

19. The light emitting device of claim 15, wherein the fused polycyclic compound represented by Formula 1-2 is represented by one of Formula 7-1 to Formula 7-5: 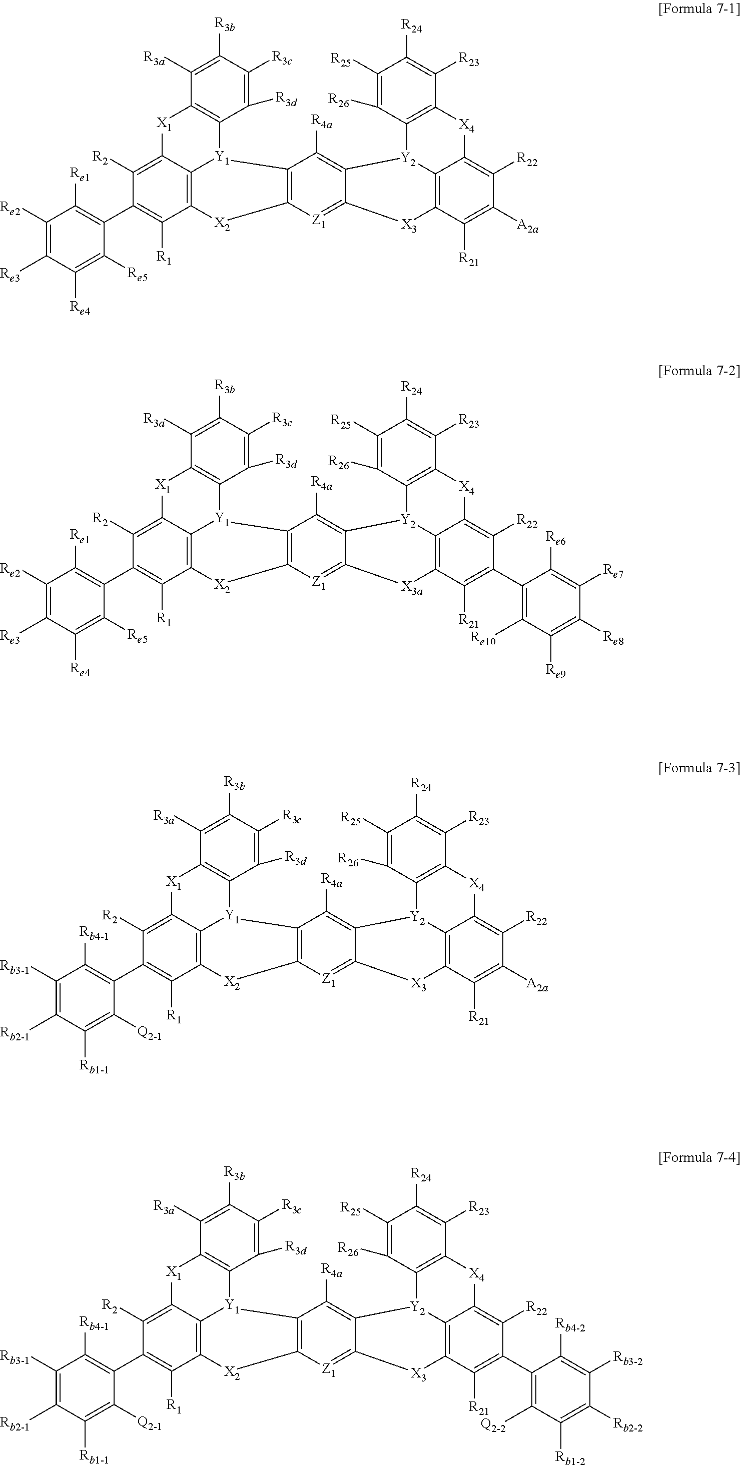
wherein in Formula 7-1 to Formula 7-4,
A₂ₐ is a hydrogen atom, a deuterium atom, a substituted or unsubstituted amine group, a substituted or unsubstituted oxy group, a substituted or unsubstituted silyl group, a substituted or unsubstituted alkyl group having 1 to 20 carbon atoms, or a substituted or unsubstituted heteroaryl group containing N as a ring-forming atom,
Rₑ₁ to Rₑ₁₀ are each independently a hydrogen atom, a deuterium atom, a halogen atom, a nitro group, a substituted or unsubstituted silyl group, a substituted or unsubstituted methyl group, a substituted or unsubstituted alkenyl group having 2 to 20 carbon atoms, or a substituted or unsubstituted phenyl group, or are bonded to an adjacent group to form a ring,
Q₂₋₁ and Q₂₋₂ are each independently a substituted or unsubstituted arylamine group, a substituted or unsubstituted arylsilyl group, a substituted or unsubstituted arylthio group, a substituted or unsubstituted aryloxy group, a substituted or unsubstituted alkyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms,
R_{b1-1} to R_{b4-1} and R_{b1-2} to R_{b4-2} are each independently a hydrogen atom, a deuterium atom, a substituted or unsubstituted alkyl group having 1 to 20 carbon atoms, or a substituted or unsubstituted aryl group having 6 to 30 ring-forming carbon atoms, and
X₁ to X₄, Y₁, Y₂, Z₁, R₁, R₂, R₃ₐ to R_{3d}, R₄ₐ, and R₂₁ to R₂₆ are the same as defined in Formula 1, Formula 1-1, and Formula 1-2.

20. The light emitting device of claim 11, wherein the fused polycyclic compound comprises at least one among compounds in Compound Group 1: 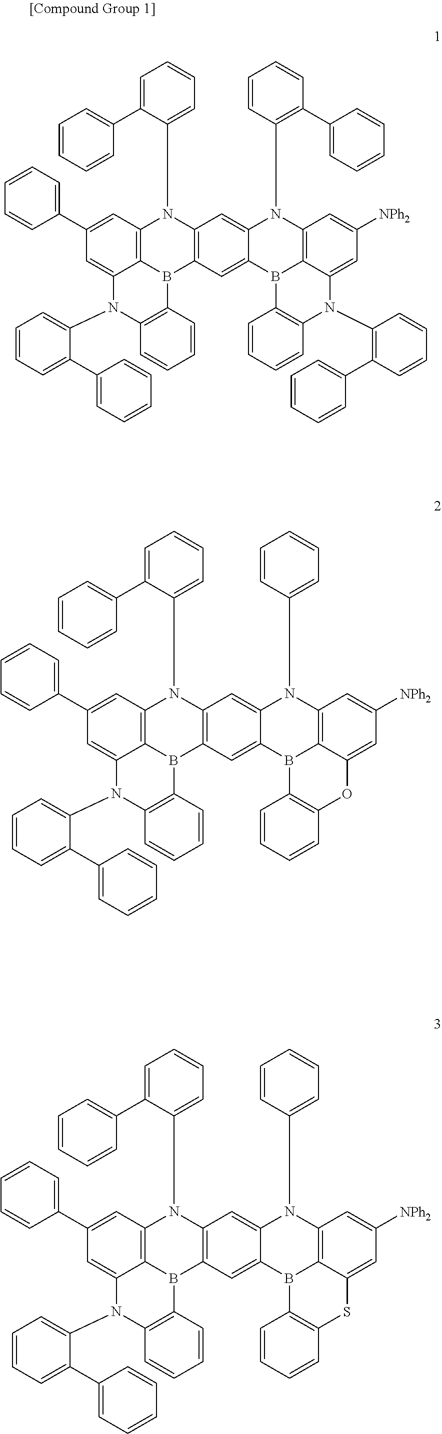 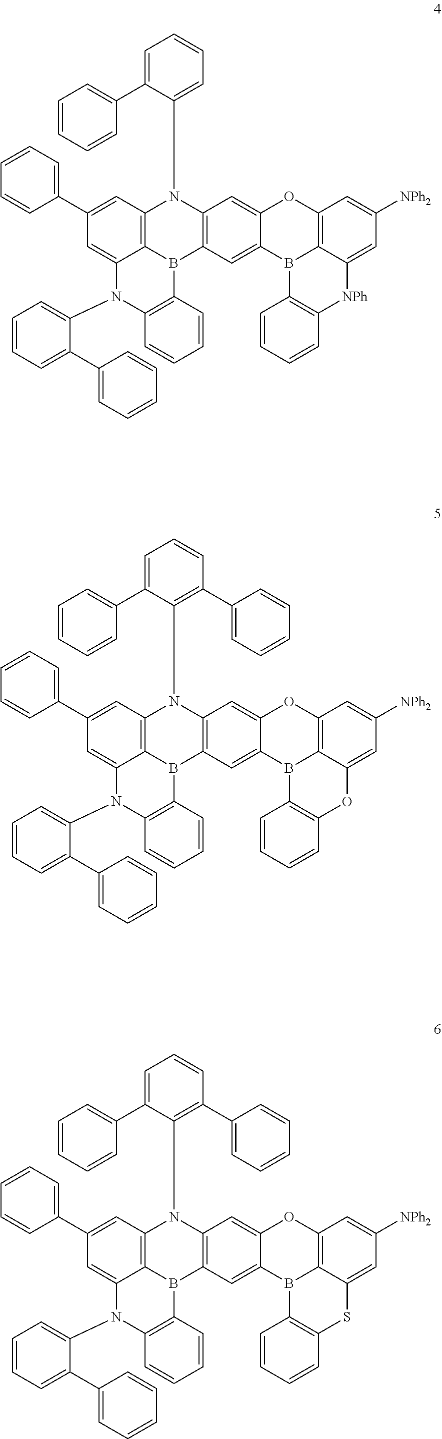 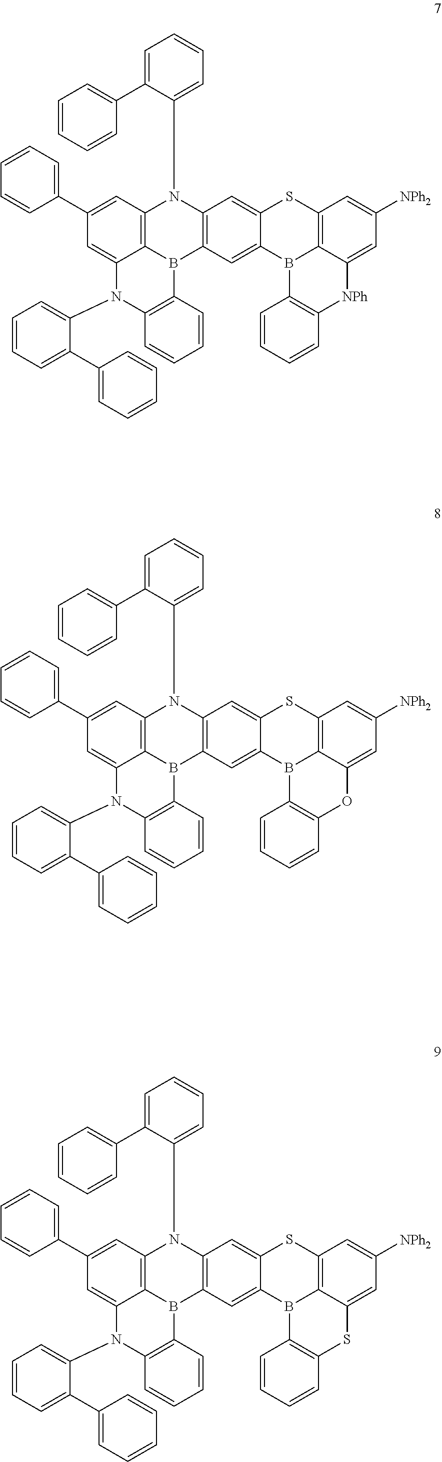 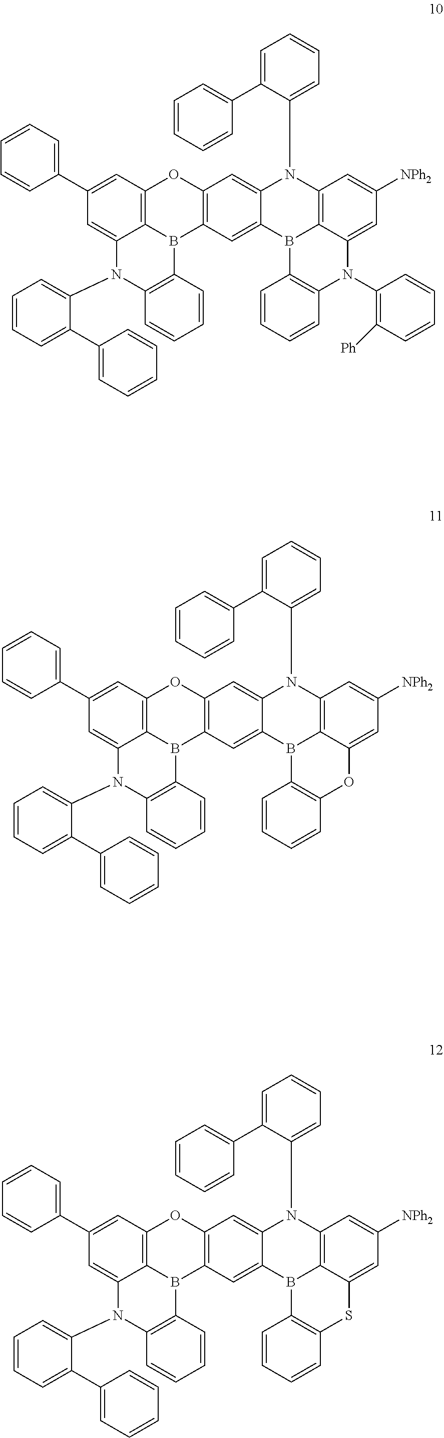 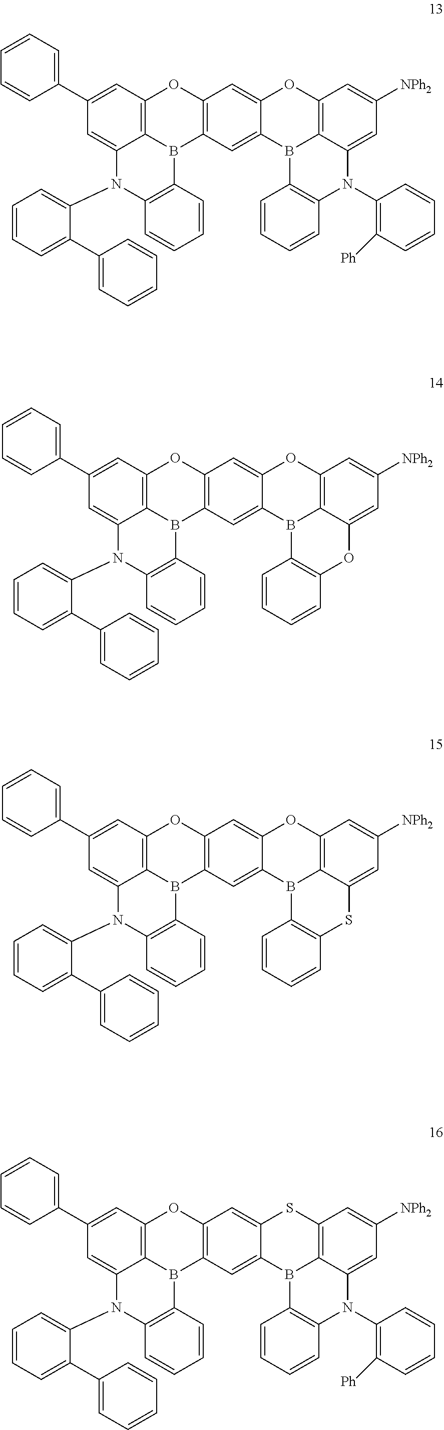 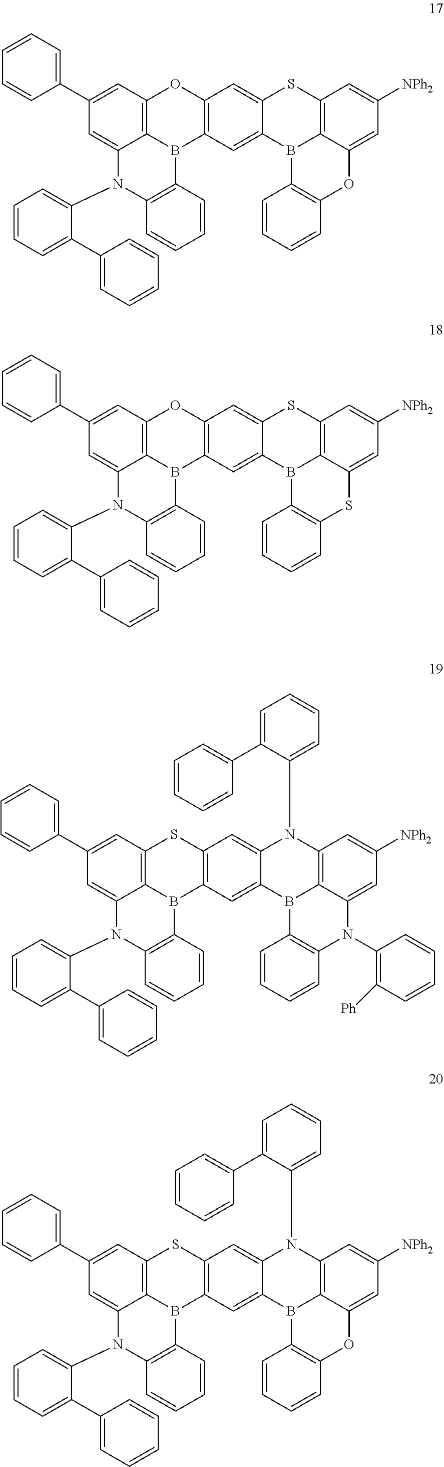 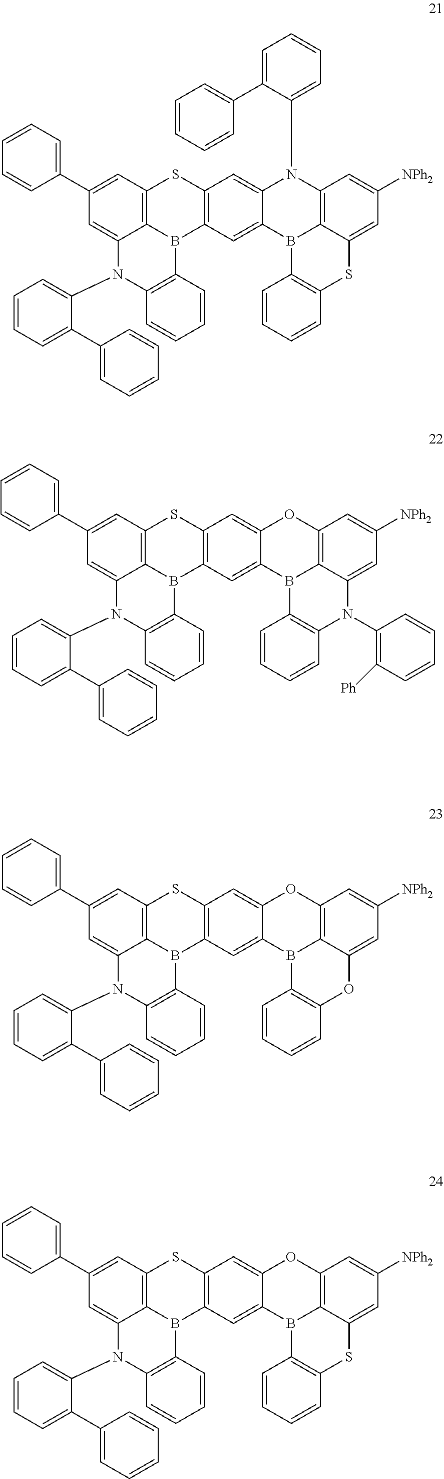 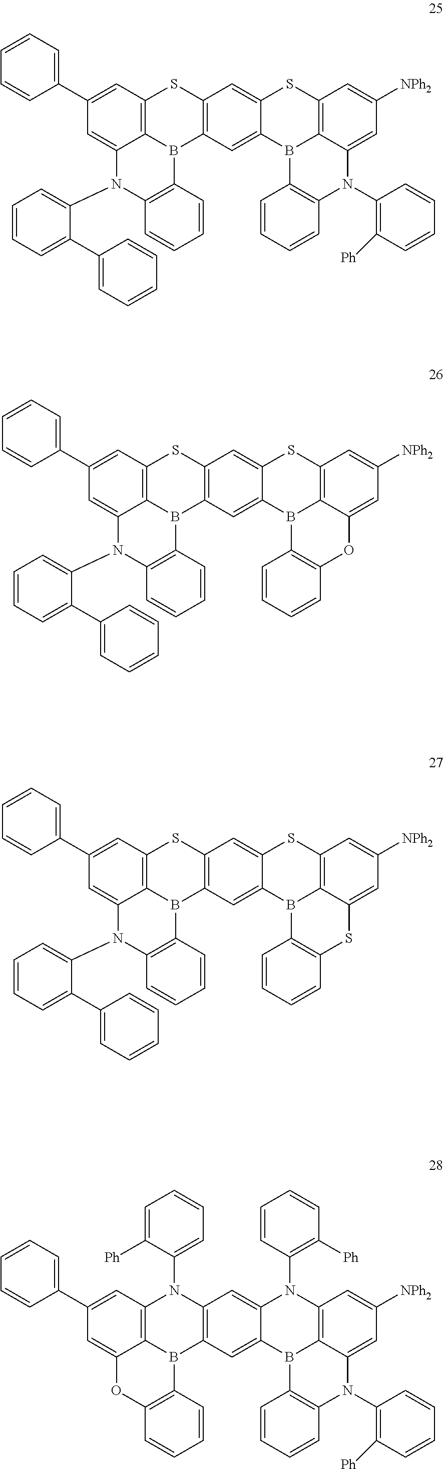 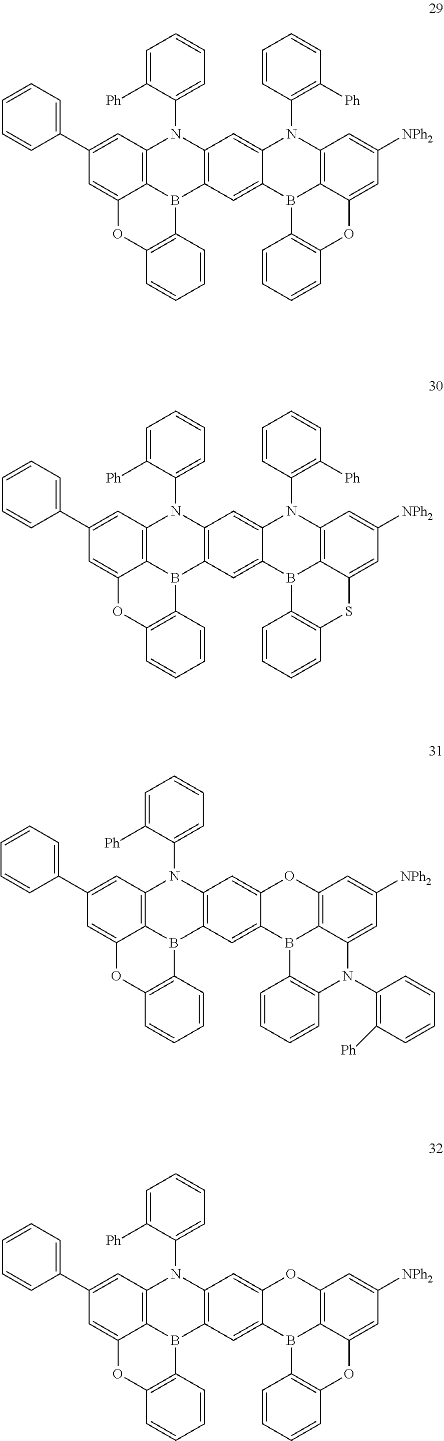 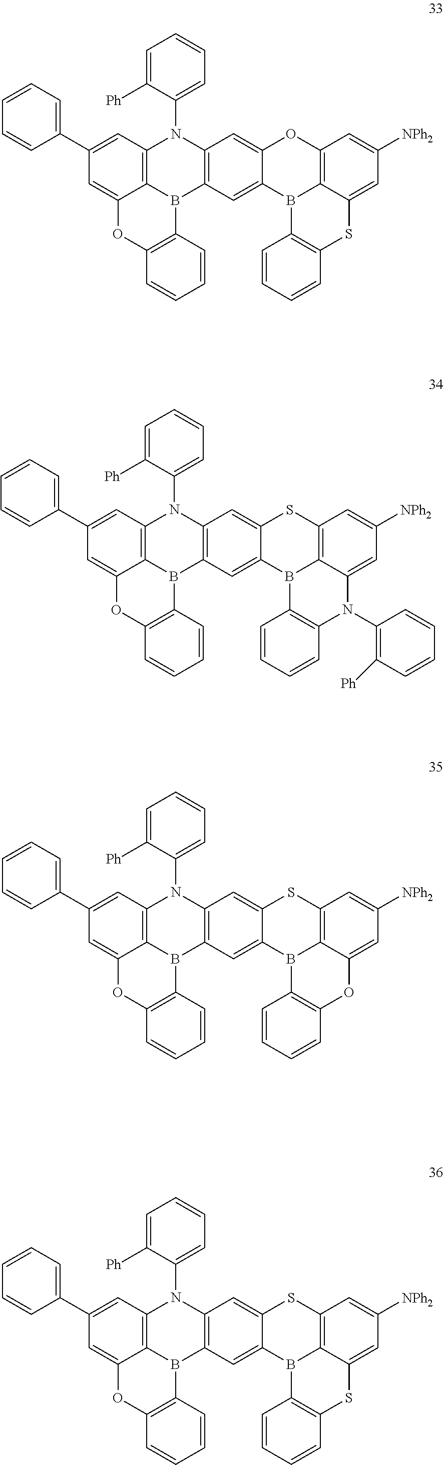 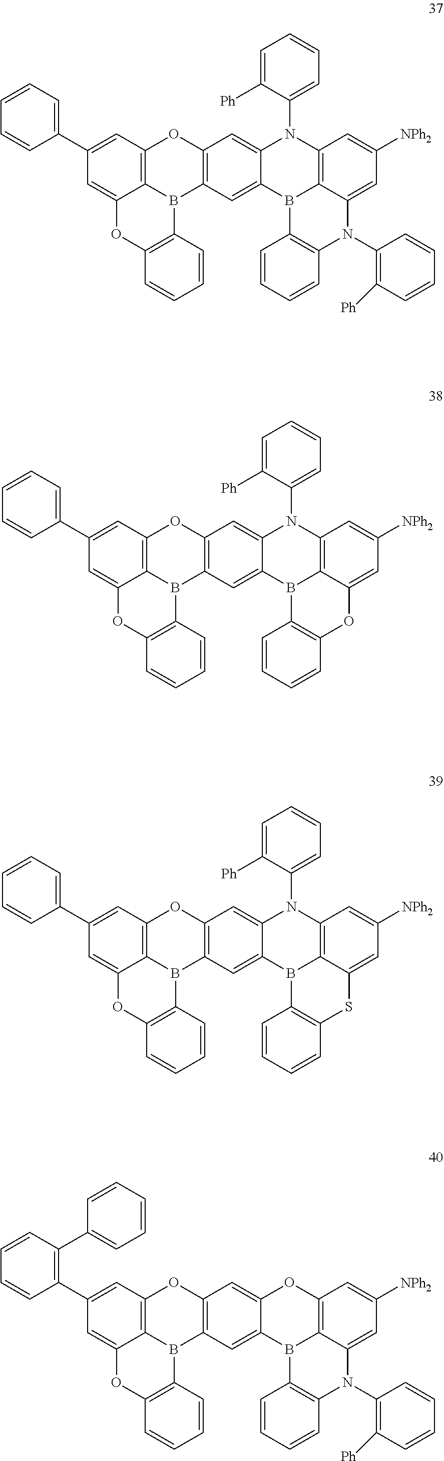 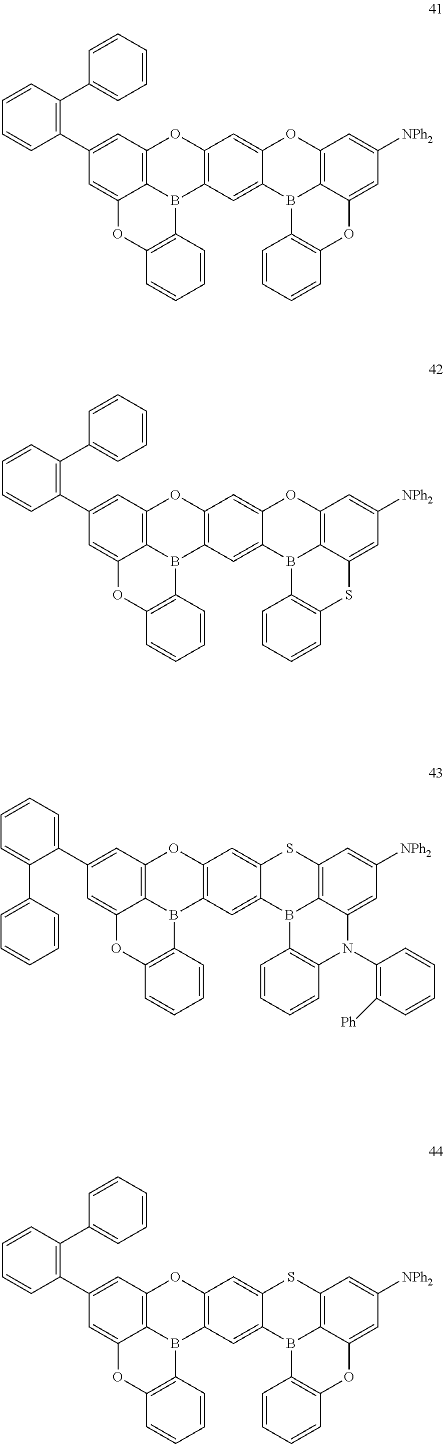 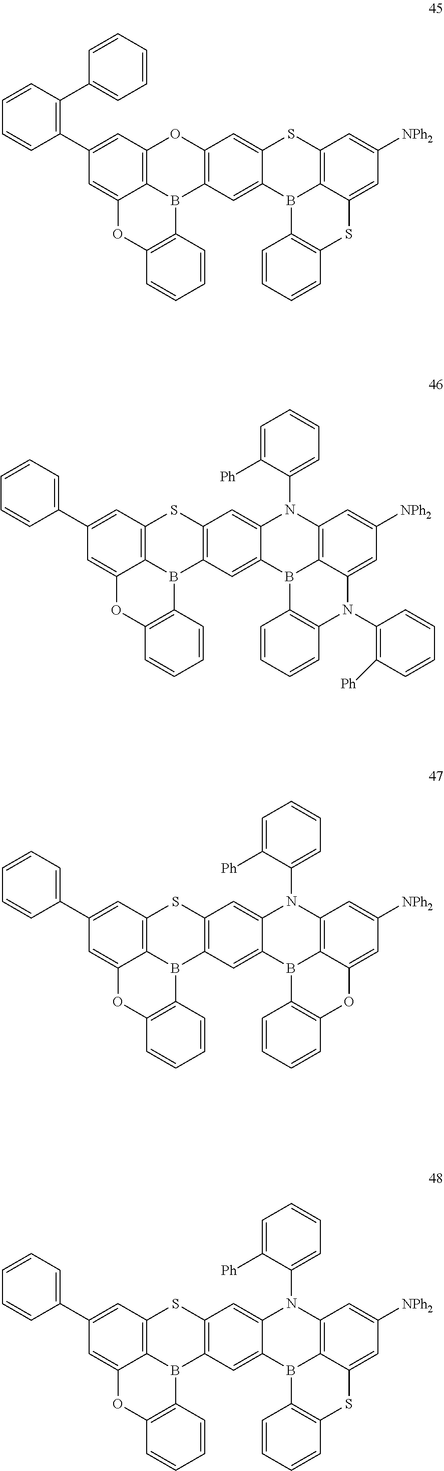 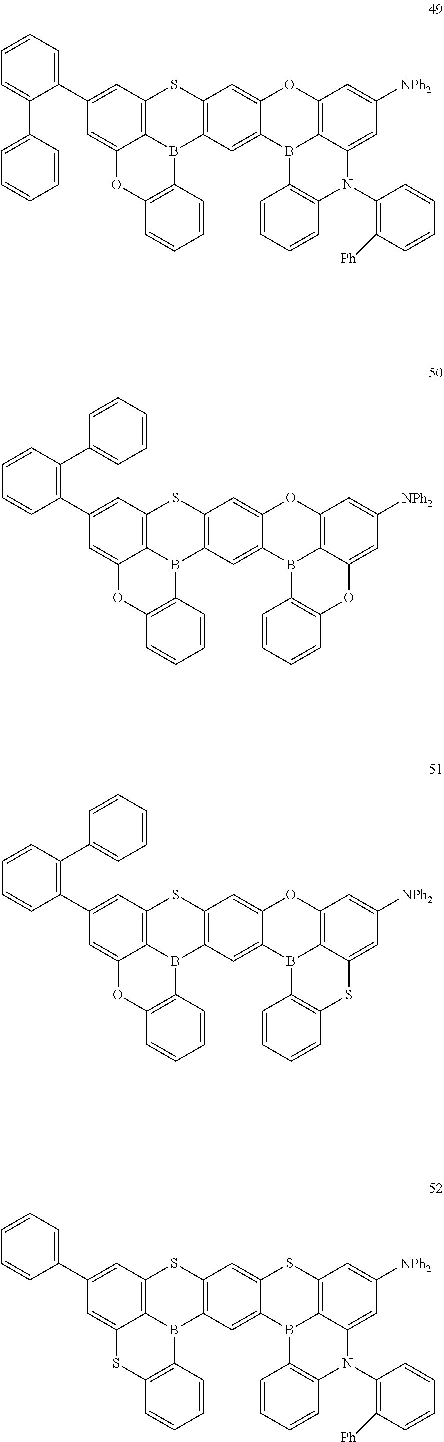 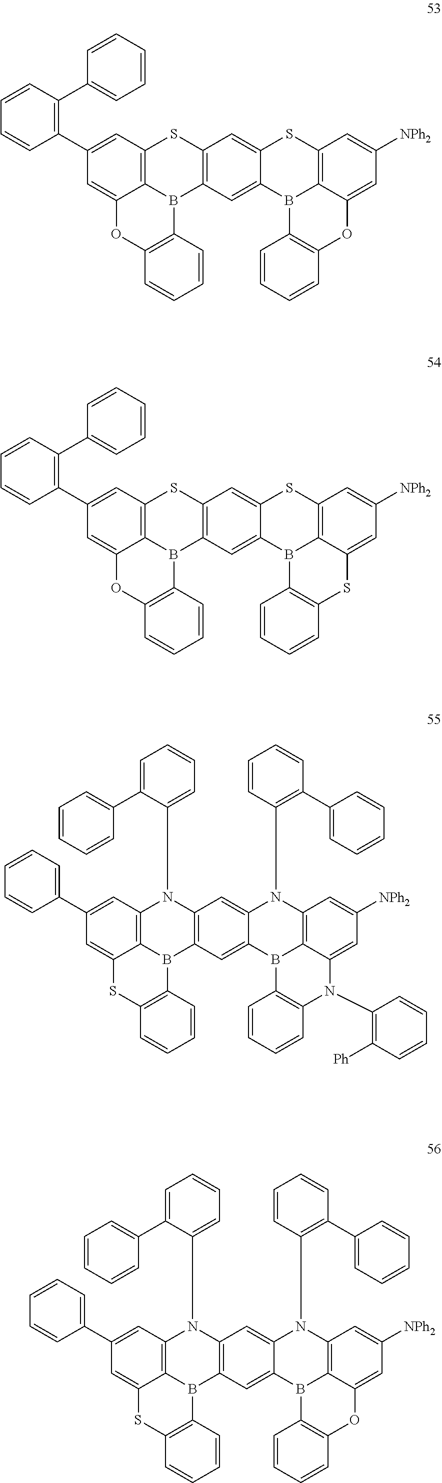 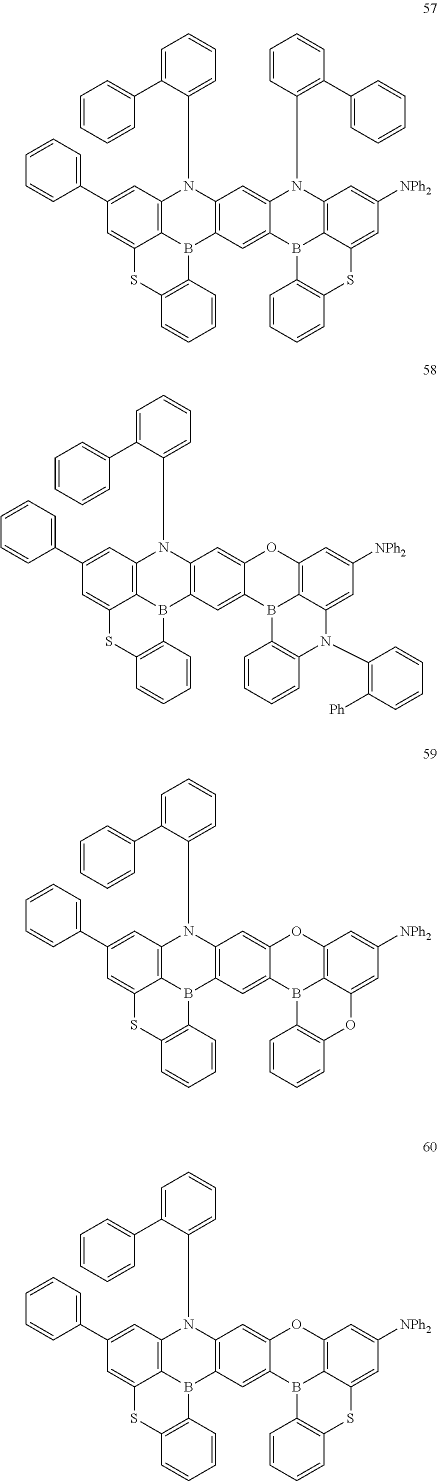 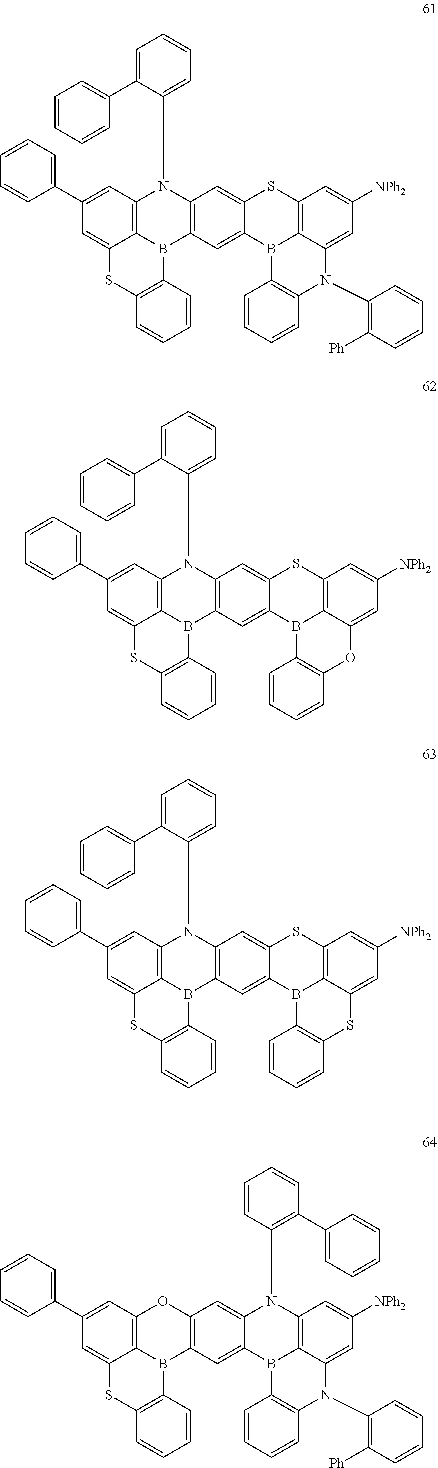 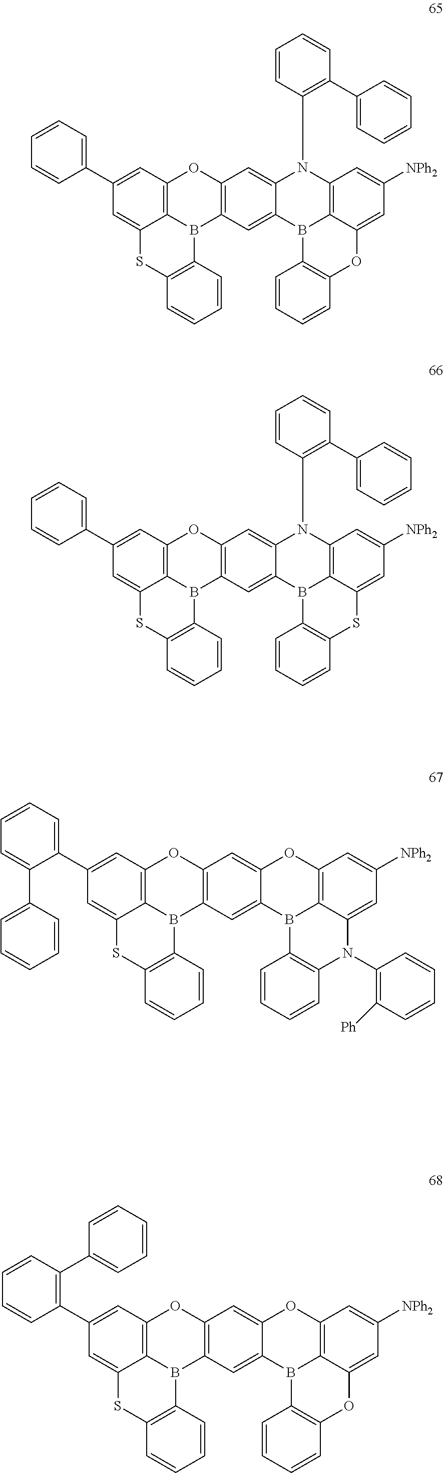 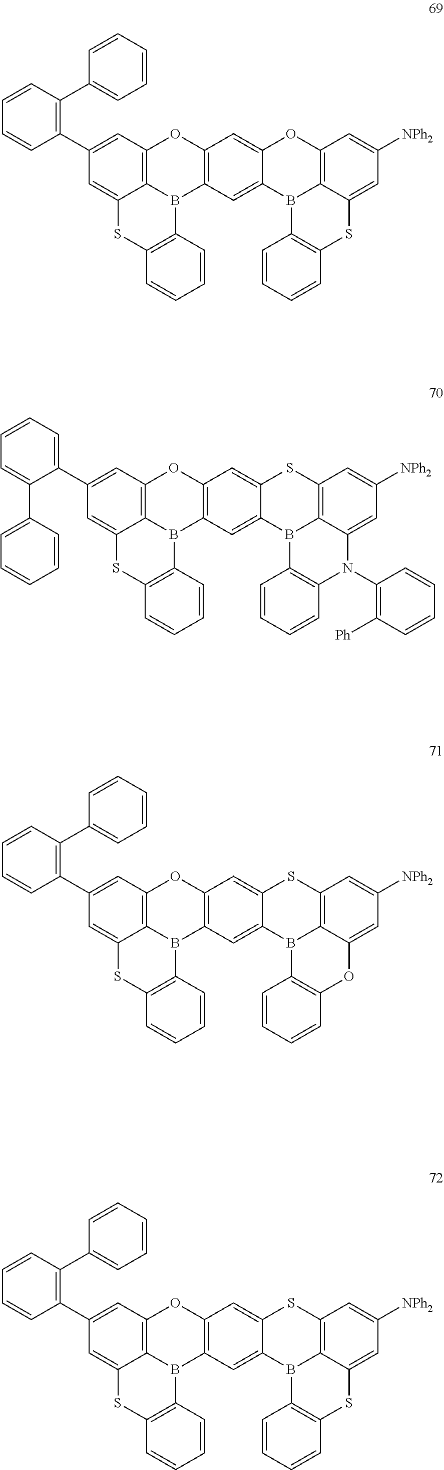 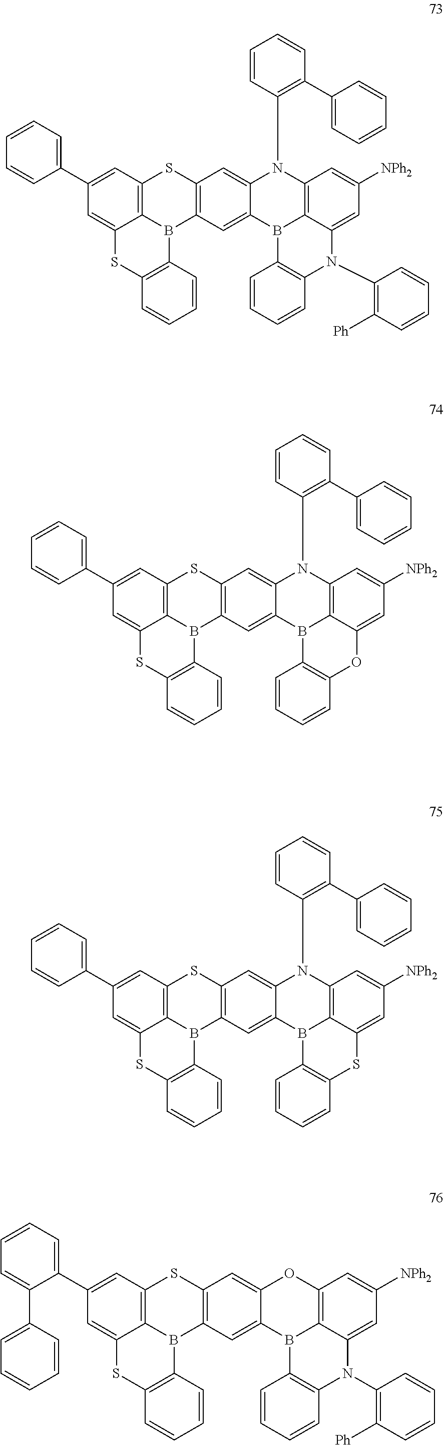 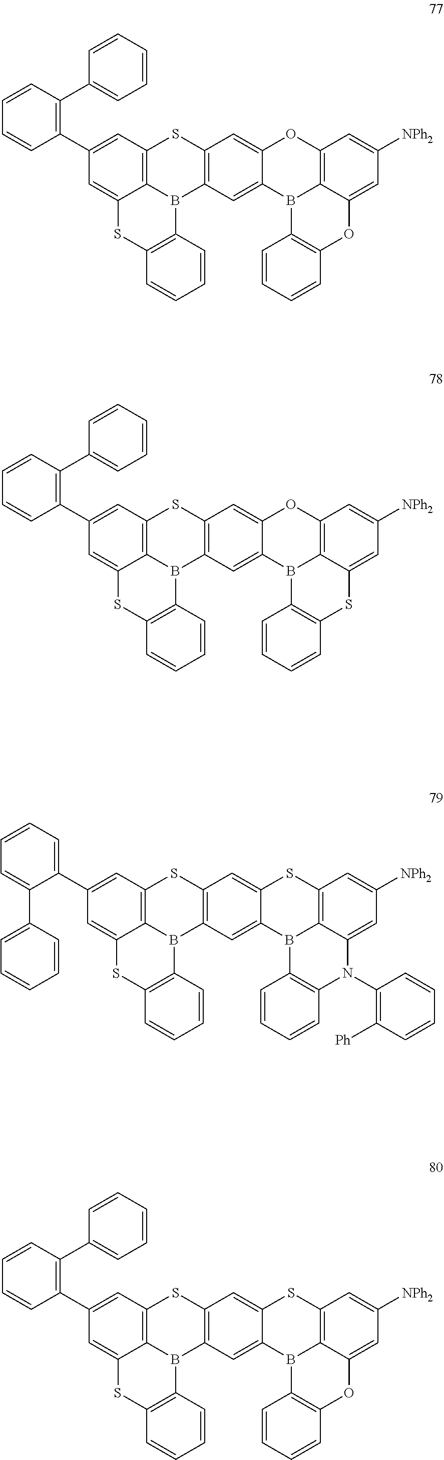 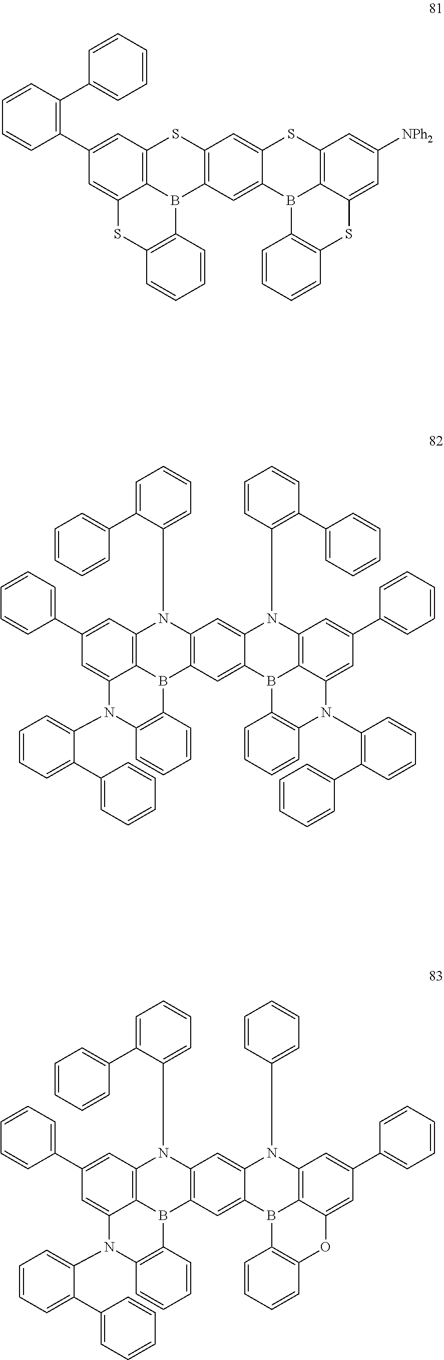 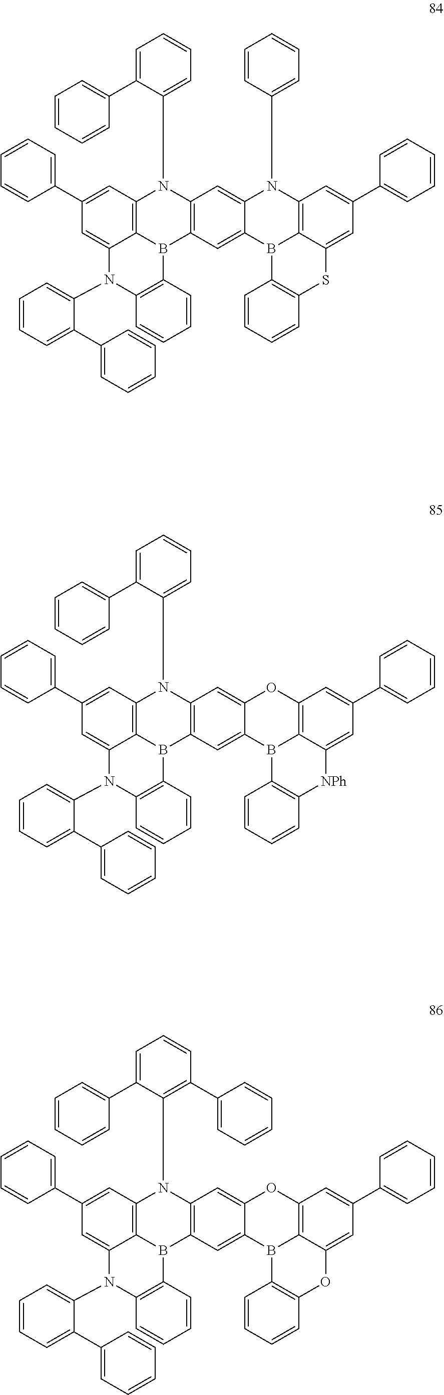 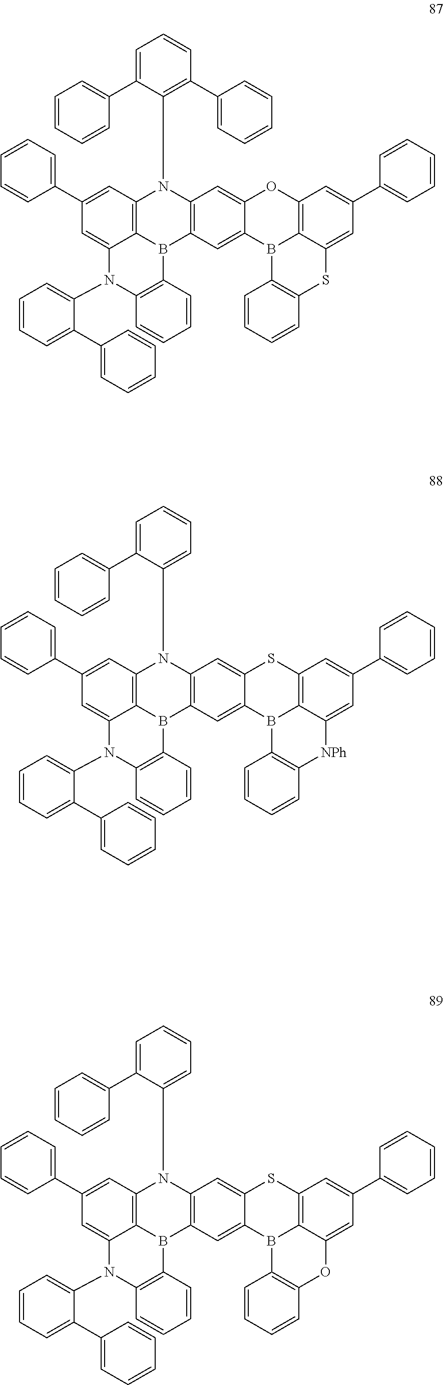 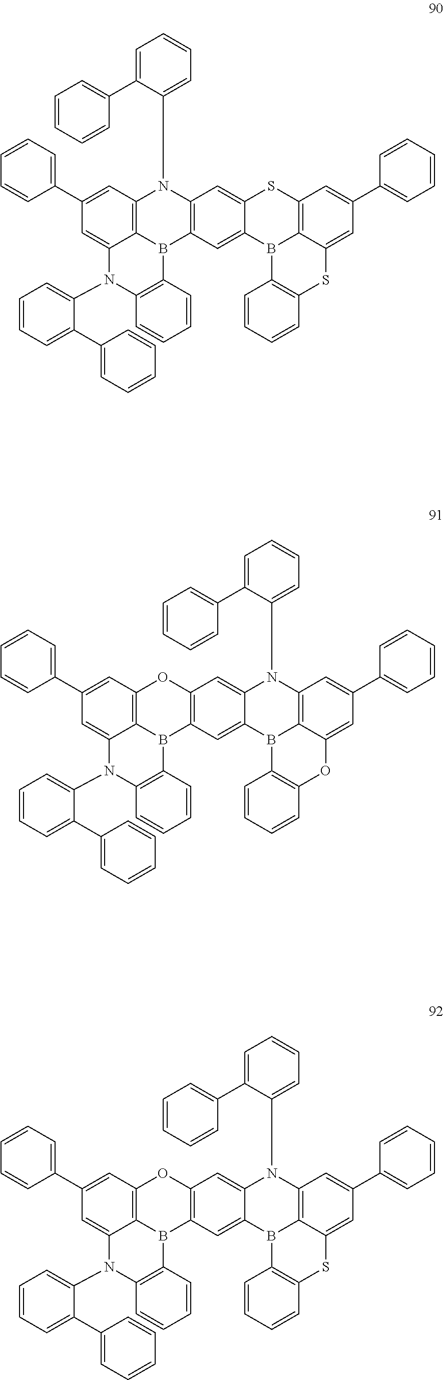 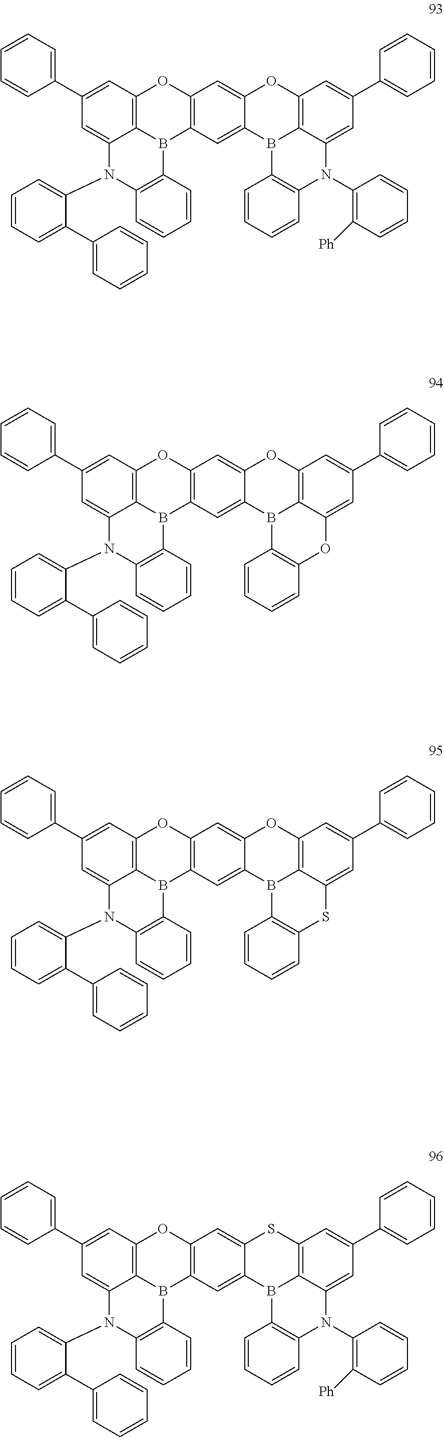 [SMILES: c1ccc(-c2cc3c4c(c2)N(c2ccccc2-c2ccccc2)c2ccccc2B4c2cc4c(cc2O3)Oc2cc(-c3ccccc3)cc3c2B4c2ccccc2N3c2ccccc2-c2ccccc2)cc1 ; c1ccc(-c2cc3c4c(c2)Oc2cc5c(cc2B4c2ccccc2O3)B2c3ccccc3N(c3ccccc3-c3ccccc3)c3cc(-c4ccccc4)cc(c32)O5)cc1 ; c1ccc(-c2cc3c4c(c2)Sc2ccccc2B4c2cc4c(cc2O3)Oc2cc(-c3ccccc3)cc3c2B4c2ccccc2N3c2ccccc2-c2ccccc2)cc1 ; c1ccc(-c2cc3c4c(c2)N(c2ccccc2-c2ccccc2)c2ccccc2B4c2cc4c(cc2O3)Sc2cc(-c3ccccc3)cc3c2B4c2ccccc2N3c2ccccc2-c2ccccc2)cc1] 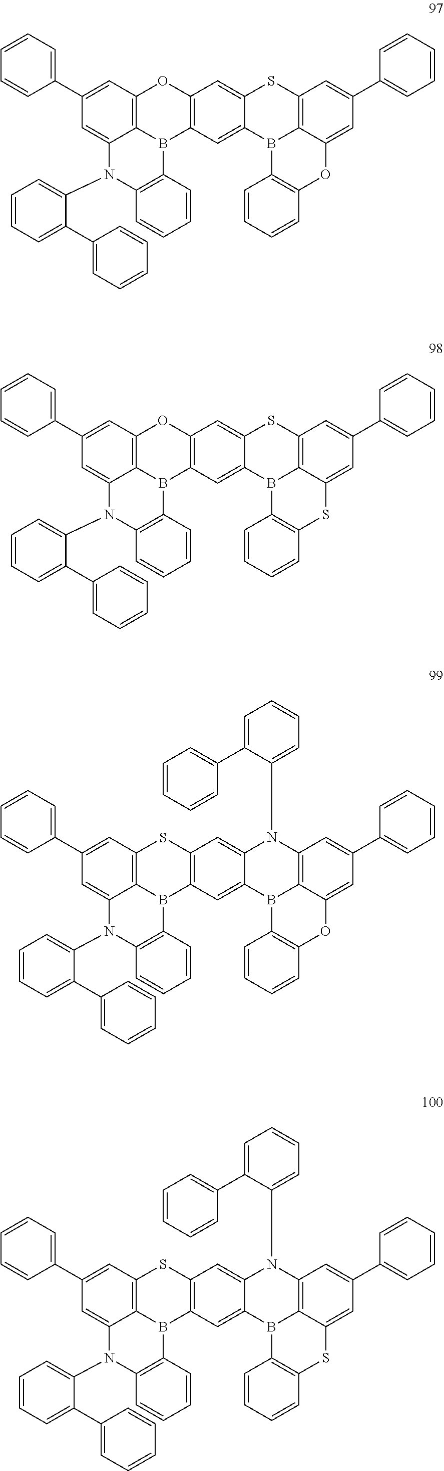 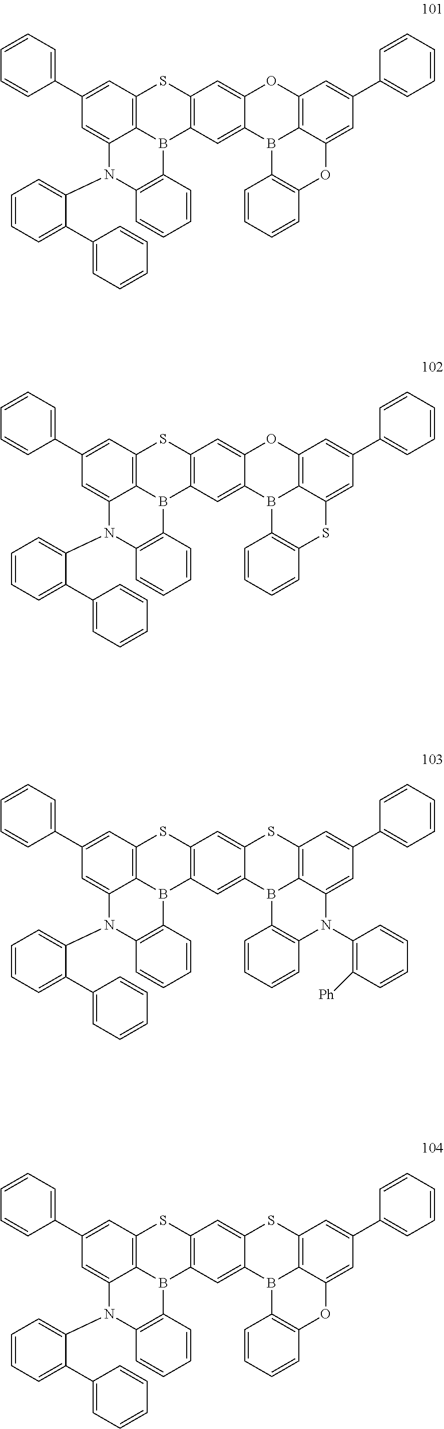 [SMILES: c1ccc(-c2cc3c4c(c2)Oc2cc5c(cc2B4c2ccccc2O3)B2c3ccccc3N(c3ccccc3-c3ccccc3)c3cc(-c4ccccc4)cc(c32)S5)cc1 ; c1ccc(-c2cc3c4c(c2)Sc2ccccc2B4c2cc4c(cc2O3)Sc2cc(-c3ccccc3)cc3c2B4c2ccccc2N3c2ccccc2-c2ccccc2)cc1 ; c1ccc(-c2cc3c4c(c2)N(c2ccccc2-c2ccccc2)c2ccccc2B4c2cc4c(cc2S3)Sc2cc(-c3ccccc3)cc3c2B4c2ccccc2N3c2ccccc2-c2ccccc2)cc1 ; c1ccc(-c2cc3c4c(c2)Sc2cc5c(cc2B4c2ccccc2O3)B2c3ccccc3N(c3ccccc3-c3ccccc3)c3cc(-c4ccccc4)cc(c32)S5)cc1] 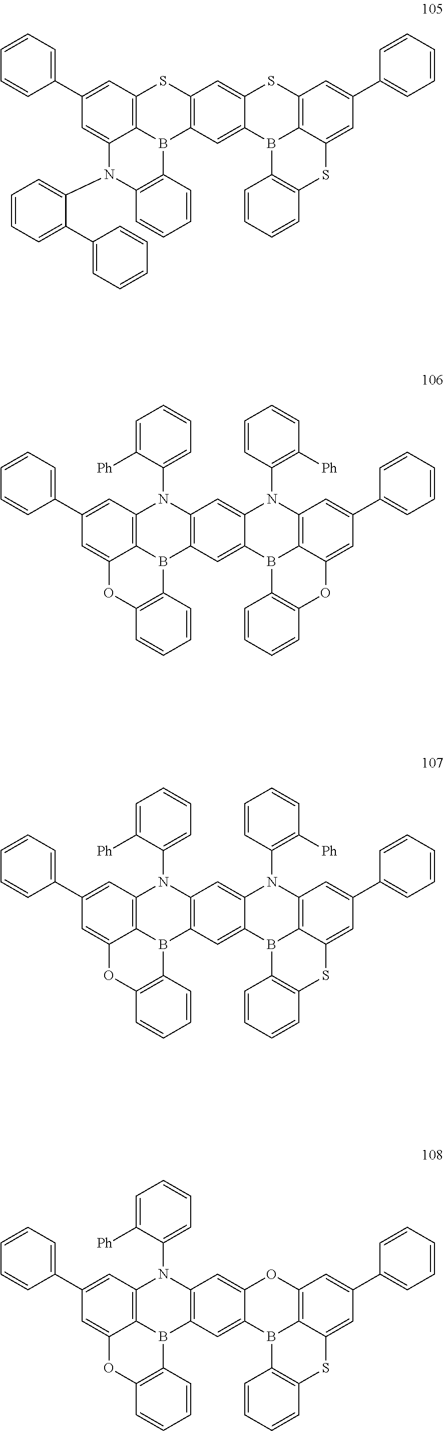 [SMILES: c1ccc(-c2cc3c4c(c2)Sc2cc5c(cc2B4c2ccccc2S3)B2c3ccccc3N(c3ccccc3-c3ccccc3)c3cc(-c4ccccc4)cc(c32)S5)cc1 ; c1ccc(-c2cc3c4c(c2)N(c2ccccc2-c2ccccc2)c2cc5c(cc2B4c2ccccc2O3)B2c3ccccc3Oc3cc(-c4ccccc4)cc(c32)N5c2ccccc2-c2ccccc2)cc1 ; c1ccc(-c2cc3c4c(c2)N(c2ccccc2-c2ccccc2)c2cc5c(cc2B4c2ccccc2O3)B2c3ccccc3Sc3cc(-c4ccccc4)cc(c32)N5c2ccccc2-c2ccccc2)cc1 ; c1ccc(-c2cc3c4c(c2)Sc2ccccc2B4c2cc4c(cc2O3)N(c2ccccc2-c2ccccc2)c2cc(-c3ccccc3)cc3c2B4c2ccccc2O3)cc1] 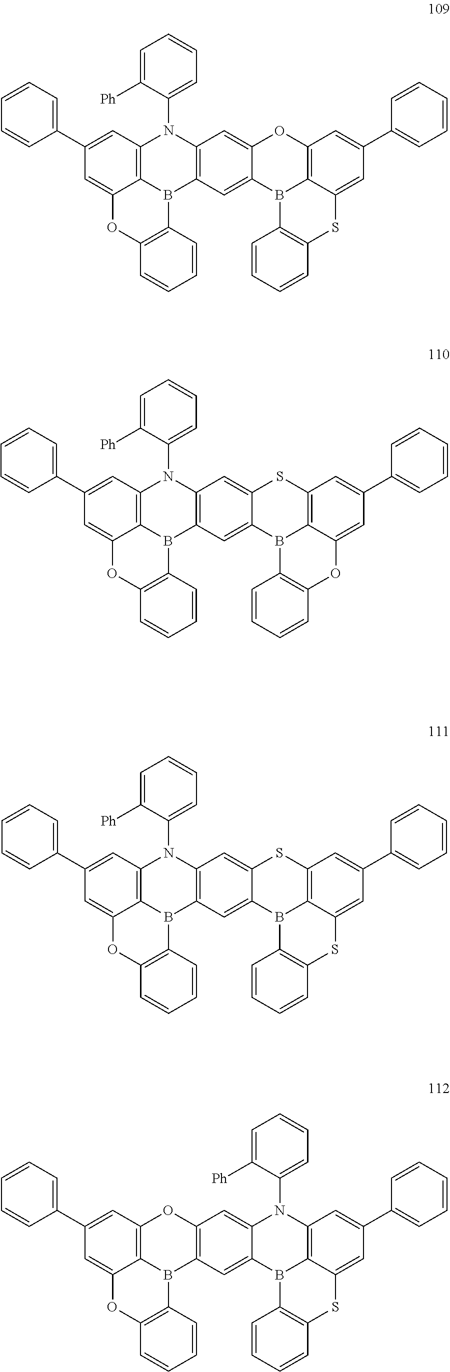 [SMILES: c1ccc(-c2cc3c4c(c2)Sc2ccccc2B4c2cc4c(cc2O3)N(c2ccccc2-c2ccccc2)c2cc(-c3ccccc3)cc3c2B4c2ccccc2O3)cc1 ; c1ccc(-c2cc3c4c(c2)Sc2cc5c(cc2B4c2ccccc2O3)B2c3ccccc3Oc3cc(-c4ccccc4)cc(c32)N5c2ccccc2-c2ccccc2)cc1 ; c1ccc(-c2cc3c4c(c2)Sc2cc5c(cc2B4c2ccccc2S3)B2c3ccccc3Oc3cc(-c4ccccc4)cc(c32)N5c2ccccc2-c2ccccc2)cc1 ; c1ccc(-c2cc3c4c(c2)Oc2cc5c(cc2B4c2ccccc2O3)B2c3ccccc3Sc3cc(-c4ccccc4)cc(c32)N5c2ccccc2-c2ccccc2)cc1] 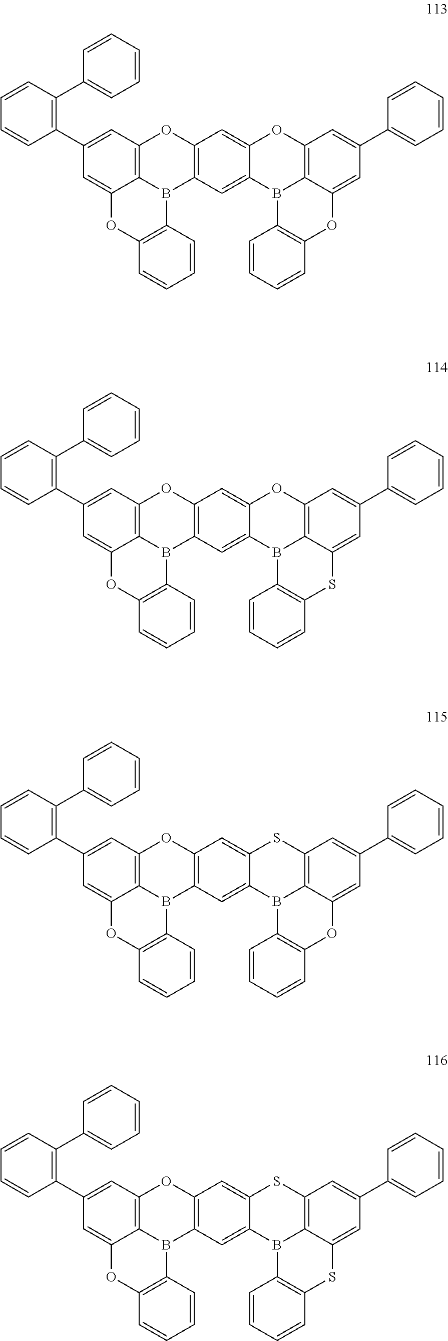 [SMILES: c1ccc(-c2cc3c4c(c2)Oc2cc5c(cc2B4c2ccccc2O3)B2c3ccccc3Oc3cc(-c4ccccc4-c4ccccc4)cc(c32)O5)cc1 ; c1ccc(-c2cc3c4c(c2)Sc2ccccc2B4c2cc4c(cc2O3)Oc2cc(-c3ccccc3-c3ccccc3)cc3c2B4c2ccccc2O3)cc1 ; c1ccc(-c2cc3c4c(c2)Sc2cc5c(cc2B4c2ccccc2O3)B2c3ccccc3Oc3cc(-c4ccccc4-c4ccccc4)cc(c32)O5)cc1 ; c1ccc(-c2cc3c4c(c2)Sc2cc5c(cc2B4c2ccccc2S3)B2c3ccccc3Oc3cc(-c4ccccc4-c4ccccc4)cc(c32)O5)cc1] 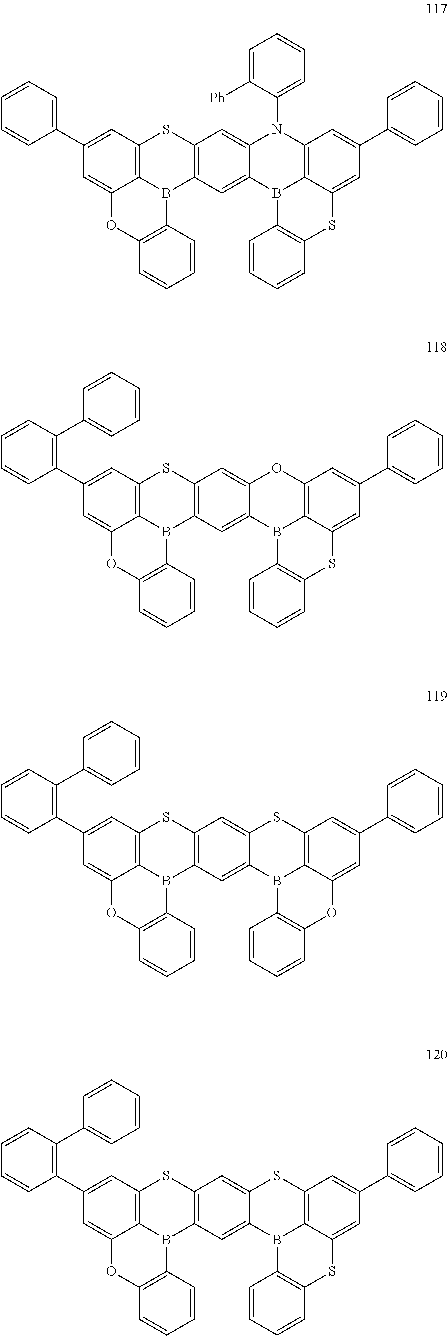 [SMILES: c1ccc(-c2cc3c4c(c2)Sc2cc5c(cc2B4c2ccccc2O3)B2c3ccccc3Sc3cc(-c4ccccc4)cc(c32)N5c2ccccc2-c2ccccc2)cc1 ; c1ccc(-c2cc3c4c(c2)Sc2ccccc2B4c2cc4c(cc2O3)Sc2cc(-c3ccccc3-c3ccccc3)cc3c2B4c2ccccc2O3)cc1 ; c1ccc(-c2cc3c4c(c2)Sc2cc5c(cc2B4c2ccccc2O3)B2c3ccccc3Oc3cc(-c4ccccc4-c4ccccc4)cc(c32)S5)cc1 ; c1ccc(-c2cc3c4c(c2)Sc2cc5c(cc2B4c2ccccc2S3)B2c3ccccc3Oc3cc(-c4ccccc4-c4ccccc4)cc(c32)S5)cc1] 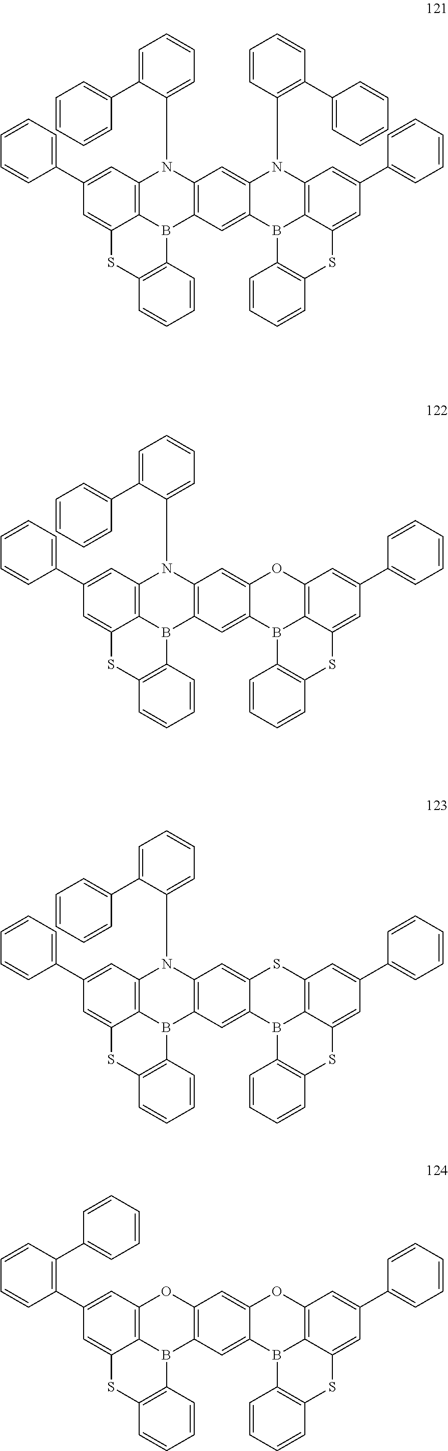 [SMILES: c1ccc(-c2cc3c4c(c2)N(c2ccccc2-c2ccccc2)c2cc5c(cc2B4c2ccccc2S3)B2c3ccccc3Sc3cc(-c4ccccc4)cc(c32)N5c2ccccc2-c2ccccc2)cc1 ; c1ccc(-c2cc3c4c(c2)Sc2ccccc2B4c2cc4c(cc2O3)N(c2ccccc2-c2ccccc2)c2cc(-c3ccccc3)cc3c2B4c2ccccc2S3)cc1 ; c1ccc(-c2cc3c4c(c2)Sc2cc5c(cc2B4c2ccccc2S3)B2c3ccccc3Sc3cc(-c4ccccc4)cc(c32)N5c2ccccc2-c2ccccc2)cc1 ; c1ccc(-c2cc3c4c(c2)Sc2ccccc2B4c2cc4c(cc2O3)Oc2cc(-c3ccccc3-c3ccccc3)cc3c2B4c2ccccc2S3)cc1] 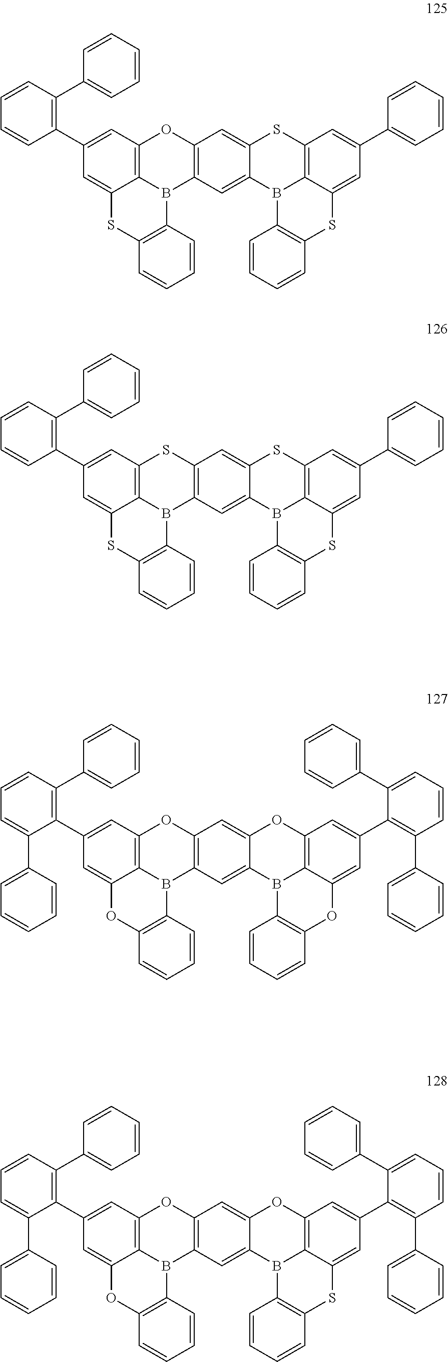 [SMILES: c1ccc(-c2cc3c4c(c2)Sc2cc5c(cc2B4c2ccccc2S3)B2c3ccccc3Sc3cc(-c4ccccc4-c4ccccc4)cc(c32)O5)cc1 ; c1ccc(-c2cc3c4c(c2)Sc2cc5c(cc2B4c2ccccc2S3)B2c3ccccc3Sc3cc(-c4ccccc4-c4ccccc4)cc(c32)S5)cc1 ; c1ccc(-c2cccc(-c3ccccc3)c2-c2cc3c4c(c2)Oc2cc5c(cc2B4c2ccccc2O3)B2c3ccccc3Oc3cc(-c4c(-c6ccccc6)cccc4-c4ccccc4)cc(c32)O5)cc1 ; c1ccc(-c2cccc(-c3ccccc3)c2-c2cc3c4c(c2)Oc2cc5c(cc2B4c2ccccc2O3)B2c3ccccc3Sc3cc(-c4c(-c6ccccc6)cccc4-c4ccccc4)cc(c32)O5)cc1] 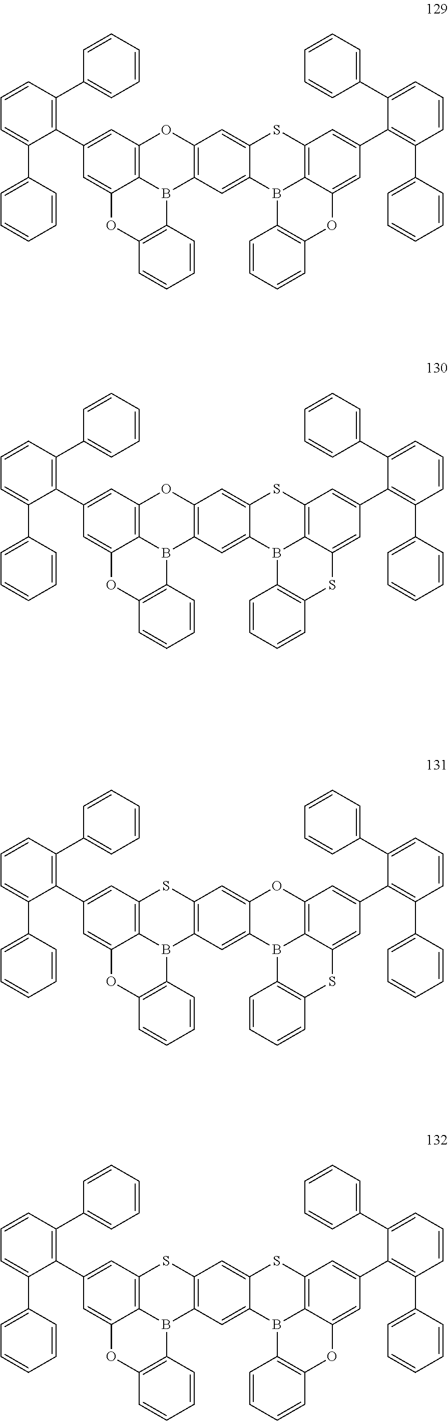 [SMILES: c1ccc(-c2cccc(-c3ccccc3)c2-c2cc3c4c(c2)Oc2cc5c(cc2B4c2ccccc2O3)B2c3ccccc3Oc3cc(-c4c(-c6ccccc6)cccc4-c4ccccc4)cc(c32)S5)cc1 ; c1ccc(-c2cccc(-c3ccccc3)c2-c2cc3c4c(c2)Oc2cc5c(cc2B4c2ccccc2O3)B2c3ccccc3Sc3cc(-c4c(-c6ccccc6)cccc4-c4ccccc4)cc(c32)S5)cc1 ; c1ccc(-c2cccc(-c3ccccc3)c2-c2cc3c4c(c2)Sc2ccccc2B4c2cc4c(cc2O3)Sc2cc(-c3c(-c5ccccc5)cccc3-c3ccccc3)cc3c2B4c2ccccc2O3)cc1 ; c1ccc(-c2cccc(-c3ccccc3)c2-c2cc3c4c(c2)Sc2cc5c(cc2B4c2ccccc2O3)B2c3ccccc3Oc3cc(-c4c(-c6ccccc6)cccc4-c4ccccc4)cc(c32)S5)cc1] 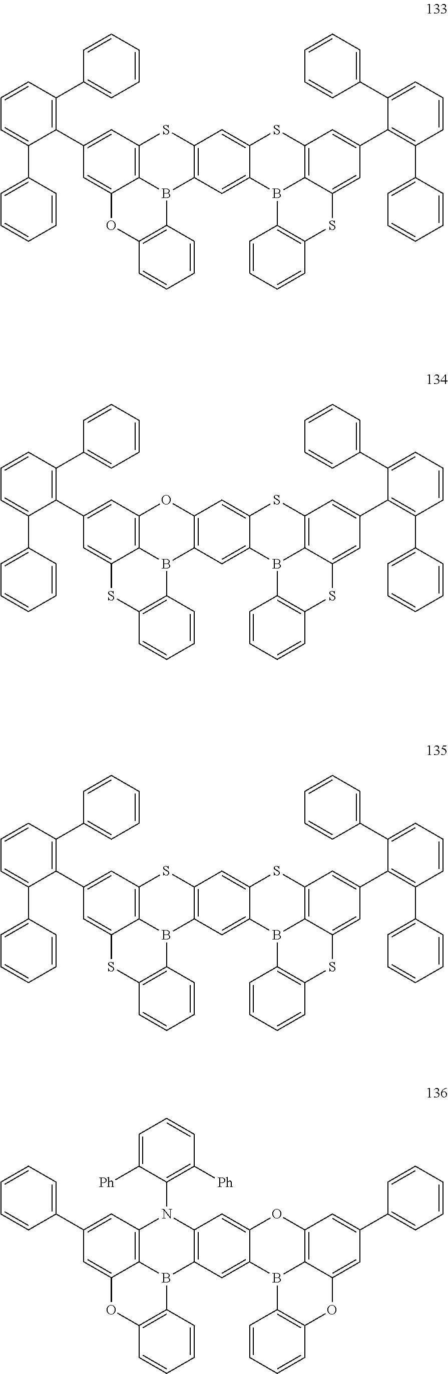 [SMILES: c1ccc(-c2cccc(-c3ccccc3)c2-c2cc3c4c(c2)Sc2cc5c(cc2B4c2ccccc2O3)B2c3ccccc3Sc3cc(-c4c(-c6ccccc6)cccc4-c4ccccc4)cc(c32)S5)cc1 ; c1ccc(-c2cccc(-c3ccccc3)c2-c2cc3c4c(c2)Sc2ccccc2B4c2cc4c(cc2O3)Sc2cc(-c3c(-c5ccccc5)cccc3-c3ccccc3)cc3c2B4c2ccccc2S3)cc1 ; c1ccc(-c2cccc(-c3ccccc3)c2-c2cc3c4c(c2)Sc2cc5c(cc2B4c2ccccc2S3)B2c3ccccc3Sc3cc(-c4c(-c6ccccc6)cccc4-c4ccccc4)cc(c32)S5)cc1 ; c1ccc(-c2cc3c4c(c2)Oc2cc5c(cc2B4c2ccccc2O3)B2c3ccccc3Oc3cc(-c4ccccc4)cc(c32)N5c2c(-c3ccccc3)cccc2-c2ccccc2)cc1] 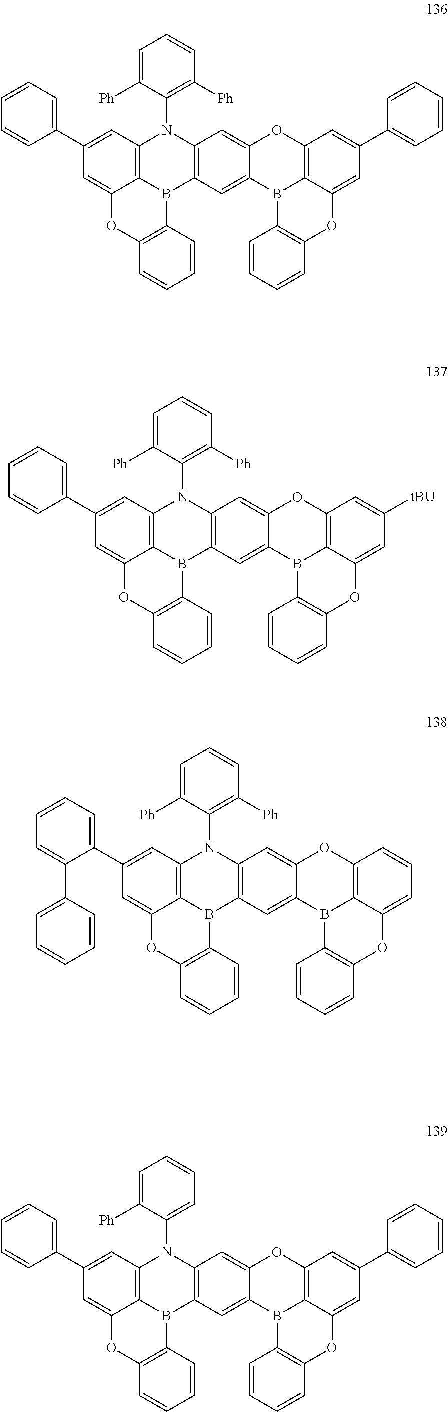 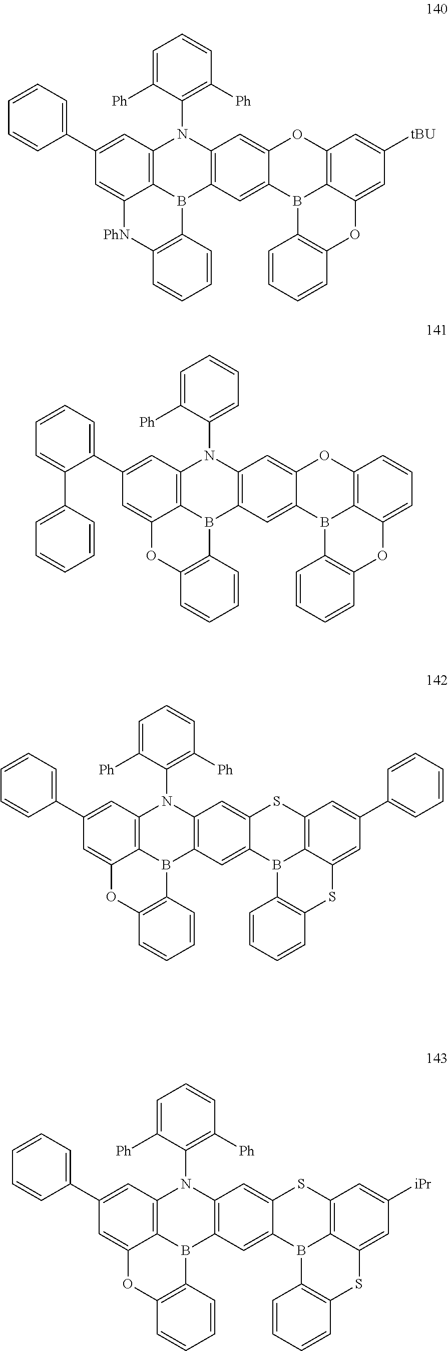 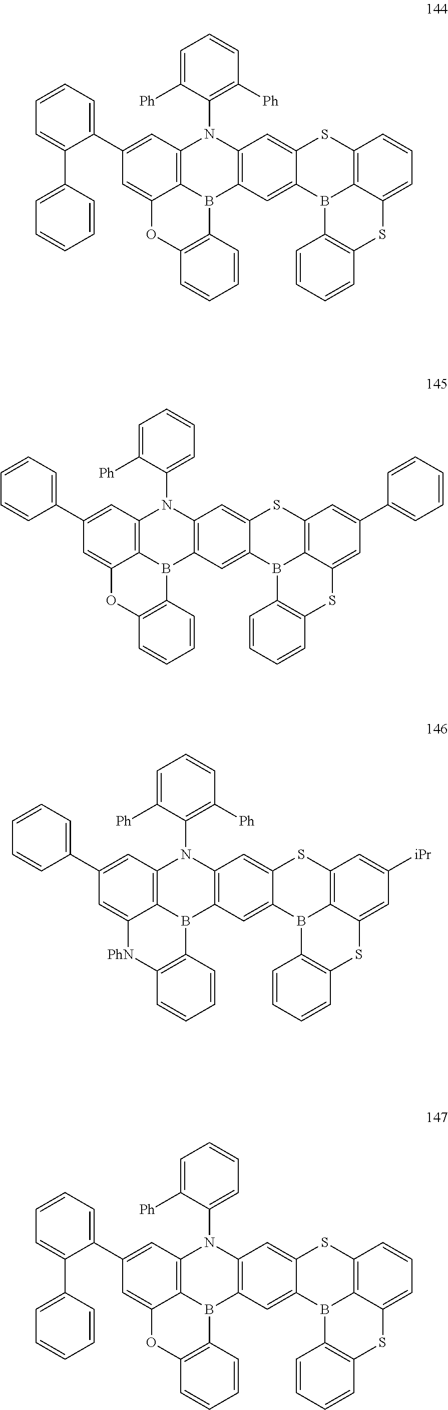 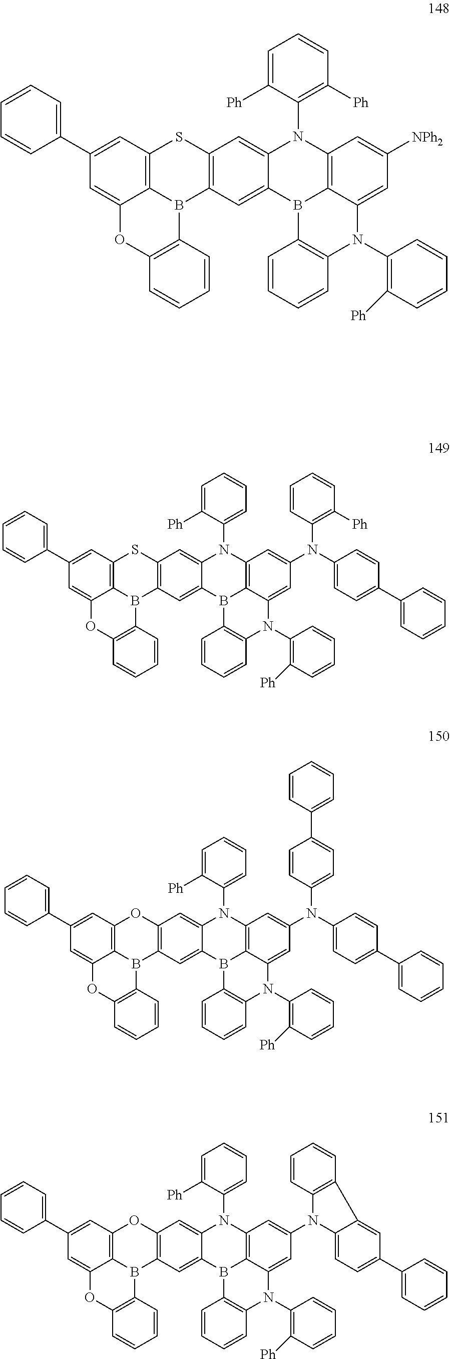 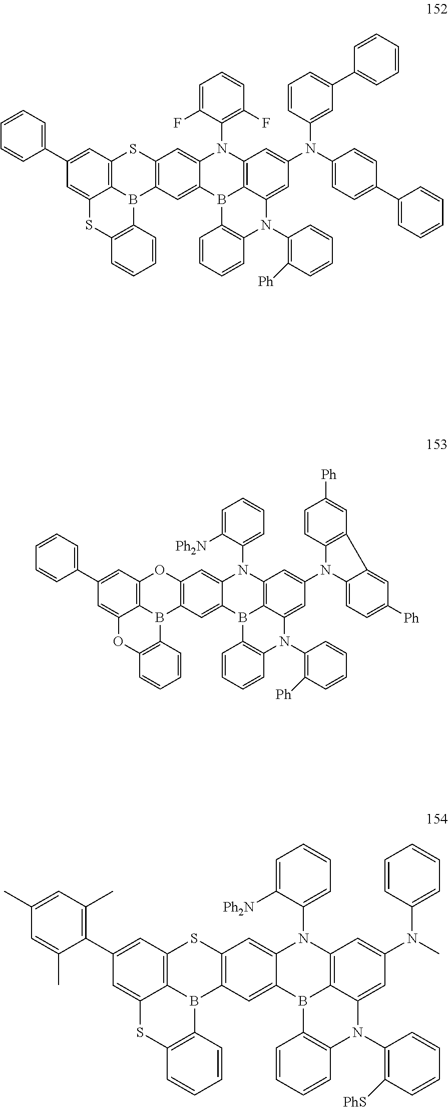 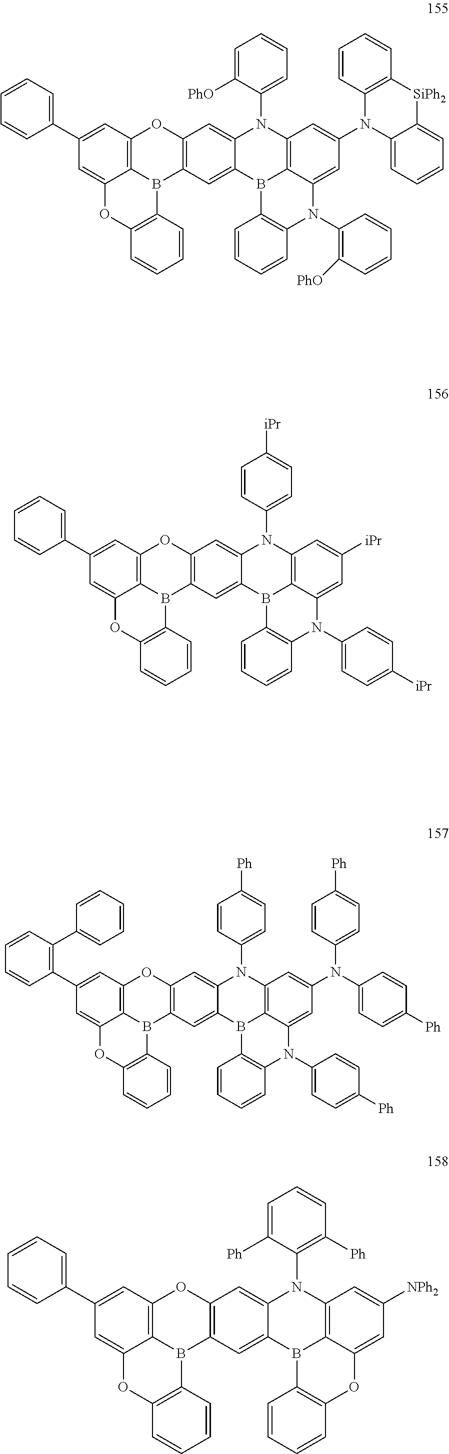 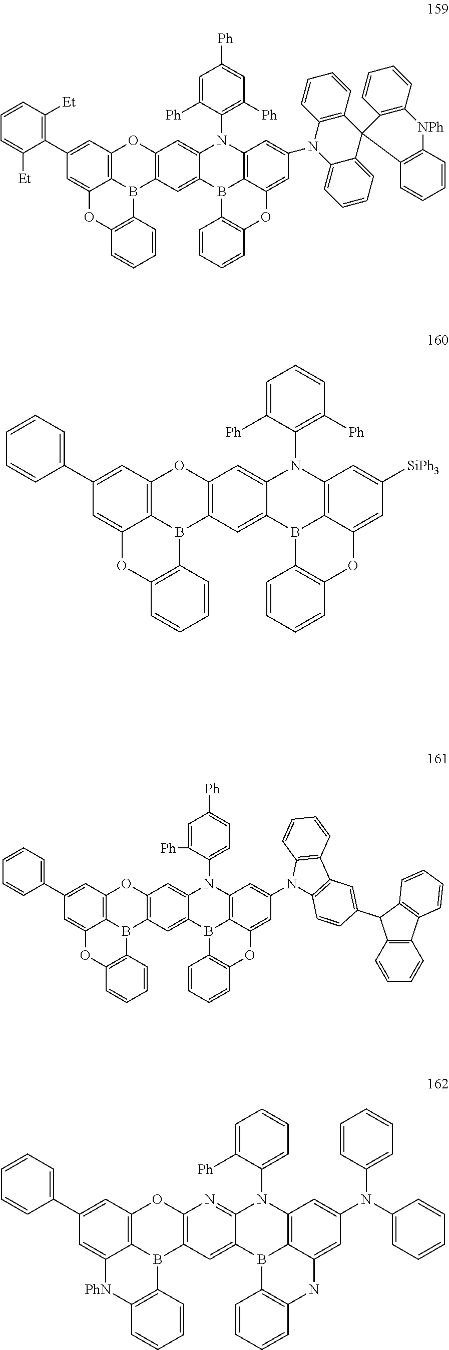 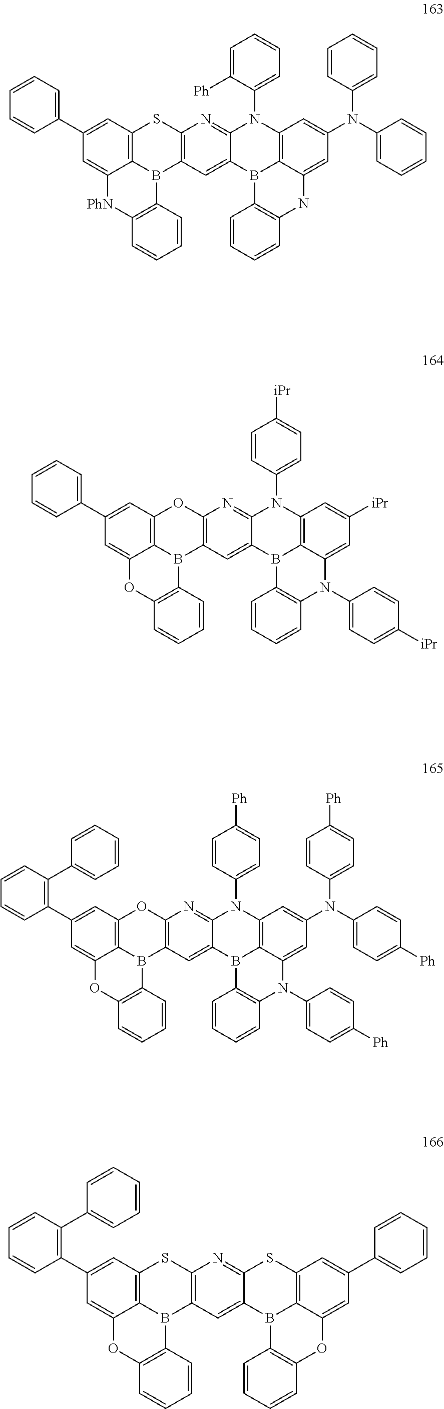 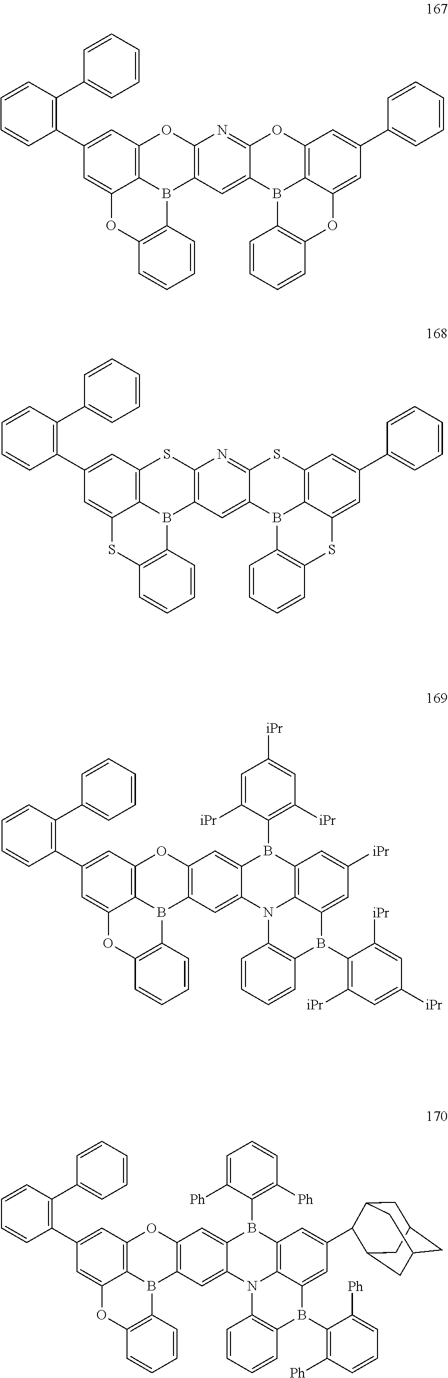 [SMILES: c1ccc(-c2cc3c4c(c2)Oc2nc5c(cc2B4c2ccccc2O3)B2c3ccccc3Oc3cc(-c4ccccc4-c4ccccc4)cc(c32)O5)cc1 ; c1ccc(-c2cc3c4c(c2)Sc2nc5c(cc2B4c2ccccc2S3)B2c3ccccc3Sc3cc(-c4ccccc4-c4ccccc4)cc(c32)S5)cc1 ; CC(C)c1cc2c3c(c1)B(c1c(C(C)C)cc(C(C)C)cc1C(C)C)c1cc4c(cc1N3c1ccccc1B2c1c(C(C)C)cc(C(C)C)cc1C(C)C)B1c2ccccc2Oc2cc(-c3ccccc3-c3ccccc3)cc(c21)O4 ; c1ccc(-c2ccccc2-c2cc3c4c(c2)Oc2cc5c(cc2B4c2ccccc2O3)N2c3ccccc3B(c3c(-c4ccccc4)cccc3-c3ccccc3)c3cc(C4C6CC7CC(C6)CC4C7)cc(c32)B5c2c(-c3ccccc3)cccc2-c2ccccc2)cc1] 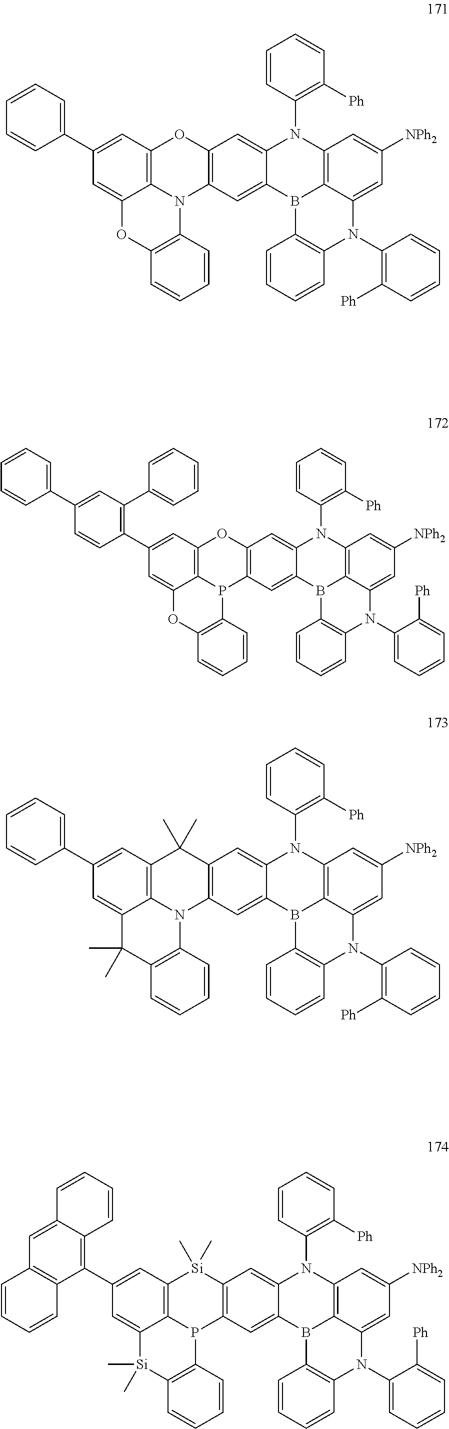 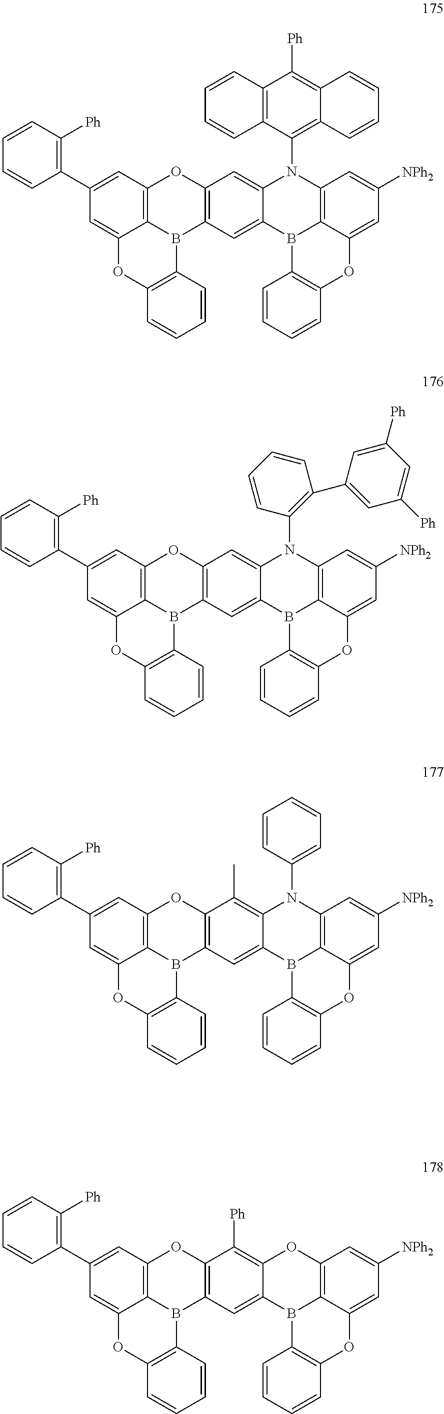 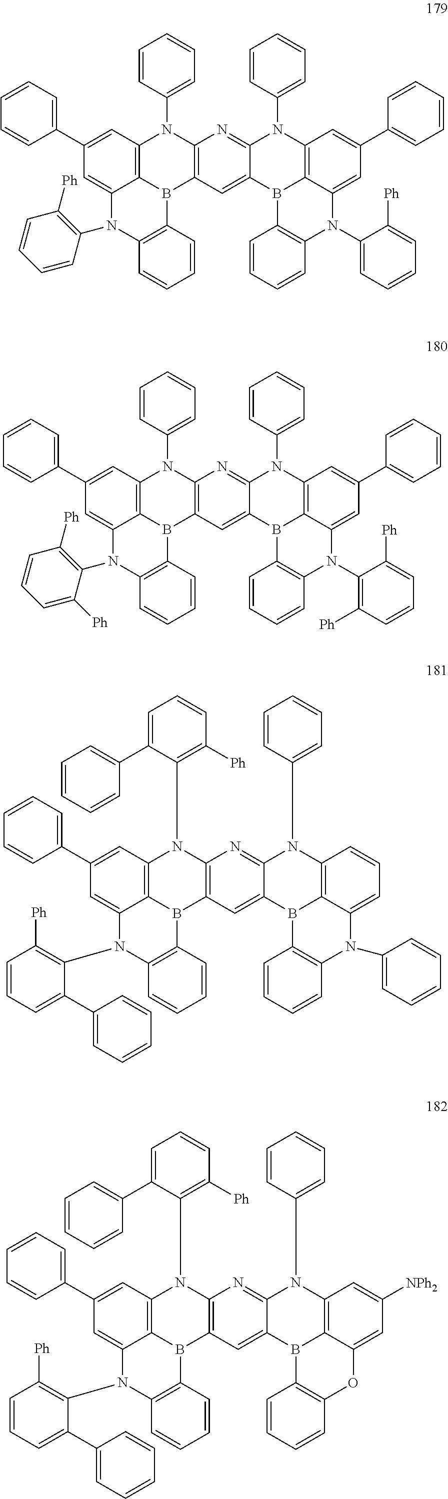 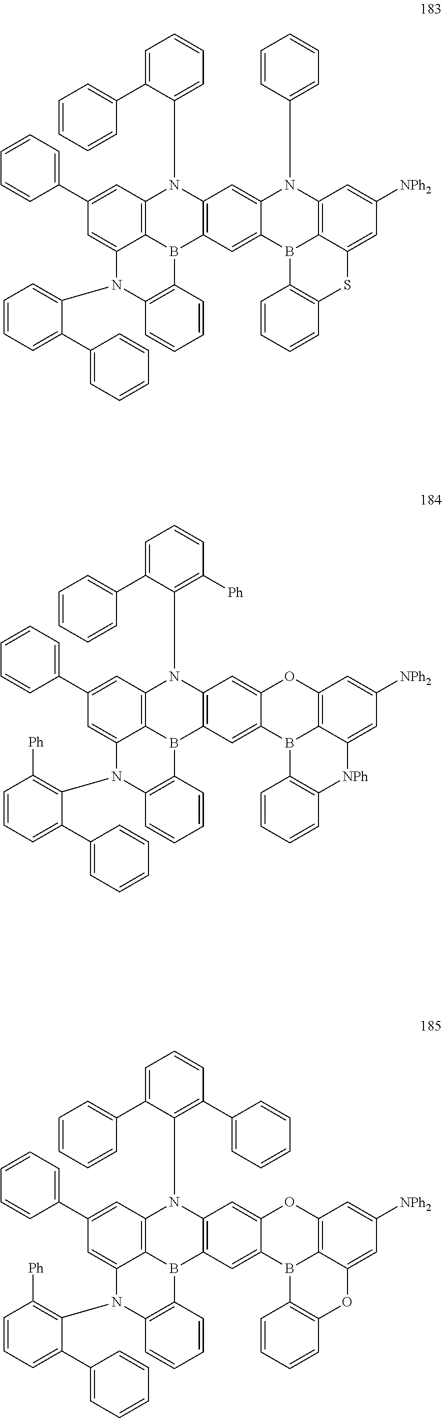 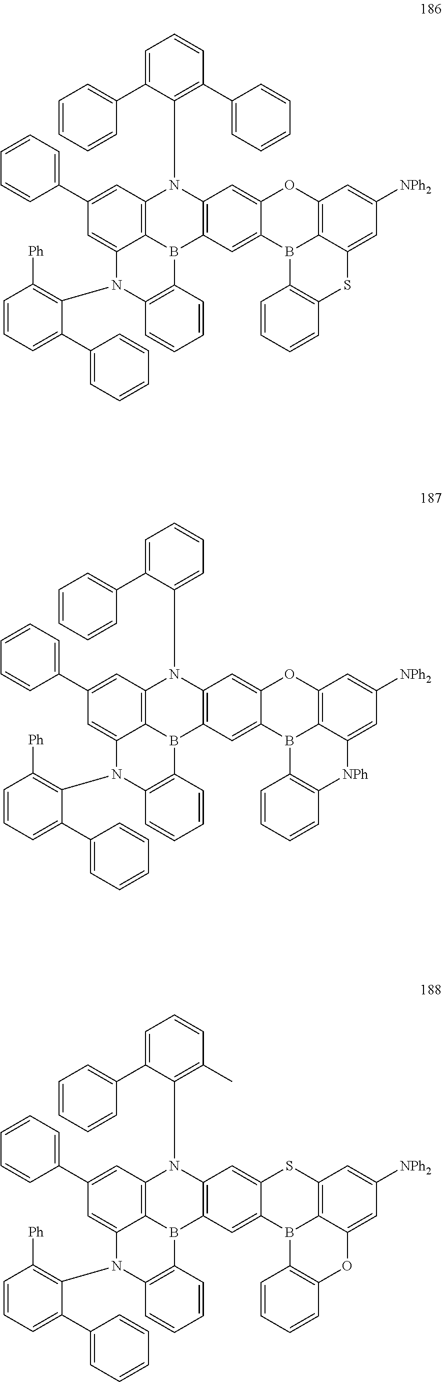 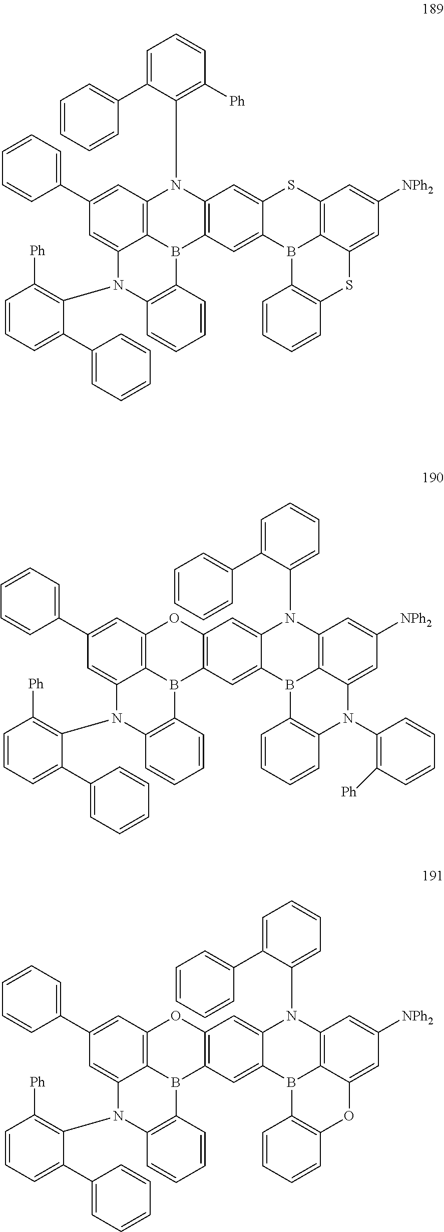 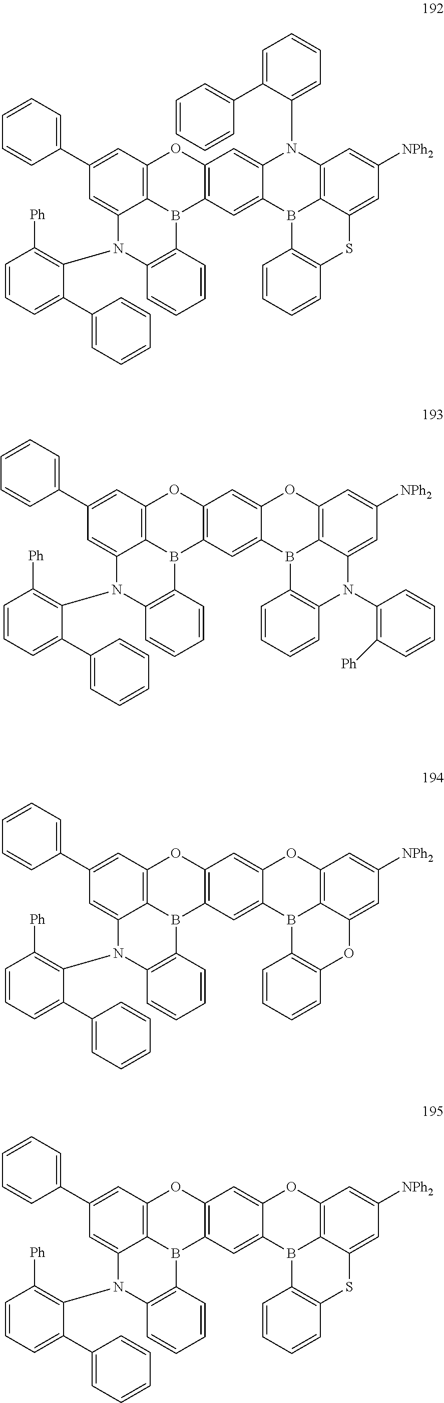 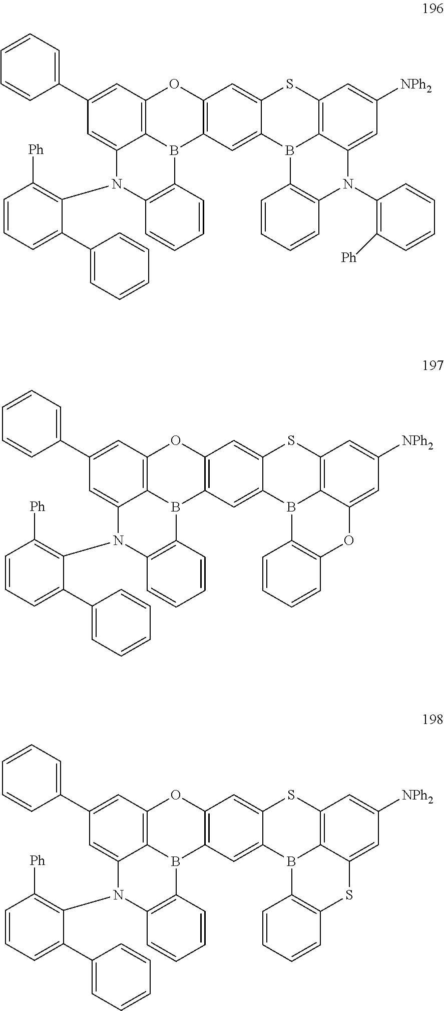 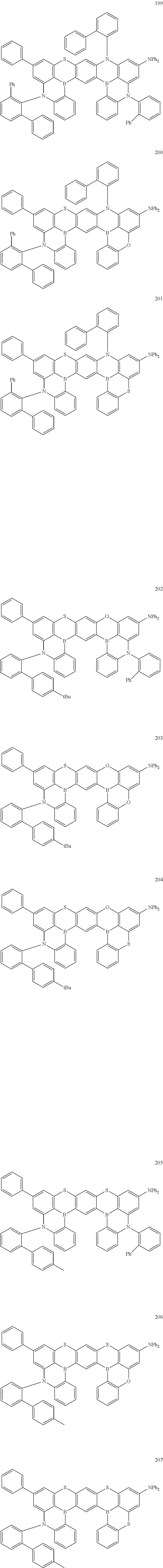 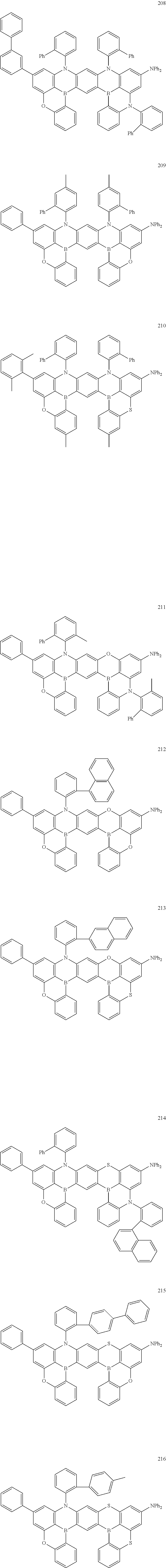 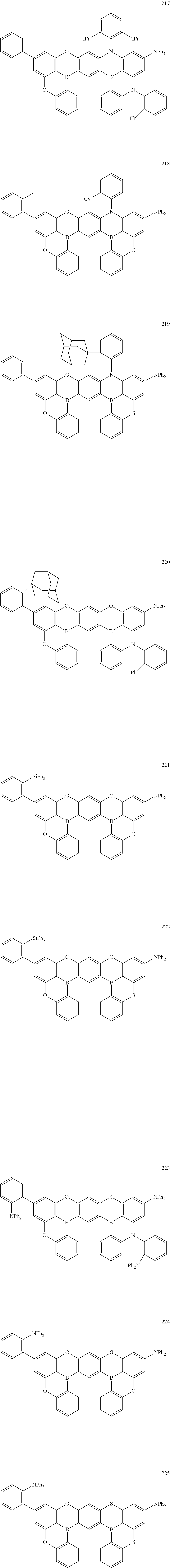 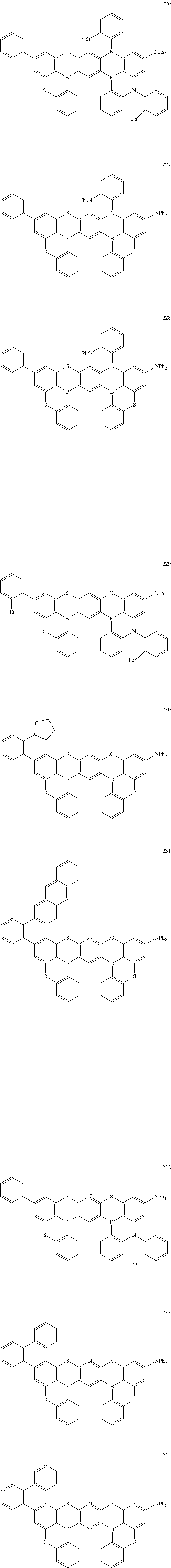 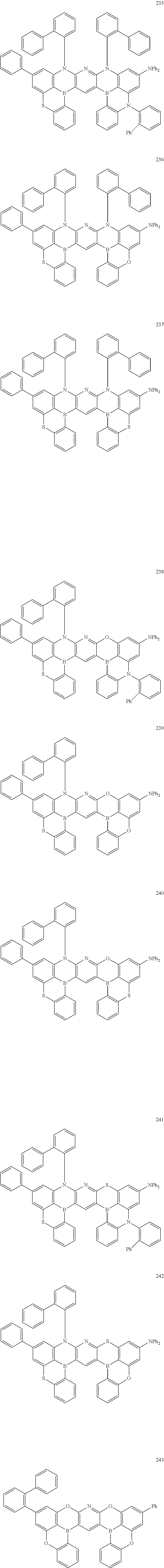 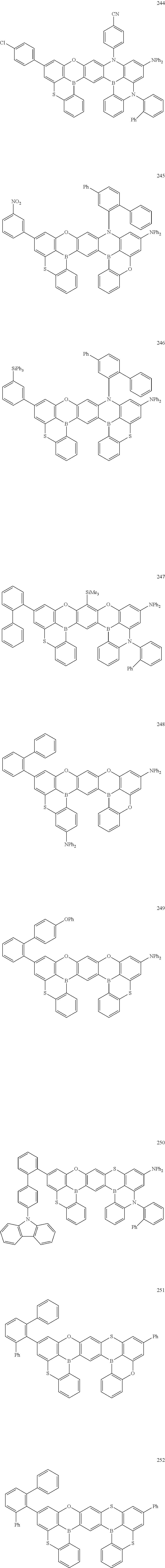 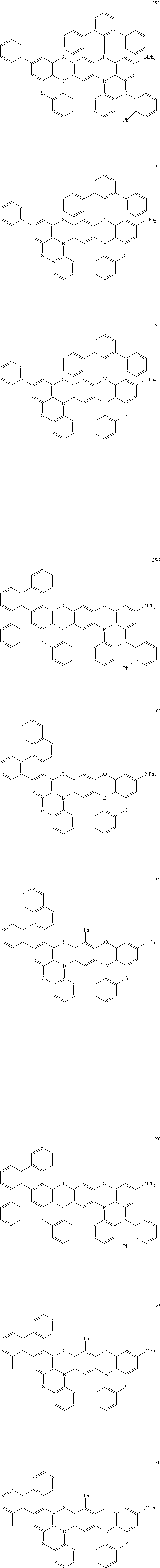 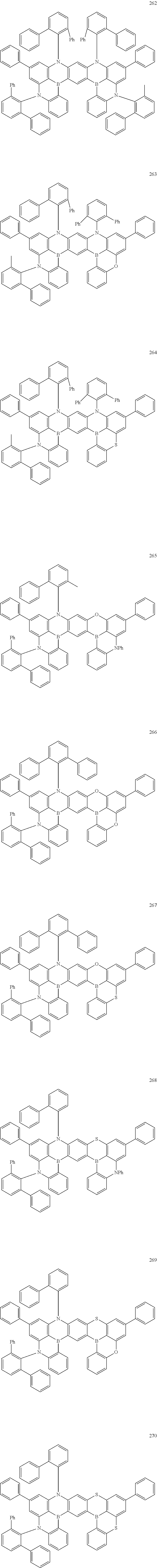 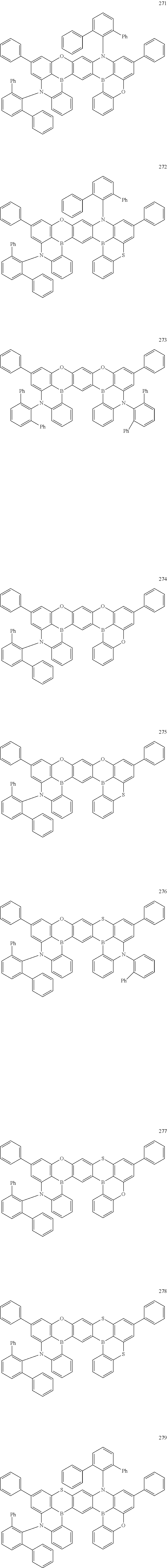 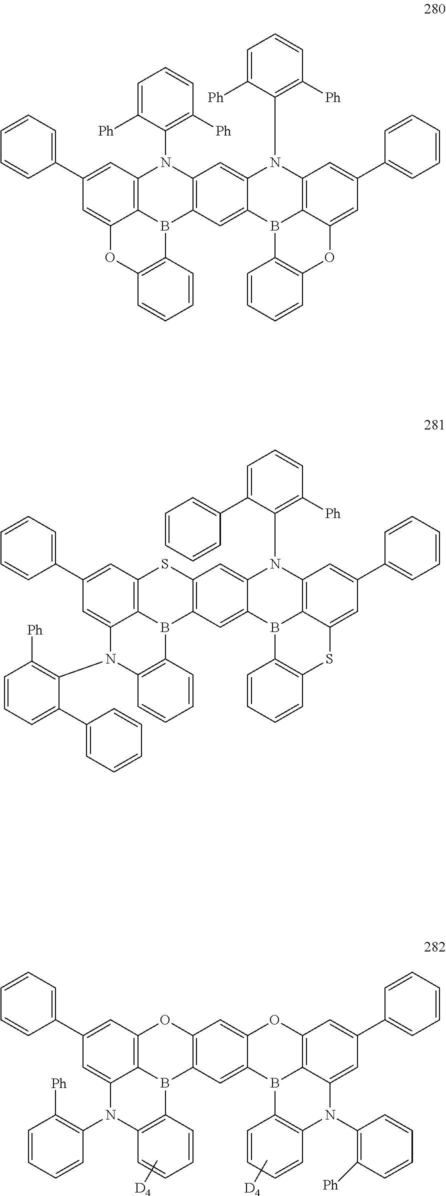 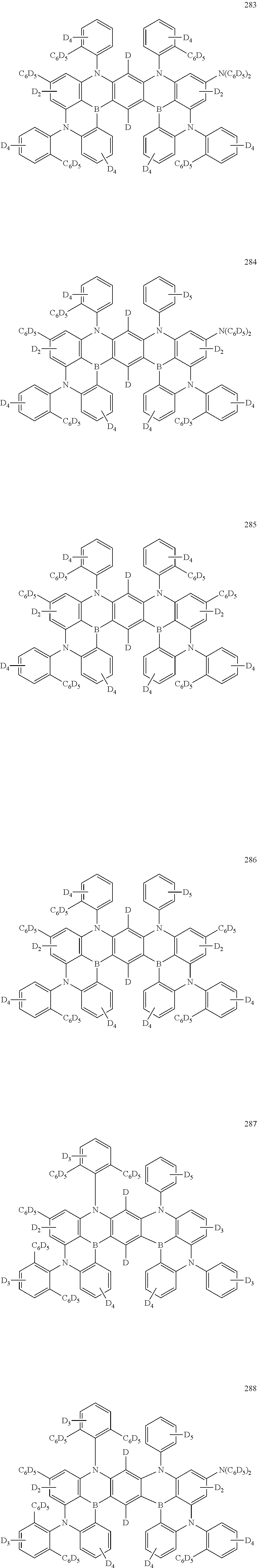 [chemical structure]
